(19) United States
(12) Patent Application Publication
(10) Pub. No.: US 2012/0171618 A1
(43) Pub. Date: Jul. 5, 2012

(54) ACTINIC-RAY- OR RADIATION-SENSITIVE RESIN COMPOSITION AND METHOD OF FORMING A PATTERN USING THE SAME

(75) Inventors: Yusuke IIZUKA, Shizuoka (JP); Hidenori TAKAHASHI, Shizuoka (JP); Michihiro SHIRAKAWA, Shizuoka (JP); Masahiro YOSHIDOME, Shizuoka (JP); Shuji HIRANO, Shizuoka (JP)

(73) Assignee: FUJIFILM CORPORATION, Tokyo (JP)

(21) Appl. No.: 13/421,680

(22) Filed: Mar. 15, 2012

Related U.S. Application Data
(63) Continuation of application No. PCT/JP2010/066624, filed on Sep. 16, 2010.
(60) Provisional application No. 61/265,909, filed on Dec. 2, 2009.

(30) Foreign Application Priority Data
Sep. 18, 2009 (JP) 2009-217366
Dec. 2, 2009 (JP) 2009-274903
Feb. 22, 2010 (JP) 2010-036669

(51) Int. Cl. G03F 7/20; G03F 7/004

(52) U.S. Cl. 430/285.1; 430/270.1; 430/325

(57) ABSTRACT

According to one embodiment, an actinic-ray- or radiation-sensitive resin composition includes a resin containing a repeating unit (A) containing both a structural moiety (S1) that is decomposed by an action of an acid to thereby generate an alkali-soluble group and a structural moiety (S2) that is decomposed by an action of an alkali developer to thereby increase its rate of dissolution into the alkali developer, and a compound that generates an acid when exposed to actinic rays or radiation.

### CROSS REFERENCE TO RELATED APPLICATIONS

This application is a Continuation Application of PCT Application No. PCT/JP2010/066624, filed Sep. 16, 2010 and this application claims the benefit of U.S. Provisional Application No. 61/265,909, filed Dec. 2, 2009 and this application is based upon and claims the benefit of priority from prior Japanese Patent Applications No. 2009-217366, filed Sep. 18, 2009; No. 2009-274903, filed Dec. 2, 2009; and No. 2010-036669, filed Feb. 22, 2010, the entire contents of all of which are incorporated herein by reference.

### BACKGROUND OF THE INVENTION

1. Field of the Invention

The present invention relates to an actinic-ray- or radiation-sensitive resin composition and a method of forming a pattern using the same. More particularly, the present invention relates to a composition that is suitable for use in an ultramicrolithography process applicable to a process for manufacturing a super-LSI or a high-capacity microchip, a process for fabricating a nanoimprint mold, a process for producing a high-density information recording medium, etc. and other photofabrication processes, and relates to a method of forming a pattern using the same. In particular, the present invention is concerned with a composition that is suitable for exposure using a liquid-immersion projection exposure unit in which a far ultraviolet light of wavelength 300 nm or shorter is employed as a light source and with a method of forming a pattern using the same.

In the present invention, the terms “actinic rays” and “radiation” mean, for example, a mercury lamp bright line spectrum, far ultraviolet rays represented by an excimer laser, extreme ultraviolet rays, X-rays, electron beams and the like. In the present invention, the term “light” means actinic rays or radiation.

The expression “exposure” used herein, unless otherwise noted, means not only light irradiation using a mercury lamp, far ultraviolet, X-rays, EUV light, etc. but also lithography using particle beams, such as an electron beam and an ion beam.

2. Description of the Related Art

A chemical amplification resist is a material for forming a pattern capable of, upon exposure to far ultraviolet rays or other radiation, generating an acid at the exposed area. A reaction catalyzed by the generated acid allow the solubility of the exposed area in a developer to be different from that of the non-exposed area. The difference in the solubility between those areas makes it possible to attain pattern formation on a substrate.

In using a KrF excimer laser as an exposure light source, a resin whose fundamental skeleton consists of a poly(hydroxystyrene) exhibiting a low absorption mainly in the region of 248 nm is employed as a major component. Accordingly, favorable pattern with high sensitivity and high resolving power can be formed. Thus, a system superior to the conventional naphthoquinone diazide/novolak resin system has been realized.

On the other hand, in using a light source of a further shorter wavelength, for example, an ArF excimer laser (193 nm) as an exposure light source, the above-mentioned chemical amplification system has not been satisfactory because the compounds having an aromatic group inherently exhibit a sharp absorption in the region around 193 nm.

Therefore, various resists for an ArF excimer laser containing an alicyclic hydrocarbon structure have been developed. However, the current situation is that it is extremely difficult to discover an appropriate combination among an employed resin, a photoacid generator, an additive and a solvent, etc., from the viewpoint of the comprehensive performance of a resist. In particular, in the formation of a nanopattern of 100 nm or less line width, there is a demand for enhancing the line pattern roughness performance and resolving power.

In recent years, it has been discovered that the roughness performance, such as line edge roughness, can be enhanced by introducing a repeating unit containing a specified lactone structure in the above resin having an alicyclic hydrocarbon structure.

For example, patent reference 1 describes a resin containing a repeating unit with a structure in which an acid-decomposable group is bonded to a specified position of a norbornane skeleton and further a resist composition containing the resin. In the reference, it is described that the pattern configuration, exposure margin, etc. can be enhanced by using this composition.

Moreover, patent reference 2 describes a polymeric compound containing a repeating unit with a specified lactone structure having an electron withdrawing group and a resist composition containing the polymeric compound. In the reference, it is described that this polymeric compound excels in the solubility in solvents, hydrolyzability, etc.

However, it is still demanded to strike a good balance between pattern configuration or exposure latitude and development defect performance from the viewpoint of the overall performance of resists. Further, there is a demand for attaining an enhancement with respect to process-permitted focus range (depth of focus) as well.
[Patent reference 1] Japanese Patent No. 4288518, and
[Patent reference 2] Jpn. Pat. Appln. KOKAI Publication No. (hereinafter referred to as JP-A-) 2008-231059.

### BRIEF SUMMARY OF THE INVENTION

It is an object of the present invention to provide an actinic-ray- or radiation-sensitive resin composition that excels in the roughness characteristics, exposure latitude, depth of focus and development defect performance and that ensures the formation of a pattern of favorable configuration. It is another object of the present invention to provide a method of forming a pattern using the composition.

Some aspects of the present invention are as follows.

[1] An actinic-ray- or radiation-sensitive resin composition comprising:

a resin containing a repeating unit (A) containing both a structural moiety (S1) that is decomposed by an action of an acid to thereby generate an alkali-soluble group and a structural moiety (S2) that is decomposed by an action of an alkali developer to thereby increase its rate of dissolution into the alkali developer, and a compound that generates an acid when exposed to actinic rays or radiation.

[2] The composition according to [1], wherein the structural moiety (S2) contains a lactone structure.

[3] The composition according to [2], wherein the structural moiety (S1) is bonded to at least one of the two carbon atoms neighboring the ester group as a constituent of the lactone structure.

[4] The composition according to [3], wherein the repeating unit (A) contains any of the structures of general formula (1) below:

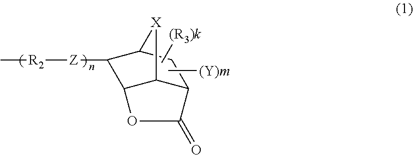

in which

R₂, each independently when n≧2, represents an alkylene group or a cycloalkylene group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the structural moiety (S1);

Z, each independently when n≧2, represents a single bond, an ether bond, an ester bond, an amido bond, a urethane bond or a urea bond;

k is an integer of 0 to 5;

m is an integer of 1 to 5 satisfying a relationship m+k≦6; and

n is an integer of 0 to 5.

[5] The composition according to [4], wherein the repeating unit (A) is any of those of general formula (PL-1) below:

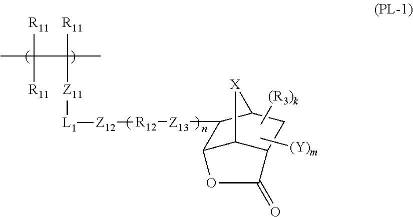

in which

each of R₁₁s independently represents a hydrogen atom, an alkyl group or a halogen atom;

R₁₂, each independently when n≧2, represents an alkylene group or a cycloalkylene group;

L₁ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the structural moiety (S1);

each of Z₁₁ and Z₁₂ independently represents a single bond, —O—, —S—, —CO—, —SO₂—, —NR— (R is a hydrogen atom or an alkyl group), a bivalent nitrogenous nonaromatic heterocyclic group or a group consisting of a combination thereof;

Z₁₃, each independently when n≧2, represents a single bond, —O—, —S—, —CO—, —SO₂—, —NR— (R is a hydrogen atom or an alkyl group), a bivalent nitrogenous nonaromatic heterocyclic group or a group consisting of a combination thereof;

k is an integer of 0 to 5;

m is an integer of 1 to 5 satisfying a relationship m+k≦6; and

n is an integer of 0 to 5.

[6] The composition according to [4], wherein the repeating unit (A) is any of those of general formula (2) below:

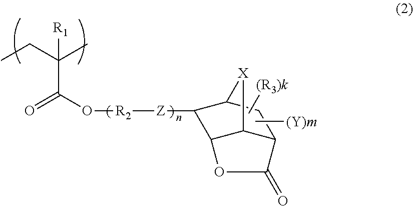

in which

R₁ represents a hydrogen atom, an alkyl group or a halogen atom;

R₂, each independently when n≧2, represents an alkylene group or a cycloalkylene group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the structural moiety (S1);

Z, each independently when n≧2, represents a single bond, an ether bond, an ester bond, an amido bond, a urethane bond or a urea bond;

k is an integer of 0 to 5;

m is an integer of 1 to 5 satisfying a relationship m+k≦6; and

n is an integer of 0 to 5.

[7] The composition according to [6], wherein the repeating unit (A) is any of those of general formula (2A) below:

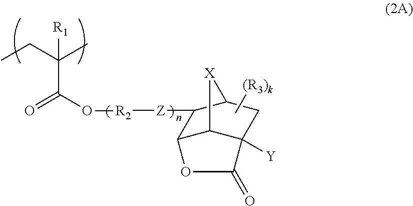

in which

R₁ represents a hydrogen atom, an alkyl group or a halogen atom;

R₂, each independently when n≧2, represents an alkylene group or a cycloalkylene group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the structural moiety (S1);

Z, each independently when n≧2, represents a single bond, an ether bond, an ester bond, an amido bond, a urethane bond or a urea bond;

k is an integer of 0 to 5; and

n is an integer of 0 to 5.

[8] The composition according to [6] or [7], wherein the R₁ is a hydrogen atom or an alkyl group.

[9] The composition according to any of [4] to [8], wherein the Y is any of the groups of formula (Y1) below:

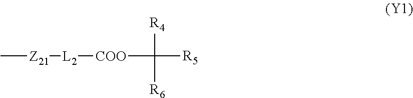

in which

Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;

L₂ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₄ represents an alkyl group; and

each of R₅ and R₆ independently represents an alkyl group or a cycloalkyl group, provided that the R₅ and R₆ may be bonded to each other to thereby form a ring.

[10] The composition according to any of [4] to [8], wherein the Y is any of the groups of formula (Y2) below:

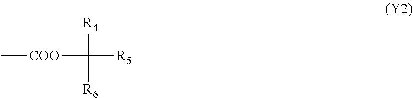

in which

R₄ represents an alkyl group; and

each of R₅ and R₆ independently represents an alkyl group or a cycloalkyl group, provided that the R₅ and R₆ may be bonded to each other to thereby form a ring.

[11] The composition according to any of [4] to [8], wherein the Z is an ester bond.

[12] The composition according to [7], wherein the repeating unit (A) is any of those of general formula (PL-2) below:

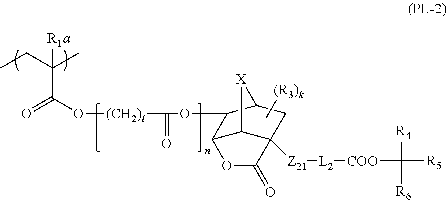

in which

R₁ₐ represents a hydrogen atom or an alkyl group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

k is an integer of 0 to 5;

l is an integer of 1 to 5;

n is an integer of 0 to 5;

Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;

L₂ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₄ represents an alkyl group; and

each of R₅ and R₆ independently represents an alkyl group or a cycloalkyl group, provided that the R₅ and R₆ may be bonded to each other to thereby form a ring.

[13] The composition according to [7], wherein the repeating unit (A) is any of those of general formula (3) below:

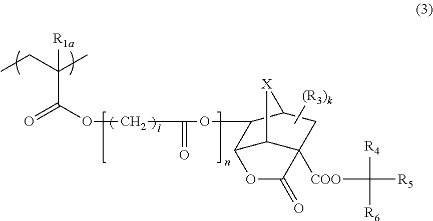

in which

R₁ₐ represents a hydrogen atom or an alkyl group;

R₃, each independently when k≧2, represents an alkyl group or a cycloalkyl group, provided that when k≧2, at least two of the R₃s may be bonded to each other to thereby form a ring;

R₄ represents an alkyl group;

each of R₅ and R₆ independently represents an alkyl group or a cycloalkyl group, provided that the R₅ and R₆ may be bonded to each other to thereby form a ring;

X represents an alkylene group, an oxygen atom or a sulfur atom;

k is an integer of 0 to 5;

l is an integer of 1 to 5; and

n is an integer of 0 to 5.

[14] The composition according to any of [1] to [13], further comprising a hydrophobic resin.

[15] A resist film formed from the composition according to any of [1] to [14].

[16] A method of forming a pattern, comprising: forming the composition according to any of [1] to [14] into a film; exposing the film to light; and developing the exposed film.

[17] The method according to [16], wherein the exposure is performed through a liquid for liquid immersion.

[18] A compound represented by the general formula (3M) below:

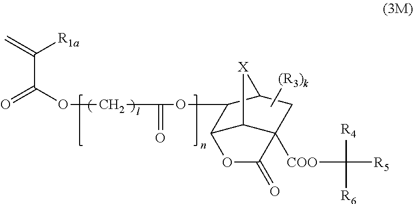

in which

R₁ₐ represents a hydrogen atom or an alkyl group;

R₃, each independently when k≧2, represents an alkyl group or a cycloalkyl group, provided that when k≧2, at least two of the R₃s may be bonded to each other to thereby form a ring;

R₄ represents an alkyl group;

each of R₅ and R₆ independently represents an alkyl group or a cycloalkyl group, provided that the R₅ and R₆ may be bonded to each other to thereby form a ring;

X represents an alkylene group, an oxygen atom or a sulfur atom;

k is an integer of 0 to 5;

l is an integer of 1 to 5; and

n is an integer of 0 to 5.

[19] A compound represented by the general formula (PL-2M) below:

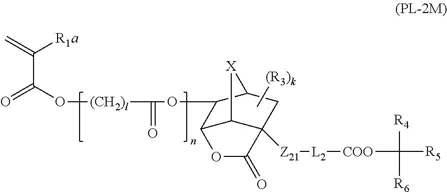

in which

R₁ₐ represents a hydrogen atom or an alkyl group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

k is an integer of 0 to 5;

1 is an integer of 1 to 5;

n is an integer of 0 to 5;

Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;

L₂ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₄ represents an alkyl group; and

each of R₅ and R₆ independently represents an alkyl group or a cycloalkyl group, provided that the R₅ and R₆ may be bonded to each other to thereby form a ring.

The present invention has made it feasible to provide an actinic-ray- or radiation-sensitive resin composition that excels in the roughness characteristics, exposure latitude, depth of focus and development defect performance and that ensures the formation of a pattern of favorable configuration. The present invention has also made it feasible to provide a method of forming a pattern using the composition.

### DETAILED DESCRIPTION OF THE INVENTION

The present invention will be described below.

Note that, with respect to the expression of a group (or an atomic group) used in this specification, the expression without explicitly referring to whether the group is substituted or unsubstituted encompasses not only groups with no substituents but also groups having one or more substituents. For example, the expression “alkyl group” encompasses not only alkyl groups having no substituents (viz. unsubstituted alkyl groups) but also alkyl groups having one or more substituents (viz. substituted alkyl groups).

[1] Resin (P)

The actinic-ray- or radiation-sensitive resin composition of the present invention contains a resin (P) containing a repeating unit (A) containing both a structural moiety (S1) that is decomposed by the action of an acid to thereby generate an alkali-soluble group and a structural moiety (S2) that is decomposed by the action of an alkali developer to thereby increase its rate of dissolution into the alkali developer. The incorporation of this resin in the composition can enhance the roughness characteristics, exposure latitude, depth of focus, development defect performance and pattern configuration.

The structural moiety (S2) introduced in the repeating unit (A) is not particularly limited. For example, it may be one containing an aryl ester structure or a lactone structure. The structural moiety (S2) preferably contains a lactone structure. For example, the adhesion to substrates can be further improved by the employment of the structural moiety (S2) containing a lactone structure.

When the structural moiety (S2) contains a lactone structure, it is preferred for the structural moiety (S1) to be bonded to the ring containing a lactone structure (hereinafter also referred to as a lactone ring) as shown in general formula (4) below. The employment of this structural arrangement can enhance, for example, the hydrolyzability of the resin and the development defect performance of the composition.

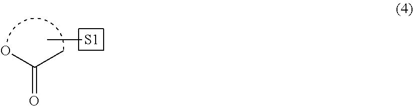

In the formula, S1 represents a group corresponding to the structural moiety (S1). The dashed portion represents an atomic group required for forming a lactone ring in cooperation with the ester group.

When the structural moiety (S2) contains a lactone structure, it is more preferred for the structural moiety (S1) to be bonded to at least one of the two carbon atoms neighboring the ester group as a constituent of the lactone structure. That is, the repeating unit (A) preferably contains the structure of either general formula (4-1) below or general formula (4-2) below. More preferably, the repeating unit (A) contains the structure of general formula (4-1) below.

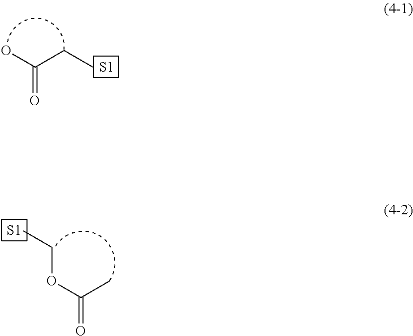

In the formulae, S1 represents a group corresponding to the structural moiety (S1). The dashed portion represents an atomic group required for forming a lactone ring in cooperation with the ester group.

The employment of this structural arrangement can further enhance, for example, the hydrolyzability of the resin and the development defect performance of the composition.

When the structural moiety (S2) contains a lactone structure, it is preferred for the lactone structure to be one having a 5 to 7-membered ring. Another cyclic structure may be condensed with this lactone structure having a 5 to 7-membered ring in a fashion to form a bicyclo structure or Spiro structure.

As lactone structures, those represented by any of general formulae (LC₁₋₁) to (LC₁₋₁₇) below can be exemplified. Of these, more preferred are those of formulae (LC₁₋₁), (LC₁₋₄), (LC₁₋₅), (LC₁₋₆), (LC₁₋₁₃) and (LC₁₋₁₄), and particularly preferred are those of formulae (LC₁₋₄) and (LC₁₋₅).

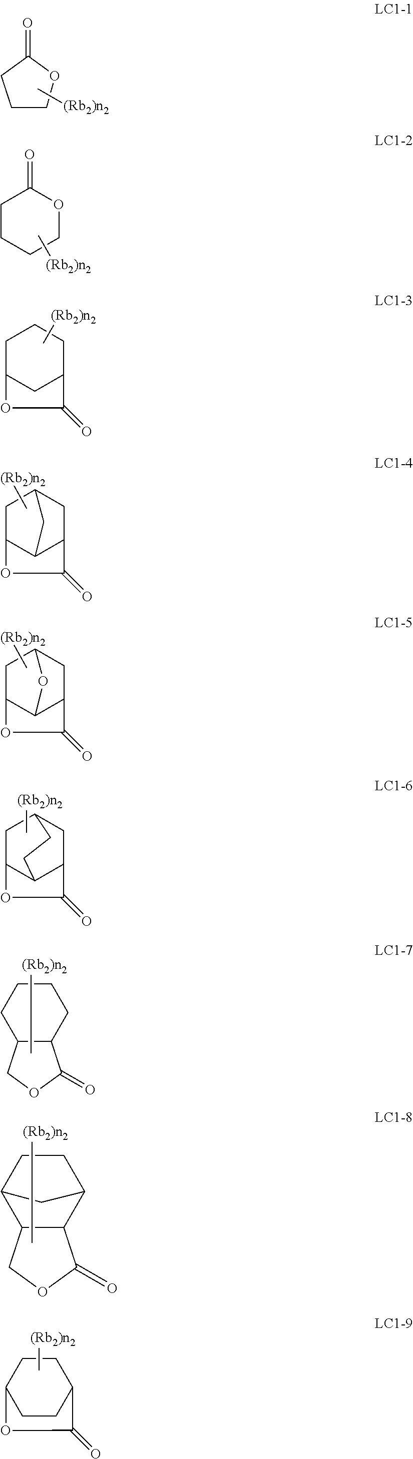

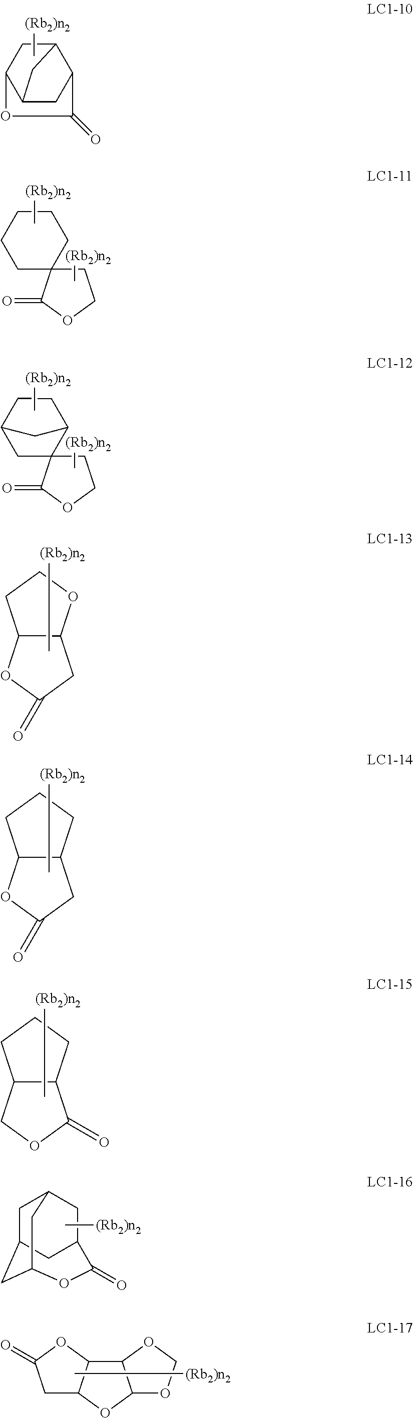

The presence of a substituent Rb₂ on the lactone structure is optional. As a preferred substituent Rb₂, an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxy group, a cyano group, and an acid-decomposable group can be exemplified.

In the formulae, n₂ is an integer of 0 to 4. When n₂ is 2 or greater, the plurality of present substituents Rb₂ may be identical to or different from each other. Further, the plurality of present substituents Rb₂ may be bonded to each other to form a ring.

The repeating unit containing a lactone structure is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity thereof is preferably 90% ee or higher, more preferably 95% ee or higher.

[Repeating Unit (A)]

It is preferred for the repeating unit (A) to contain any of the structures of general formula (1) below:

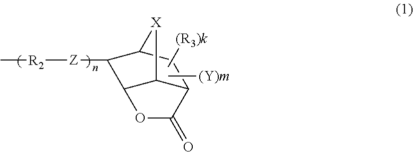

In the general formula (1),

R₂, each independently when n≧2, represents an alkylene group or a cycloalkylene group;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the above-mentioned structural moiety (S1);

Z, each independently when n≧2, represents a single bond, an ether bond, an ester bond, an amido bond, a urethane bond or a urea bond;

k is an integer of 0 to 5;

m is an integer of 1 to 5 satisfying the relationship m+k≦6; and

n is an integer of 0 to 5.

As mentioned above, R₂ is an alkylene group or a cycloalkylene group. Preferably, R₂ is an alkylene group. Each of these alkylene and cycloalkylene groups may further have one or more substituents.

The alkylene group represented by R₂ is preferably one having 1 to 10 carbon atoms, more preferably one having 1 to 5 carbon atoms. As such an alkylene group, there can be mentioned, for example, a methylene group, an ethylene group or a propylene group.

The cycloalkylene group represented by R₂ is preferably one having 3 to 20 carbon atoms. As such a cycloalkylene group, there can be mentioned, for example, a cyclohexylene group, a cyclopentylene group, a norbornylene group or an adamantylene group.

As the substituent that can be introduced in the alkylene group or cycloalkylene group, there can be mentioned, for example, a halogen atom, such as a fluorine atom, a chlorine atom or a bromine atom; a mercapto group; a hydroxyl group; an alkoxy group, such as a methoxy group, an ethoxy group, an isopropoxy group, a t-butoxy or a benzyloxy group; an alkyl group, such as a methyl group, an ethyl group, a propyl group, an isopropyl group, a butyl group, a sec-butyl group, a t-butyl group, a pentyl group or a hexyl group; a cycloalkyl group, such as a cyclopropyl group, a cyclobutyl group, a cyclopentyl group, a cyclohexyl group or a cycloheptyl group; a cyano group; a nitro group; a sulfonyl group; a silyl group; an ester group; an acyl group; a vinyl group; or an aryl group.

As mentioned above, R₃ represents an alkyl group or a cycloalkyl group. Each of these alkyl and cycloalkyl groups may further have one or more substituents.

The alkyl group represented by R₃ preferably has 1 to 30 carbon atoms, more preferably 1 to 15 carbon atoms. The alkyl group represented by R₃ may be linear or branched.

As the linear alkyl group, there can be mentioned, for example, a methyl group, an ethyl group, an n-propyl group, an n-butyl group, an n-pentyl group, an n-hexyl group, an n-octyl group, an n-dodecyl group, an n-tetradecyl group or an n-octadecyl group.

As the branched alkyl group, there can be mentioned, for example, an isopropyl group, an isobutyl group, a t-butyl group, a neopentyl group or a 2-ethylhexyl group.

The cycloalkyl group represented by R₃ may be monocyclic or polycyclic. The carbon atoms of the cycloalkyl group represented by R₃ may be partially substituted with hetero-atoms, such as an oxygen atom.

The cycloalkyl group represented by R₃ preferably has 3 to 20 carbon atoms. As such a cycloalkyl group, there can be mentioned, for example, a cyclopropyl group, a cyclopentyl group, a cyclohexyl group, a norbornyl group or an adamantyl group.

As the substituent that can be introduced in the alkyl group or cycloalkyl group represented by R₃, there can be mentioned, for example, a halogen atom, such as a fluorine atom, a chlorine atom or a bromine atom; a mercapto group; a hydroxyl group; an alkoxy group, such as a methoxy group, an ethoxy group, an isopropoxy group, a t-butoxy or a benzyloxy group; an alkyl group, such as a methyl group, an ethyl group, a propyl group, an isopropyl group, a butyl group, a sec-butyl group, a t-butyl group, a pentyl group or a hexyl group; a cycloalkyl group, such as a cyclopropyl group, a cyclobutyl group, a cyclopentyl group, a cyclohexyl group or a cycloheptyl group; a cyano group; a nitro group; a sulfonyl group; a silyl group; an ester group; an acyl group; a vinyl group; or an aryl group.

When k≧2, at least two of the R₃s may be bonded to each other to thereby form a ring. The group formed by the mutual bonding of at least two of the R₃s is preferably a cycloalkylene group.

As mentioned above, X represents an alkylene group, an oxygen atom or a sulfur atom. The alkylene group may further have one or more substituents.

The alkylene group represented by X preferably has one or two carbon atoms. That is, the alkylene group represented by X is preferably a methylene group or an ethylene group.

As the substituent that can be introduced in the alkylene group represented by X, there can be mentioned, for example, a halogen atom, such as a fluorine atom, a chlorine atom or a bromine atom; a mercapto group; a hydroxyl group; an alkoxy group, such as a methoxy group, an ethoxy group, an isopropoxy group, a t-butoxy or a benzyloxy group; an alkyl group, such as a methyl group, an ethyl group, a propyl group, an isopropyl group, a butyl group, a sec-butyl group, a t-butyl group, a pentyl group or a hexyl group; a cycloalkyl group, such as a cyclopropyl group, a cyclobutyl group, a cyclopentyl group, a cyclohexyl group or a cycloheptyl group; a cyano group; a nitro group; a sulfonyl group; a silyl group; an ester group; an acyl group; a vinyl group; or an aryl group.

Y represents the structural moiety (Sl) that is decomposed by the action of an acid to thereby generate an alkali-soluble group. Namely, Y represents a group that is decomposed by the action of an acid to thereby generate an alkali-soluble group (hereinafter also referred to as an acid-decomposable group).

The acid-decomposable group is preferably a group derived by substituting the hydrogen atom of an alkali-soluble group with a group that is cleaved by the action of an acid.

As the alkali-soluble group, a phenolic hydroxy group, a carboxy group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group can be exemplified.

As preferred alkali-soluble groups, a carboxy group, a fluoroalcohol group, and a sulfonate group can be exemplified. As a fluoroalcohol group, a hexafluoroisopropanol group is particularly preferable.

As a group that is cleaved by the action of an acid, there can be mentioned, for example, a group represented by —C(R₃₆)(R₃₇)(R₃₈), —C(R₃₆)(R₃₇)(OR₃₉) or —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may be bonded to each other to form a ring. Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like. Particularly preferred is a tertiary alkyl ester group.

It is preferred for the acid-decomposable group to contain an alicyclic structure. Namely, it is preferred for the acid-decomposable resin to contain a repeating unit with an acid-decomposable group containing an alicyclic structure. For example, the etching resistance and resolution can be further enhanced by the employment of this structural arrangement. The alicyclic structure that can be introduced in the acid-decomposable group may be monocyclic or polycyclic.

Y is expressed in the form of, for example, -(connecting group)-(group consisting of an alkali-soluble group devoid of a hydrogen atom)-(group cleaved by the action of an acid). Y is preferably expressed by formula (Y1) below:

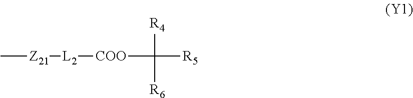

In the formula (Y1),

Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;

L₂ represents a single bond, an alkylene group, an alkenylene group, a cycloalkylene group, a bivalent aromatic ring group or a group consisting of a combination of two or more thereof, provided that in the group consisting of such a combination, the two or more groups combined together may be identical to or different from each other, and provided that these two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₄ represents an alkyl group; and

each of R₅ and R₆ independently represents an alkyl group or a cycloalkyl group, provided that these R₅ and R₆ may be bonded to each other to thereby form a ring.

In the group —NR— represented by Z₂₁, the alkyl group represented by R may be linear or branched. The alkyl group may have one or more substituents. As the alkyl group represented by R, there can be mentioned, for example, an alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is preferred, and an alkyl group having up to 3 carbon atoms is especially preferred. Most preferably, R is a hydrogen atom, a methyl group or an ethyl group.

The expression “bivalent nitrogenous nonaromatic heterocyclic group” means a nonaromatic heterocyclic group, preferably 3 to 8-membered, having at least one nitrogen atom. In particular, there can be mentioned, for example, bivalent connecting groups with the following structures:

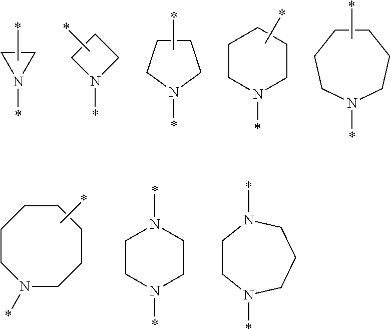

Z₂₁ is preferably a single bond, —O—, —OCO—, —COO—, —OSO₂—, —SO₃—, —CONR— or a group consisting of —CO— combined with a bivalent nitrogenous nonaromatic heterocyclic group. A single bond, —COO—, —SO₃— and —CONR— are more preferred. A single bond and —COO— are most preferred.

The alkylene group represented by L₂ may be linear or branched. The alkylene group is preferably one having 1 to 8 carbon atoms, such as a methylene group, an ethylene group, a propylene group, a butylene group, a hexylene group or an octylene group. The alkylene group represented by L₂ is more preferably an alkylene group having 1 to 6 carbon atoms, most preferably an alkylene group having 1 to 4 carbon atoms.

As the alkenylene group represented by L₂, there can be mentioned a group consisting of each of the above alkylene groups bearing a double bond at an arbitrary position thereof.

The cycloalkylene group represented by L₂ may be monocyclic or polycyclic. The cycloalkylene group is preferably one having 3 to 17 carbon atoms, such as a cyclobutylene group, a cyclopentylene group, a cyclohexylene group, a norbornanylene group, an adamantylene group or a diadamantanylene group. As the cycloalkylene group represented by L₂, a cycloalkylene group having 5 to 12 carbon atoms is more preferred, and a cycloalkylene group having 6 to 10 carbon atoms is most preferred.

As the bivalent aromatic ring group represented by L₂, there can be mentioned an arylene group having 6 to 14 carbon atoms, such as a phenylene group, a tolylene group or a naphthylene group, or a bivalent aromatic ring group containing a hetero-ring, such as thiophene, furan, pyrrole, benzothiophene, benzofuran, benzopyrrole, triazine, imidazole, benzimidazole, triazole, thiadiazole or thiazole. These bivalent aromatic ring groups may each have substituents.

L₂ is preferably a single bond, an alkylene group, a cycloalkylene group, a group consisting of an alkylene group combined with a cycloalkylene group or a group consisting of an alkylene group combined with a bivalent aromatic ring group. A single bond, an alkylene group and a cycloalkylene group are more preferred. A single bond and an alkylene group are most preferred.

The alkyl group represented by R₄ or R₅ may be linear or branched. The alkyl group may have one or more substituents. As the alkyl group represented by R₄ or R₅, there can be mentioned, for example, an alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is preferred, and an alkyl group having up to 3 carbon atoms is especially preferred.

The cycloalkyl group represented by R₅ or R₆ may be monocyclic or polycyclic. As the cycloalkyl group, there can be mentioned, for example, a cyclopropyl group, a cyclopentyl group, a cyclohexyl group, a cycloheptyl group, an adamantyl group, a diadamantyl group, a tetracyclodecanyl group or a tetracyclododecanyl group. A cycloalkyl group having 3 to 20 carbon atoms is preferred, and a cycloalkyl group having 5 to 10 carbon atoms is more preferred.

The ring that can be formed by the mutual bonding of R₅ and R₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅ and R₆ are bonded to each other to thereby form a ring, R₄ is preferably an alkyl group having 1 to 3 carbon atoms, more preferably a methyl group or an ethyl group.

Preferably, Y is any of the groups of formula (Y2) below. Namely, in the above formula, it is preferred for Z₂₁ and L₂ to simultaneously represent a single bond. If so, the glass transition temperature (Tg) of the resin can be increased to thereby enhance, for example, the exposure latitude.

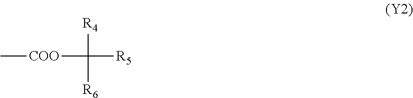

In the formula (Y2), R₄ represents an alkyl group, and each of R₅ and R₆ independently represents an alkyl group or a cycloalkyl group. R₅ and R₆ may be bonded to each other to thereby form a ring. These R₄, R₅ and R₆ are as defined above.

The alkyl group represented by R₄ may be linear or branched. The alkyl group represented by R₄ is preferably one having 1 to 10 carbon atoms, more preferably having 1 to 5 carbon atoms. As such an alkyl group, there can be mentioned, for example, a methyl group, an ethyl group or an isopropyl group.

The alkyl group represented by R₄ may further have one or more substituents. As such a substituent, there can be mentioned, for example, any of those mentioned above as the substituents that can be introduced in the alkyl group represented by R₃.

As mentioned above, each of R₅ and R₆ represents an alkyl group or a cycloalkyl group. Each of these alkyl and cycloalkyl groups may contain an oxygen atom, a sulfur atom or a nitrogen atom in its chain. Further, each of these alkyl and cycloalkyl groups may have one or more substituents.

The alkyl group represented by R₅ or R₆ preferably has 1 to 10 carbon atoms. The alkyl group may be linear or branched. As the linear alkyl group, there can be mentioned, for example, a methyl group, an ethyl group, an n-propyl group, an n-butyl group, an n-pentyl group, an n-hexyl group, an n-octyl group, an n-dodecyl group, an n-tetradecyl group or an n-octadecyl group. As the branched alkyl group, there can be mentioned, for example, an isopropyl group, an isobutyl group, a t-butyl group, a neopentyl group or a 2-ethylhexyl group.

The cycloalkyl group represented by R₅ or R₆ may be monocyclic or polycyclic. The cycloalkyl group preferably has 3 to 10 carbon atoms. As such a cycloalkyl group, there can be mentioned, for example, a cyclopropyl group, a cyclopentyl group, a cyclohexyl group, a cycloheptyl group, an adamantyl group or a diadamantyl group.

It is preferred for either R₅ or R₆ to be an adamantyl group. Namely, it is preferred for the general formula (Y2) to have the structure of formula given below. The formula given below shows the structure in which R₆ is an adamantyl group.

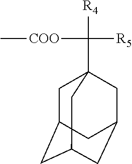

In the formula, R₅ and R₆ are as defined above in connection with the general formula (Y2).

It is also preferable that R₅ and R₆ are bonded to each other to thereby form a ring. This ring has, for example, the structure of formula given below.

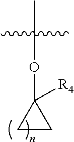

In the formula, R₄ is as defined above in connection with the general formula (Y2).

In the formula, n is an integer of 1 to 5, preferably 3 or 4. That is, it is preferred for the ring formed by the mutual bonding of R₅ and R₆ to be a 5- or 6-membered ring.

Although Y is not particularly limited, specific examples thereof are as follows.

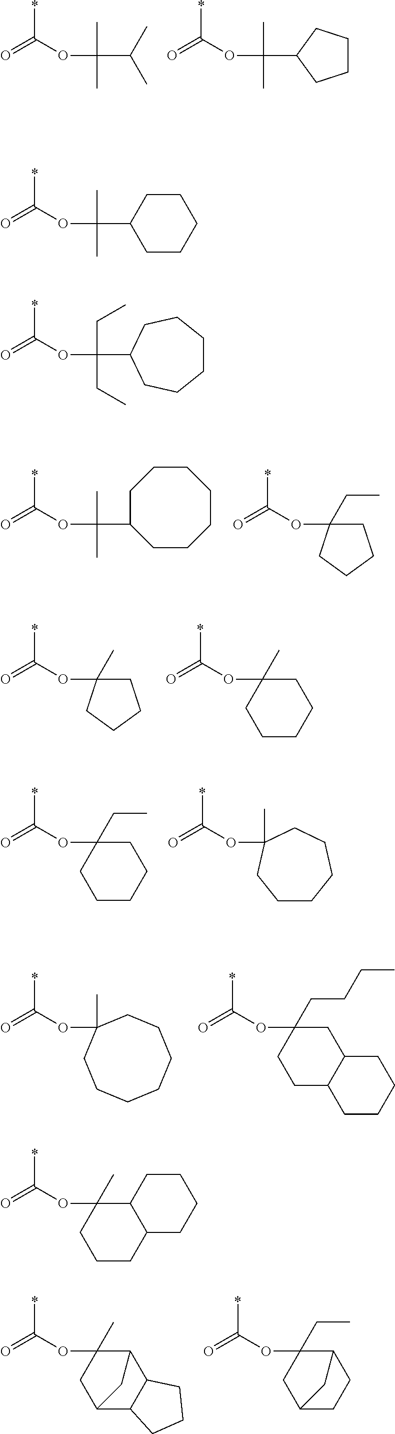

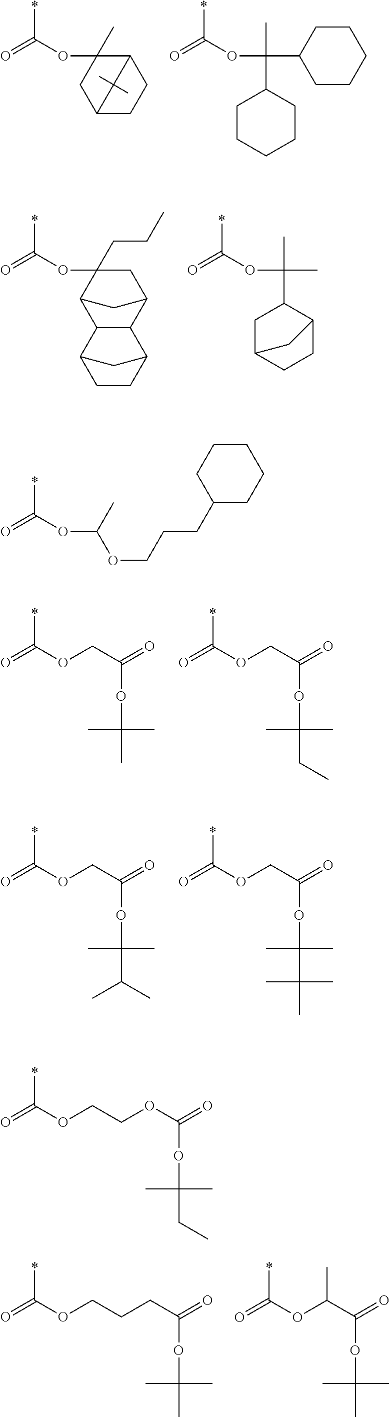

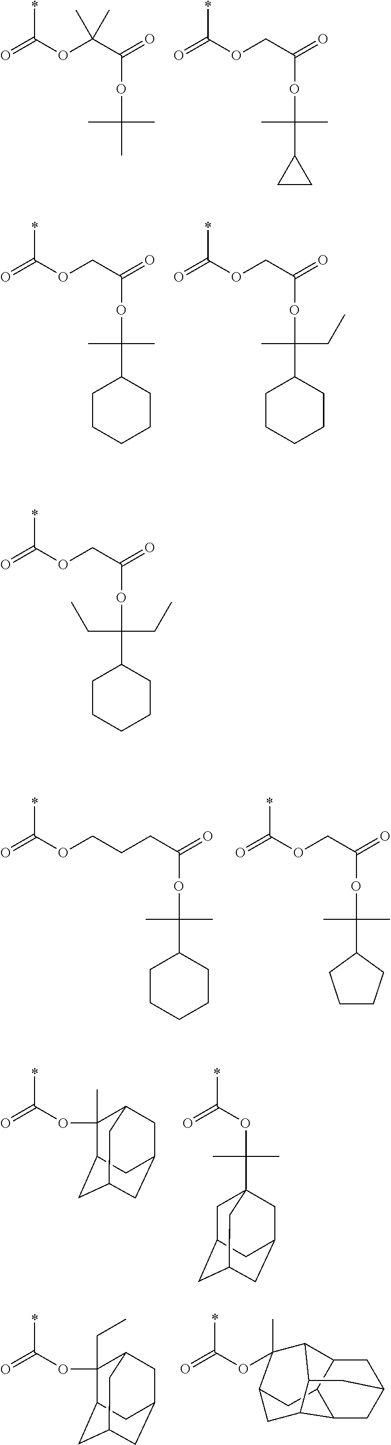

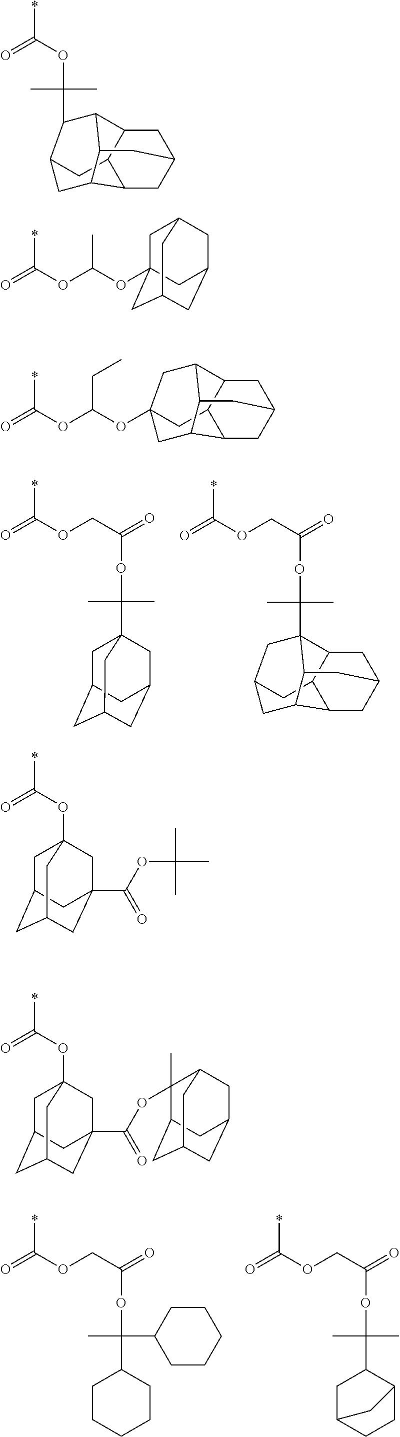

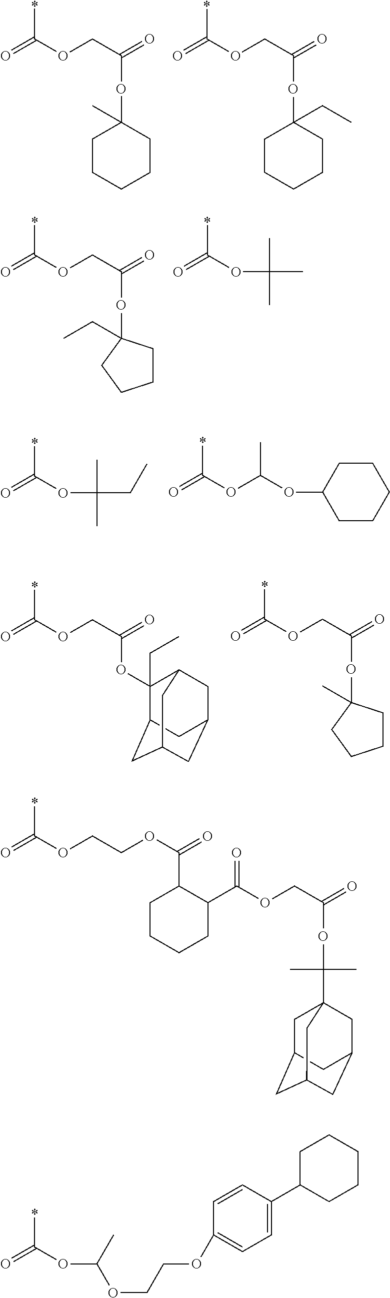

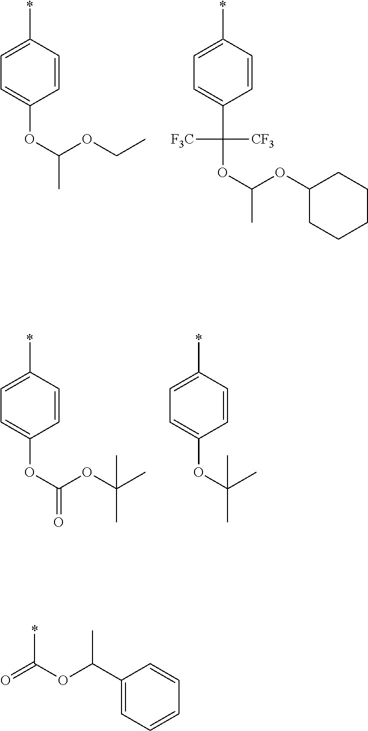

As mentioned above, Z represents a single bond, an ether bond, an ester bond, an amido bond, a urethane bond or a urea bond. Z is preferably a single bond, an ether bond or an ester bond, more preferably an ester bond. Z may be positioned on either the endo-side or the exo-side of the norbornane skeleton.

As mentioned above, k is an integer of 0 to 5. Preferably, k is an integer of 0 to 3.

As mentioned above, m is an integer of 1 to 5 satisfying the relationship m+k≦6. Preferably, m is an integer of 1 to 3, and most preferably, m is 1.

As mentioned above, n is an integer of 0 to 5. Preferably, n is an integer of 0 to 2.

That is, n may be 0, and may be an integer of 1 to 5. In the former case, the glass transition temperature (Tg) of the resin can be increased to thereby enhance, for example, the exposure latitude. In the latter case, the solubility of the resin in developers can be further increased.

It is preferred for the repeating unit (A) to be any of those of general formula (PL-1) below:

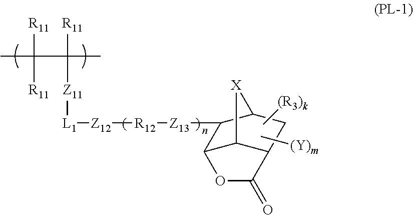

In the general formula (PL-1),

each of R₁₁s independently represents a hydrogen atom, an alkyl group or a halogen atom;

R₁₂, each independently when n∝2, represents an alkylene group or a cycloalkylene group;

L₁ represents a single bond, an alkylene group, an alkenylene group, a cycloalkylene group, a bivalent aromatic ring group or a group consisting of a combination of two or more thereof, provided that in the group consisting of such a combination, the two or more groups combined together may be identical to or different from each other, and provided that these two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;

R₃, each independently when k≧2, represents an alkyl group or a cycloalkyl group, provided that when k≧2, at least two of the R₃s may be bonded to each other to thereby form a ring;

X represents an alkylene group, an oxygen atom or a sulfur atom;

Y, each independently when m≧2, represents the structural moiety (S1);

each of Z₁₁ and Z₁₂ independently represents a single bond, —O—, —S—, —CO—, —SO₂—, —NR— (R is a hydrogen atom or an alkyl group), a bivalent nitrogenous nonaromatic heterocyclic group or a group consisting of a combination thereof;

Z₁₃, each independently when n≧2, represents a single bond, —O—, —S—, —CO—, —SO₂—, —NR— (R is a hydrogen atom or an alkyl group), a bivalent nitrogenous nonaromatic heterocyclic group or a group consisting of a combination thereof;

k is an integer of 0 to 5;

m is an integer of 1 to 5 satisfying the relationship m+k≦6; and

n is an integer of 0 to 5.

The alkyl group represented by R¹¹ in the general formula (PL-1) is preferably one having 1 to 5 carbon atoms, most preferably a methyl group. The alkyl group represented by R₁₁ may further have one or more substituents. As the substituent, there can be mentioned, for example, a halogen atom, a hydroxyl group or an alkoxy group, such as a methoxy group, an ethoxy group, an isopropoxy group, a t-butoxy or a benzyloxy group. Preferably, R₁₁ is a hydrogen atom or an alkyl group. More preferably, R₁₁ is a hydrogen atom, a methyl group, a hydroxymethyl group or a trifluoromethyl group.

As the alkylene group or cycloalkylene group represented by R₁₂ in the general formula (PL-1), there can be mentioned, for example, the same groups as set forth with respect to the R₂ of the general formula (1).

The alkylene group represented by L₁ in the general formula (PL-1) may be linear or branched. The alkylene group is preferably an alkylene group having 1 to 8 carbon atoms, such as a methylene group, an ethylene group, a propylene group, a butylene group, a hexylene group or an octylene group. The alkylene group represented by L₁ is more preferably an alkylene group having 1 to 6 carbon atoms, most preferably an alkylene group having 1 to 4 carbon atoms.

As the alkenylene group represented by L₁, there can be mentioned a group consisting of each of the above alkylene groups bearing a double bond at an arbitrary position thereof.

The cycloalkylene group represented by L₁ may be monocyclic or polycyclic. The cycloalkylene group is preferably one having 3 to 17 carbon atoms, such as a cyclobutylene group, a cyclopentylene group, a cyclohexylene group, a norbornanylene group, an adamantylene group or a diadamantanylene group. As the cycloalkylene group represented by L₁, a cycloalkylene group having 5 to 12 carbon atoms is more preferred, and a cycloalkylene group having 6 to 10 carbon atoms is most preferred.

As the bivalent aromatic ring group represented by L₁, there can be mentioned an arylene group having 6 to 14 carbon atoms, such as a phenylene group, a tolylene group or a naphthylene group, or a bivalent aromatic ring group containing a hetero-ring, such as thiophene, furan, pyrrole, benzothiophene, benzofuran, benzopyrrole, triazine, imidazole, benzimidazole, triazole, thiadiazole or thiazole. These bivalent aromatic ring groups may each have one or more substituents.

L₁ is preferably a single bond, a cycloalkylene group, a group consisting of an alkylene group combined with a cycloalkylene group, a bivalent aromatic ring group, or a group consisting of an alkylene group combined with a bivalent aromatic ring group. A single bond, a cycloalkylene group and a bivalent aromatic ring group are more preferred. A single bond and a cycloalkylene group are most preferred.

In the group —NR— represented by Z₁₁, Z₁₂ or Z₁₃, the alkyl group represented by R may be linear or branched. The alkyl group may have one or more substituents. As the alkyl group represented by R, there can be mentioned, for example, an alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is preferred, and an alkyl group having up to 3 carbon atoms is especially preferred. Most preferably, R is a hydrogen atom, a methyl group or an ethyl group.

The expression “bivalent nitrogenous nonaromatic heterocyclic group” means a nonaromatic heterocyclic group, preferably 3 to 8-membered, having at least one nitrogen atom. In particular, there can be mentioned, for example, the same bivalent connecting groups as mentioned above with respect to Z₂₁.

Z₁₁ is preferably a single bond, —COO—, —COO—, —SO₃—, —CONR— or a group consisting of —CO— combined with a bivalent nitrogenous nonaromatic heterocyclic group. A single bond, —COO—, —CONR— and a group consisting of —CO— combined with a bivalent nitrogenous nonaromatic heterocyclic group are more preferred. —COO— and —CONR— are most preferred.

Each of Z₁₂ and Z₁₃ is preferably a single bond, —O—, —COO—, —COO—, —OSO₂—, —CONR— or —NRCO—. A single bond, —O—, —COO—, —COO— and —CONR— are more preferred. A single bond, —O—, —COO- and —COO— are most preferred.

X, R₃, Y, k, m and n are as defined above in connection with the general formula (1), and preferred examples thereof are also as set forth there.

It is more preferred for the repeating unit (A) to be any of the repeating units of general formula (2) below.

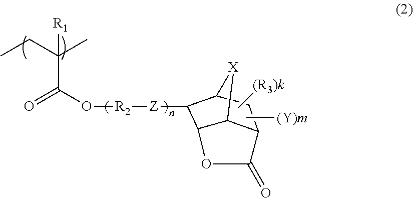

In the general formula (2),

R₁ represents a hydrogen atom, an alkyl group or a halogen atom; and

R₂, R₃, X, Y, Z, k, m, and n are as defined above in connection with the general formula (1).

The alkyl group represented by R₁ is preferably one having 1 to 5 carbon atoms, most preferably a methyl group. The alkyl group represented by R₁ may have one or more substituents. As the substituent, there can be mentioned, for example, a halogen atom, a hydroxyl group or an alkoxy group, such as a methoxy group, an ethoxy group, an isopropoxy group, a t-butoxy or a benzyloxy group. Preferably, R₁ is a hydrogen atom or an alkyl group. More preferably, R₁ is a hydrogen atom, a methyl group, a hydroxymethyl group or a trifluoromethyl group.

Further, it is more preferred for the repeating unit (A) to be any of the repeating units of general formula (2A) below. For example, the hydrolyzability of the lactone can be further enhanced by the employment of this structural arrangement.

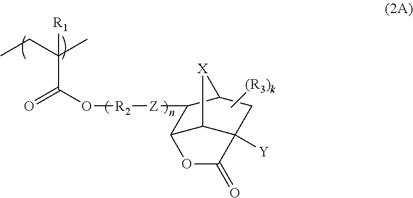

In the general formula (2A), R₁, R₂, R₃, X, Y, Z, k, and n are as defined above in connection with the general formula (1).

It is further more preferred for the repeating unit (A) to be any of the repeating units of general formula (PL-2) below. By the employment of this structural arrangement, the alkali solubility of the resin can be increased to thereby enhance, for example, the roughness characteristics.

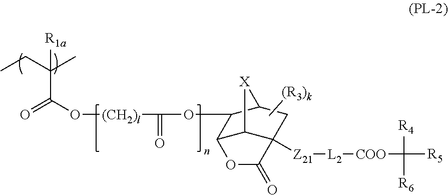

In the general formula (PL-2),

R₁ₐ represents a hydrogen atom or an alkyl group;

R₃, X, k, and n are as defined above in connection with the general formula (1);

l is an integer of 1 to 5 and preferably 1;

Z₂₁, L₂, R₄, R₅ and R₆ are as defined above in connection with the general formula (Y1).

As mentioned above, R₁ₐ represents a hydrogen atom or an alkyl group. The alkyl group represented by R₁ₐ is preferably one having 1 to 5 carbon atoms, most preferably a methyl group. The alkyl group represented by R₁ₐ may further have one or more substituents. As the substituent, there can be mentioned, for example, a halogen atom, a hydroxyl group or an alkoxy group, such as a methoxy group, an ethoxy group, an isopropoxy group, a t-butoxy or a benzyloxy group. Preferably, R₁ₐ is a hydrogen atom, a methyl group, a hydroxymethyl group or a trifluoromethyl group.

It is particularly preferred for the repeating unit (A) to be any of the repeating units of general formula (3) below. Namely, in the general formula (PL-2), it is most preferred for Z₂₁ and L₂ to be simultaneously a single bond. By the employment of this structural arrangement, the alkali solubility and glass transition temperature (Tg) of the resin can be increased to thereby enhance, for example, the exposure latitude and roughness characteristics.

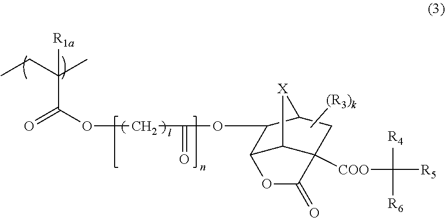

In the general formula (3),

R₁ₐ and l are as defined above in connection with the general formula (PL-2);

R₃, X, k and n are as defined above in connection with the general formula (1);

R₄ to R₆ are as defined above in connection with the general formula (Y2).

When n is a integer of 1 to 5, 1 is preferably 1.

The resin (P) can be obtained by, for example, polymerizing any of the compounds of general formula (3M) below or copolymerizing any of them with another monomer.

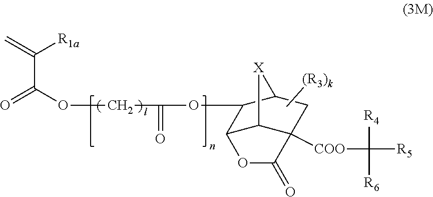

In the general formula (3M), R₁ₐ, R₃, R₄, R₅, R₆, X, k, l and n are as defined above in connection with the general formula (3).

The compounds of the general formula (3M) can be synthesized according to, for example, the following scheme.

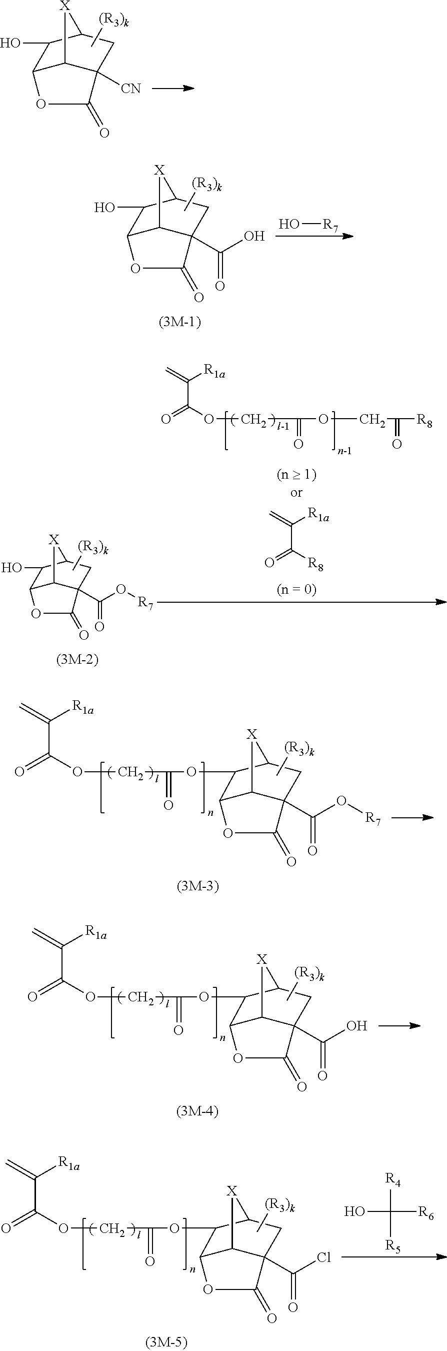

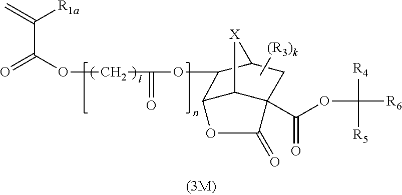

First, the cyanolactones (lactones substituted with one or more cyano groups) of the above formula are hydrolyzed to convert the cyano group to a carboxyl group. Thus, the carboxylic acids of general formula (3M-1) are obtained.

The obtained carboxylic acids of general formula (3M-1) are reacted with alcohols to thereby obtain the compounds of general formula (3M-2).

This reaction is performed by, for example, sequentially or simultaneously incorporating the carboxylic acids of general formula (3M-1), the alcohols, bases and condensing agents in solvents. According to necessity, the reaction system may be cooled or heated.

As the reaction solvents, there can be mentioned, for example, tetrahydrofuran, chloroform, dichloroethane, ethyl acetate and acetonitrile. As the bases, there can be mentioned, for example, 4-dimethylaminopyridine. As the condensing agents, there can be mentioned, for example, N,N′-dicyclohexylcarbodiimide, 1-ethyl-3-(3-dimethylaminopropyl)carbodiimide hydrochloride, N,N′-diisopropylcarbodiimide, N-(tert-butyl)-N′-ethylcarbodiimide and N,N′-di(tert-butyl)carbodiimide.

Subsequently, the alcohol compounds of general formula (3M-2) are reacted with polymerizable moieties to thereby obtain the esters represented by general formula (3M-3). The polymerizable moieties can be easily introduced by routine procedure.

For example, when the polymerizable moieties consist of acid chlorides, such as methacrylic acid chloride and norbornenecarboxylic acid chloride, the above reaction is carried out, for example, in the following manner. Namely, the reaction is carried out by, for example, sequentially or simultaneously incorporating the alcohol compounds of general formula (3M-2), the above acid chlorides and bases in solvents. According to necessity, the reaction system may be cooled or heated.

As the reaction solvents, there can be mentioned, for example, tetrahydrofuran, acetonitrile, ethyl acetate, diisopropyl ether and methyl ethyl ketone. As the bases, there can be mentioned, for example, triethylamine, pyridine and 4-dimethylaminopyridine.

Alternatively, when the polymerizable moieties consist of carboxylic acids, such as methacrylic acid and norbornenecarboxylic acid, the above reaction is carried out, for example, in the following manner. Namely, the reaction is carried out by, for example, heating while mixing the alcohol compounds of general formula (3M-2), the above carboxylic acids and inorganic acids and/or organic acids in solvents. This reaction may be performed while removing water generated by the reaction outside the system.

As the reaction solvents, there can be mentioned, for example, toluene and hexane. As the inorganic acids, there can be mentioned, for example, hydrochloric acid, sulfuric acid, nitric acid and perchloric acid. As the organic acids, there can be mentioned, for example, p-toluenesulfonic acid and benzenesulfonic acid.

Subsequently, the obtained esters of general formula (3M-3) are hydrolyzed. Thus, the carboxylic acids of general formula (3M-4) are obtained.

This hydrolyzing reaction is carried out by, for example, sequentially or simultaneously incorporating the esters of general formula (3M-3) and bases in solvents. According to necessity, the reaction system may be cooled or heated.

As the reaction solvents, there can be mentioned, for example, acetone, tetrahydrofuran, acetonitrile and water. As the bases, there can be mentioned, for example, sodium hydroxide and potassium carbonate.

Thereafter, the acid moieties of the carboxylic acids of general formula (3M-4) are converted to acid chlorides, thereby obtaining the acid chlorides of general formula (3M-5). This reaction is carried out by, for example, sequentially or simultaneously incorporating the carboxylic acids of general formula (3M-4) and thionyl chloride. According to necessity, the reaction system may be cooled or heated. Further, a solvent, such as benzene or dichloromethane, and/or a catalyst, such as dimethylformamide, hexamethylphosphoric acid triamide or pyridine, may be added thereto.

Finally, the acid chlorides of general formula (3M-5) are reacted with corresponding alcohols, thereby obtaining the compounds of general formula (3M). This reaction between acid chloride and alcohol can be performed in the same manner as in the aforementioned synthesis of the compounds of general formula (3M-3).

Also, the resin (P) may be produced by polymerizing any of the compounds of general formula (PL-2M) below or copolymerizing any of the compounds with another monomer. The compounds can be synthesized, for example, in the same manner as described above for the compounds of general formula (3M).

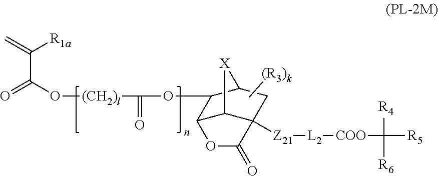

In the general formula (PL-2M), R₁ₐ, R₃, X, k, l, n, Z₂₁, L₂, R₄, R₅ and R₆ are as defined above in connection with the general formula (PL-2).

The content of repeating unit (A) based on all the repeating units of the resin (P) is preferably in the range of 15 to 100 mol %, more preferably 20 to 100 mol % and further more preferably 30 to 100 mol %.

As the repeating units (A) with a lactone structure of the general formula (1), there can be mentioned, for example, a (meth)acrylic ester derivative, a (meth)acrylamide derivative, a vinyl ether derivative, an olefin derivative and a styrene derivative each having any of the structures of the general formula (1). It is preferred for the repeating unit (A) to consist of a (meth)acrylic ester derivative having any of the structures of the general formula (1).

Specific examples of the repeating units (A) with a lactone structure of the general formula (1) will be shown below. In the specific examples, R₁ represents a hydrogen atom, an optionally substituted alkyl group or a halogen atom. Preferably, R₁ is a hydrogen atom, a methyl group, a hydroxymethyl group, a trifluoromethyl group or a halogen atom.

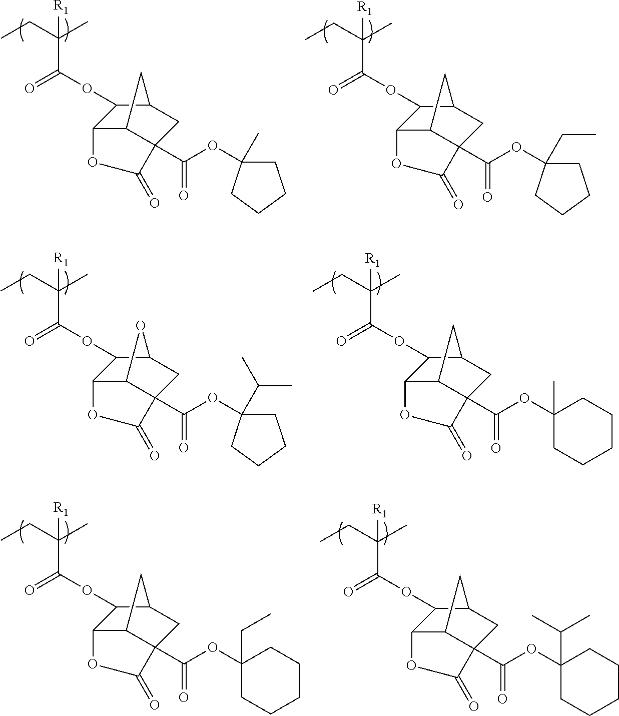

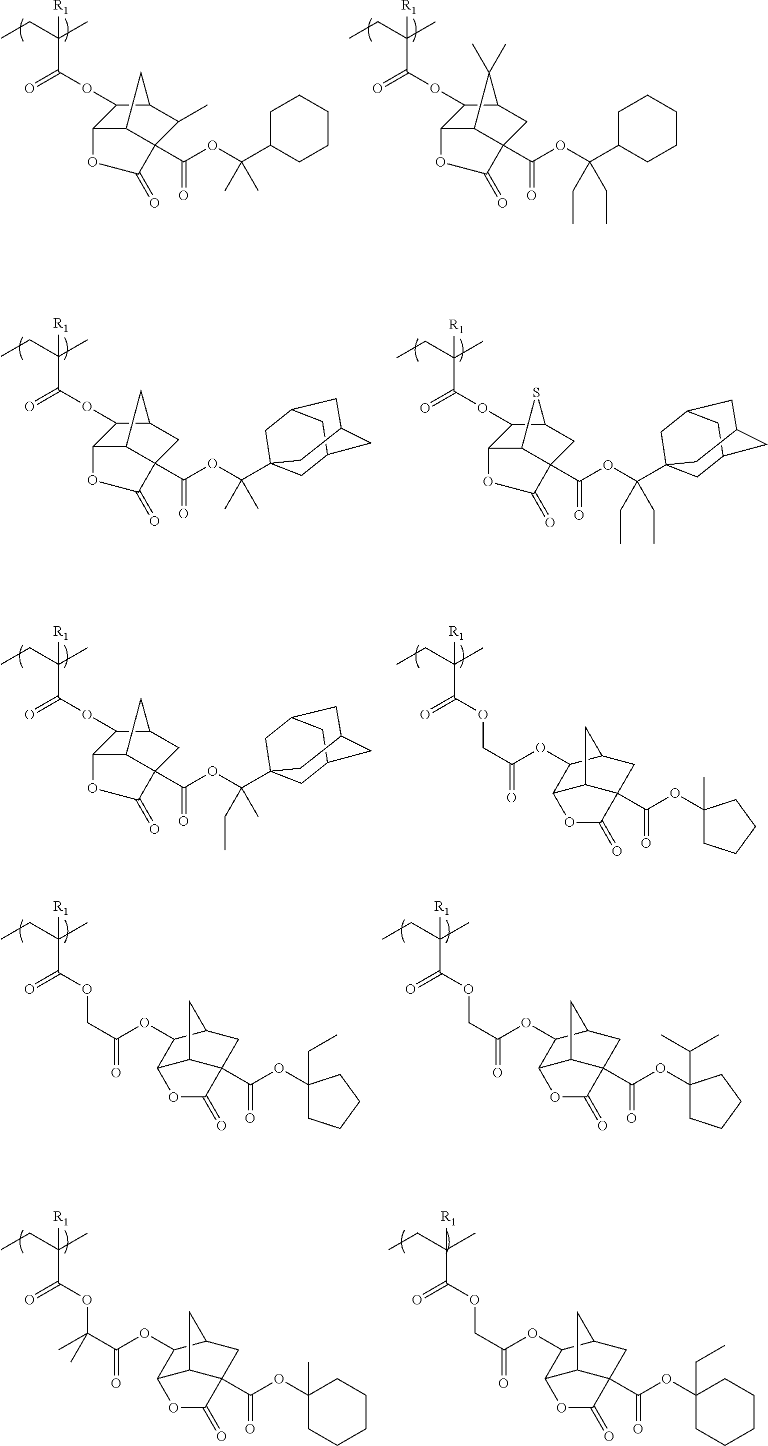

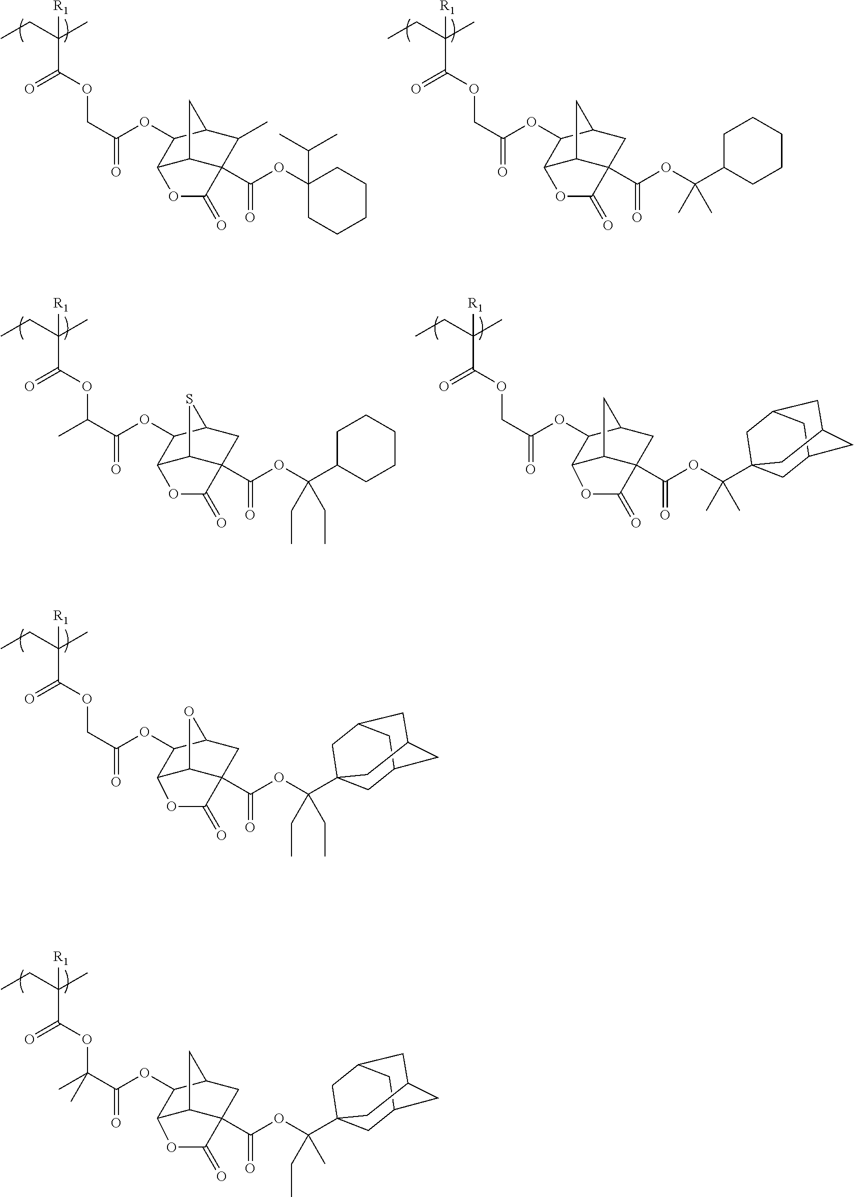

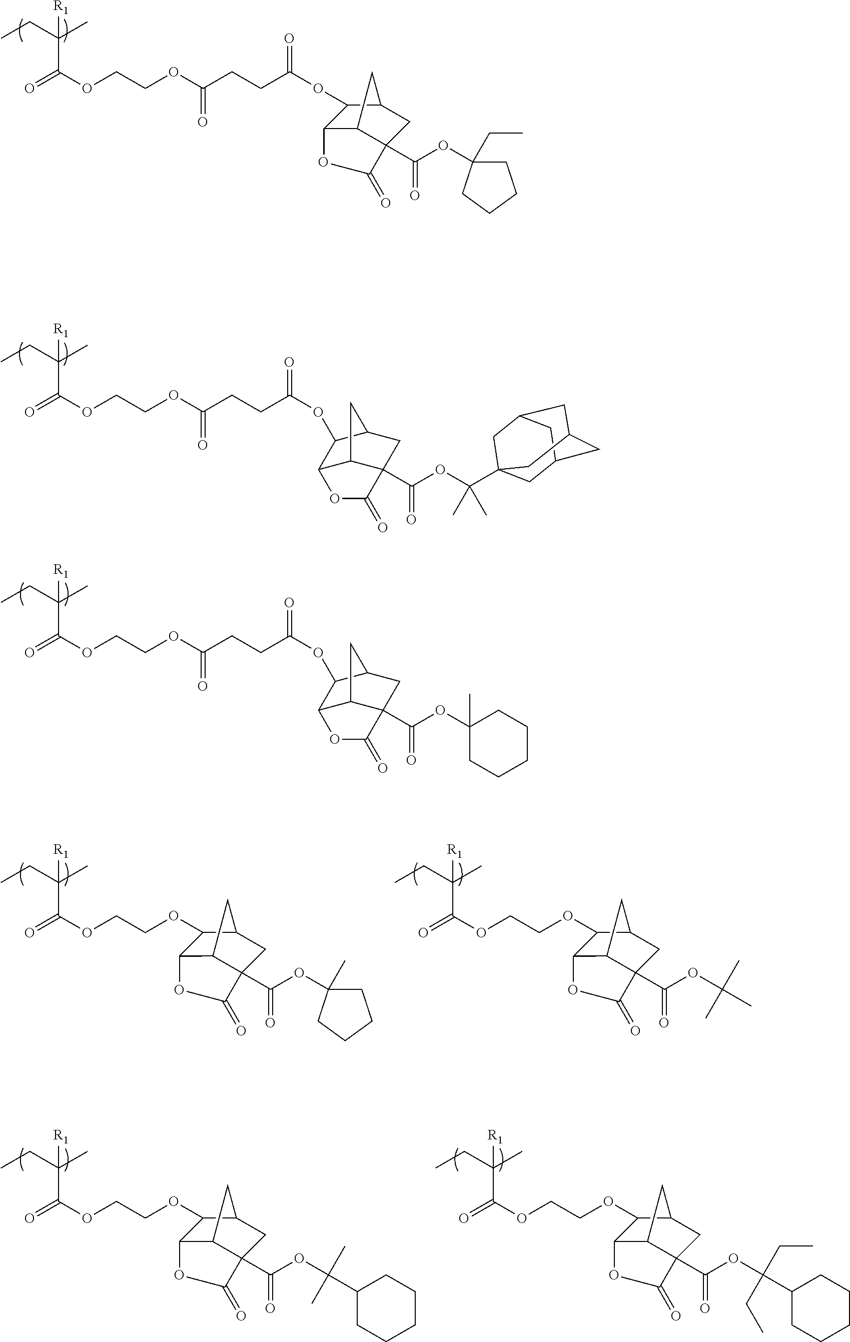

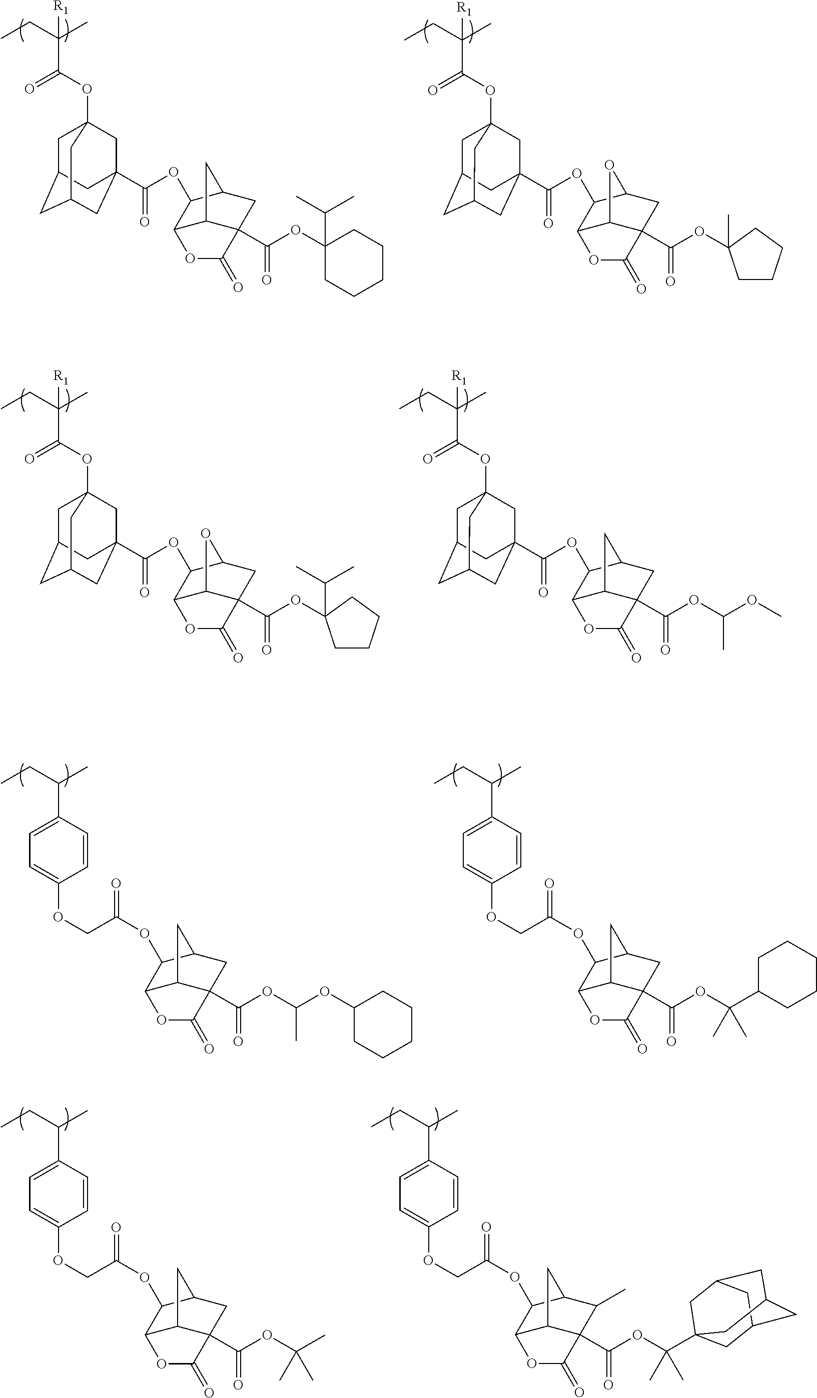

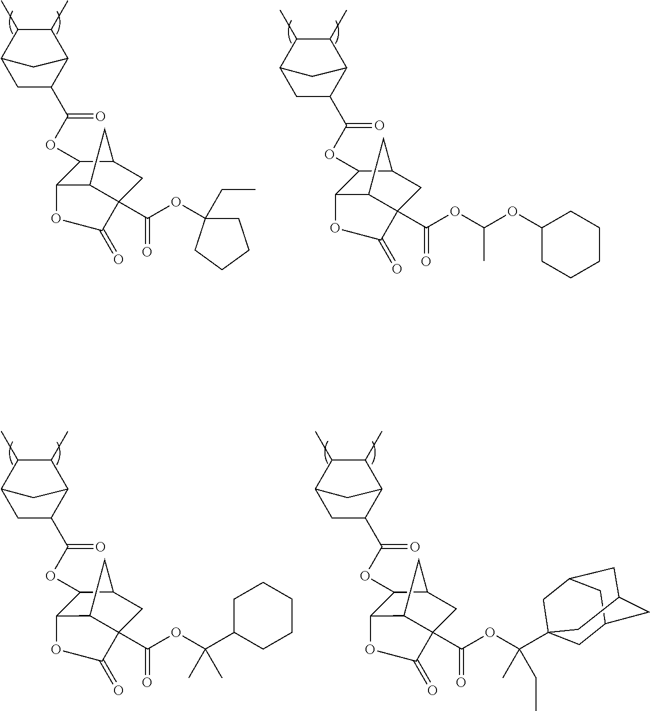

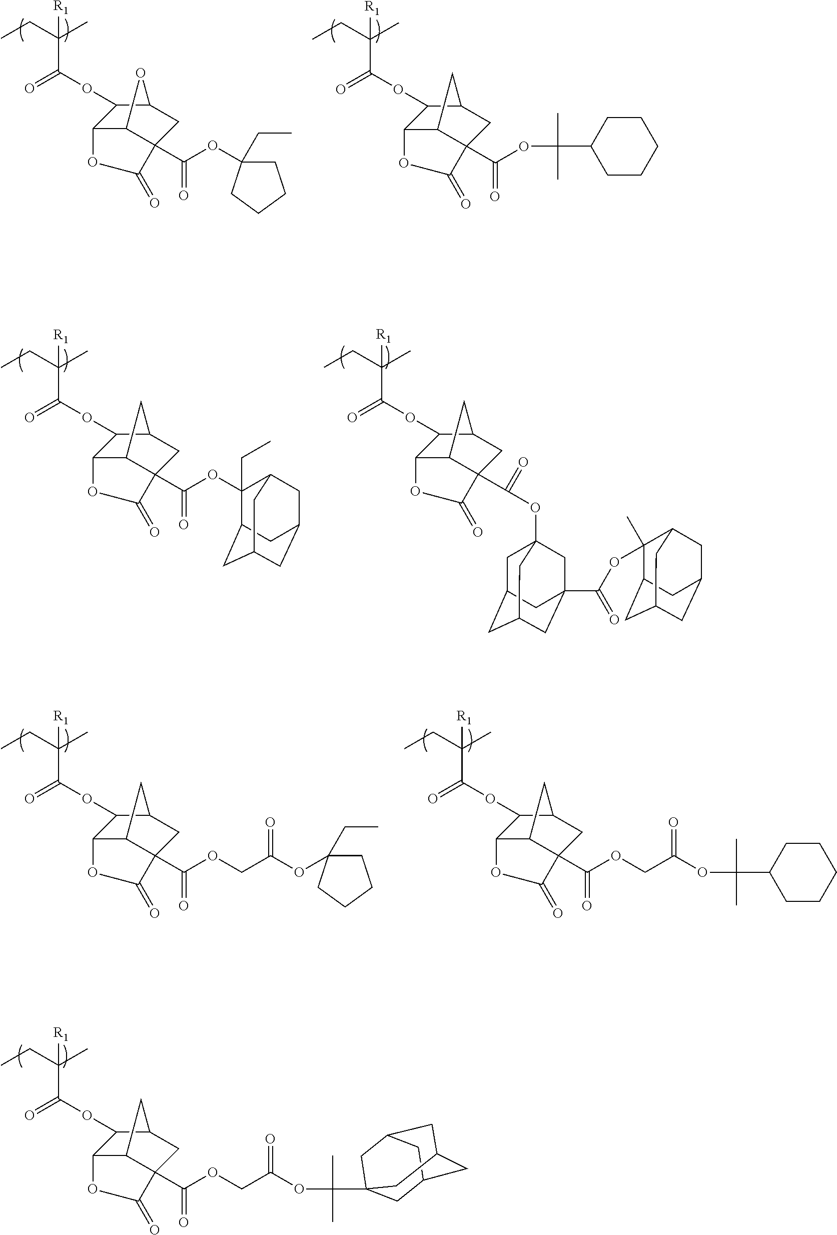

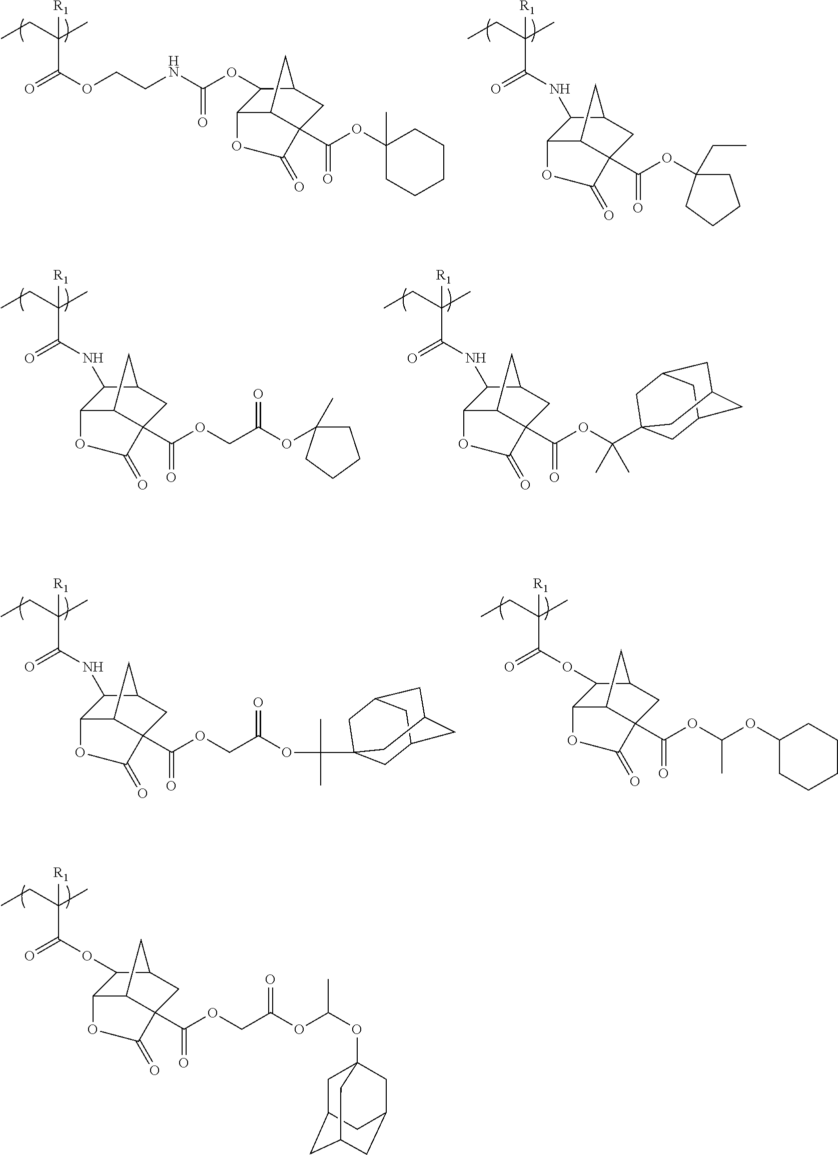

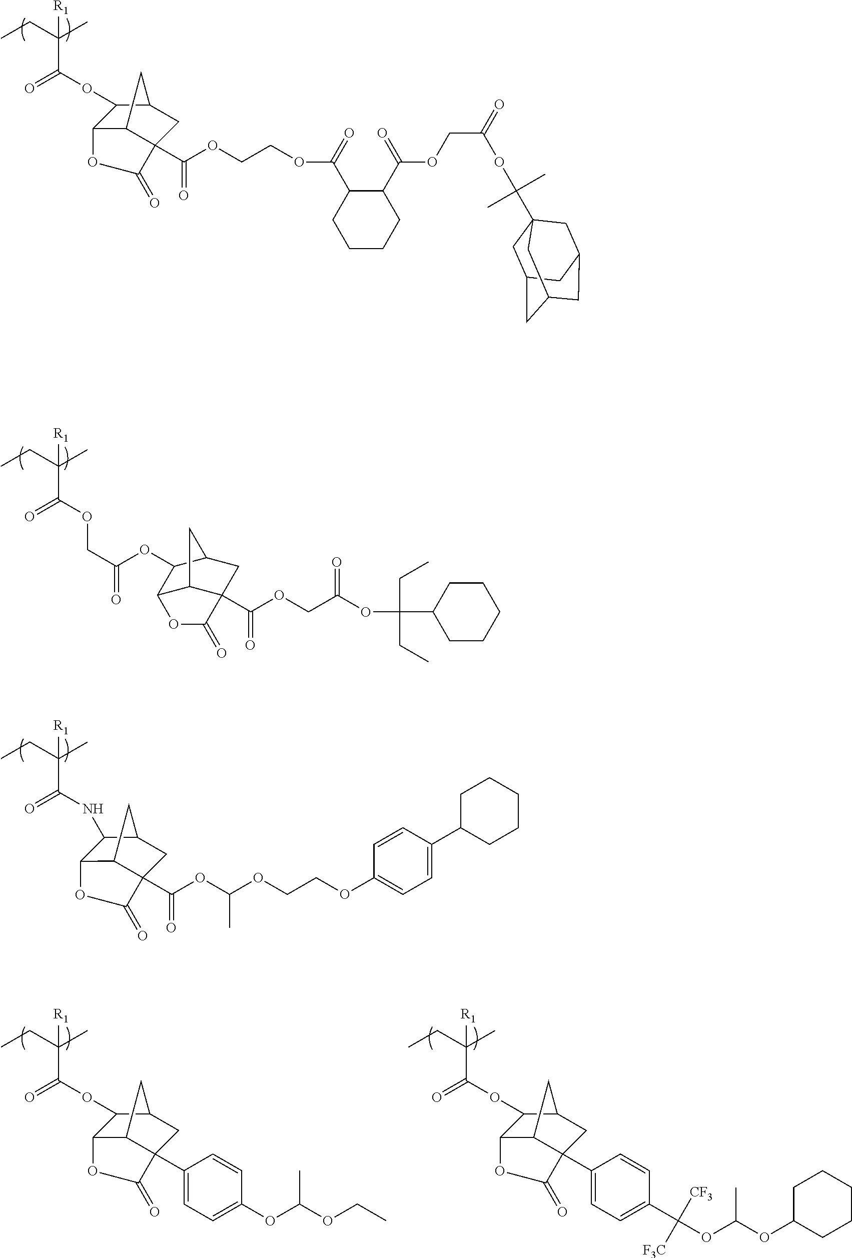

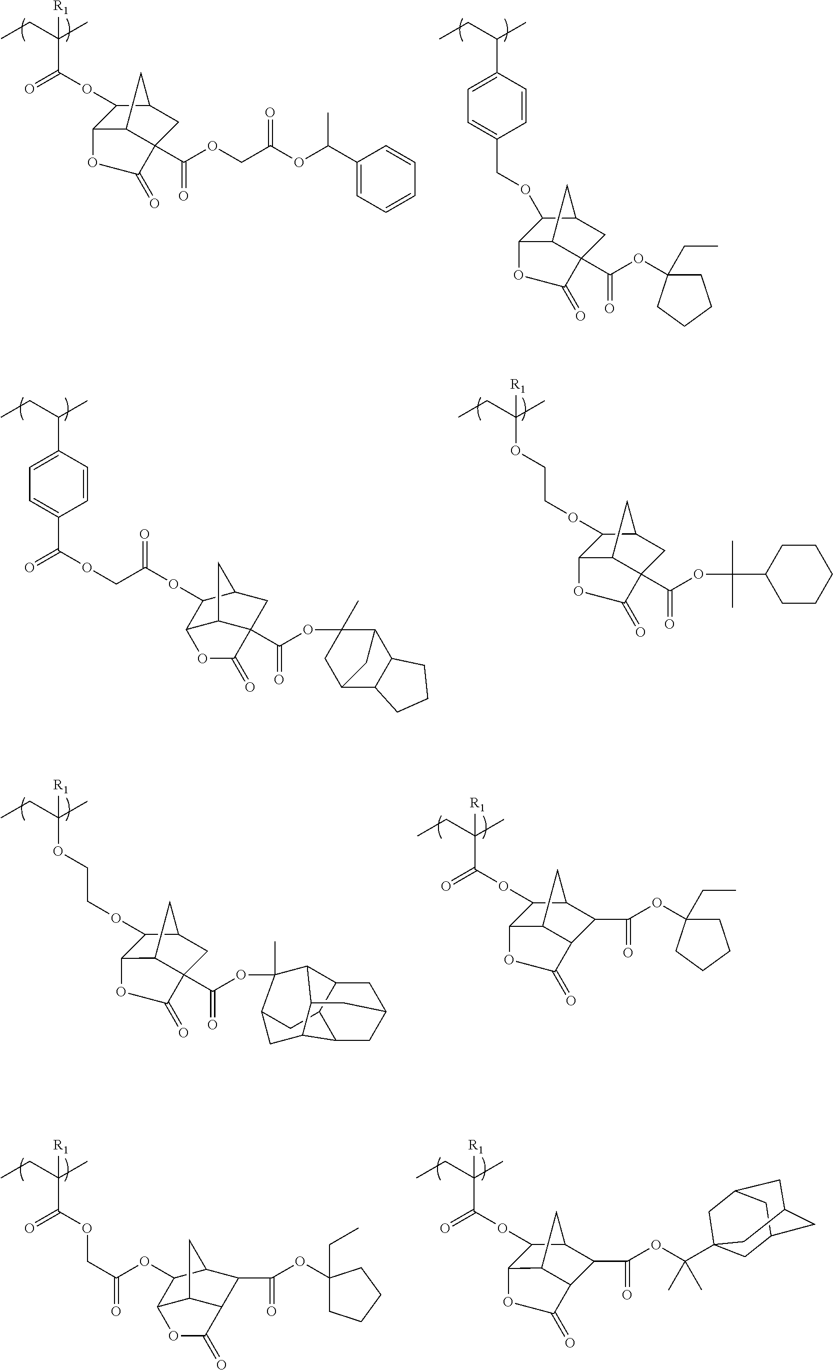

Specific examples of repeating units (A) other than the repeating units with a lactone structure of the general formula (1) will be shown below. In the specific examples, R₁ represents a hydrogen atom, an optionally substituted alkyl group or a halogen atom. Preferably, R₁ is a hydrogen atom, a methyl group, a hydroxymethyl group, a trifluoromethyl group or a halogen atom.

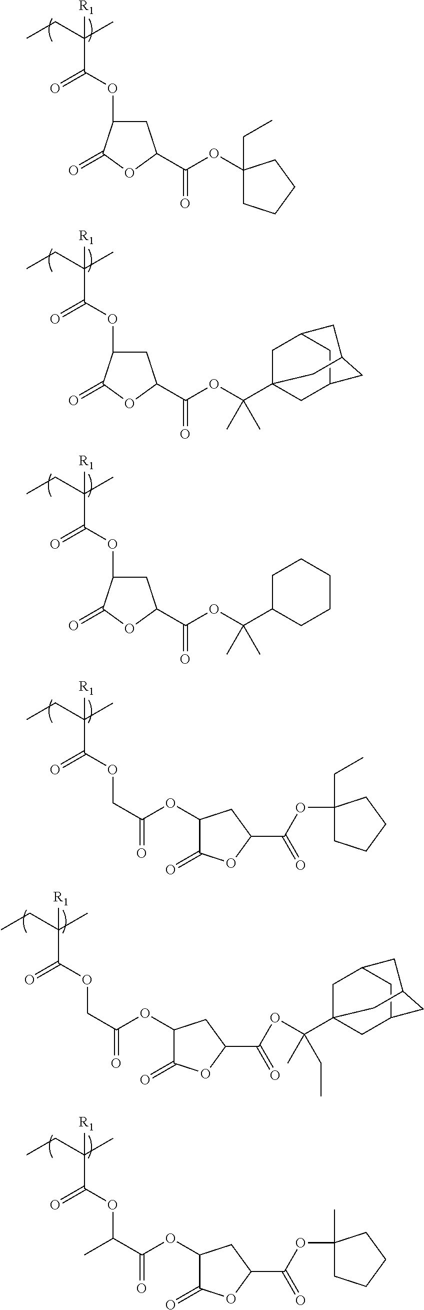

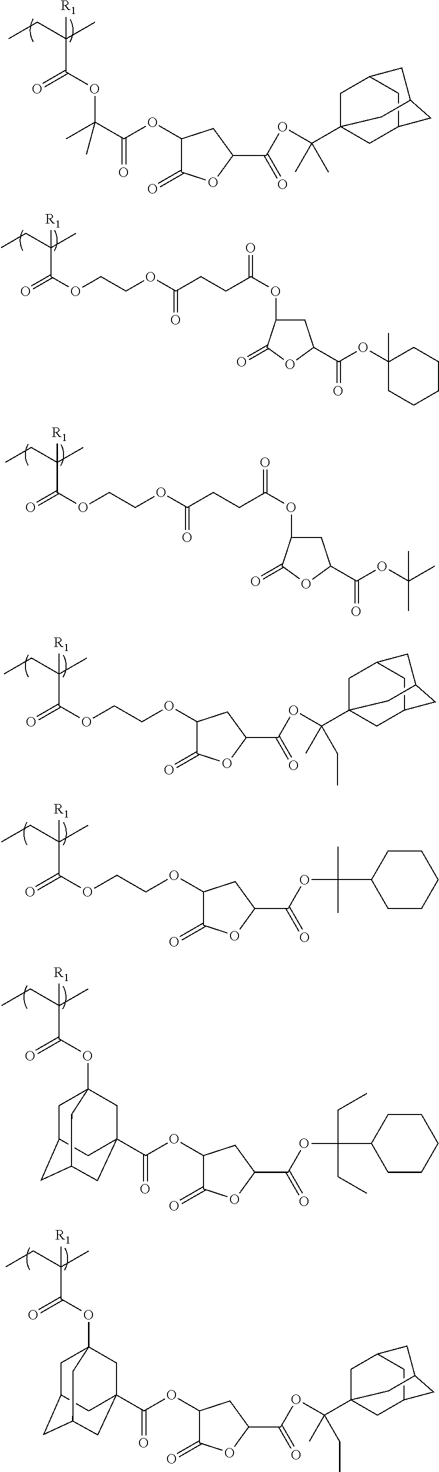

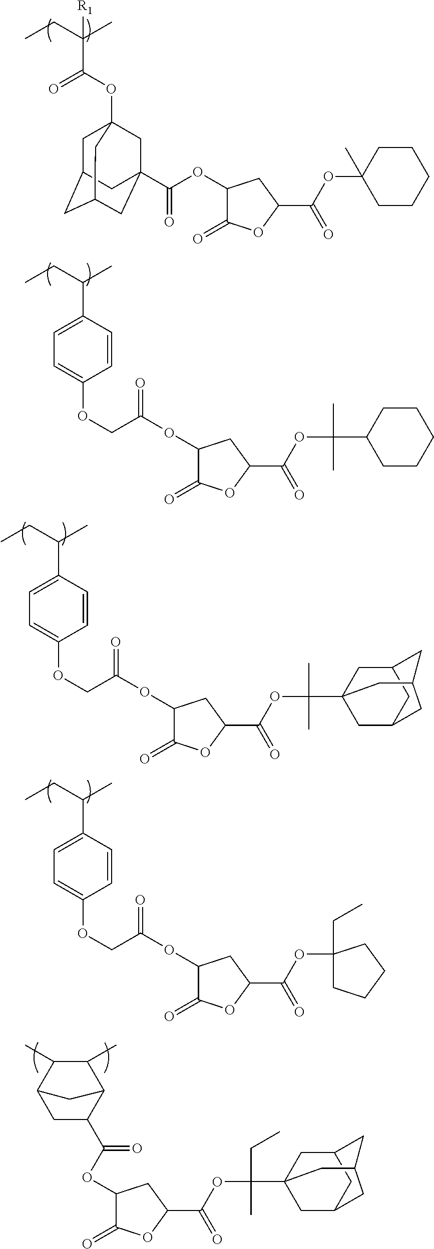

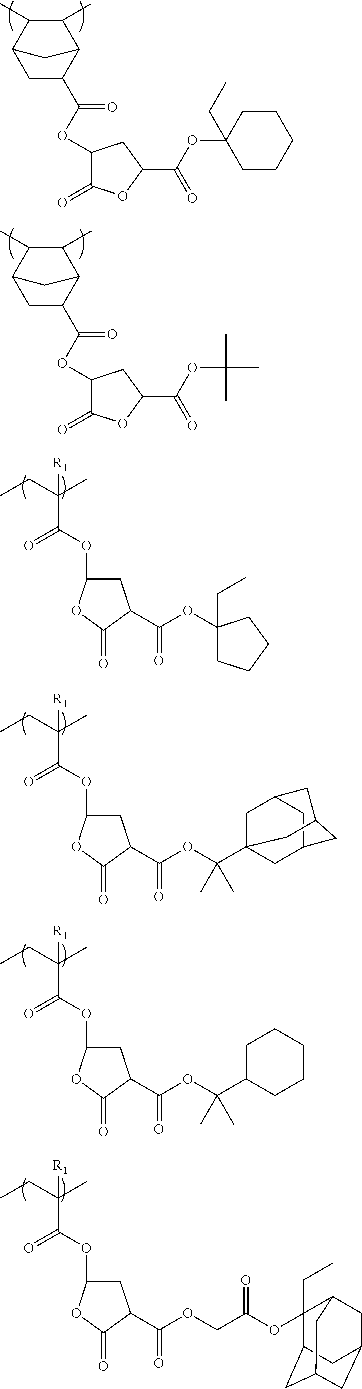

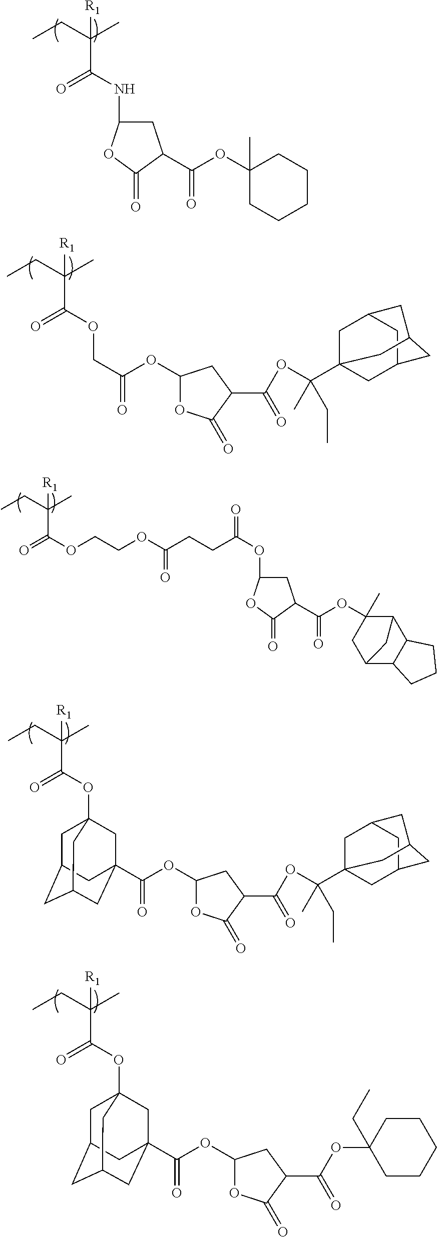

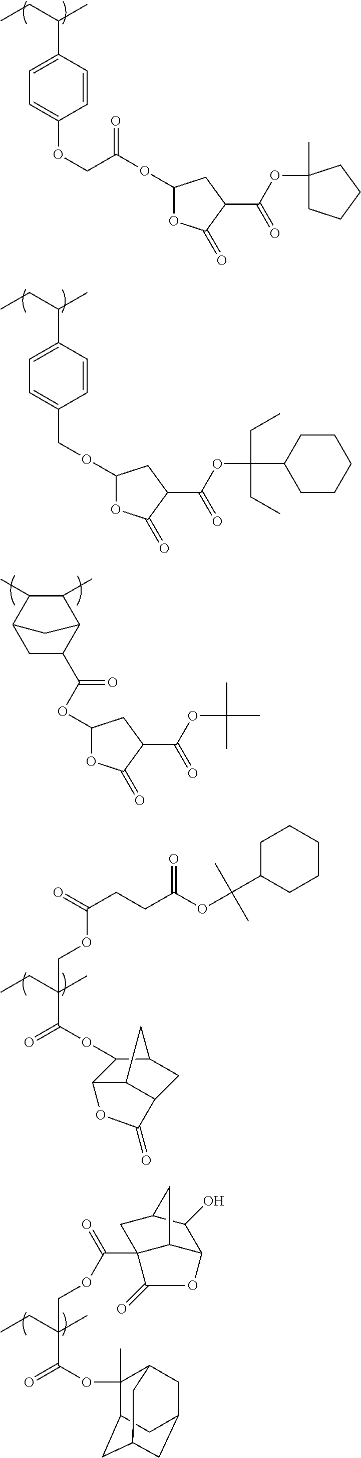

[Repeating Unit (B)]

The resin (P) may contain a repeating unit (B), different from the above repeating units (A), that is decomposed by the action of an acid to thereby generate an alkali-soluble group (hereinafter may be referred to as “repeating unit containing an acid-decomposable group”).

As the alkali-soluble group, a phenolic hydroxy group, a carboxy group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group can be exemplified.

As preferred alkali-soluble groups, a carboxy group, a fluoroalcohol group (preferably hexafluoroisopropanol) and a sulfonate group can be exemplified.

The acid-decomposable group is preferably a group as obtained by substituting the hydrogen atom of any of these alkali-soluble groups with an acid-eliminable group.

As the acid-eliminable group, groups represented by —C(R₃₆)(R₃₇)(R₃₈), —C(R₃₆)(R₃₇)(OR₃₉) and —C(R₀₁)(R₀₂)(OR₃₉) can be exemplified.

In the formulae, each of R₃₆ to R₃₉ independently represents an alkyl group, a cycloalkyl group, an aryl group, an aralkyl group or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like. Particularly preferred is a tertiary alkyl ester group.

As the repeating unit (B), those represented by general formula (V) are more preferable.

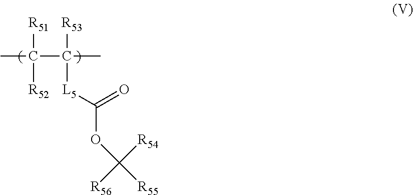

In the general formula (V), each of R₅₁, R₅₂ and R₅₃ independently represents a hydrogen atom, an alkyl group, a cycloalkyl group, a halogen atom, a cyano group or an alkoxycarbonyl group. R₅₂ may be bonded to L₅ to thereby form a ring (preferably, a 5-membered or 6-membered ring). If so, R₅₂ represents an alkylene group.

L₅ represents a single bond or a bivalent connecting group. When a ring is formed in cooperation with R₅₂, L₅ represents a trivalent connecting group.

R₅₄ represents an alkyl group. Each of R₅₅ and R₅₆ independently represents a hydrogen atom, an alkyl group, a cycloalkyl group or a monovalent aromatic ring group. R₅₅ and R₅₆ may be bonded to each other to thereby form a ring. However, R₅₅ and R₅₆ do not simultaneously represent a hydrogen atom.

More detailed description on the general formula (V) will be presented below.

As a preferred alkyl group represented by each of R₅₁ to R₅₃ in the general formula (V), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred, and an alkyl group having up to 3 carbon atoms is most preferred.

The alkyl group contained in the alkoxycarbonyl group is preferably the same as that represented by each of R₅₁ to R₅₃.

The cycloalkyl group may be monocyclic or polycyclic. The cycloalkyl group is preferably an optionally substituted monocyclic cycloalkyl group, having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is especially preferred.

As preferred substituents that can be introduced in these groups, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group and the like. Preferably, the number of carbon atoms of each of the substituents is up to 8.

When R₅₂ is an alkylene group and forms a ring in cooperation with L₅, the alkylene group is preferably an alkylene group having 1 to 8 carbon atoms, such as a methylene group, an ethylene group, a propylene group, a butylene group, a hexylene group or an octylene group. An alkylene group having 1 to 4 carbon atoms is more preferred, and an alkylene group having 1 or 2 carbon atoms is especially preferred.

In the formula (V), each of R₅₁ and R₅₃ is more preferably a hydrogen atom, an alkyl group or a halogen atom, most preferably a hydrogen atom, a methyl group, an ethyl group, a trifluoromethyl group (—CF₃), a hydroxymethyl group (—CH₂—OH), a chloromethyl group (—CH₂—Cl) or a fluorine atom (—F). R₅₂ is more preferably a hydrogen atom, an alkyl group, a halogen atom or an alkylene group (forming a ring in cooperation with L₅), most preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (forming a ring in cooperation with L₅) or an ethylene group (forming a ring in cooperation with L₅).

As the bivalent connecting group represented by L₅, there can be mentioned an alkylene group, a bivalent aromatic ring group, —COO-L₁-, —O-L₁-, a group consisting of a combination of two or more thereof or the like. In the formulae, L₁ represents an alkylene group, a cycloalkylene group, a bivalent aromatic ring group or a group consisting of an alkylene group combined with a bivalent aromatic ring group.

L₅ is preferably a single bond, any of the groups of the formula —COO-L₁- or a bivalent aromatic ring group. When the exposure is conducted using an ArF excimer laser, a single bond or —COO-L₁- is preferred from the viewpoint that the absorption in the region of 193 nm can be reduced. L₁ is preferably an alkylene group having 1 to 5 carbon atoms, more preferably a methylene group or a propylene group.

The alkyl group represented by each of R₅₄ to R₅₆ is preferably one having 1 to 20 carbon atoms, more preferably one having 1 to 10 carbon atoms and most preferably one having 1 to 4 carbon atoms, such as a methyl group, an ethyl group, an n-propyl group, an isopropyl group, an n-butyl group, an isobutyl group or a t-butyl group.

The cycloalkyl group represented by each of R₅₅ and R₅₆ is preferably one having 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group.

The ring formed by the mutual bonding of R₅₅ and R₅₆ preferably has 3 to 20 carbon atoms. It may be a monocyclic one, such as a cyclopentyl group or a cyclohexyl group, or a polycyclic one, such as a norbonyl group, an adamantyl group, a tetracyclodecanyl group or a tetracyclododecanyl group. When R₅₅ and R₅₆ are bonded to each other to thereby form a ring, R₅₄ is preferably an alkyl group having 1 to 3 carbon atoms, more preferably a methyl group or an ethyl group.

The monovalent aromatic ring group represented by each of R₅₅ and R₅₆ is preferably one having 6 to 20 carbon atoms. As such, there can be mentioned, for example, a phenyl group, a naphthyl group or the like. When either R₅₅ or R₅₆ is a hydrogen atom, it is preferred for the other to be a monovalent aromatic ring group.

When the exposure is conducted using an ArF excimer laser, it is preferred for each of R₅₅ and R₅₆ to independently represent a hydrogen atom, an alkyl group or a cycloalkyl group so that the absorption in the region of 193 nm can be reduced.

As the method of synthesizing the monomers corresponding to the repeating units of general formula (V), use can be made of a routine process for synthesizing esters containing a polymerizable group. The method is not particularly limited.

Specific examples of the repeating units (B) will be shown below, which however in no way limit the scope of the present invention. In the specific examples, Rx and Xₐₗ each represents a hydrogen atom, a methyl group, an ethyl group, a trifluoromethyl group (—CF₃), a hydroxymethyl group (—CH₂OH), a chloromethyl group (—CH₂Cl), or a fluorine atom. Rxa and RXb each represents an alkyl group having 1 to 4 carbon atoms. Each of Zs independently represents a substituent containing polar group. More specifically, Z represents a polar group itself such as a hydroxyl group, a cyano group, an amino group, an alkylamide group, sulfonamide group, or the like, or linear or branched alkyl group or cycloalkyl group containing one or more polar groups. P represents 0 or an integer equal to or greater than 1.

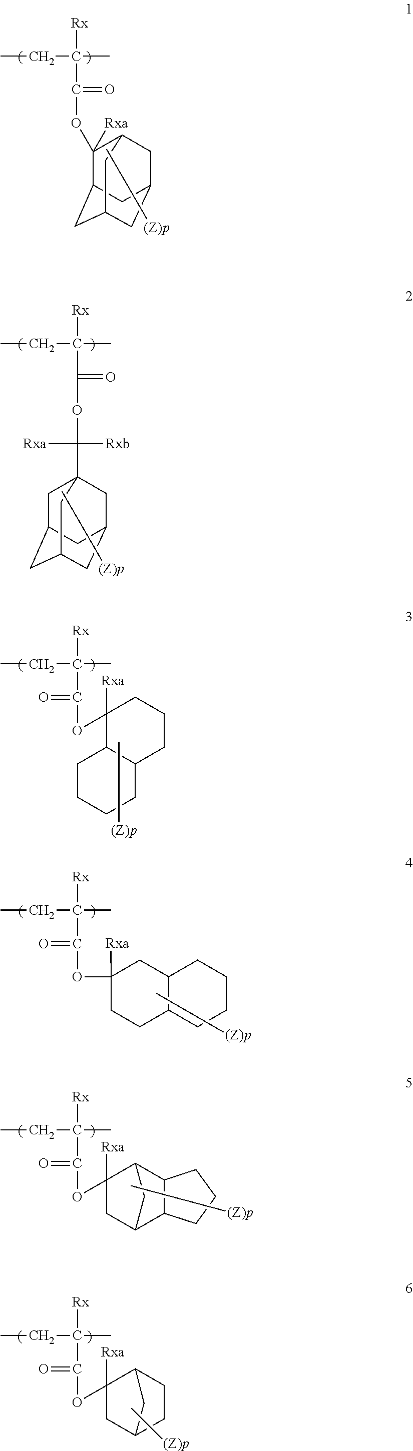

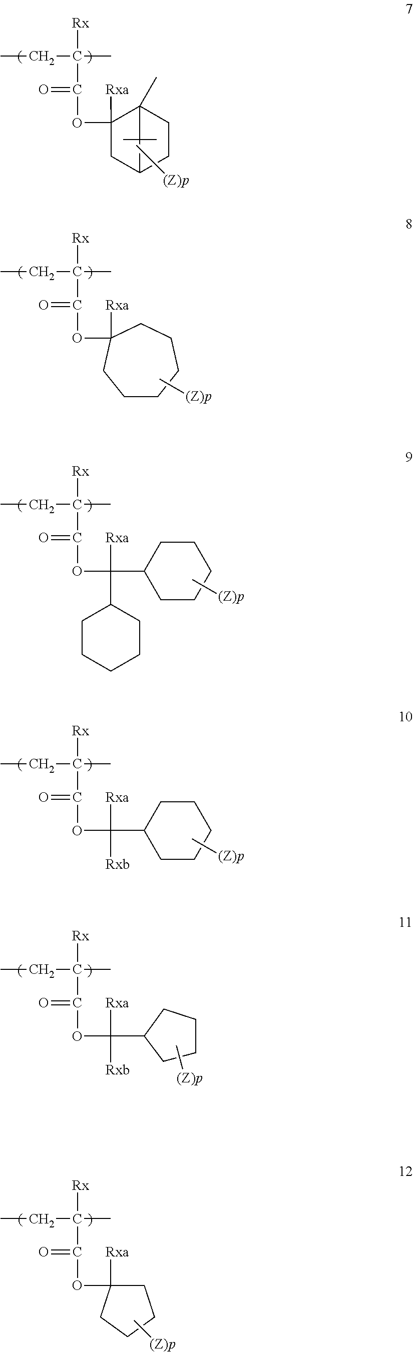

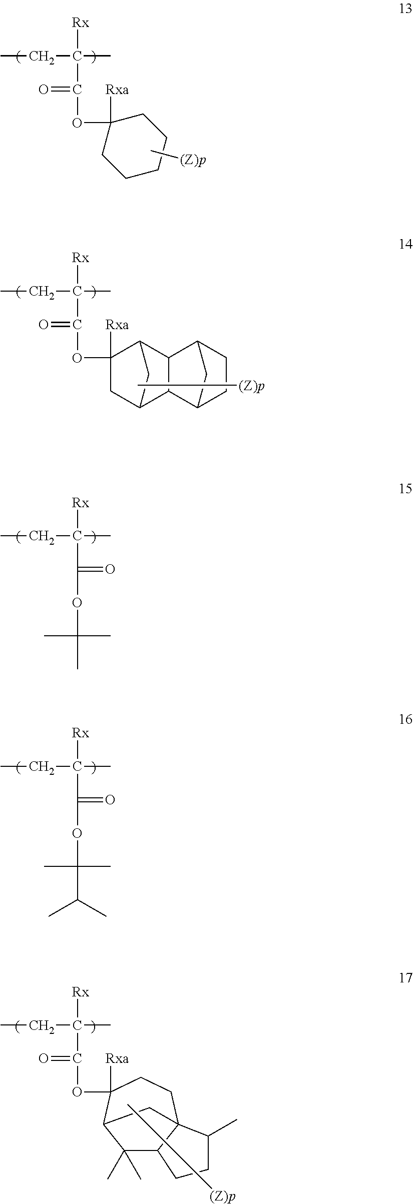

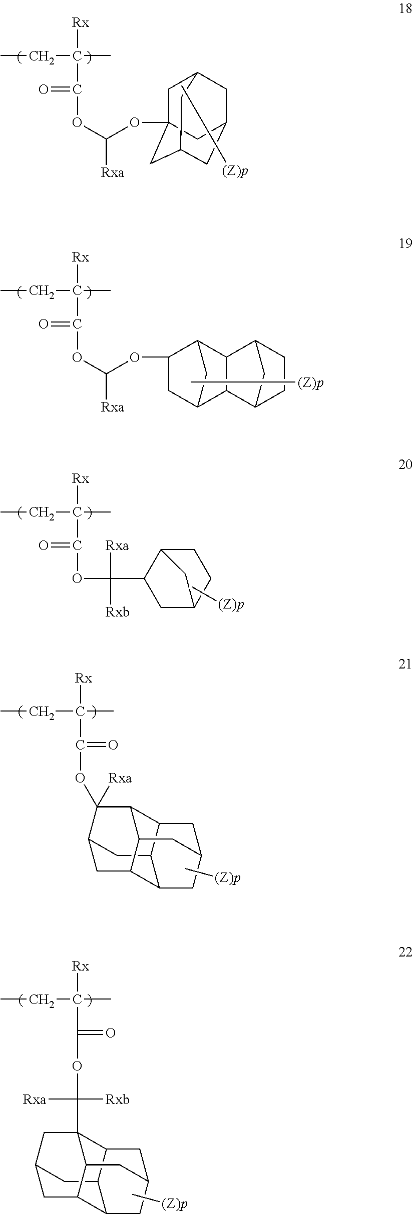

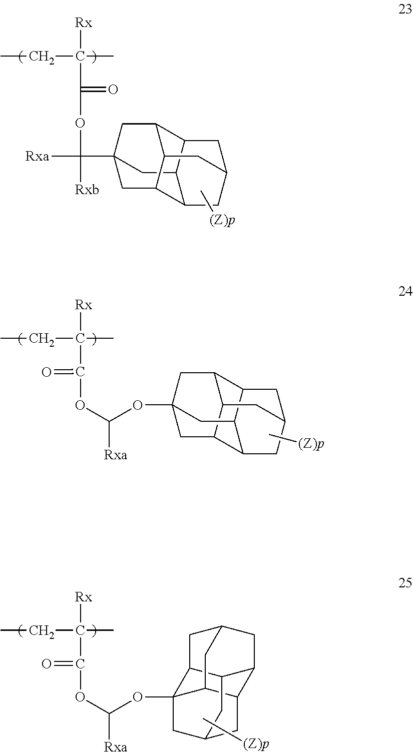

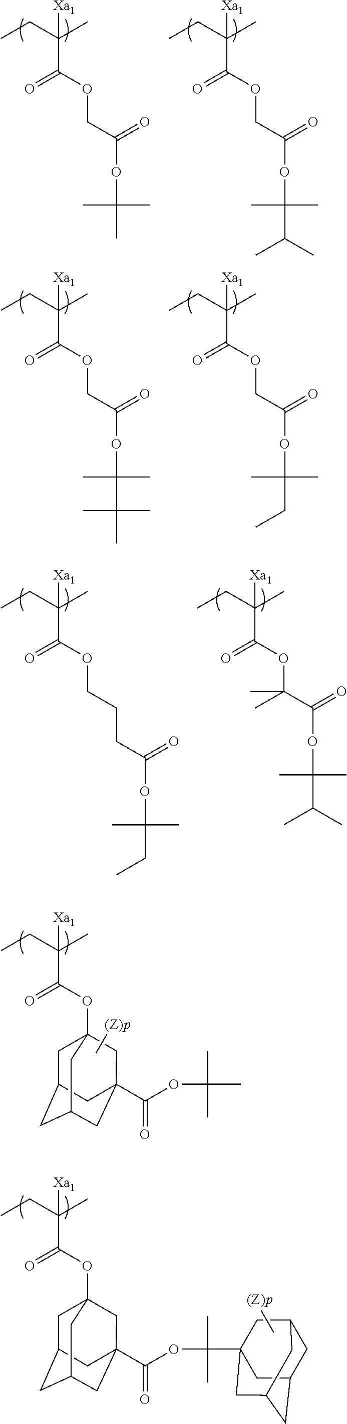

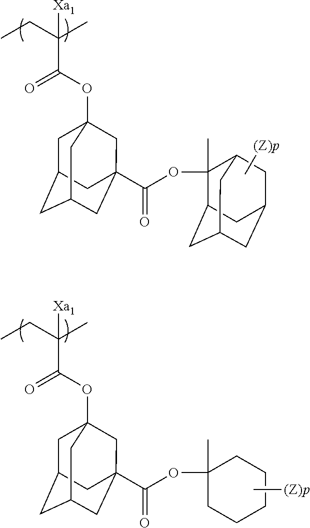

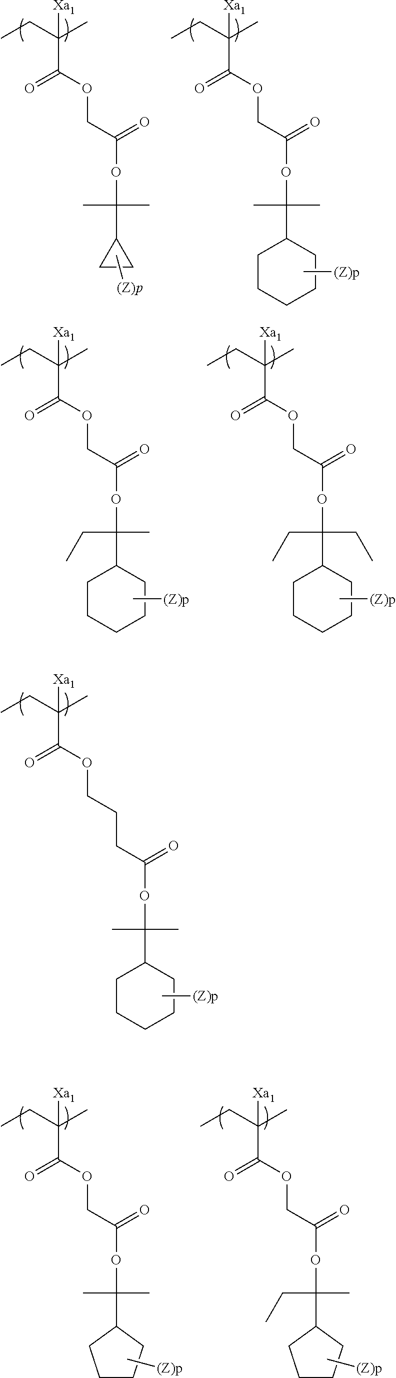

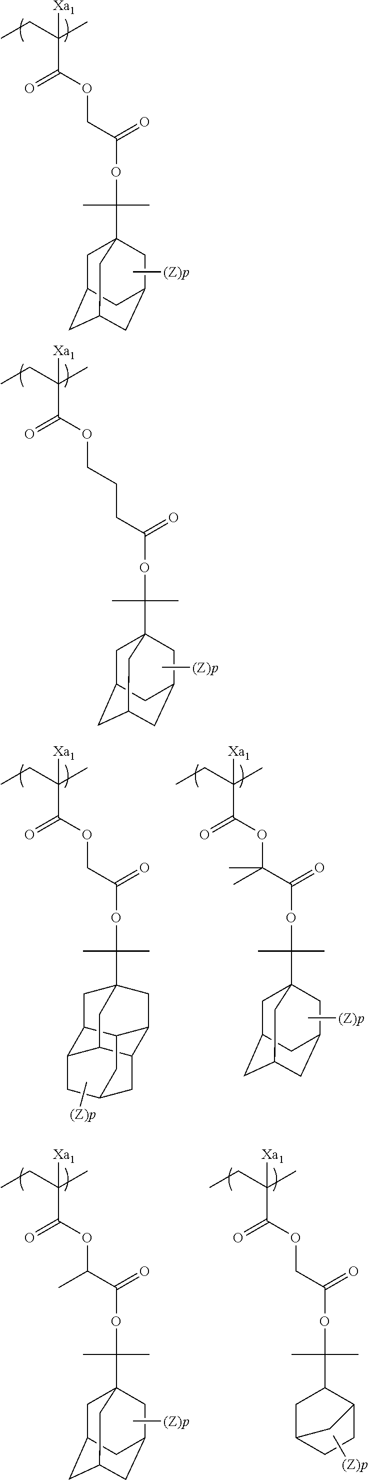

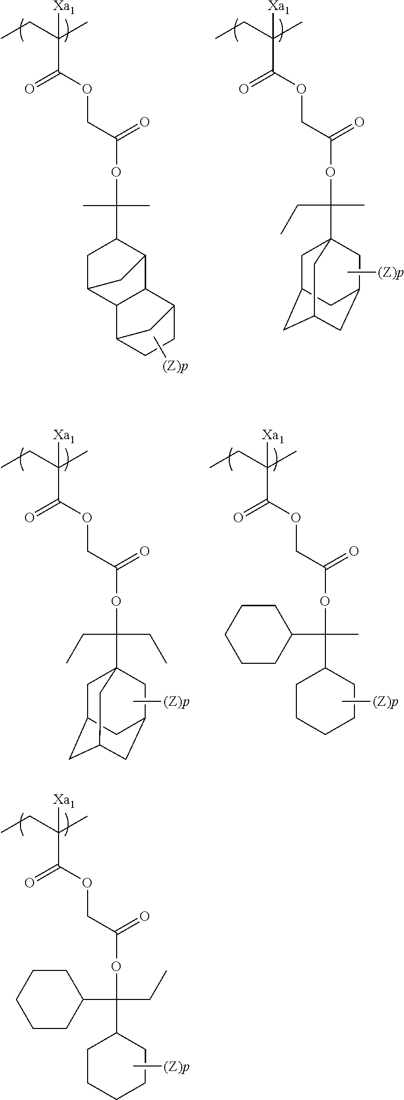

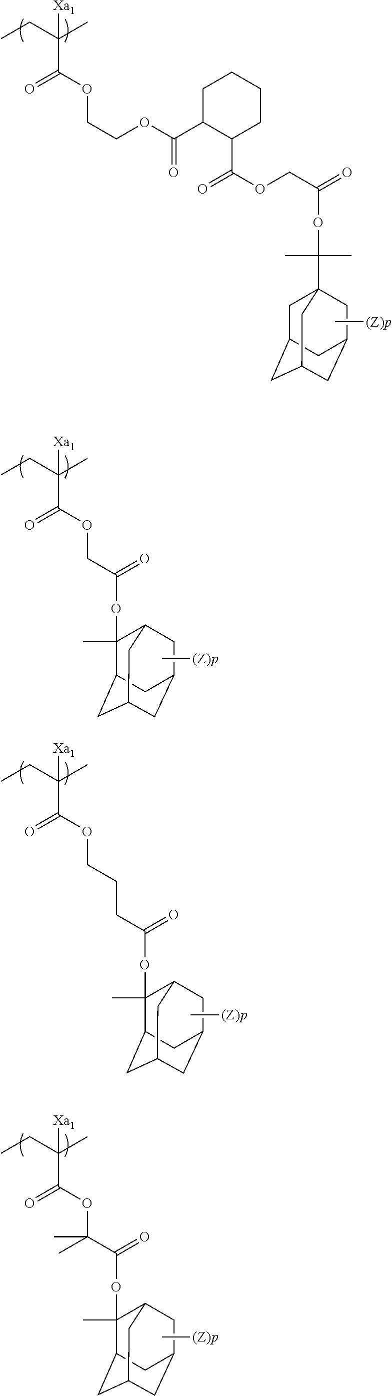

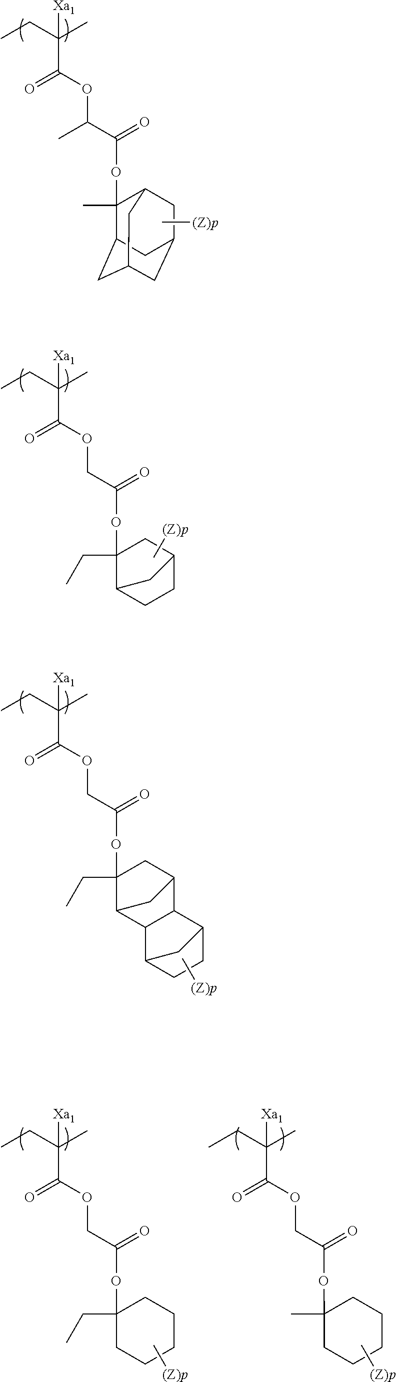

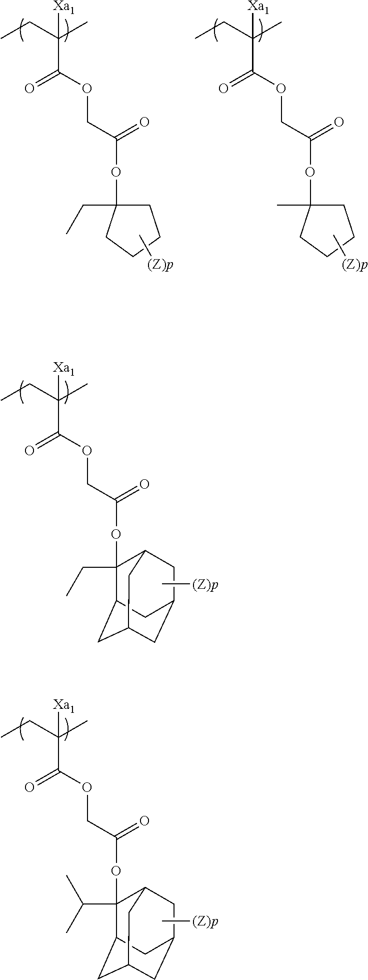

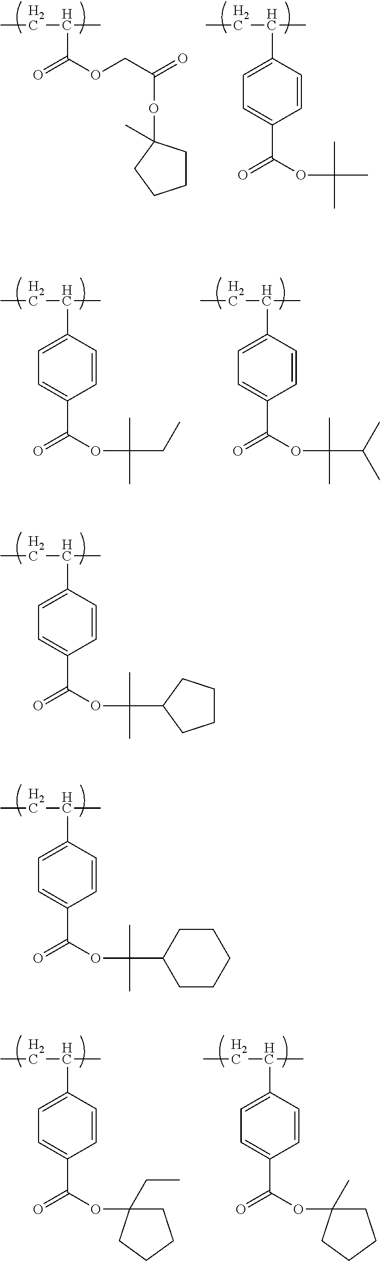

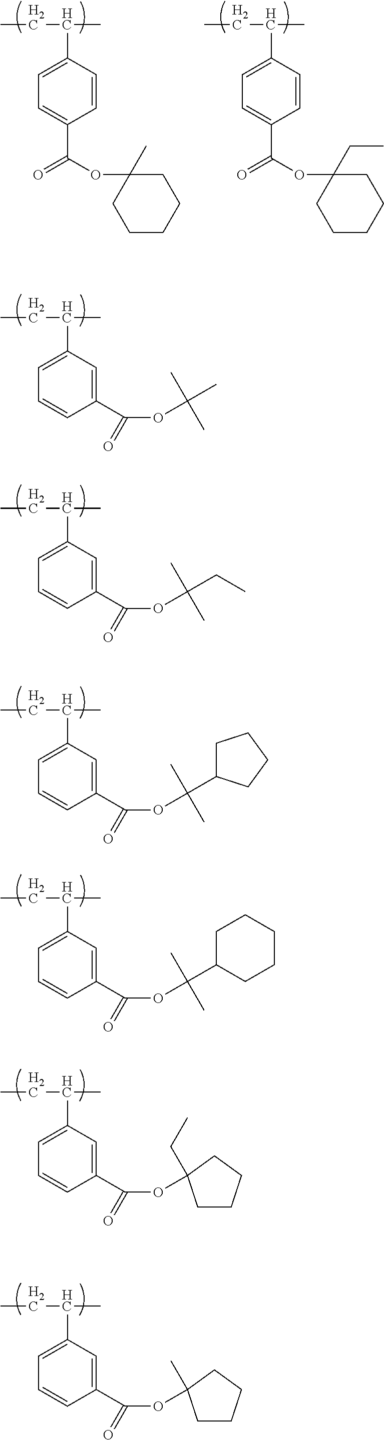

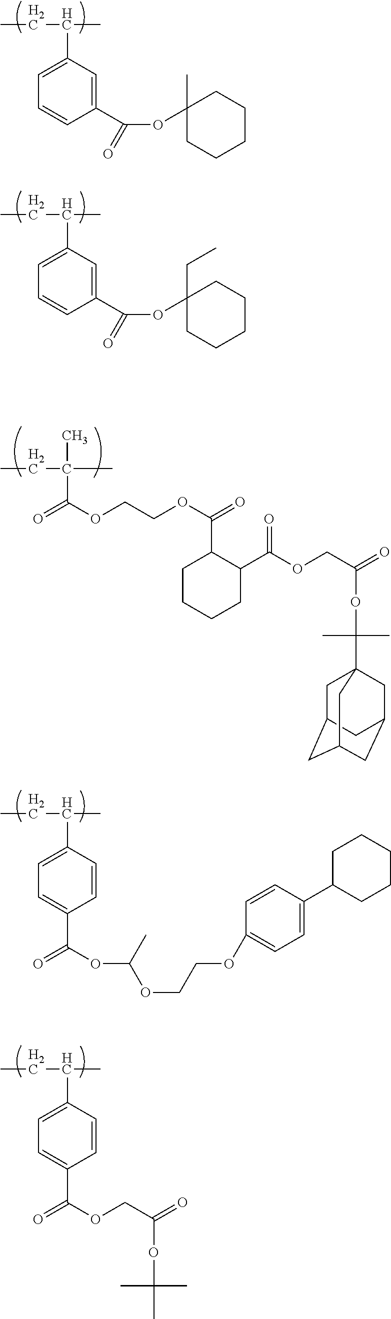

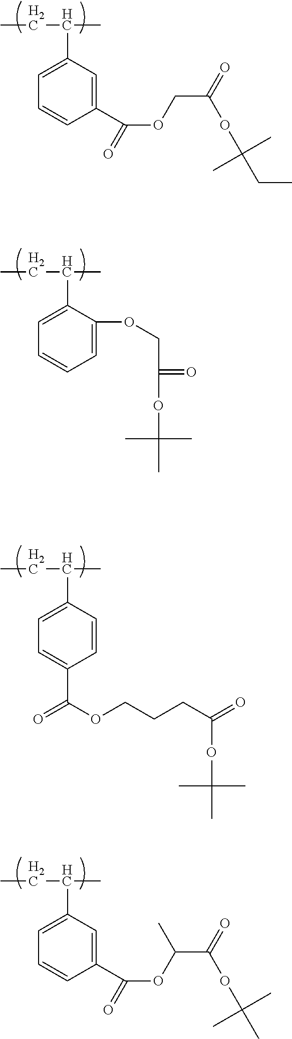

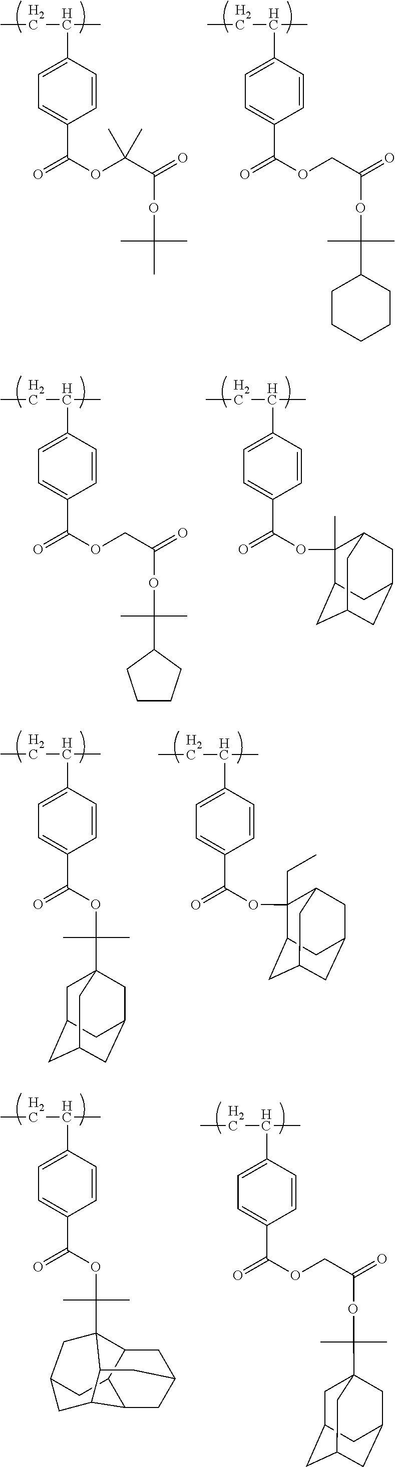

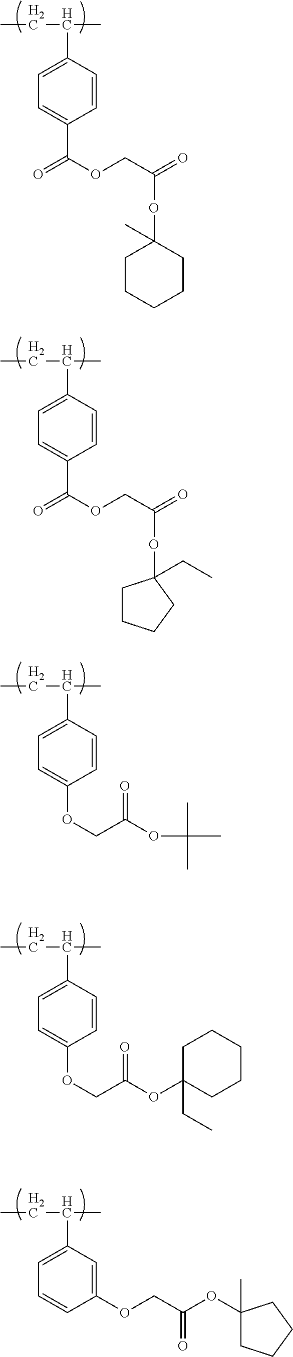

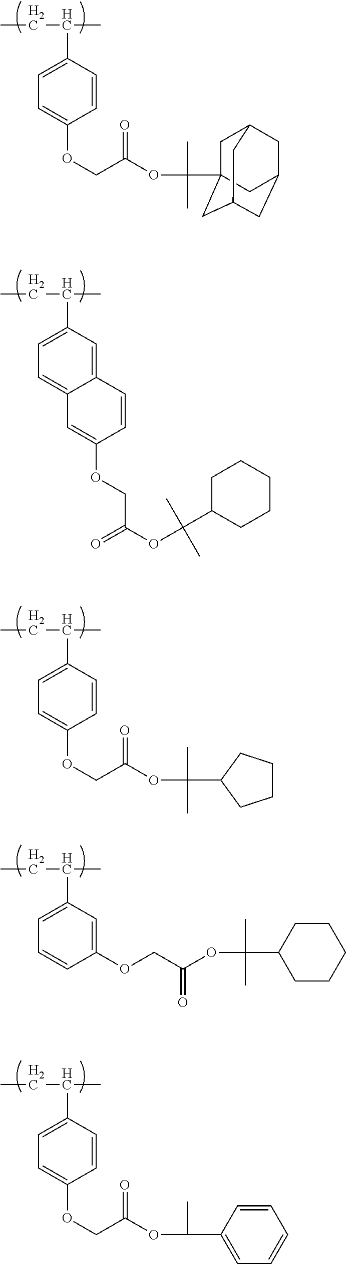

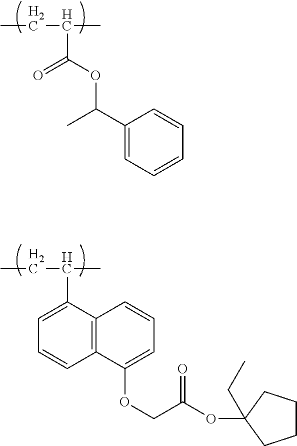

Moreover, the resin (P) may contain any of the repeating units of general formula (VI) below as the repeating unit (B). This is especially preferred when the exposure is performed using electron beams or EUV.

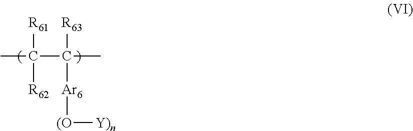

In the general formula (VI), each of R₆₁, R₆₂ and R₆₃ independently represents a hydrogen atom, an alkyl group, a cycloalkyl group, a halogen atom, a cyano group or an alkoxycarbonyl group. R₆₂ may be bonded to Ar₆ to thereby form a ring (preferably, a 5-membered or 6-membered ring). If so, R₆₂ represents an alkylene group.

Ar₆ represents a bivalent aromatic ring group. Y, or each of Ys independently, represents a hydrogen atom or a group that is cleaved by the action of an acid, provided that at least one of Ys represents a group that is cleaved, by the action of an acid. In the formula, n is an integer of 1 to 4.

More detailed description on the general formula (VI) will be presented below.

As a preferred alkyl group represented by each of R₆₁ to R₆₃ in the general formula (VI), there can be mentioned an optionally substituted alkyl group having up to 20 carbon atoms, such as a methyl group, an ethyl group, a propyl group, an isopropyl group, an n-butyl group, a sec-butyl group, a hexyl group, a 2-ethylhexyl group, an octyl group or a dodecyl group. An alkyl group having up to 8 carbon atoms is more preferred.

The alkyl group contained in the alkoxycarbonyl group is preferably the same as that represented by each of R₆₁ to R₆₃.

The cycloalkyl group may be monocyclic or polycyclic. The cycloalkyl group is preferably an optionally substituted monocyclic cycloalkyl group having 3 to 8 carbon atoms, such as a cyclopropyl group, a cyclopentyl group or a cyclohexyl group.

As the halogen atom, there can be mentioned a fluorine atom, a chlorine atom, a bromine atom or an iodine atom. A fluorine atom is especially preferred.

When R₆₂ is an alkylene group, the alkylene group is preferably an optionally substituted alkylene group having 1 to 8 carbon atoms, such as a methylene group, an ethylene group, a propylene group, a butylene group, a hexylene group or an octylene group.

Ar₆ represents a bivalent aromatic ring group. The bivalent aromatic ring group may have one or more substituents. As preferred examples thereof, there can be mentioned an arylene group having 6 to 18 carbon atoms, such as a phenylene group, a tolylene group or a naphthylene group, and a bivalent aromatic ring group containing a hetero-ring, such as thiophene, furan, pyrrole, benzothiophene, benzofuran, benzopyrrole, triazine, imidazole, benzimidazole, triazole, thiadiazole or thiazole.

Specific examples of the substituents that can be introduced in the above alkyl group, cycloalkyl group, alkoxycarbonyl group, alkylene group and bivalent aromatic ring group are the same as those which can be introduced in the above groups represented by R₅₁ to R₅₃ in the general formula (V).

In the formula, n is preferably 1 or 2, more preferably 1.

Each of n Ys independently represents a hydrogen atom or a group that is cleaved by the action of an acid, provided that at least one of n Ys represents a group that is cleaved by the action of an acid.

As the group that is cleaved by the action of an acid, Y, there can be mentioned, for example, —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), —CH(R₃₆)(Ar) or the like.

In the formulae, each of R₃₆ to R₃₉ independently represents an alkyl group, a cycloalkyl group, a monovalent aromatic ring group, a group consisting of an alkylene group combined with a monovalent aromatic ring group, or an alkenyl group. R₃₆ and R₃₇ may be bonded to each other to form a ring.

Each of R₀₁ and R₀₂ independently represents a hydrogen atom, an alkyl group, a cycloalkyl group, a monovalent aromatic ring group, a group consisting of an alkylene group combined with a monovalent aromatic ring group, or an alkenyl group.

Ar represents a monovalent aromatic group.

Each of the alkyl groups represented by R₃₆ to R₃₉, R₀₁ and R₀₂ preferably has a carbon number of 1 to 8. For example, there can be mentioned a methyl group, an ethyl group, a propyl group, an n-butyl group, a sec-butyl group, a hexyl group, an octyl group or the like.

The cycloalkyl groups represented by R₃₆ to R₃₉, R₀₁ and R₀₂ may be monocyclic or polycyclic. When the cycloalkyl group is monocyclic, it is preferably a cycloalkyl group having 3 to 8 carbon atoms. As such, there can be mentioned, for example, a cyclopropyl group, a cyclobutyl group, a cyclopentyl group, a cyclohexyl group, a cyclooctyl group or the like. When the cycloalkyl group is polycyclic, it is preferably a cycloalkyl groups having 6 to 20 carbon atoms. As such, there can be mentioned, for example, an adamantyl group, a norbornyl group, an isobornyl group, a camphonyl group, a dicyclopentyl group, an α-pinel group, a tricyclodecanyl group, a tetracyclododecyl group, an androstanyl group or the like. With respect to these, the carbon atoms of each of the cycloalkyl groups may be partially substituted with a hetero-atom, such as an oxygen atom.

Each of the monovalent aromatic ring groups represented by R₃₆ to R₃₉, R₀₁, R₀₂ and Ar is preferably one having 6 to 10 carbon atoms. For example, there can be mentioned an aryl group, such as a phenyl group, a naphthyl group or an anthryl group, or a monovalent aromatic ring group containing a hetero-ring, such as thiophene, furan, pyrrole, benzothiophene, benzofuran, benzopyrrole, triazine, imidazole, benzimidazole, triazole, thiadiazole or thiazole.

Each of the groups consisting of an alkylene group combined with a monovalent aromatic ring group, represented by R₃₆ to R₃₉, R₀₁ and R₀₂ is preferably an aralkyl group having 7 to 12 carbon atoms. For example, there can be mentioned a benzyl group, a phenethyl group, a naphthylmethyl group or the like.

Each of the alkenyl groups represented by R₃₆ to R₃₉, R₀₁ and R₀₂ preferably has 2 to 8 carbon atoms. For example, there can be mentioned a vinyl group, an allyl group, a butenyl group, a cyclohexenyl group or the like.

The ring formed by the mutual bonding of R₃₆ and

R₃₇ may be monocyclic or polycyclic. The monocyclic structure is preferably a cycloalkyl structure having 3 to 8 carbon atoms. As such, there can be mentioned, for example, a cyclopropane structure, a cyclobutane structure, a cyclopentane structure, a cyclohexane structure, a cycloheptane structure, a cyclooctane structure or the like. The polycyclic structure is preferably a cycloalkyl structure having 6 to 20 carbon atoms. As such, there can be mentioned, for example, an adamantine structure, a norbornane structure, a dicyclopentane structure, a tricyclodecane structure, a tetracyclododecane structure or the like. With respect to these, the carbon atoms of each of the cycloalkyl structures may be partially substituted with a hetero-atom, such as an oxygen atom.

Each of the above groups represented by R₃₆ to R₃₉, R₀₁, R₀₂ and Ar may have one or more substituents. As the substituent, there can be mentioned, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, a nitro group or the like. Preferably, the number of carbon atoms of each of the substituents is up to 8.

The group that is cleaved by the action of an acid, Y, more preferably has any ofthe structures of general formula (VI-A) below.

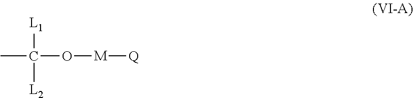

In the formula, each of L₁ and L₂ independently represents a hydrogen atom, an alkyl group, a cycloalkyl group, a monovalent aromatic ring group or a group consisting of an alkylene group combined with a monovalent aromatic ring group.

M represents a single bond or a bivalent connecting group.

Q represents an alkyl group, a cycloalkyl group optionally containing one or more hetero-atoms, a monovalent aromatic ring group optionally containing one or more hetero-atoms, an amino group, an ammonium group, a mercapto group, a cyano group or an aldehyde group.

At least two of Q, M and L₁ may be bonded to each other to thereby form a ring (preferably, a 5-membered or 6-membered ring).

The alkyl groups represented by L₁ and L₂ are, for example, alkyl groups having 1 to 8 carbon atoms. As preferred examples thereof, there can be mentioned a methyl group, an ethyl group, a propyl group, an n-butyl group, a sec-butyl group, a hexyl group and an octyl group.

The cycloalkyl groups represented by L₁ and L₂ are, for example, cycloalkyl groups having 3 to 15 carbon atoms. As preferred examples thereof, there can be mentioned a cyclopentyl group, a cyclohexyl group, a norbornyl group, an adamantyl group and the like.

The monovalent aromatic ring groups represented by L₁ and L₂ are, for example, aryl groups having 6 to 15 carbon atoms. As preferred examples thereof, there can be mentioned a phenyl group, a tolyl group, a naphthyl group, an anthryl group and the like.

The groups each consisting of an alkylene group combined with a monovalent aromatic ring group, represented by L₁ and L₂ are, for example, those having 6 to 20 carbon atoms. There can be mentioned aralkyl groups, such as a benzyl group and a phenethyl group.

The bivalent connecting group represented by M is, for example, an alkylene group (e.g., a methylene group, an ethylene group, a propylene group, a butylene group, a hexylene group, an octylene group, etc.), a cycloalkylene group (e.g., a cyclopentylene group, a cyclohexylene group, an adamantylene group, etc.), an alkenylene group (e.g., an ethylene group, a propenylene group, a butenylene group, etc.), a bivalent aromatic ring group (e.g., a phenylene group, a tolylene group, a naphthylene group, etc.), —S—, —O—, —CO—, —SO₂—, —N(R₀)— or a bivalent connecting group resulting from combination of these groups. R₀ represents a hydrogen atom or an alkyl group (for example, an alkyl group having 1 to 8 carbon atoms; in particular, a methyl group, an ethyl group, a propyl group, an n-butyl group, a sec-butyl group, a hexyl group, an octyl group or the like).

The alkyl group represented by Q is the same as mentioned above as being represented by each of L₁ and L₂.

As the aliphatic hydrocarbon ring group containing no hetero-atom and monovalent aromatic ring group containing no hetero-atom respectively contained in the cycloalkyl group optionally containing one or more hetero-atoms and monovalent aromatic ring group optionally containing one or more hetero-atoms both represented by Q, there can be mentioned, for example, the cycloalkyl group and monovalent aromatic ring group mentioned above as being represented by each of L₁ and L₂. Preferably, each thereof has 3 to 15 carbon atoms.

As the cycloalkyl group containing one or more hetero-atoms and monovalent aromatic ring group containing one or more hetero-atoms, there can be mentioned, for example, groups having a heterocyclic structure, such as thiirane, cyclothiorane, thiophene, furan, pyrrole, benzothiophene, benzofuran, benzopyrrole, triazine, imidazole, benzimidazole, triazole, thiadiazole, thiazole and pyrrolidone. However, the above cycloalkyl groups and monovalent aromatic ring groups are not limited to these as long as a structure generally known as a hetero-ring (ring formed by carbon and a hetero-atom or ring formed by hetero-atoms) is included.

As the ring that may be formed by the mutual bonding of at least two of Q, M and L₁, there can be mentioned one resulting from the mutual bonding of at least two of Q, M and L₁ so as to form, for example, a propylene group or a butylene group and subsequent formation of a 5-membered or 6-membered ring containing an oxygen atom.

In the general formula (VI-A), each of the groups represented by L₁, L₂, M and Q may have one or more substituents. As the substituent, there can be mentioned, for example, those mentioned above as being optionally introduced in R₃₆ to R₃₉, R₀₁, R₀₂ and Ar. Preferably, the carbon number of each of the substituents is up to 8.

The groups of the formula -M-Q are preferably groups each composed of 1 to 30 carbon atoms, more preferably 5 to 20 carbon atoms.

Specific examples of the repeating units of the general formula (VI) will be shown below as preferred specific examples of the repeating units (B), which however in no way limit the scope of the present invention.

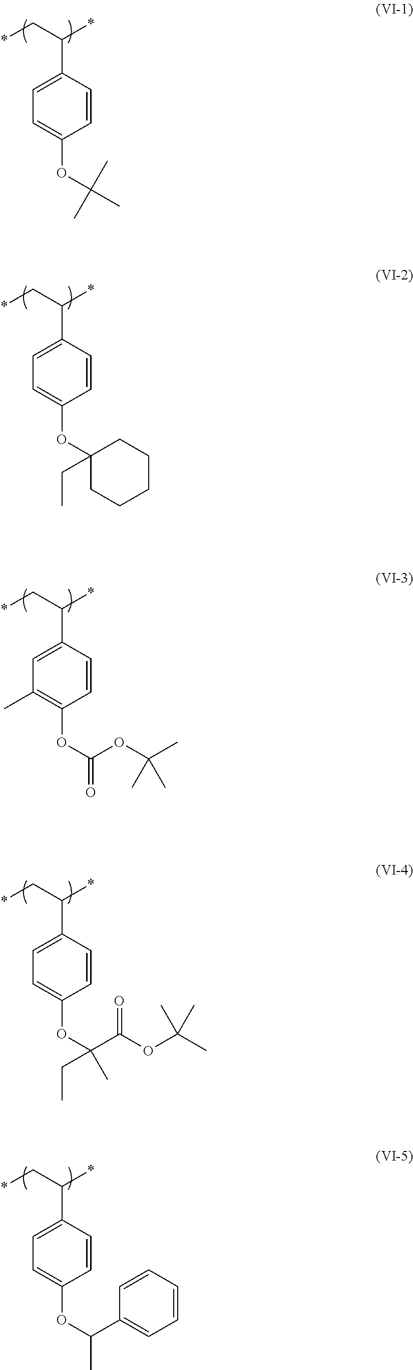

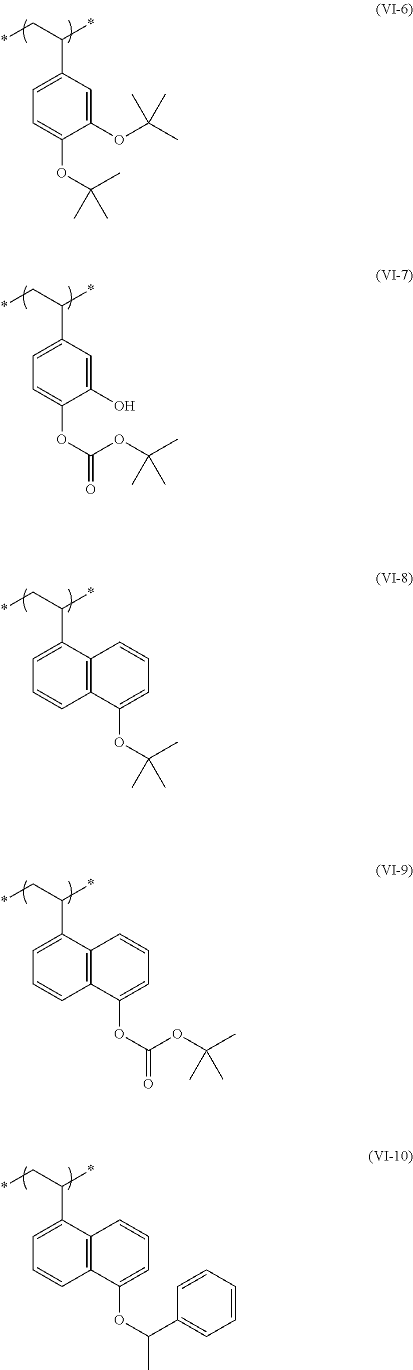

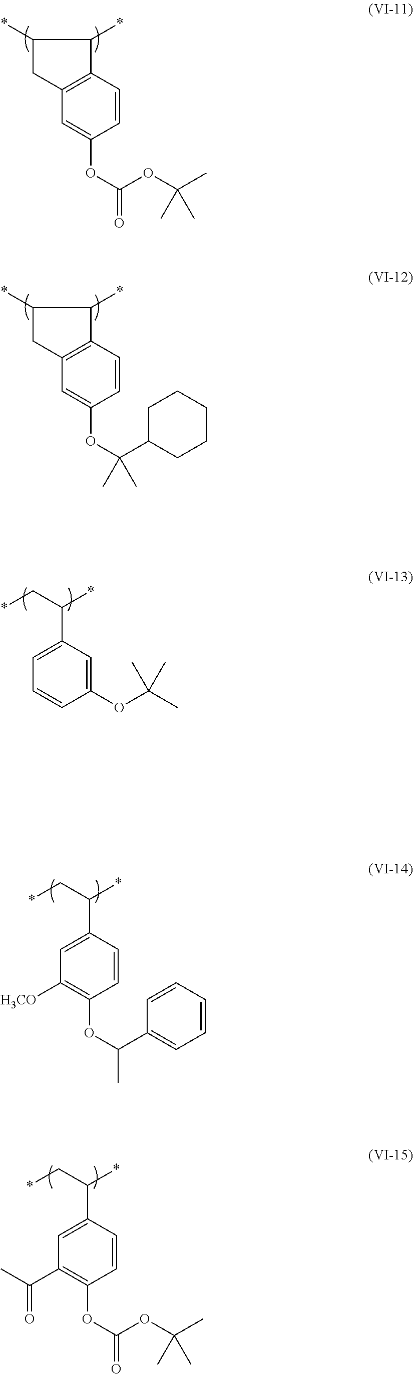

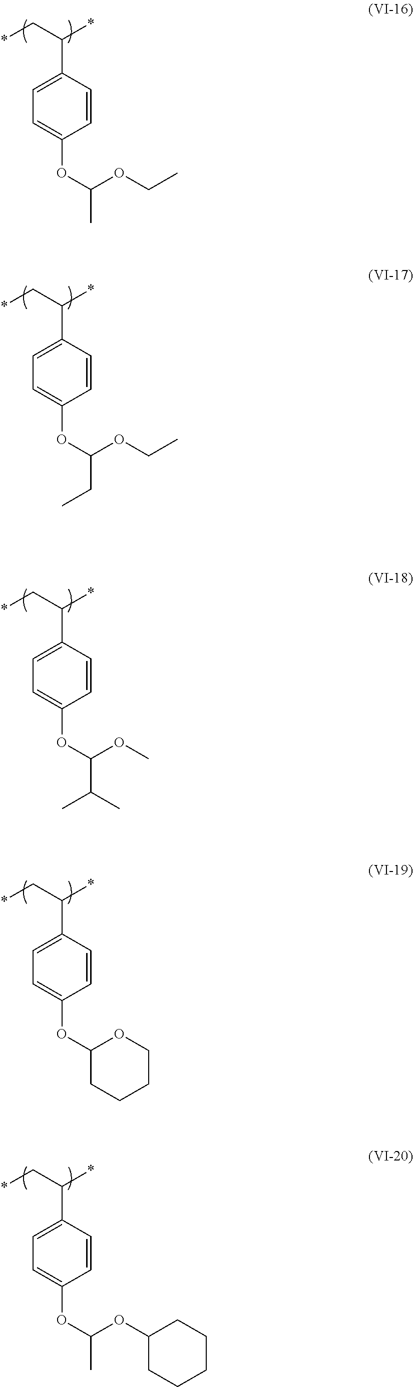

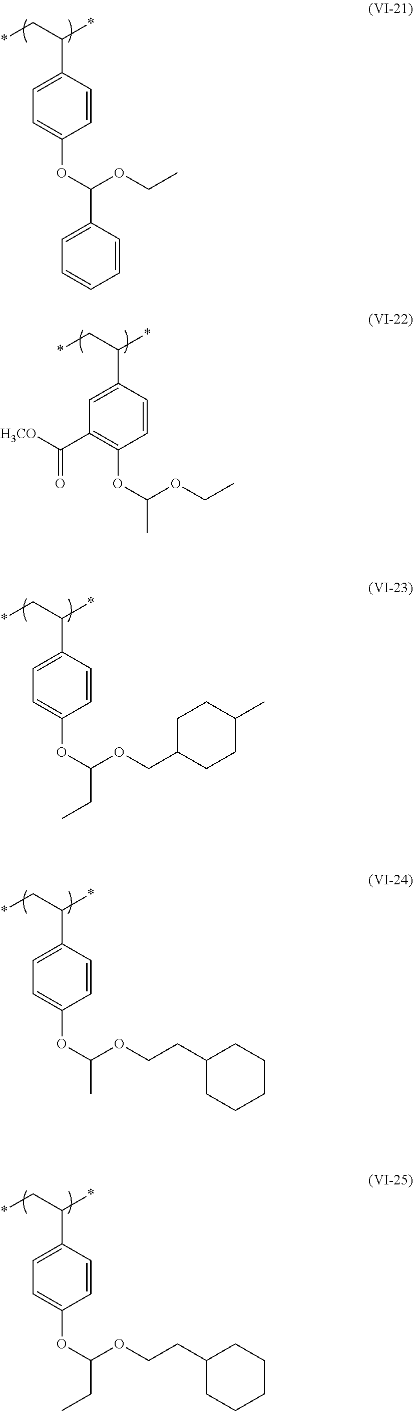

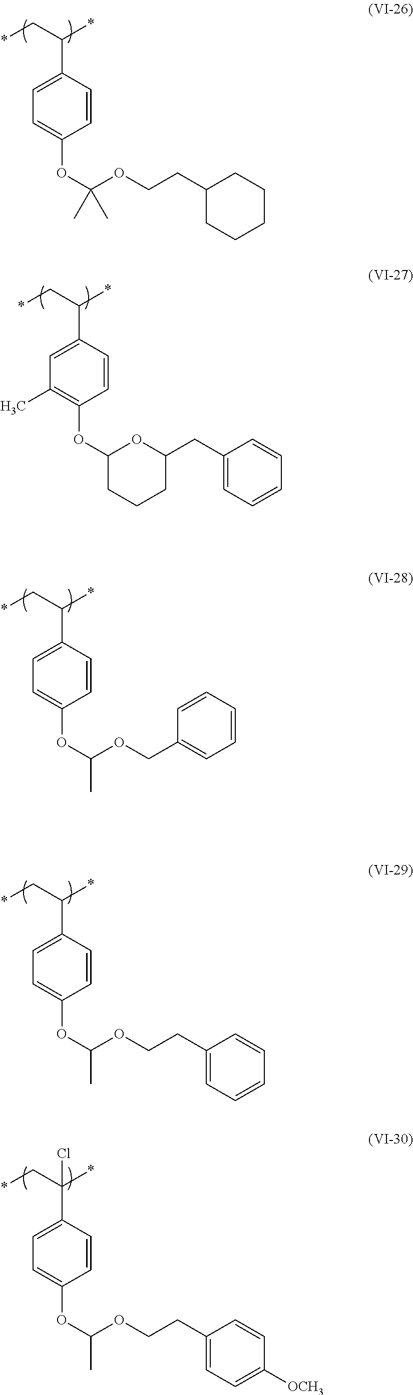

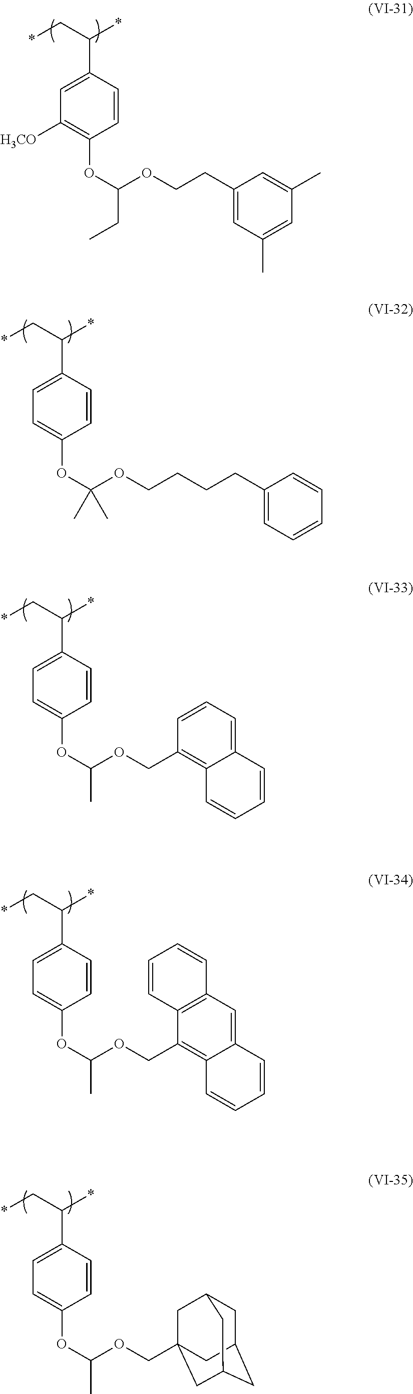

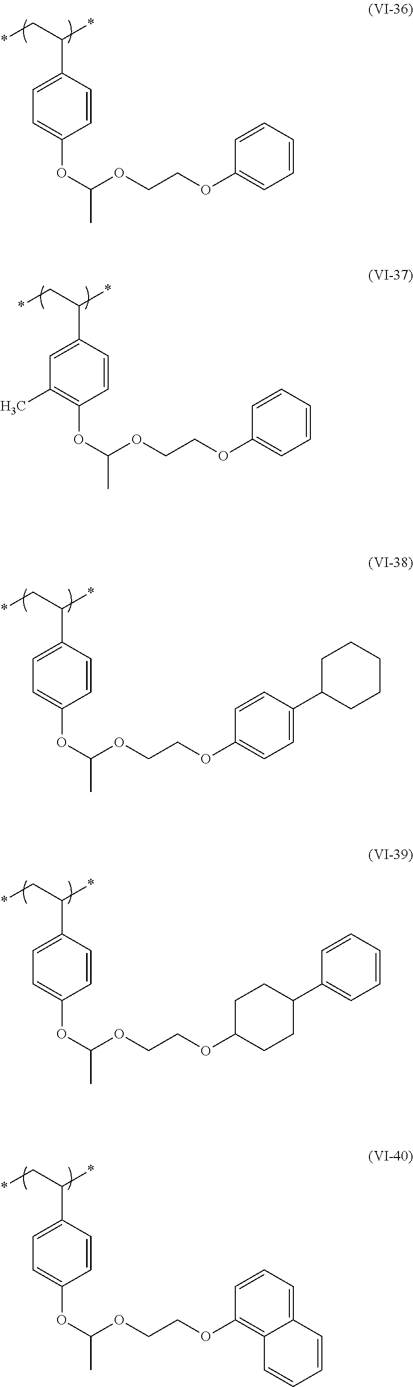

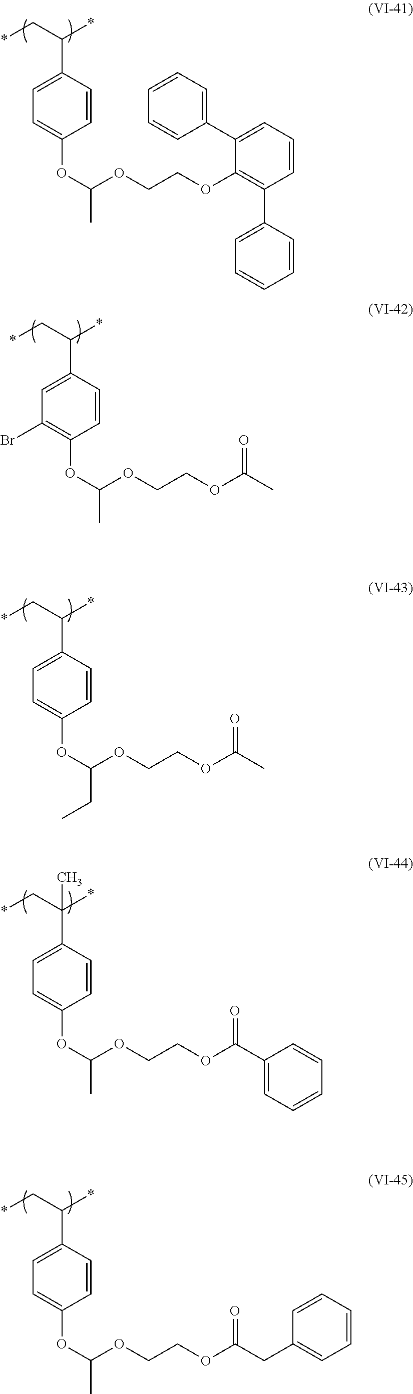

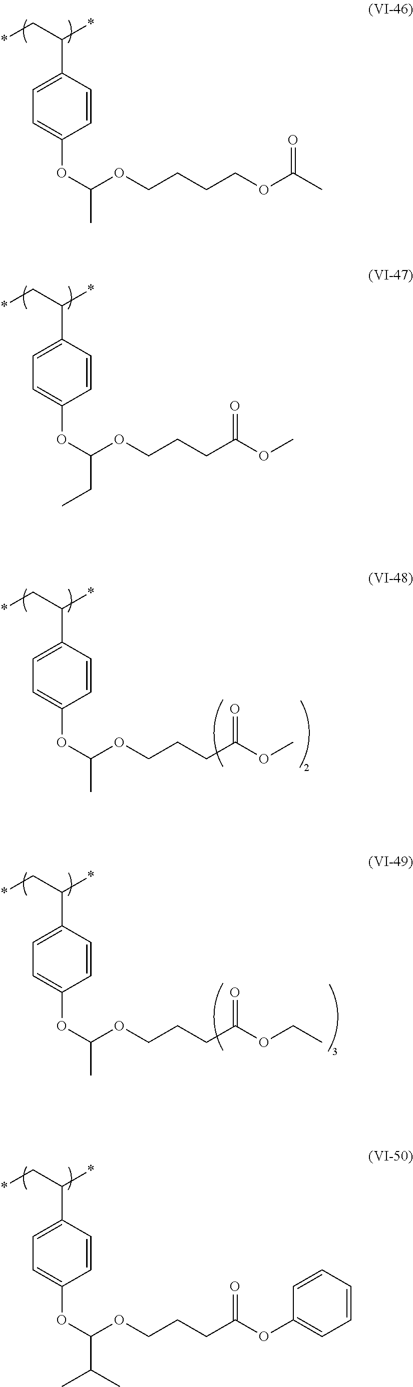

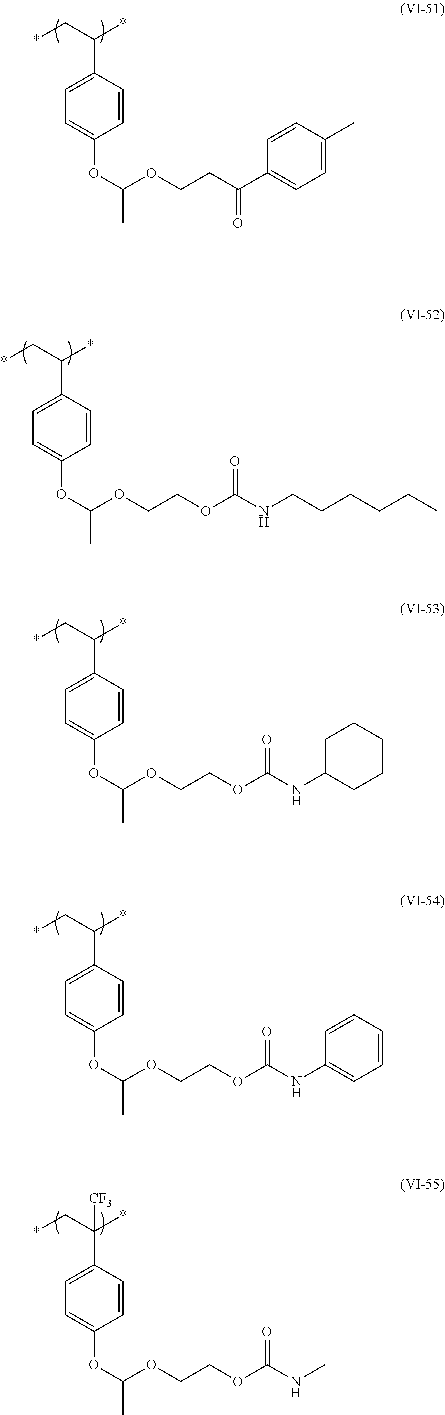

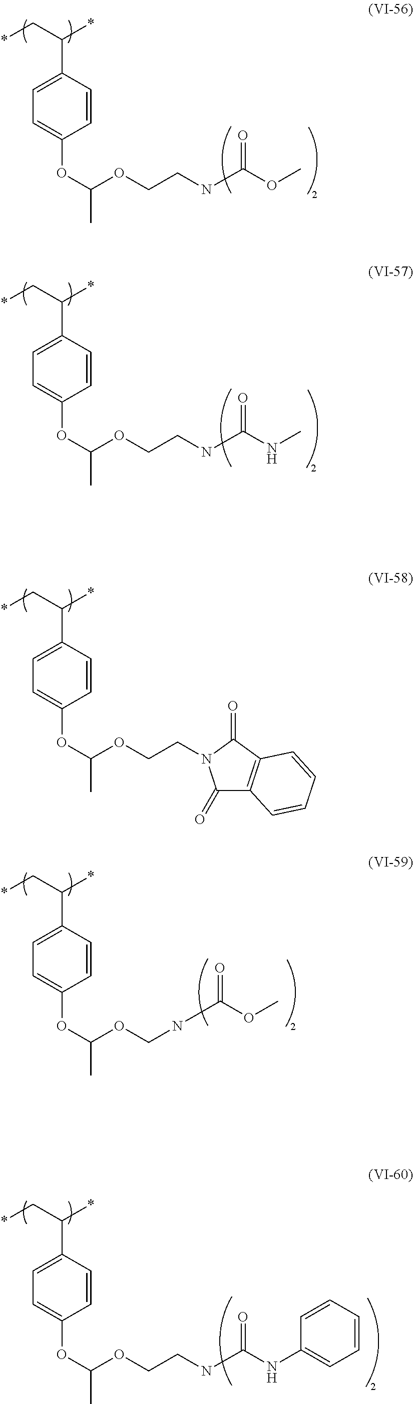

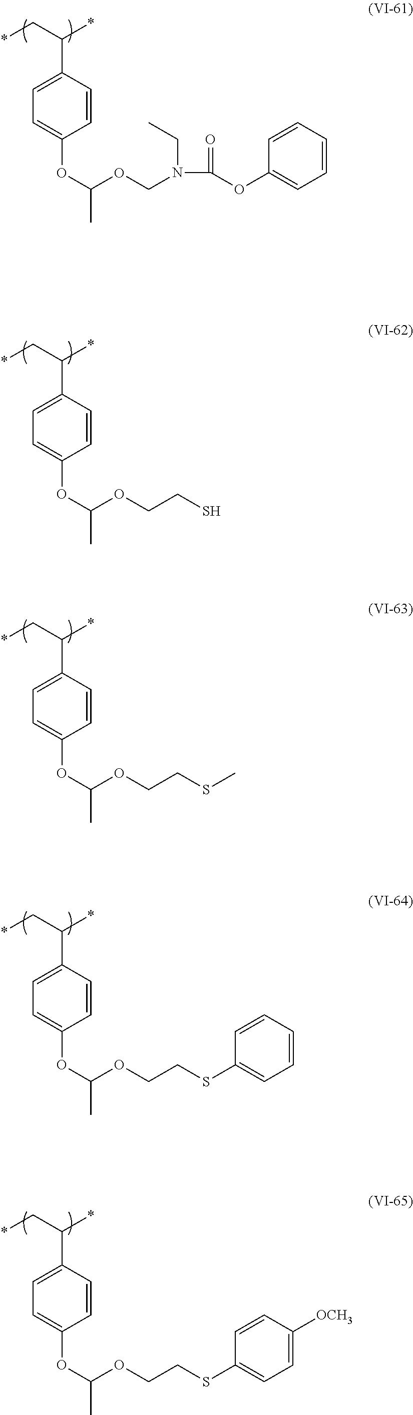

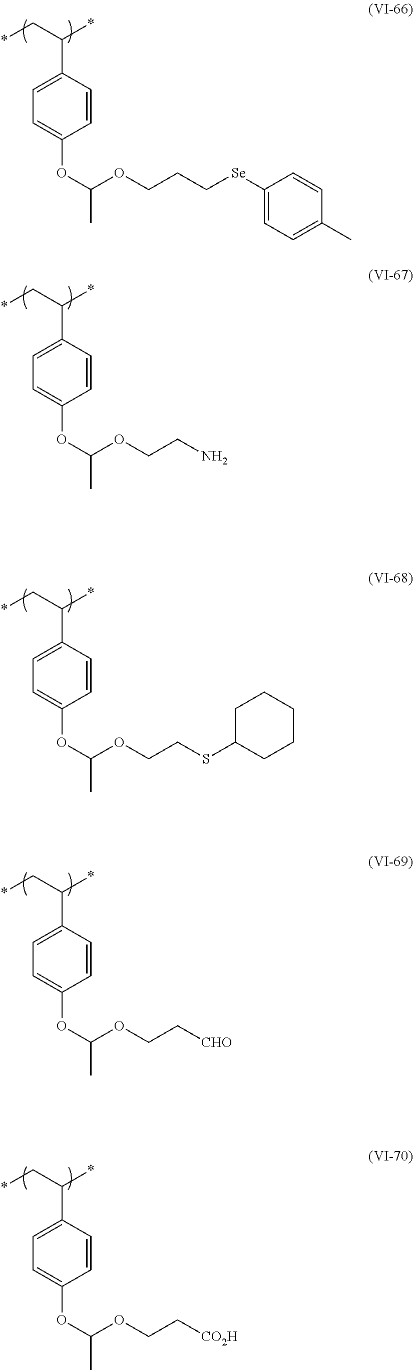

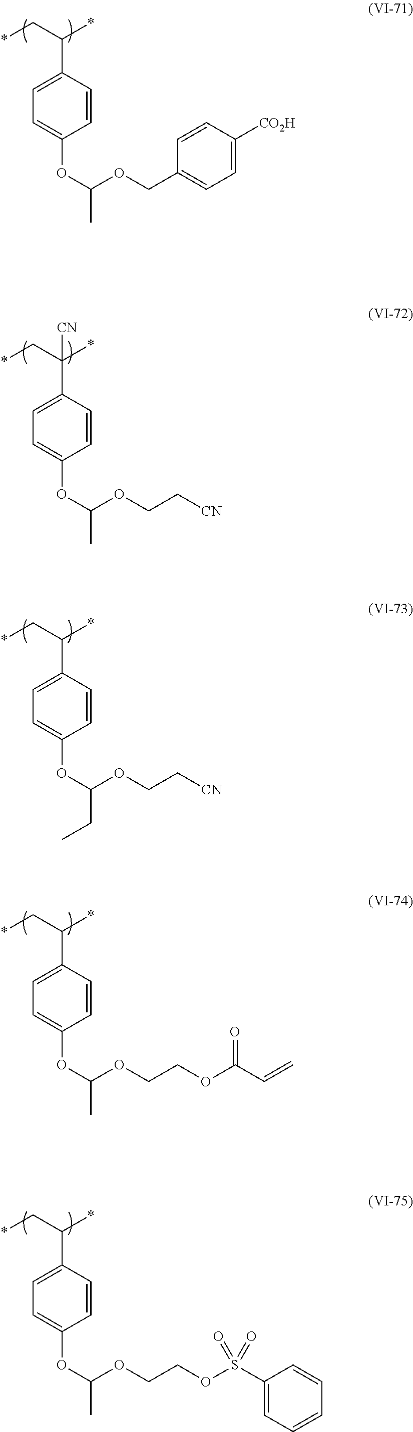

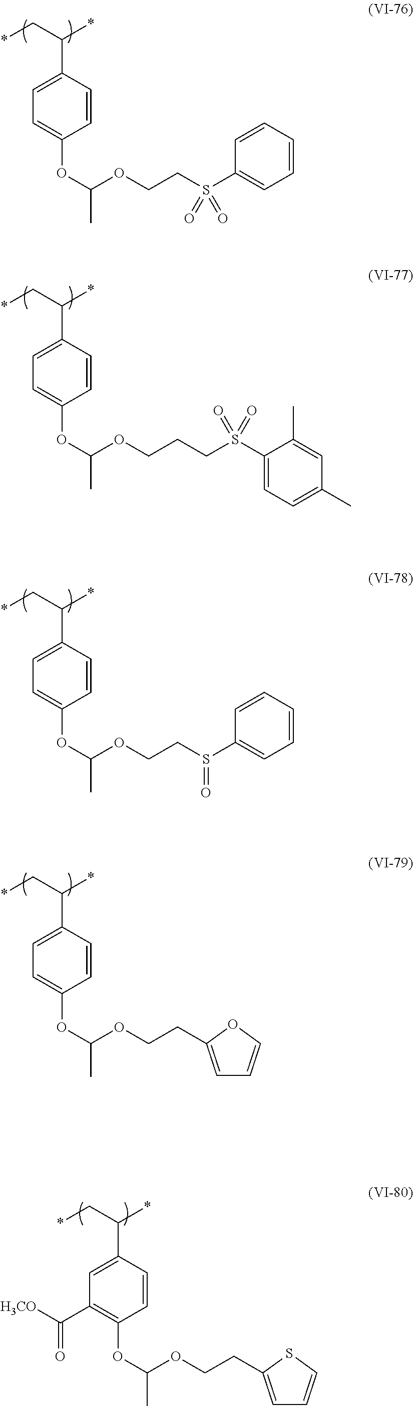

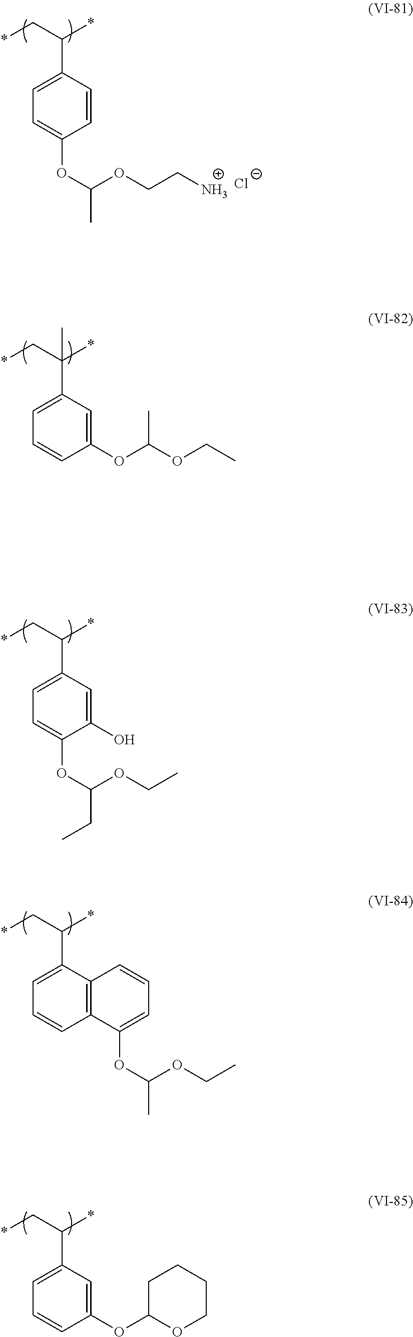

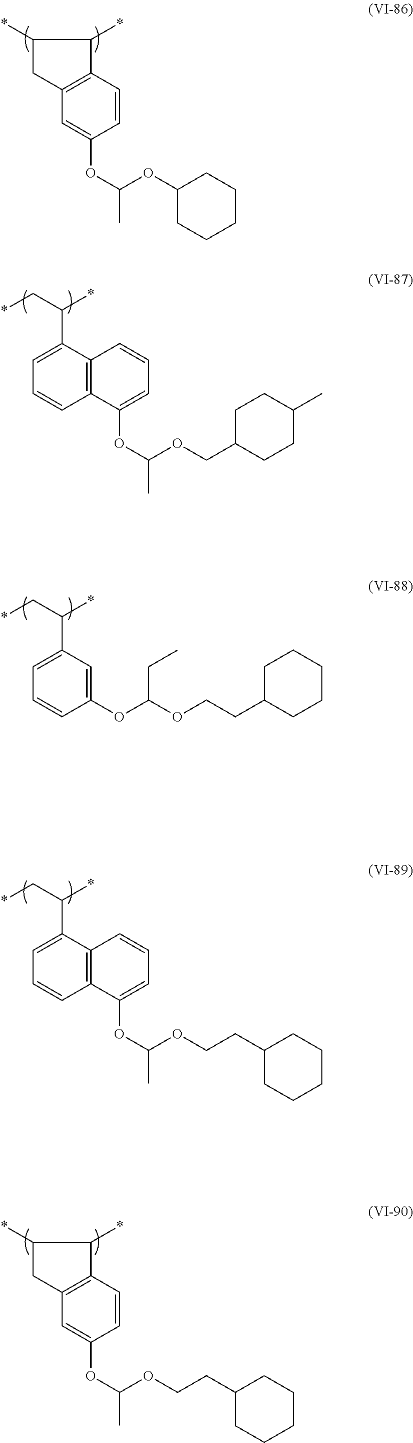

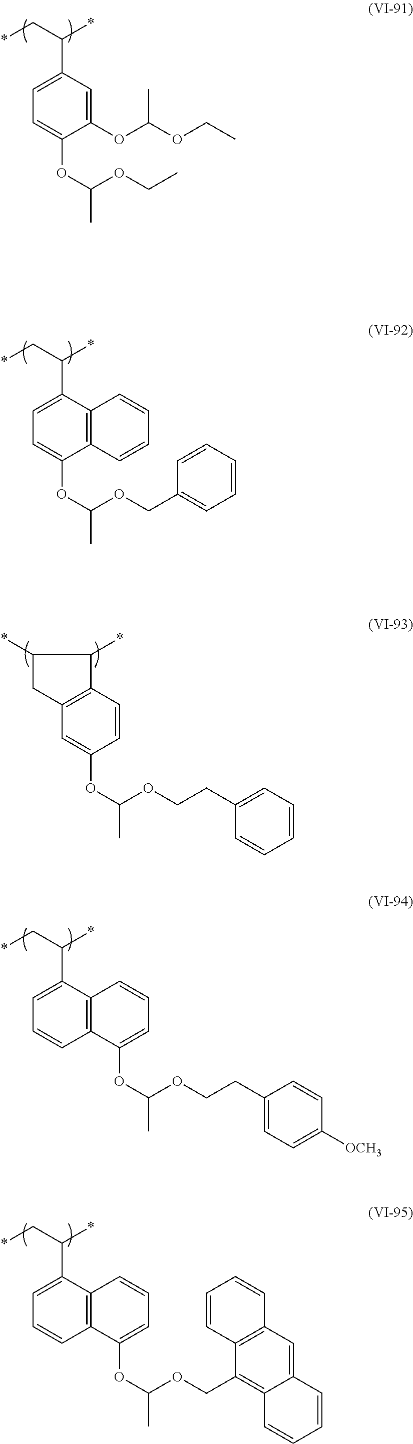

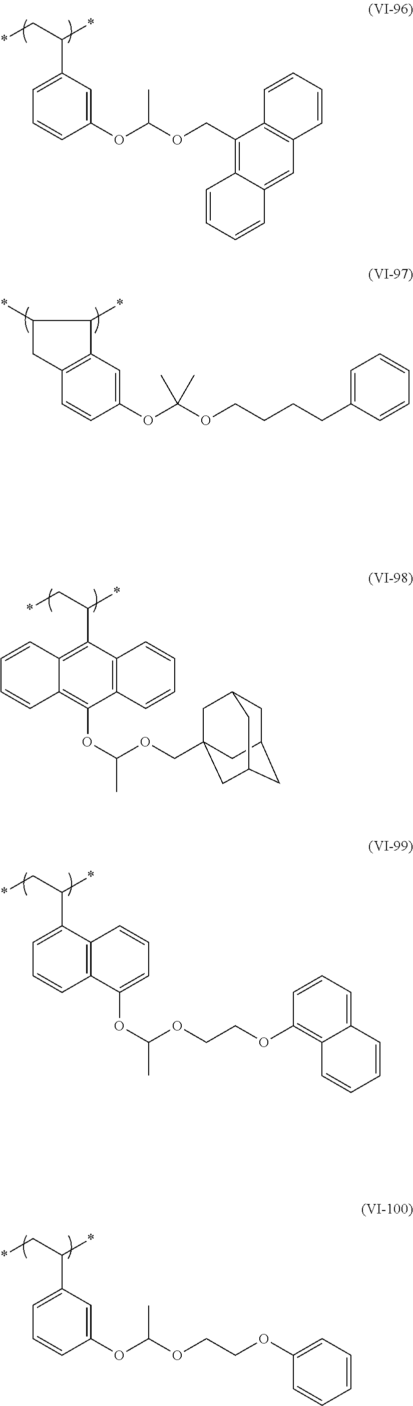

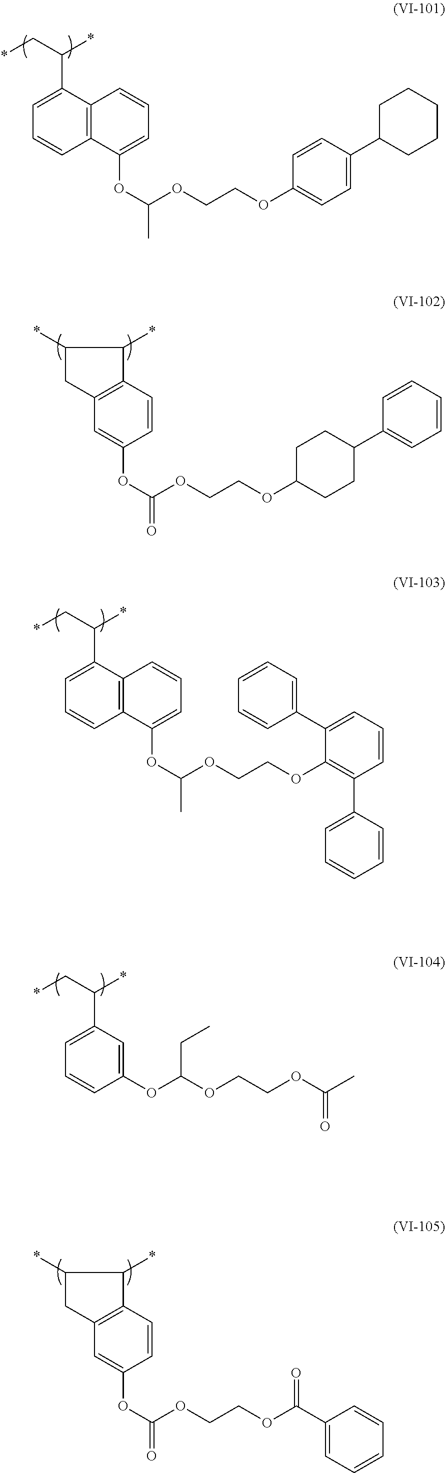

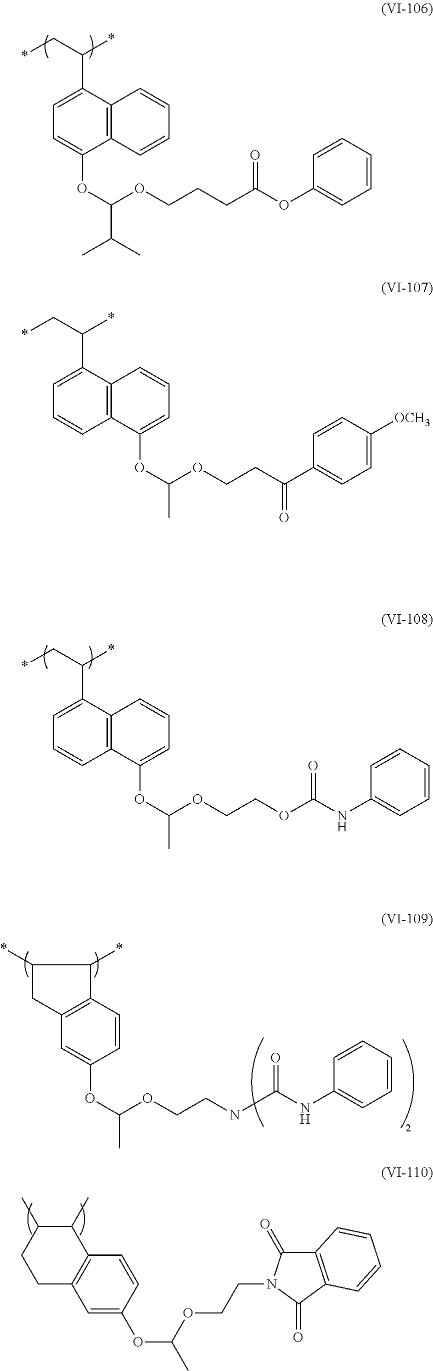

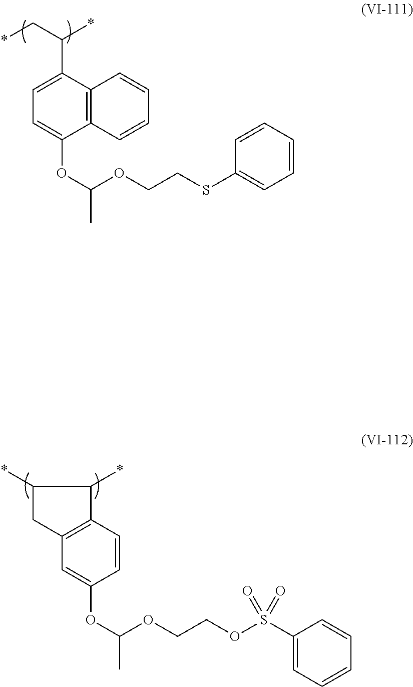

When the resin (P) according to the present invention contains the repeating unit (B), the content thereof based on all the repeating units of the resin (P) is preferably in the range of 1 to 70 mol %, more preferably 5 to 50 mol %.

[Repeating Unit (C)]

The resin (P) may contain a repeating unit (C), different from the above repeating units (A), containing a group that is decomposed by the action of an alkali developer to thereby increase its rate of dissolution into the alkali developer.

As the group that is decomposed by the action of an alkali developer to thereby increase its rate of dissolution into the alkali developer, there can be mentioned a lactone structure, a phenyl ester structure or the like.

It is preferred for the repeating unit (C) to be any of the repeating units of general formula (AII) below.

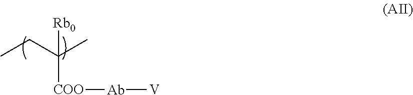

In the general formula (AII), Rb₀ represents a hydrogen atom, a halogen atom or an optionally substituted alkyl group (preferably having 1 to 4 carbon atoms).

As preferred substituents that may be introduced in the alkyl group represented by Rb₀, there can be mentioned a hydroxyl group and a halogen atom. As the halogen atom represented by Rb₀, there can be mentioned a fluorine atom, a chlorine atom, a bromine atom or an iodine atom. Rb₀ is preferably a hydrogen atom, a methyl group, a hydroxymethyl group or a trifluoromethyl group. A hydrogen atom and a methyl group are especially preferred.

Ab represents a single bond, an alkylene group, a bivalent connecting group with a monocyclic or polycyclic aliphatic hydrocarbon ring structure, an ether group, an ester group, a carbonyl group, or a bivalent connecting group resulting from combination of these. A single bond and any of the bivalent connecting groups of the formula -Ab₁-CO₂— are preferred.

Ab₁ is a linear or branched alkylene group or a monocyclic or polycyclic aliphatic hydrocarbon ring group, being preferably a methylene group, an ethylene group, a cyclohexylene group, an adamantylene group or a norbornylene group.

V represents a group that is decomposed by the action of an alkali developer to thereby increase its rate of dissolution into the alkali developer. V is preferably a group with an ester bond. In particular, a group with a lactone structure is more preferred.

The group with a lactone structure is not limited as long as a lactone structure is introduced therein. A 5 to 7-membered ring lactone structure is preferred, and one resulting from the condensation of a 5 to 7-membered ring lactone structure with another cyclic structure effected in a fashion to form a bicyclo structure or spiro structure is especially preferred. More preferably, V is a group with any of the lactone structures of the general formulae (LC₁₋₁) to (LC₁₋₁₇) set forth hereinbefore. The resin (P) may further contain, other than the repeating unit (C), a repeating unit containing a lactone structure directly bonded to the principal chain of the resin. Preferred lactone structures are those of the formulae (LC₁₋₁), (LC₁₋₄), (LC₁₋₅), (LC₁₋₆), (LC₁₋₁₃) and (LC₁₋₁₄). The use of these specified lactone structures enhances the line edge roughness performance and development defect performance.

The repeating units of general formula (III-1) below are preferably used as those of the general formula (AII).

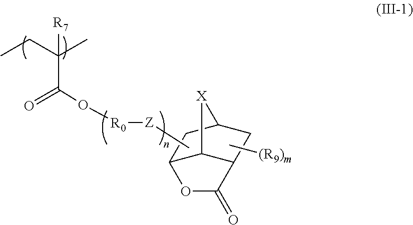

In the general formula (III-1),

R₀, or each of R₀s independently, represents an alkylene group, a cycloalkylene group or a combination thereof.

Z, or each of Zs independently, represents an ether bond, an ester bond, an amido bond, a urethane bond or a urea bond.

The urethane bond is any of those of formula below.

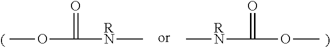

The urea bond is any of those of formula below.

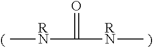

In the formulae, R represents a hydrogen atom, an alkyl group, a cycloalkyl group or an aryl group.

n represents the number of repetitions of any of the structures of the formula —R₀—Z— and is an integer of 0 to 5.

R₇ represents a hydrogen atom, a halogen atom or an alkyl group.

Each of the alkylene group and cycloalkylene group represented by R₀ may have one or more substituents.

Z preferably represents an ether bond or an ester bond, most preferably an ester bond.

R₉, or each of R₉s independently, represents an alkyl group, a cycloalkyl group, an alkoxycarbonyl group, a cyano group, a hydroxyl group or an alkoxy group. When there are R₉s, two R₉s may be bonded to each other to thereby form a ring.

X represents an alkylene group, an oxygen atom or a sulfur atom, and

m is the number of substituents and is an integer of 0 to 5. Preferably, m is 0 or 1.

The alkyl group represented by R₉ is preferably an alkyl group having 1 to 4 carbon atoms, more preferably a methyl group or an ethyl group and most preferably a methyl group. As the cycloalkyl group, there can be mentioned a cyclopropyl group, a cyclobutyl group, a cyclopentyl group or a cyclohexyl group. As the alkoxycarbonyl group, there can be mentioned a methoxycarbonyl group, an ethoxycarbonyl group, an n-butoxycarbonyl group, a t-butoxycarbonyl group or the like. As the alkoxy group, there can be mentioned a methoxy group, an ethoxy group, a propoxy group, an isopropoxy group, a butoxy group or the like. Each of these groups may have one or more substituents. As the substituent, there can be mentioned a hydroxyl group, an alkoxy group such as a methoxy group or an ethoxy group, a cyano group, or a halogen atom such as a fluorine atom. More preferably, R₉ is a methyl group, a cyano group or an alkoxycarbonyl group, further more preferably a cyano group.

As the alkylene group represented by X, there can be mentioned a methylene group, an ethylene group or the like. Preferably, X is an oxygen atom or a methylene group, more preferably a methylene group.

When m is 1 or greater, it is preferred for the substitution with at least one R₉ to take place at the α- or β-position of the carbonyl group of the lactone. The substitution at the α-position is especially preferred.

When the resin (P) according to the present invention contains the repeating unit (C), the content thereof based on all the repeating units of the resin (P) is preferably in the range of 1 to 60 mol %, more preferably 2 to 50 mol % and further more preferably 5 to 50 mol %. One type of repeating unit (C) may be used alone, or two or more types thereof may be used in combination.

Specific examples of the repeating units (C) contained in the resin (P) will be shown below, which however in no way limit the scope of the present invention. In the formulae, Rx represents H, CH₃, CH₂OH or CF₃.

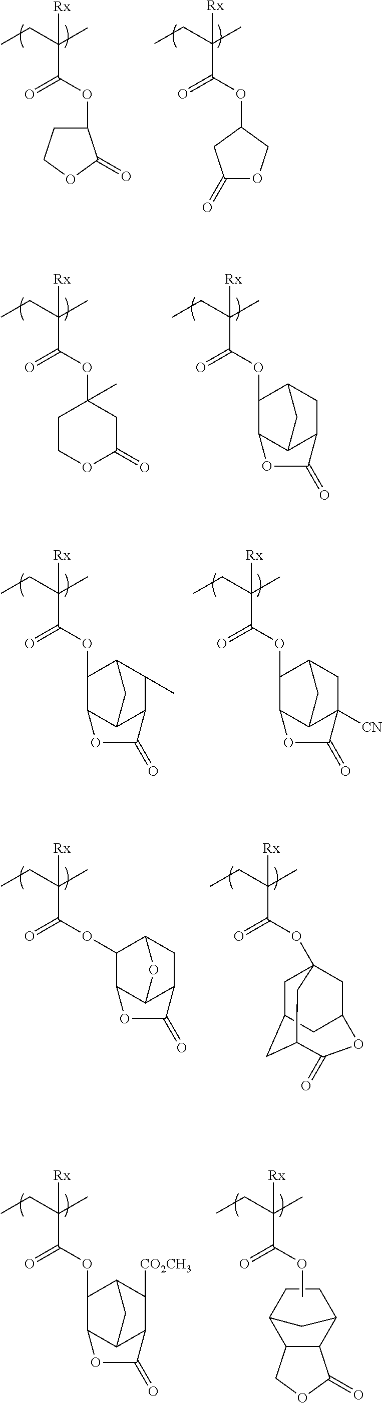

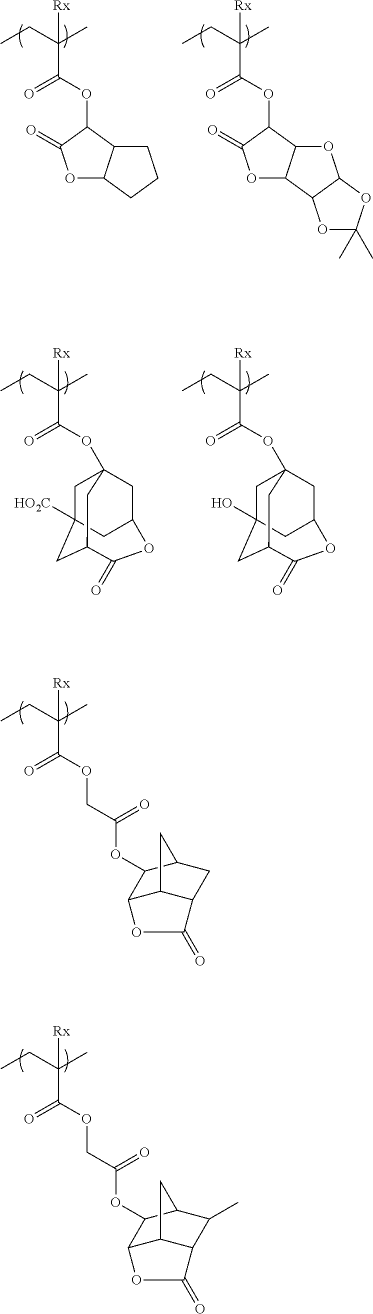

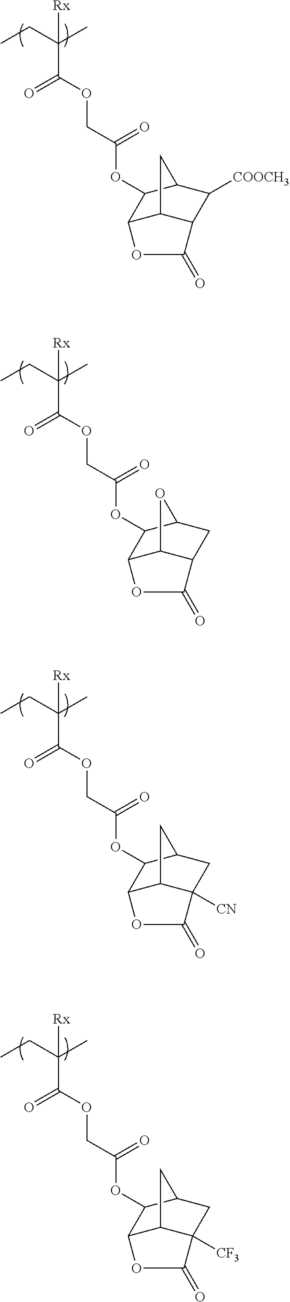

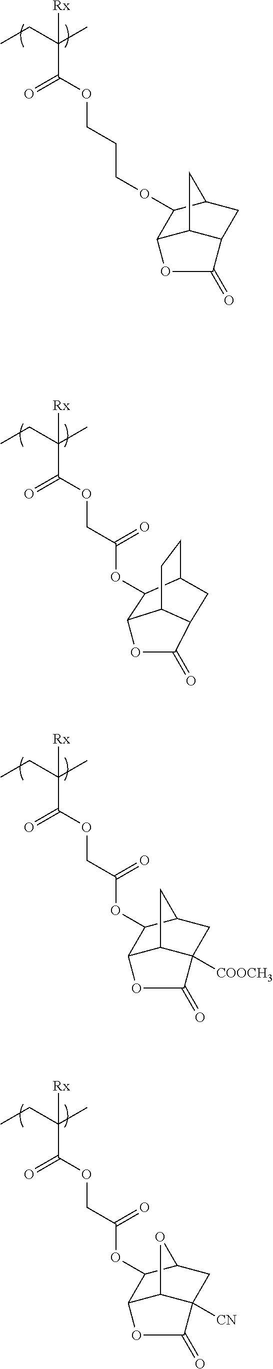

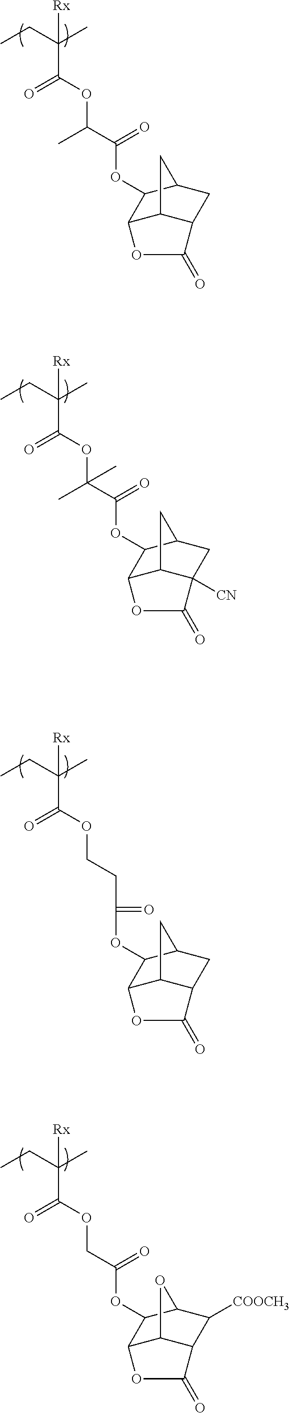

[Repeating Unit (D)]

The resin (P) may further contain a repeating unit (D) having a hydroxy group or a cyano group other than repeating units (A), (B), and (C). The containment of this repeating unit would realize enhancements of adhesion to substrate and developer affinity.

The repeating unit (D) is preferably a repeating unit having an alicyclic hydrocarbon structure substituted with a hydroxy group or a cyano group. Further, the repeating unit (D) is preferably free from the acid-decomposable group. In the alicyclic hydrocarbon structure substituted with a hydroxy group or a cyano group, the alicyclic hydrocarbon structure preferably consists of an adamantyl group, a diamantyl group or a norbornane group. As preferred alicyclic hydrocarbon structures substituted with a hydroxy group or a cyano group, the partial structures represented by the following general formulae (VIIa) to (VIId) can be exemplified.

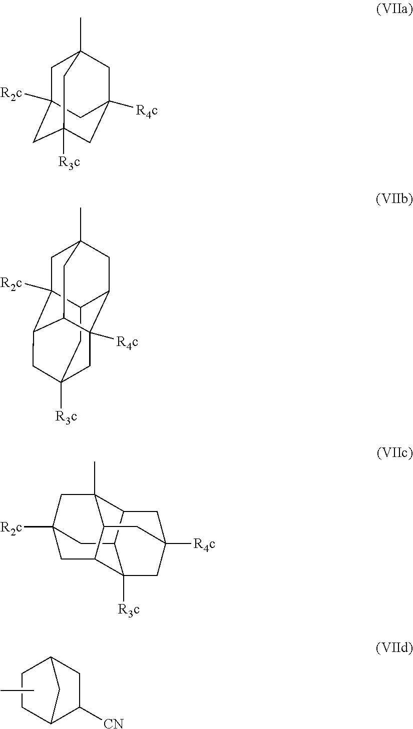

In the general formulae (VIIa) to (VIIc),

each of R₂c to R₄c independently represents a hydrogen atom, a hydroxy group or a cyano group, with the proviso that at least one of the R₂c to R₄c represents a hydroxy group or a cyano group. Preferably, one or two of the R₂c to R₄c are hydroxy groups and the remainder is a hydrogen atom. In the general formula (VIIa), more preferably, two of the R₂c to R₄c are hydroxy groups and the remainder is a hydrogen atom.

As the repeating units having any of the partial structures represented by the general formulae (VIIa) to (VIId), those of the following general formulae (AIIa) to (AIId) can be exemplified.

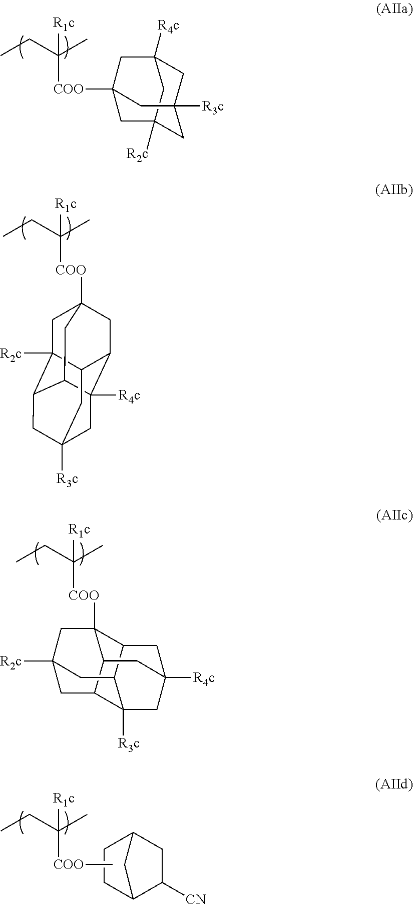

In the general formulae (AIIa) to (AIId),

R¹c represents a hydrogen atom, a methyl group, a trifluoromethyl group or a hydroxymethyl group.

R²c to R⁴c have the same meaning as those of the general formulae (VIIa) to (VIIc).

When the resin (P) according to the present invention contains the repeating unit (D) containing a hydroxyl group or a cyano group, the content thereof based on all the repeating units of the resin (P) is preferably in the range of 1 to 40 mol %, more preferably 2 to 30 mol % and further more preferably 5 to 25 mol %.

Specific examples of the repeating units (D) containing a hydroxyl group or a cyano group will be shown below, which however in no way limit the scope of the present invention.

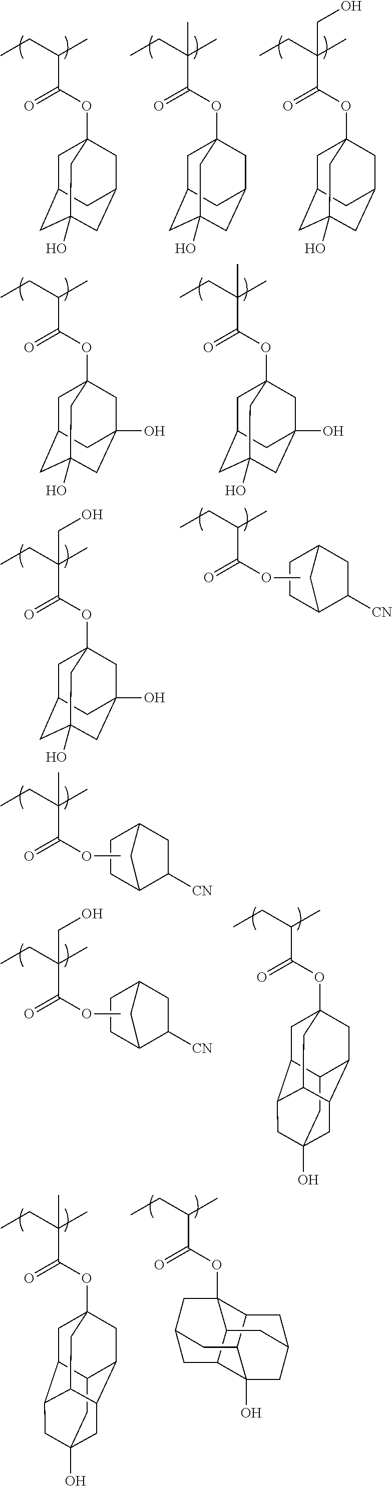

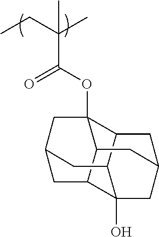

The resin (P) according to the present invention may contain a repeating unit containing an alkali-soluble group. As the alkali-soluble group, there can be mentioned a phenolic hydroxyl group, a carboxyl group, a sulfonamido group, a sulfonylimido group, a bisulfonylimido group or an aliphatic alcohol substituted at its a-position with an electron withdrawing group (for example, a hexafluoroisopropanol group).

When the exposure is performed using an ArF excimer laser, it is preferred to contain a repeating unit containing a carboxyl group. The incorporation of the repeating unit containing an alkali-soluble group increases the resolution in contact hole usage. The repeating unit containing an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a mono- or polycyclohydrocarbon structure. The repeating unit of acrylic acid or methacrylic acid is especially preferred.

When the resin (P) contains the repeating unit containing an alkali-soluble group, the content of the repeating unit based on all the repeating units of the resin (P) is preferably in the range of 1 to 20 mol %, more preferably 1 to 15 mol % and further more preferably 2 to 10 mol %.

Specific examples of the repeating units containing an alkali-soluble group will be shown below, which however in no way limit the scope of the present invention. In the specific examples, Rx represents H, CH₃, CH₂OH, or CF₃.

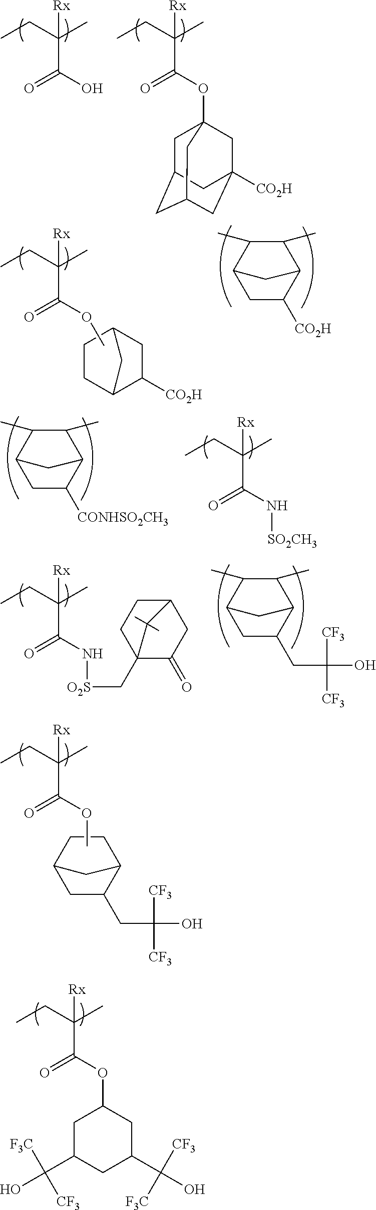

When the exposure is performed using a KrF excimer laser light, electron beams, X-rays or high-energy rays of wavelength 50 nm or shorter (for example, EUV), it is preferred to employ a repeating unit containing an aromatic ring group and an alkali-soluble group. The structures of general formula (IV) below are more preferred.

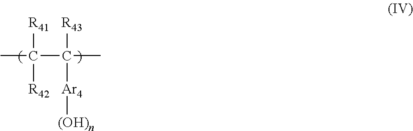

In the formula, each of R₄₁, R₄₂ and R₄₃ independently represents a hydrogen atom, an alkyl group, a cycloalkyl group, a halogen atom, a cyano group or an alkoxycarbonyl group. R₄₂ may be bonded to Ar₄ to thereby form a ring (preferably, a 5-membered or 6-membered ring). If so, R₄₂ represents an alkylene group.

Ar₄ represents a bivalent aromatic ring group, and n is an integer of 1 to 4.

Specific examples of the alkyl group, cycloalkyl group, halogen atom and alkoxycarbonyl group represented by each of R₄₁, R₄₂ and R₄₃ in the general formula (IV) and specific examples of the substituents that can be introduced therein are the same as set forth above in connection with the general formula (V).

The bivalent aromatic ring group represented by Ar₄ may have one or more substituents. As preferred examples thereof, there can be mentioned an arylene group having 6 to 18 carbon atoms, such as a phenylene group, a tolylene group, a naphthylene group or an anthracenylene group, and a bivalent aromatic ring group containing a hetero-ring, such as thiophene, furan, pyrrole, benzothiophene, benzofuran, benzopyrrole, triazine, imidazole, benzimidazole, triazole, thiadiazole or thiazole.

As preferred substituents that can be introduced in the above groups, there can be mentioned an alkyl group, an alkoxy group, such as a methoxy group, an ethoxy group, a hydroxyethoxy group, a propoxy group, hydroxypropoxy group or a butoxy group, and an aryl group, such as a phenyl group, as mentioned above with respect to R₅₁ to R₅₃ in the general formula (V).

Ar₄ is more preferably an optionally substituted arylene group having 6 to 18 carbon atoms. A phenylene group, a naphthylene group and a biphenylene group are especially preferred.

Specific examples of the repeating units each containing an aromatic ring group and an alkali-soluble group will be shown below, which however in no way limit the scope of the present invention. In the formulae, a is an integer of 0 to 2.

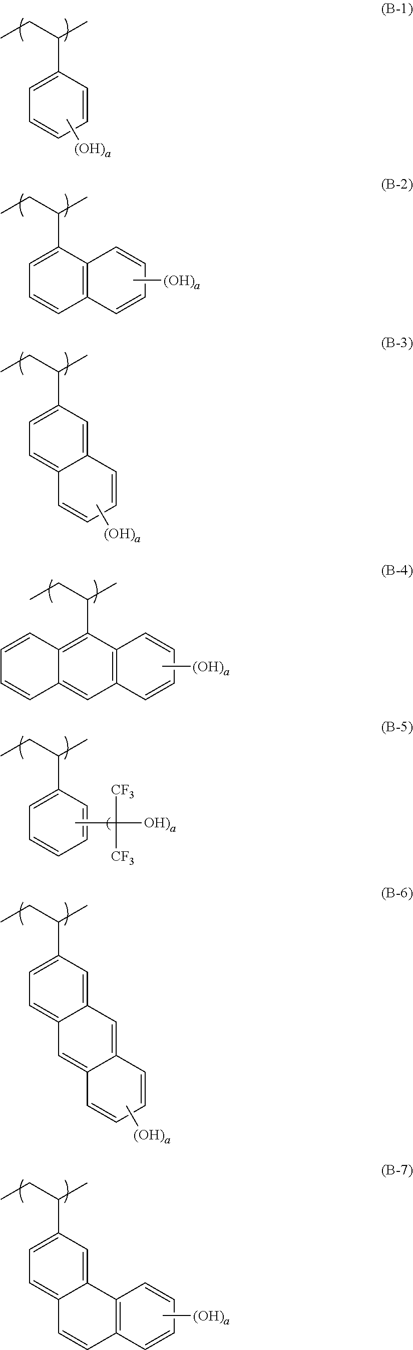

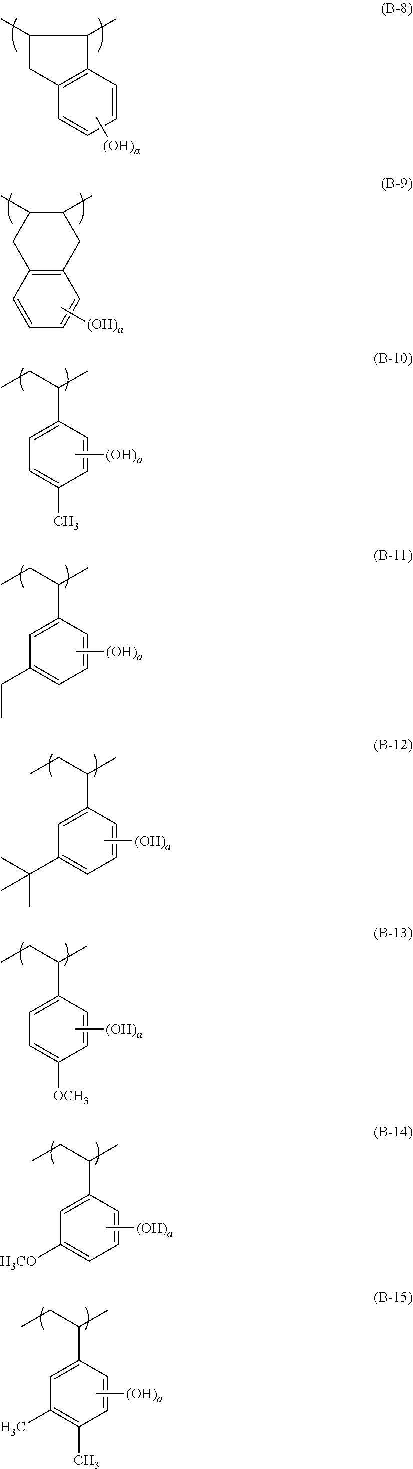

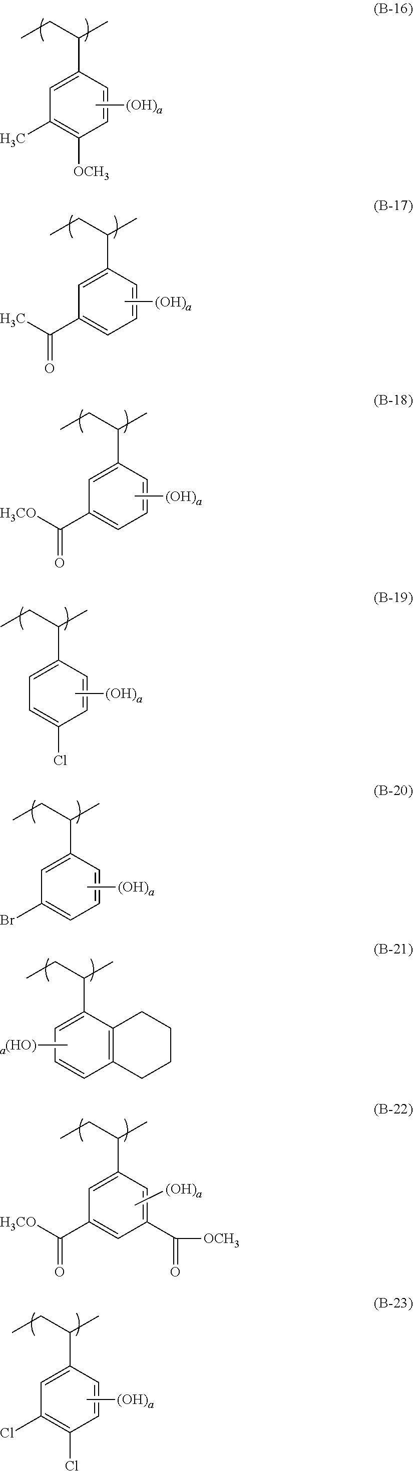

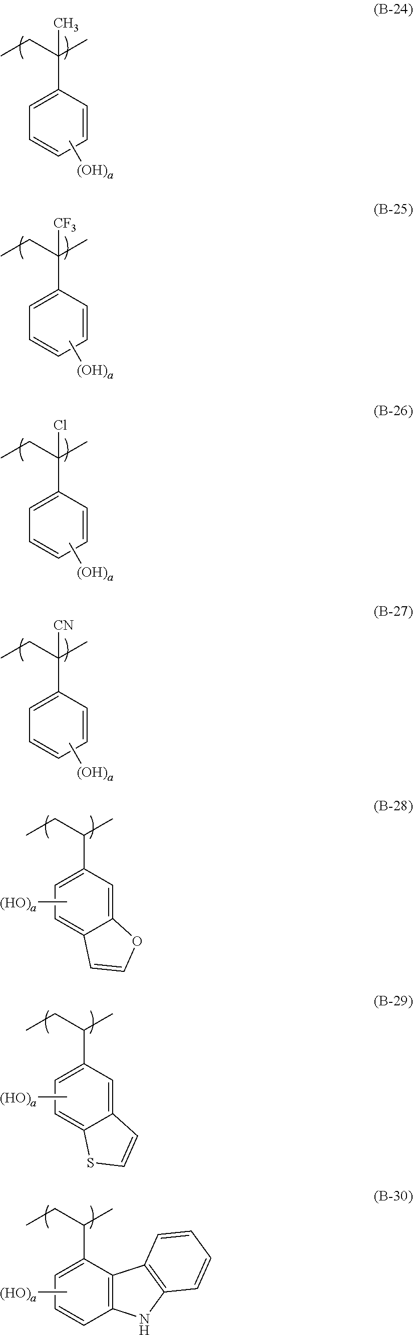

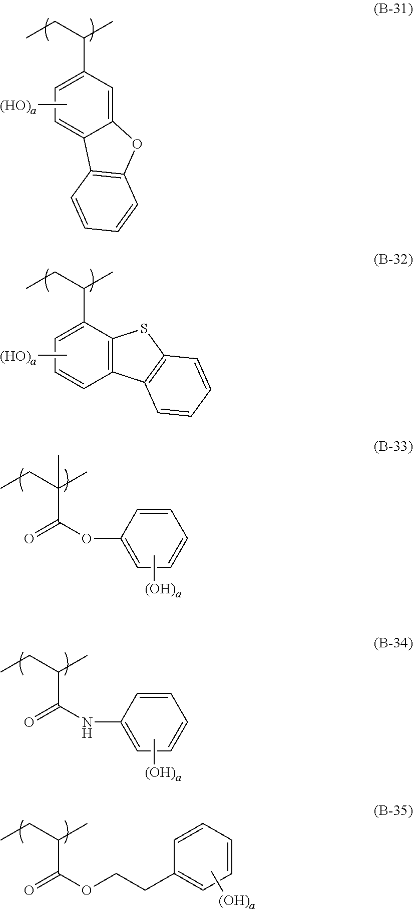

Resin (P) may further contain a repeating unit that has an alicyclic hydrocarbon structure having no polar group and does not exhibit any acid decomposability. As such, for example, any of the repeating units represented by general formula. (VII) below can be exemplified.

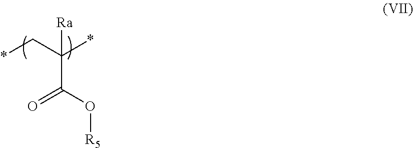

In the general formula (VII), R₅ represents a hydrocarbon group having at least one cyclic structure in which neither a hydroxyl group nor a cyano group is contained.

Ra represents a hydrogen atom, an alkyl group or a group of the formula —CH₂—O—Ra₂ in which Ra₂ represents a hydrogen atom, an alkyl group or an acyl group. Ra is preferably a hydrogen atom, a methyl group, a hydroxymethyl group or a trifluoromethyl group, further preferably a hydrogen atom or a methyl group.

The alicyclic hydrocarbon structures contained in the groups R₅ include a monocyclic hydrocarbon group and a polycyclic hydrocarbon group. As the monocyclic hydrocarbon group, there can be mentioned, for example, a cycloalkyl group having 3 to 12 carbon atoms, such as a cyclopentyl group, a cyclohexyl group, a cycloheptyl group or a cyclooctyl group, or a cycloalkenyl group having 3 to 12 carbon atoms, such as a cyclohexenyl group. Preferably, the monocyclic hydrocarbon group is a monocyclic hydrocarbon group having 3 to 7 carbon atoms. A cyclopentyl group and a cyclohexyl group are more preferred.

The polycyclic hydrocarbon groups include ring-assembly hydrocarbon groups and crosslinked-ring hydrocarbon groups. Examples of the ring-assembly hydrocarbon groups include a bicyclohexyl group, a perhydronaphthalenyl group and the like. As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings. Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenalene rings.

As preferred crosslinked-ring hydrocarbon rings, there can be mentioned a norbornyl group, an adamantyl group, a bicyclooctanyl group, a tricyclo[5.2.1.0^{2,6}]decanyl group and the like. As more preferred crosslinked-ring hydrocarbon rings, there can be mentioned a norbornyl group and an adamantyl group.

These alicyclic hydrocarbon groups may have one or more substituents. As preferred substituents, a halogen atom, an alkyl group, a hydroxyl group protected by a protective group, and an amino group protected by a protective group can be exemplified. The halogen atom is preferably a bromine, chlorine or fluorine atom, and the alkyl group is preferably a methyl, ethyl, butyl or t-butyl group. The alkyl group may further have one or more substituents. As the optional substituent, a halogen atom, an alkyl group, a hydroxyl group protected by a protective group, and an amino group protected by a protective group can be exemplified.

As the protective group, an alkyl group, a cycloalkyl group, an aralkyl group, a substituted methyl group, a substituted ethyl group, an alkoxycarbonyl group and an aralkyloxycarbonyl group can be exemplified. Preferred alkyl groups include alkyl groups having 1 to 4 carbon atoms. Preferred substituted methyl groups include methoxymethyl, methoxythiomethyl, benzyloxymethyl, t-butoxymethyl and 2-methoxyethoxymethyl groups. Preferred substituted ethyl groups include 1-ethoxyethyl and 1-methyl-1-methoxyethyl groups. Preferred acyl groups include aliphatic acyl groups having 1 to 6 carbon atoms, such as formyl, acetyl, propionyl, butyryl, isobutyryl, valeryl and pivaloyl groups. Preferred alkoxycarbonyl groups include alkoxycarbonyl groups having 1 to 4 carbon atoms and the like.

When the resin (P) contains the repeating unit that has an alicyclic hydrocarbon structure having no polar group and does not exhibit any acid decomposability, the content of the repeating unit based on all the repeating units of the resin (P) is preferably in the range of 1 to 40 mol %, more preferably 2 to 20 mol %.

Specific examples of the repeating units that have an alicyclic hydrocarbon structure having no polar group and do not exhibit any acid decomposability will be shown below, which however in no way limit the scope of the present invention. In the formulae, Ra represents H, CH₃, CH₂OH or CF₃.

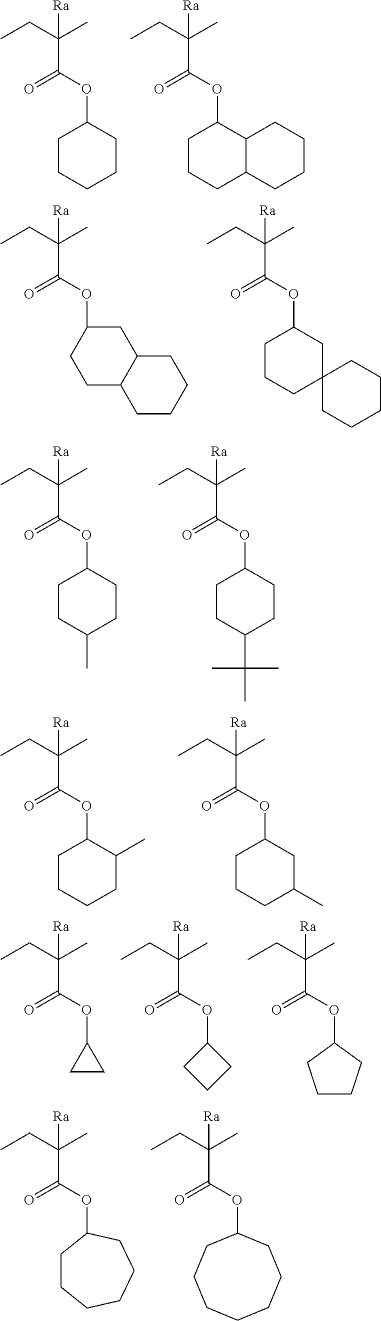

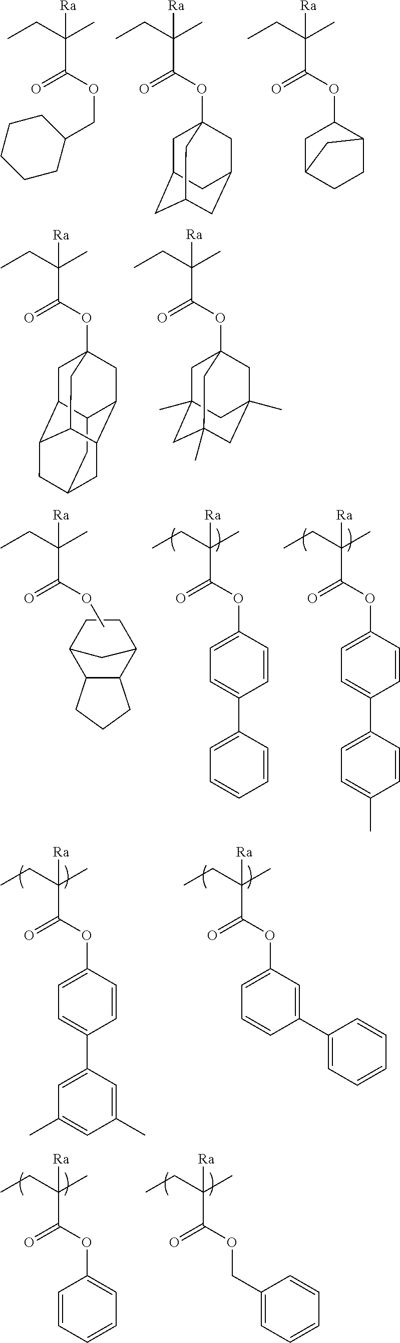

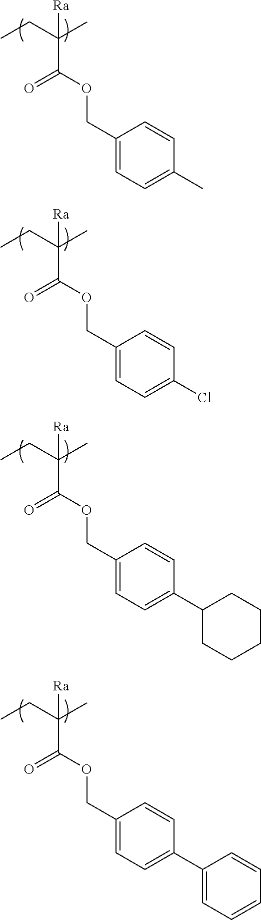

The resin (P) according to the present invention may contain various repeating structural units other than the foregoing repeating structural units for the purpose of regulating the dry etching resistance, standard developer adaptability, substrate adhesion, resist profile and generally required properties of resists such as resolving power, heat resistance and sensitivity.

As such other repeating structural units, those corresponding to the following monomers can be exemplified, which however are nonlimiting.

Such other repeating structural units would permit fine regulation of the properties required to have by the resin for use in the composition of the present invention, especially,

(1) solubility in applied solvents,

(2) film forming easiness (glass transition temperature),

(3) alkali developability,

(4) film thinning (selection of hydrophilicity/hydrophobicity and alkali-soluble group),

(5) adhesion of unexposed areas to substrate, and

(6) dry etching resistance, etc.

As the above-mentioned monomers, compounds having an unsaturated bond capable of addition polymerization, selected from among acrylic esters, methacrylic esters, acrylamides, methacrylamides, allyl compounds, vinyl ethers, vinyl esters and the like can be exemplified.

The monomers are not limited to the above, and unsaturated compounds capable of addition polymerization that are copolymerizable with the monomers corresponding to the above various repeating structural units can be used in the copolymerization.

The molar ratios of individual repeating structural units contained in the resin (P) for use in the composition of the present invention are appropriately determined from the viewpoint of regulation of not only the resist dry etching resistance but also the standard developer adaptability, substrate adhesion, resist profile and generally required properties of resists such as resolving power, heat resistance and sensitivity.

Further, when the composition further contains hydrophobic resin to be explained below, it is preferred for the resin (P) not to contain a fluorine atom and a silicon atom from the viewpoint of compatibility with the hydrophobic resin.

The resin (P) according to the present invention may have any of the random, block, comb and star configurations.

The resin (P) can be synthesized by, for example, the radical, cation or anion polymerization of unsaturated monomers corresponding to given structures. Further, the intended resin can be obtained by first polymerizing unsaturated monomers corresponding to the precursors of given structures and thereafter carrying out a polymer reaction.

As general synthetic methods, a batch polymerization method in which a monomer species and an initiator are dissolved in a solvent and heated so as to accomplish polymerization, and a dropping polymerization method in which a solution of monomer species and initiator is added by dropping to a heated solvent over a period of 1 to 10 hours can be exemplified and preferred is the dropping polymerization method.

As the solvent for use in the polymerization, there can be mentioned, for example, any of the solvents usable in the preparation of the actinic-ray- or radiation-sensitive resin composition, to be described hereinafter, or the like. It is preferred to perform the polymerization with the use of the same solvent as employed in the composition according to the present invention. This would inhibit particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxy group is especially preferred. As preferred initiators, azobisisobutyronitrile, azobisdimethylvaleronitrile, and dimethyl 2,2′-azobis(2-methylpropionate) can be exemplified. According to necessity, the polymerization may be performed in the presence of chain transfer agent such as alkylmercaptan.

The concentration during the reaction is usually in the range of 5 to 70 mass %, preferably 10 to 50 mass %. The reaction temperature is usually in the range of 10° C. to 150° C., preferably 30° C. to 120° C., and more preferably 40° C. to 100° C.

The reaction time is generally in the range of 1 to 48 hours, preferably 1 to 24 hours and more preferably 1 to 12 hours.

After the completion of the reaction, the reaction mixture is allowed to stand still to cool to room temperature and purified. In the purification, use can be made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to thereby coagulate the resin in the poor solvent and thus remove residual monomers, etc., and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to thereby precipitate the resin as a solid.

The solvent for use in the operation of precipitation or re-precipitation from a polymer solution (precipitation or re-precipitation solvent) is not limited as long as the solvent is a poor solvent for the polymer. Use can be made of any solvent appropriately selected from among a hydrocarbon, a halogenated hydrocarbon, a nitro compound, an ether, a ketone, an ester, a carbonate, an alcohol, a carboxylic acid, water, a mixed solvent containing these solvents and the like, according to the type of the polymer. Of these, it is preferred to employ a solvent containing at least an alcohol (especially methanol or the like) or water as the precipitation or re-precipitation solvent.

The amount of precipitation or re-precipitation solvent used can be appropriately selected taking efficiency, yield, etc. into account. Generally, the amount is in the range of 100 to 10,000 parts by mass, preferably 200 to 2000 parts by mass and more preferably 300 to 1000 parts by mass per 100 parts by mass of the polymer solution.

The temperature at which the precipitation or re-precipitation is carried out can be appropriately selected taking efficiency and operation easiness into account. Generally, the temperature is in the range of about 0° to 50° C., preferably about room temperature (for example, about 20° to 35° C.). The operation of precipitation or re-precipitation can be carried out by a routine method, such as a batch or continuous method, with the use of a customary mixing vessel, such as an agitation vessel.

The polymer resulting from the precipitation or re-precipitation is generally subjected to customary solid/liquid separation, such as filtration or centrifugal separation, and dried before use. The filtration is carried out with the use of a filter medium ensuring solvent resistance, preferably under pressure. The drying is performed at about 30° to 100° C., preferably about 30° to 50° C. under ordinary pressure or reduced pressure (preferably under reduced pressure).

Alternatively, after the precipitation and separation of the resin, the resultant resin may be once more dissolved in a solvent and brought into contact with a solvent in which the resin is poorly soluble or insoluble. Specifically, the method may include the steps of, after the completion of the radical polymerization reaction, bringing the polymer into contact with a solvent wherein the polymer is poorly soluble or insoluble to thereby attain resin precipitation (step a), separating the resin from the solution (step b), re-dissolving the resin in a solvent to thereby obtain a resin solution A (step c), thereafter bringing the resin solution A into contact with a solvent wherein the resin is poorly soluble or insoluble amounting to less than 10 times (preferably 5 times or less) the volume of the resin solution A to thereby precipitate a resin solid (step d) and separating the precipitated resin (step e).

Impurities, such as metals, should naturally be of minute quantity in the resin (P). Further, the content of residual monomers and oligomer components is preferably in the range of 0 to 10 mass %, more preferably 0 to 5 mass % and further more preferably 0 to 1 mass %. Accordingly, the amount of in-liquid foreign matter can be decreased, and any change of, sensitivity, etc., over time can be reduced.

The molecular weight of the resin (P) according to the present invention is not particularly limited. Preferably, the weight average molecular weight thereof is in the range of 1000 to 200,000. It is more preferably in the range of 2000 to 60,000, most preferably 2000 to 30,000. The regulation of the weight average molecular weight so as to fall within the range of 1000 to 200,000 helps to prevent any deteriorations of heat resistance and dry etching resistance and also to prevent any deterioration of developability and increase of viscosity leading to poor film forming property. Herein, the weight average molecular weight of the resin refers to the molecular weight in terms of polystyrene molecular weight measured by GPC (carrier: tetrahydrofuran (THF)).

The dispersity (Mw/Mn) of the resin is preferably in the range of 1.00 to 5.00, more preferably 1.03 to 3.50 and further more preferably 1.05 to 2.50. The narrower the molecular weight distribution, the more excellent the resolution and resist configuration and also the smoother the side wall of the resist pattern to thereby attain an excellence in roughness characteristics.

One type of resin (P) according to the present invention may be used alone, or two or more types thereof may be used in combination. The content of resin (P) or resins (P) is preferably in the range of 30 to 99 mass %, more preferably 60 to 95 mass %, based on the total solids of the actinic-ray- or radiation-sensitive resin composition of the present invention.

Specific examples of resin (P) will be shown below, which however in no way limit the scope of the present invention.

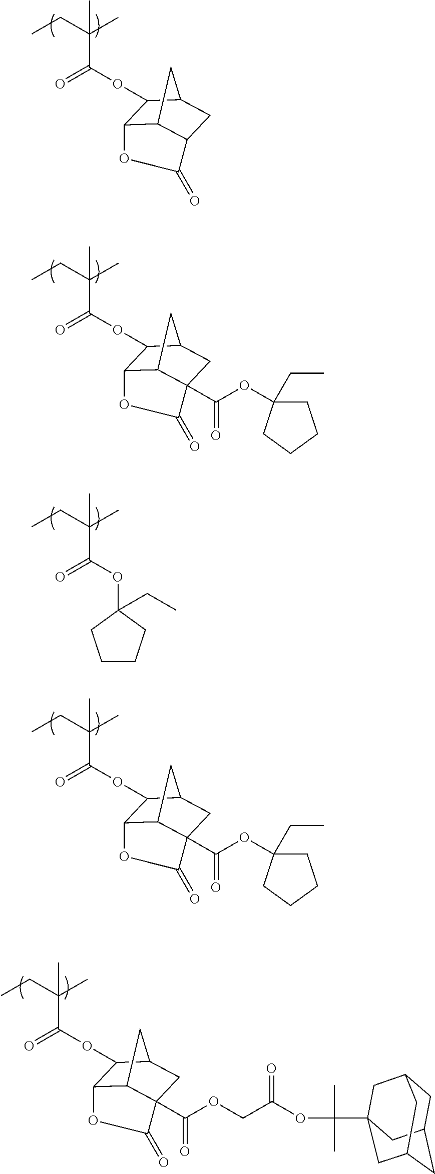

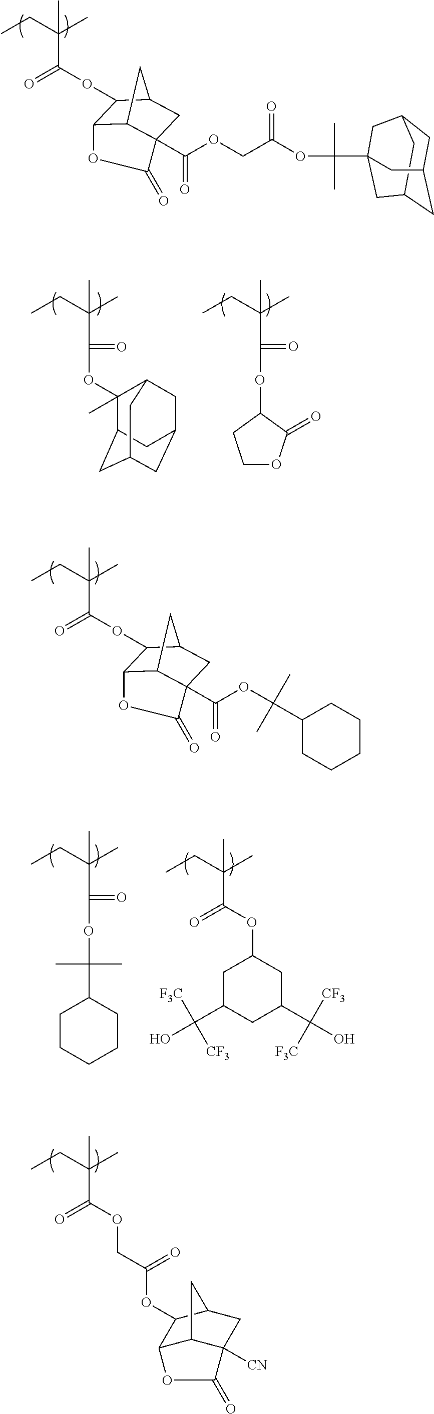

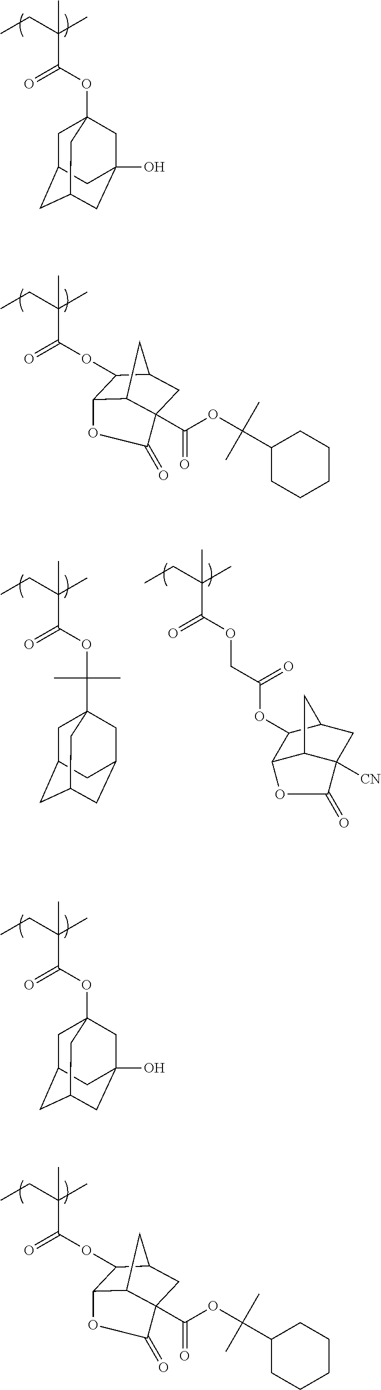

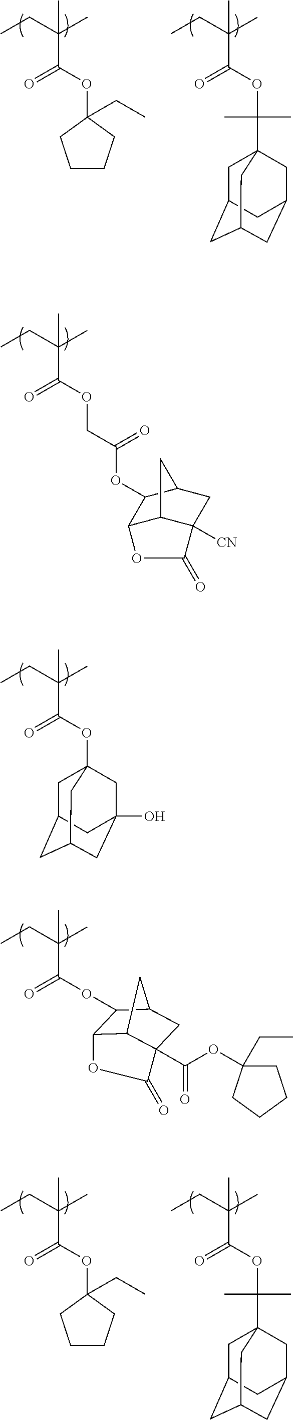

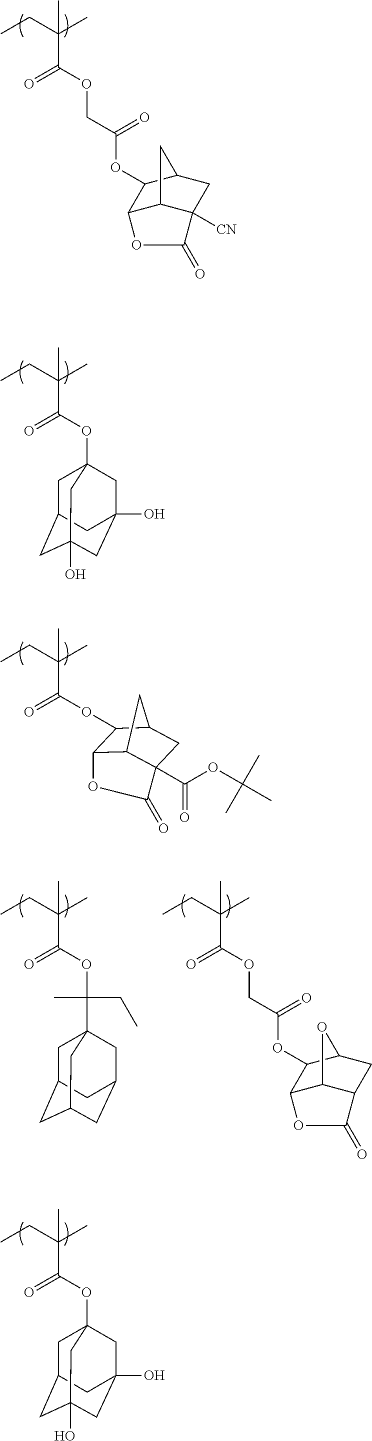

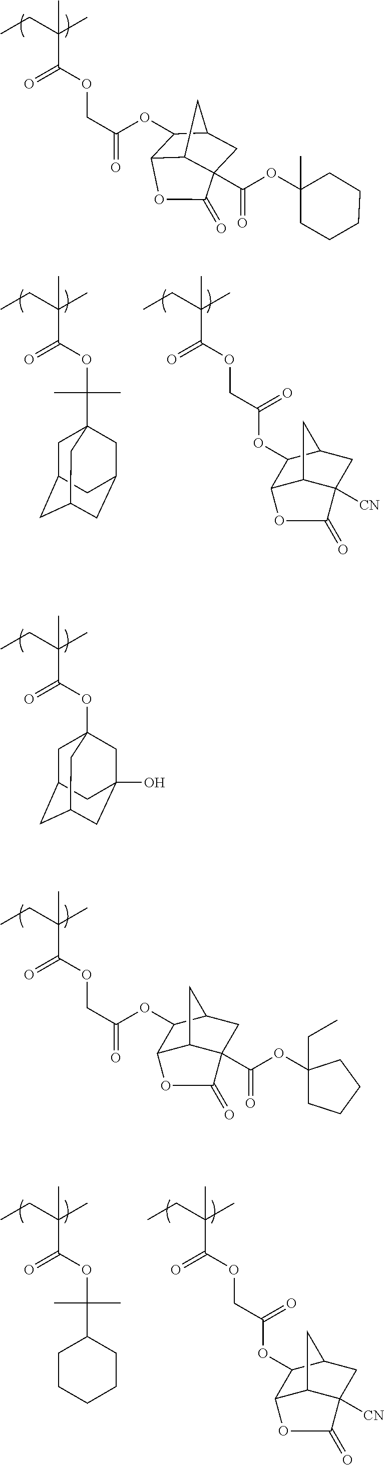

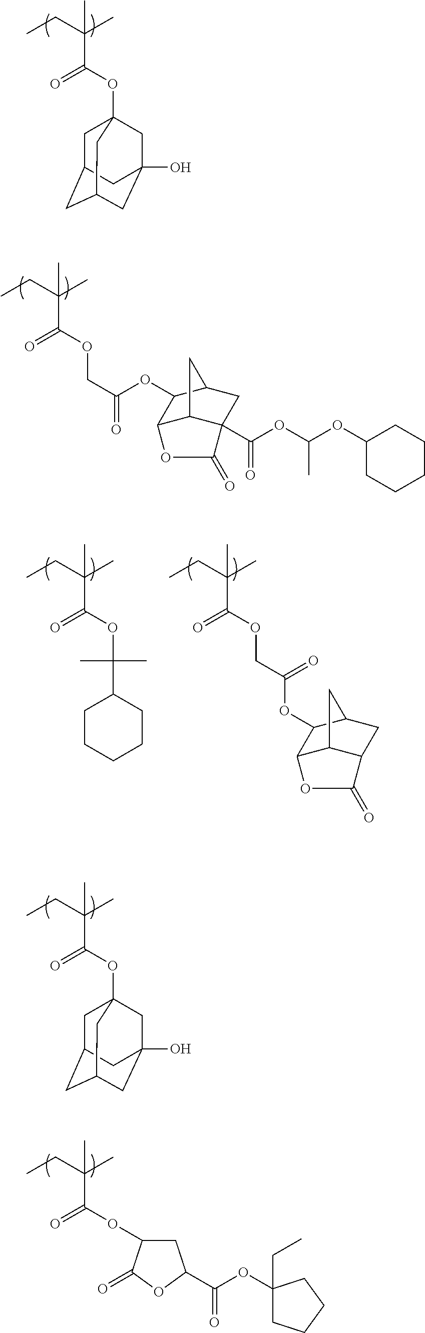

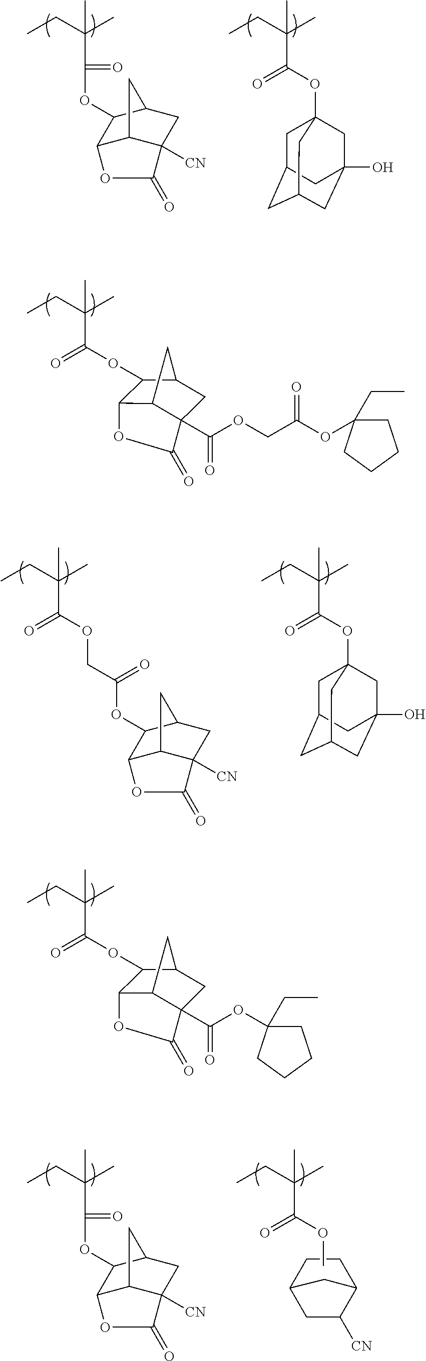

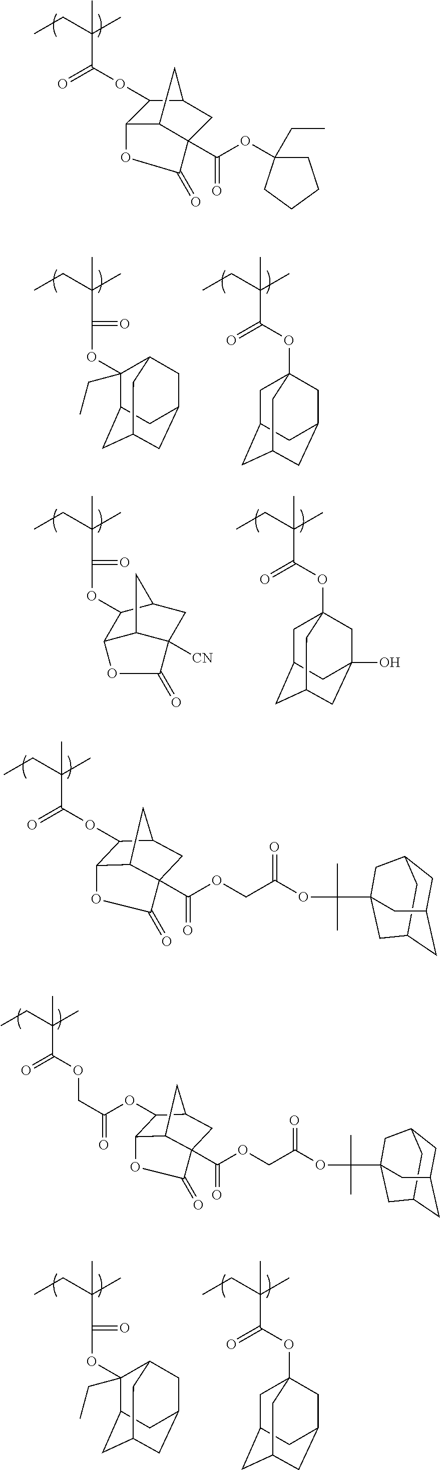

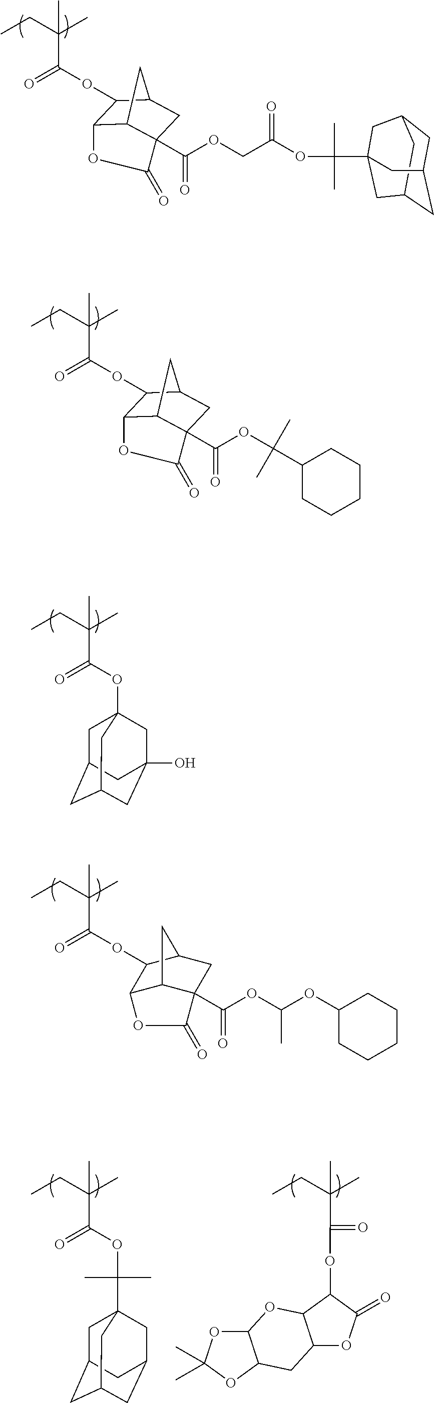

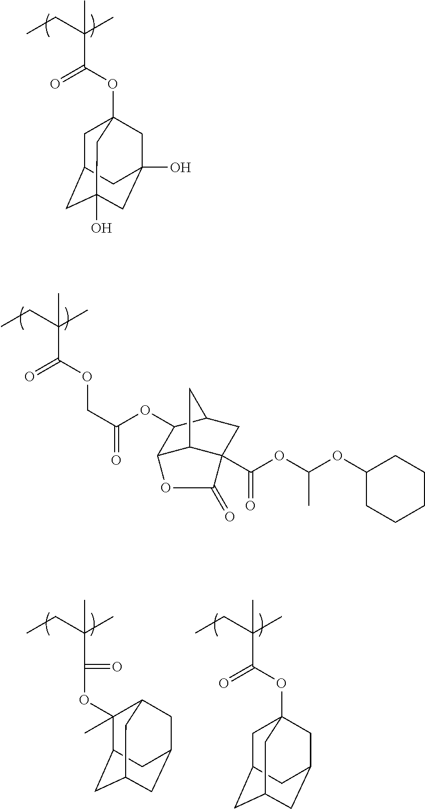

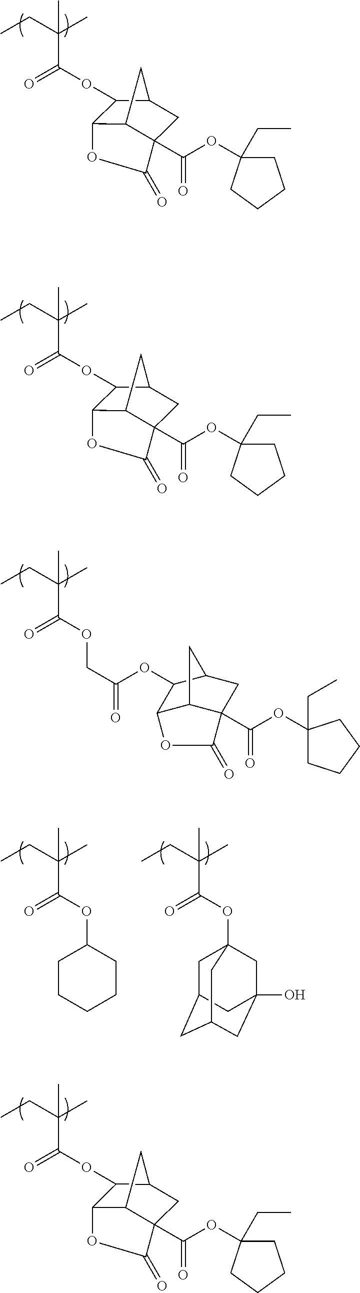

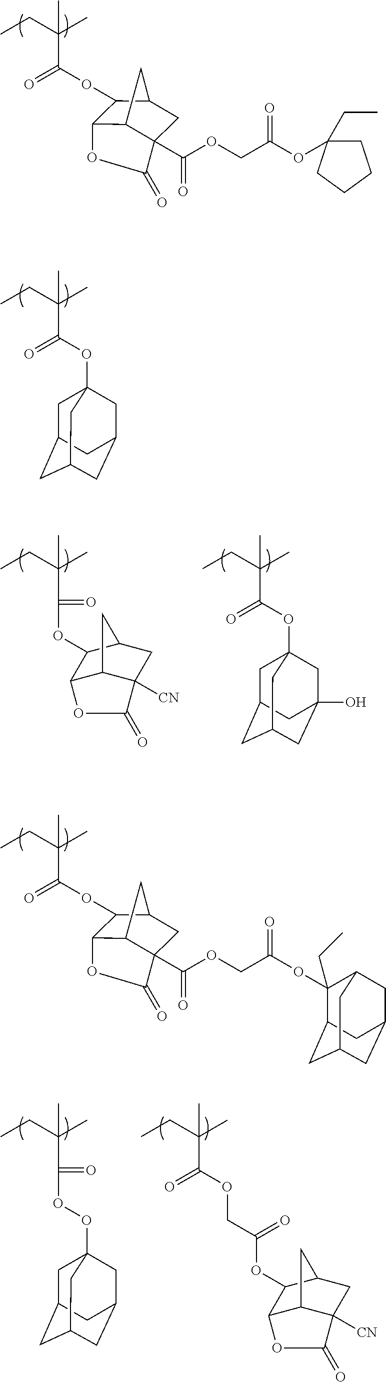

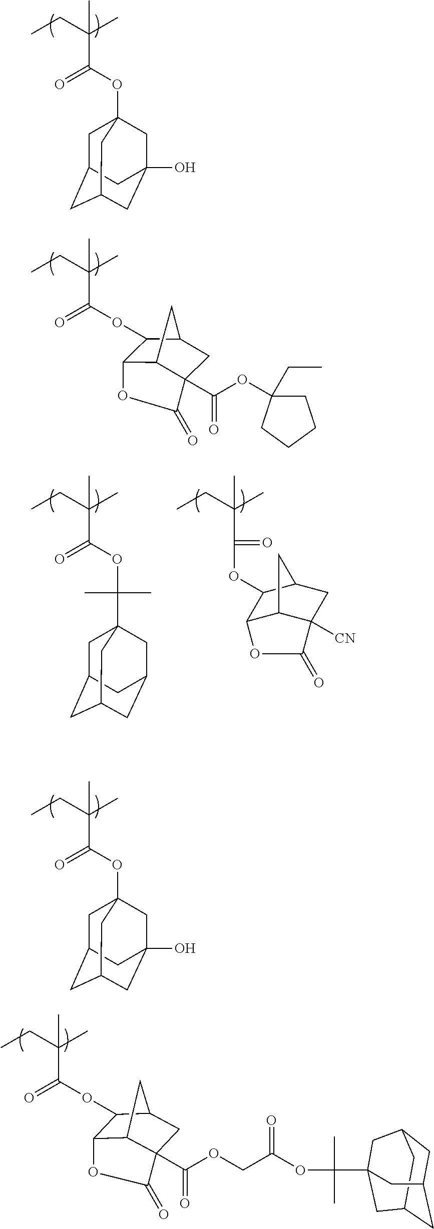

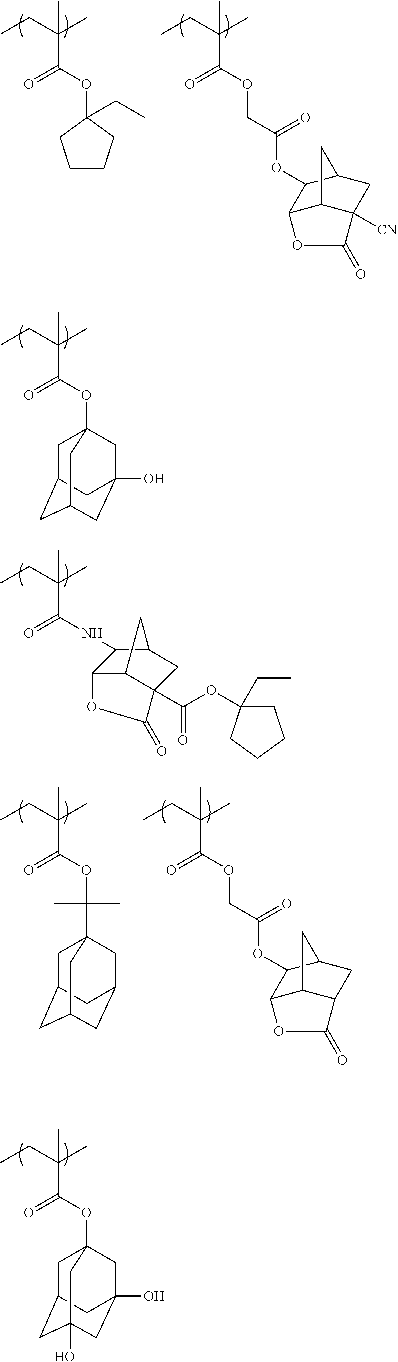

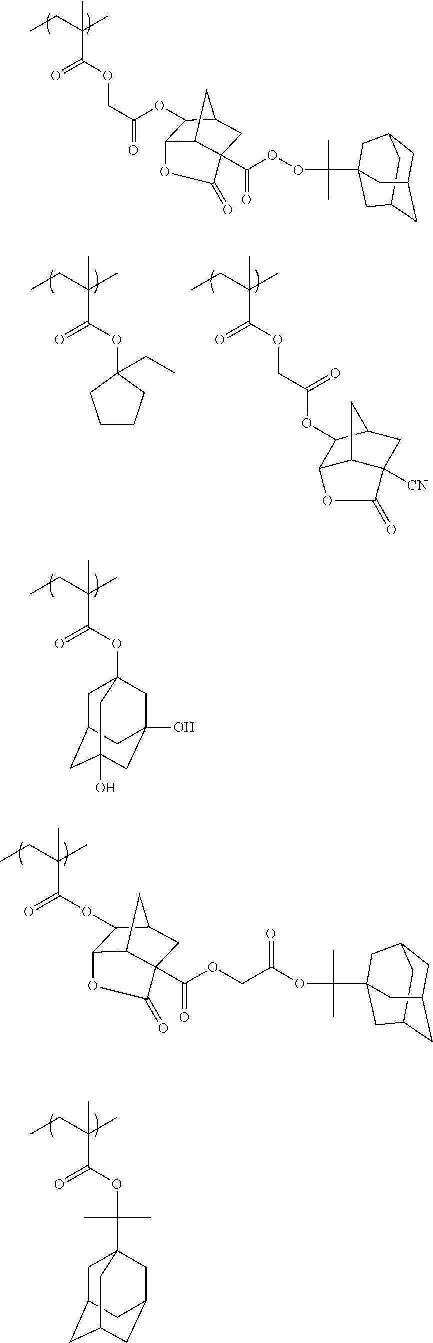

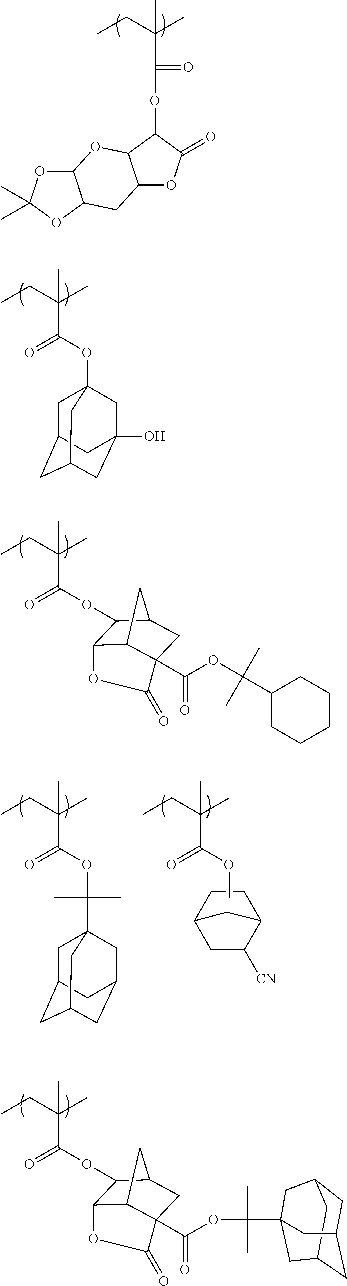

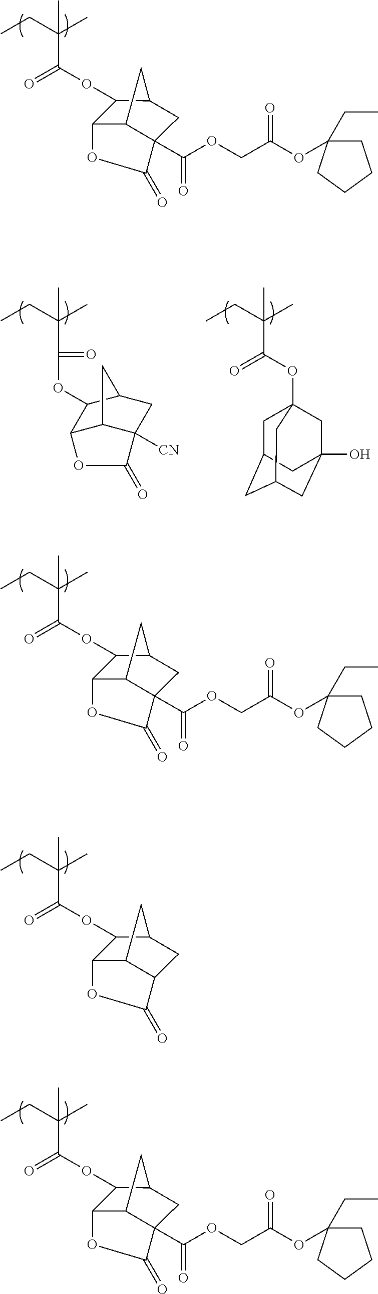

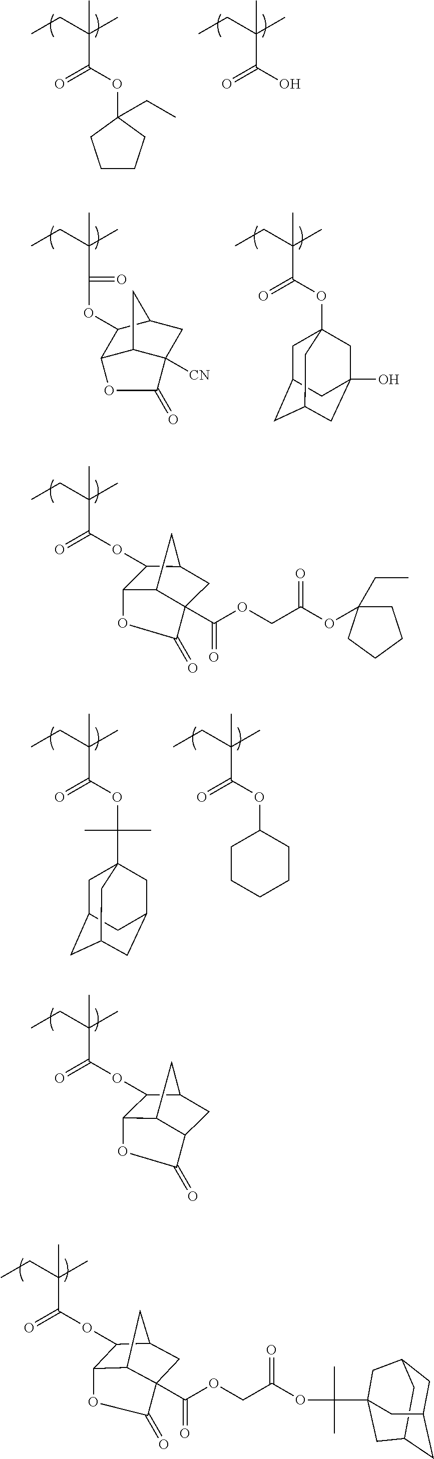

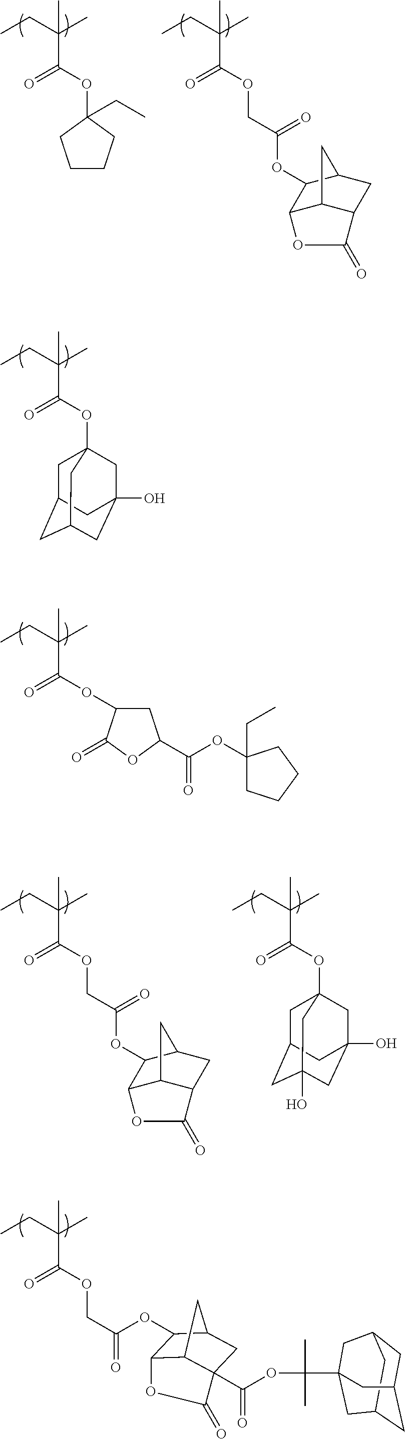

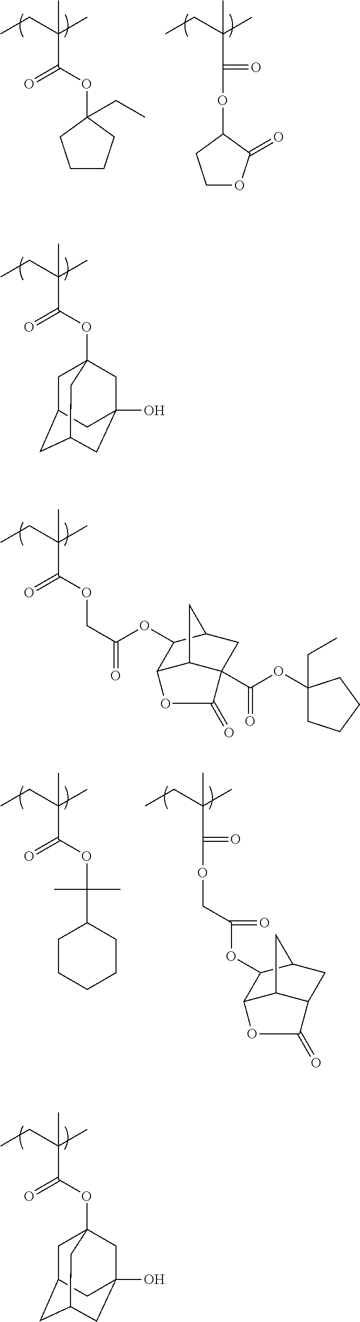

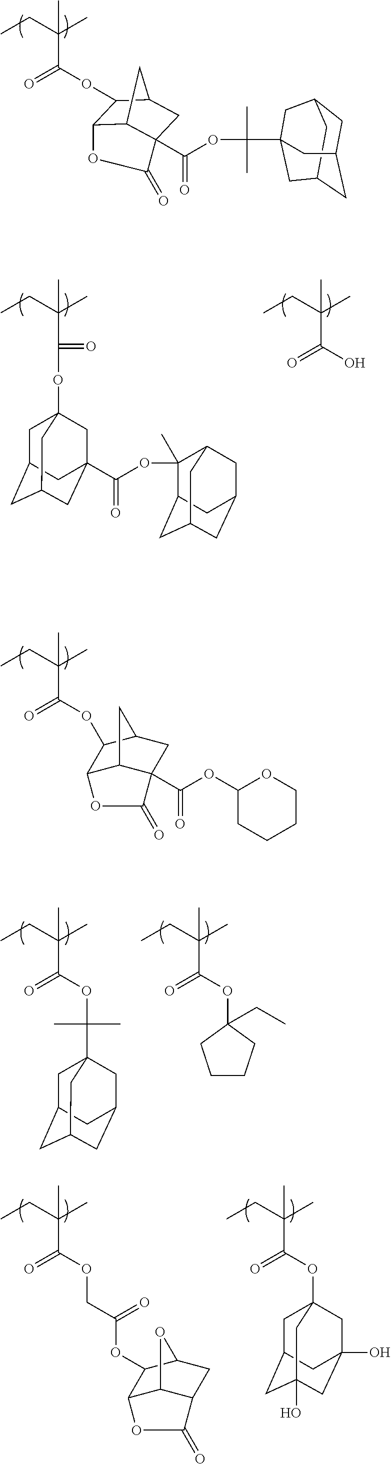

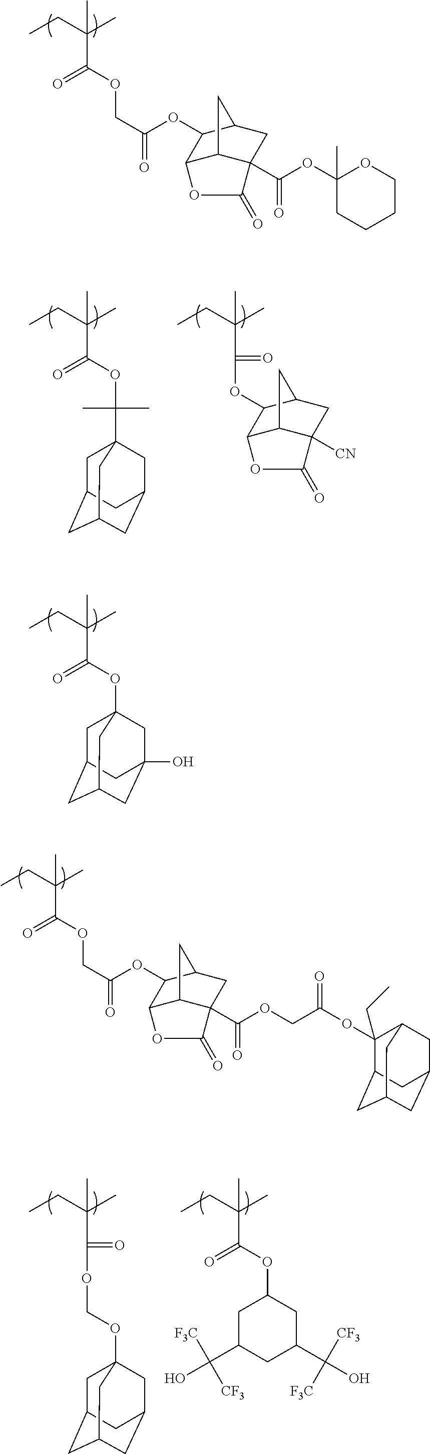

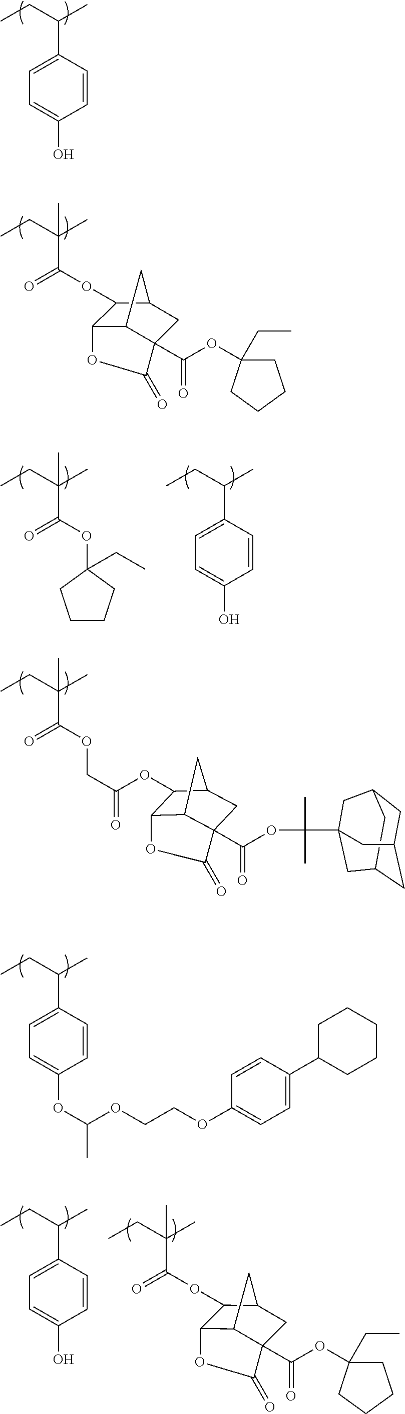

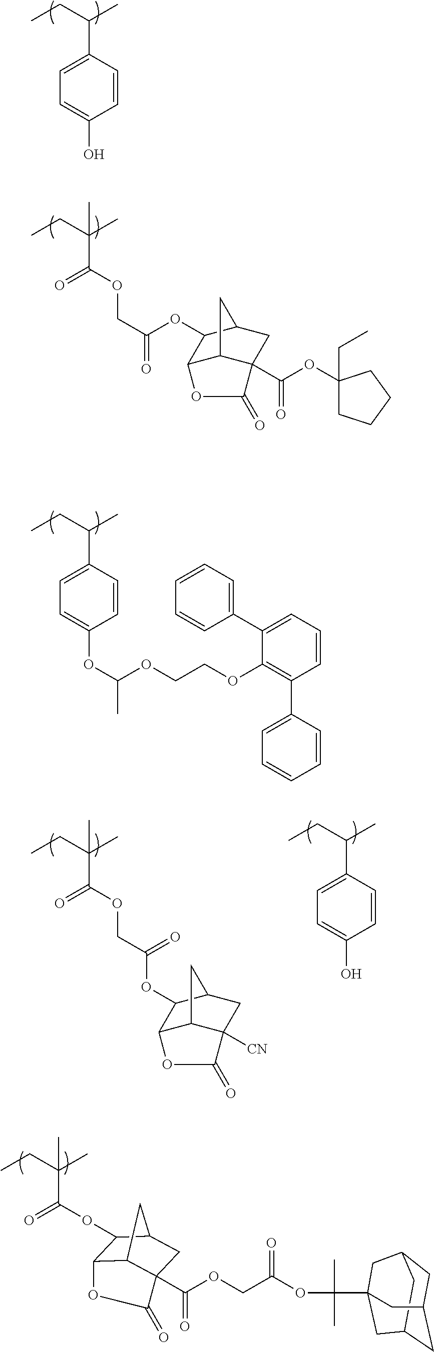

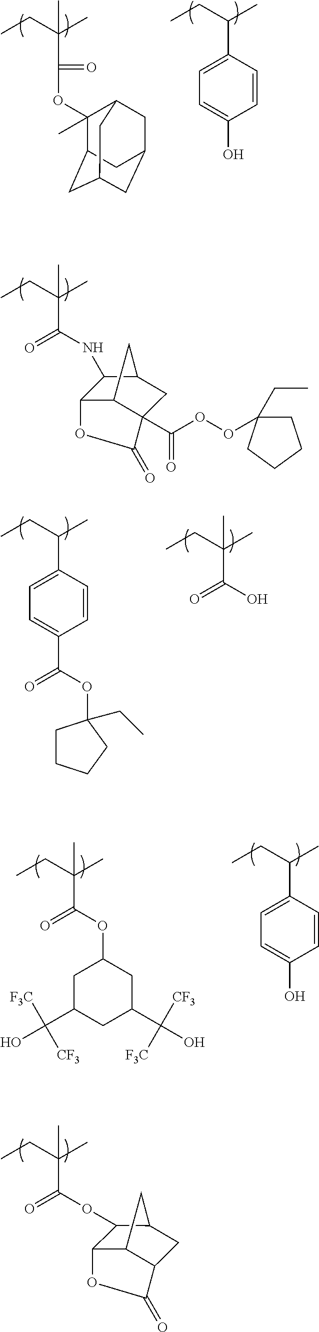

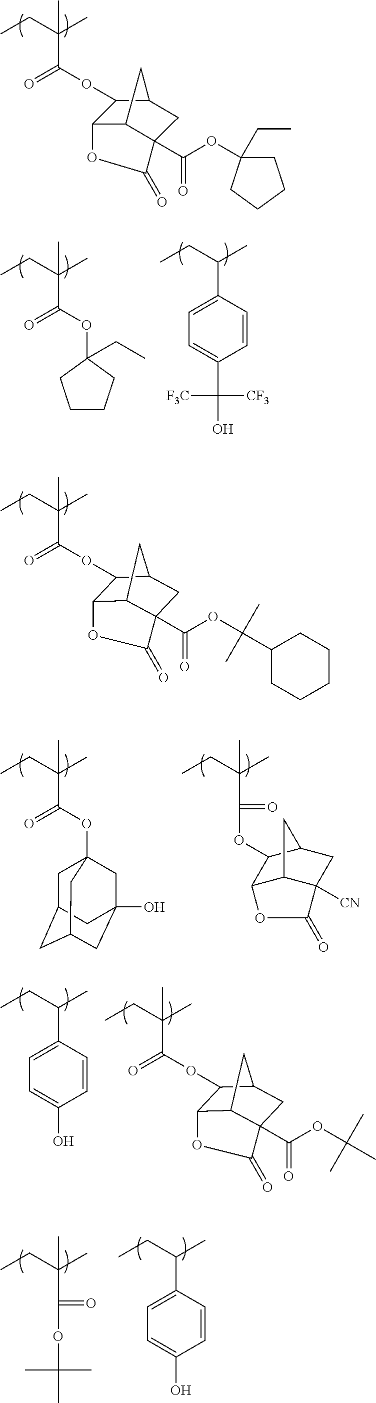

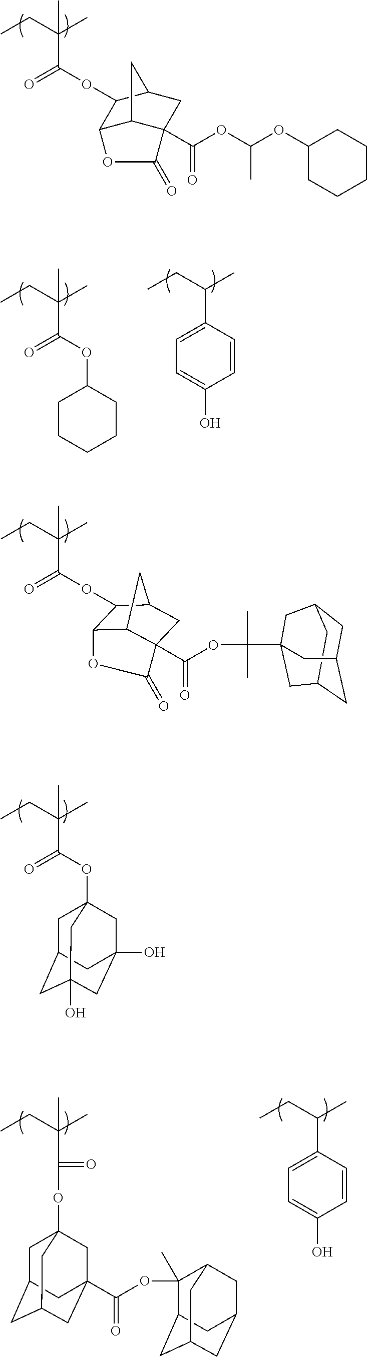

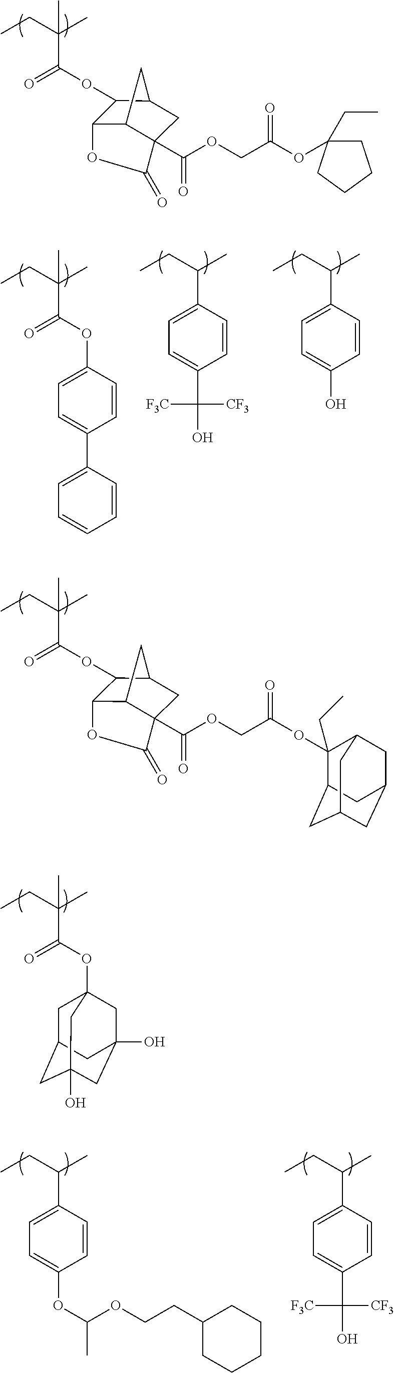

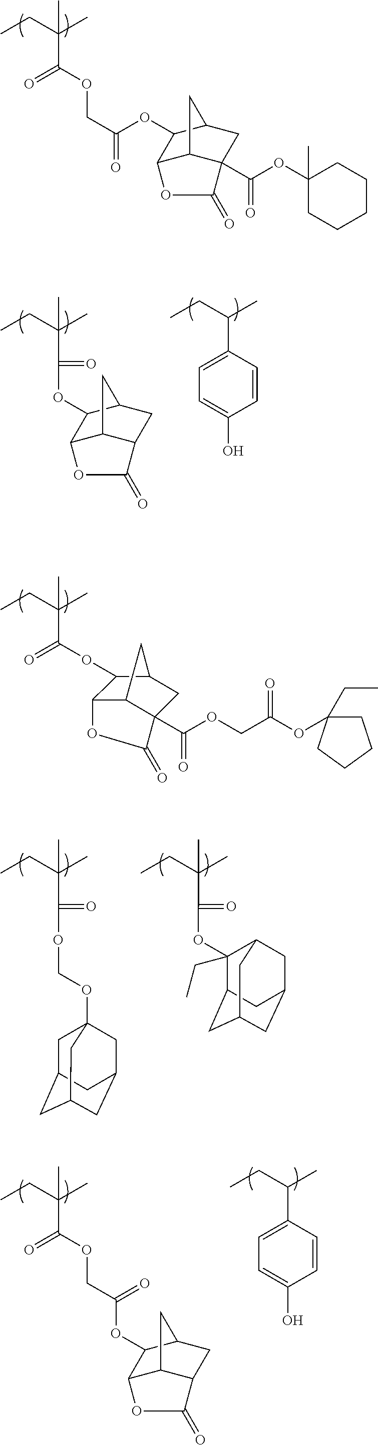

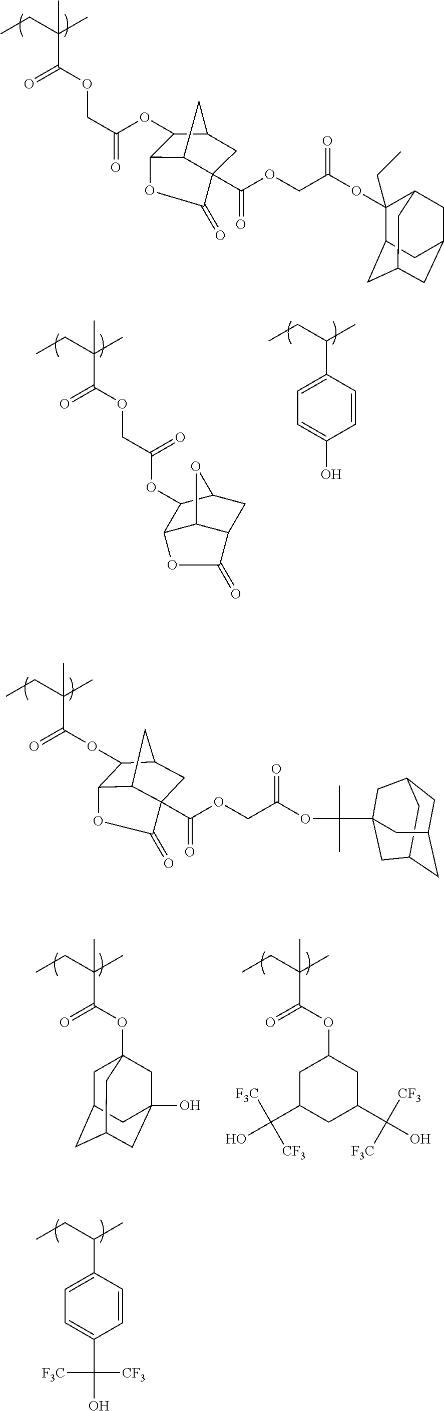

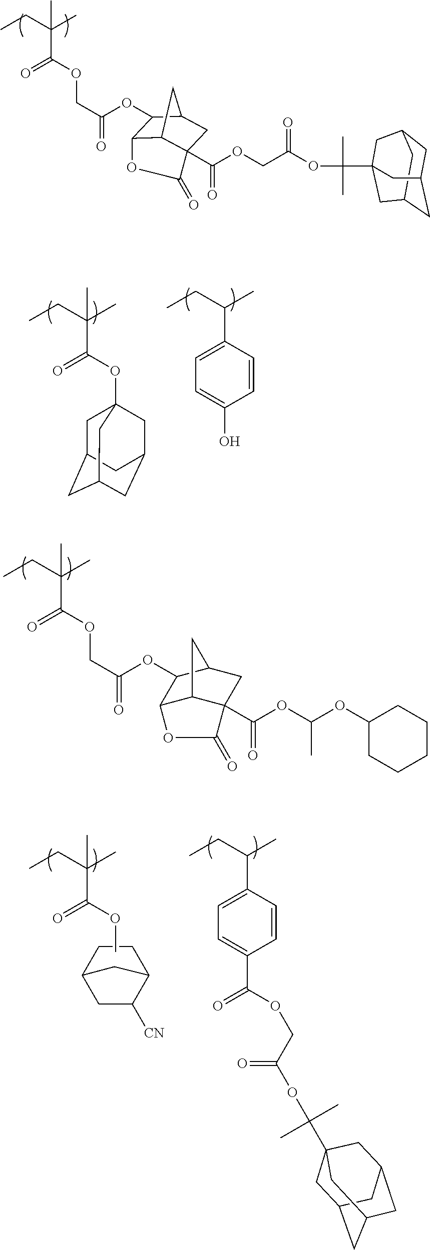

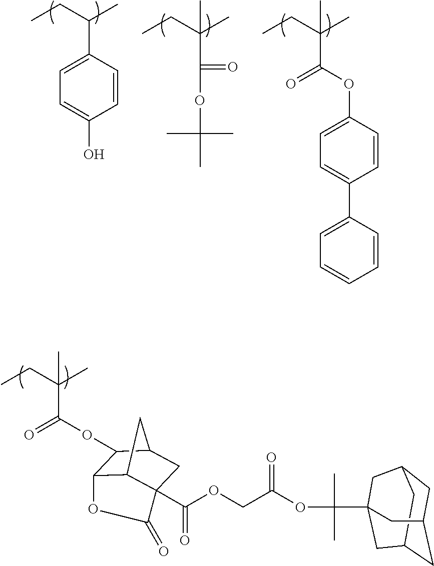

[2] Compound that Generates an Acid when Exposed to Actinic Rays or Radiation

The composition according to the present invention contains a compound that generates an acid when exposed to actinic rays or radiation (hereinafter also referred to as “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that generate an acid when exposed to actinic rays or radiation employed in microresists, etc., and mixtures thereof.

As the acid generator, a diazonium salt, a phosphonium salt, a sulfonium salt, an iodonium salt, an imide sulfonate, an oxime sulfonate, diazosulfone, disulfone and o-nitrobenzyl sulfonate can be exemplified.

Further, use can be made of compounds obtained by introducing any of the above groups or compounds that generate an acid when exposed to actinic rays or radiation in a polymer principal chain or side chain, for example, compounds described in U.S. Pat. No. 3,849,137, DE 3914407, JP-A's-63-26653, 55-164824, 62-69263, 63-146038, 63-163452, 62-153853, 63-146029, etc.

Furthermore, use can be made of compounds that generate an acid when exposed to light described in U.S. Pat. No. 3,779,778, EP 126,712, etc.

As preferred compounds among the acid generators, those represented by the following general formulae (ZI), (ZII) and (ZIII) can be exemplified.

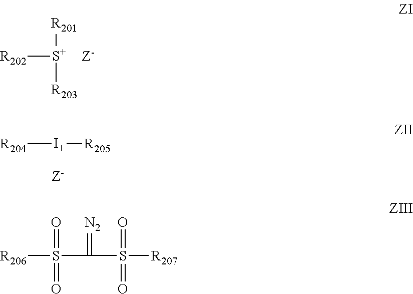

In the above general formula (ZI), each of R₂₀₁, R₂₀₂ and R₂₀₃ independently represents an organic group. The number of carbon atoms in the organic group represented by R₂₀₁, R₂₀₂ and R₂₀₃ is generally in the range of 1 to 30, preferably 1 to 20. As the organic groups represented by R₂₀₁, R₂₀₂ and R₂₀₃, there can be mentioned, for example, the corresponding groups of compounds (ZI-1), (ZI-2) and (ZI-3) to be described hereinafter.

Two of R₂₀₁ to R₂₀₃ may be bonded to each other via a single bond or a connecting group to thereby form a ring structure. As the connecting group, there can be mentioned, for example, an ether bond, a thioether bond, an ester bond, an amido bond, a carbonyl group, methylene group or an ethylene group. As the group formed by the mutual bonding of two of R₂₀₁ to R₂₀₃, there can be mentioned, for example, an alkylene group, such as a butylene group or a pentylene group.

Z⁻ represents a nonnucleophilic anion.

As the nonnucleophilic anion represented by Z⁻, a sulfonate anion, a carboxylate anion, a sulfonylimido anion, a bis(alkylsulfonyl)imido anion, and a tris(alkylsulfonyl)methyl anion can be exemplified.

The nonnucleophilic anion means an anion whose capability of inducing a nucleophilic reaction is extremely low. Any decomposition over time attributed to an intramolecular nucleophilic reaction can be suppressed by the use of this anion. Therefore, when this anion is used, the stability over time of the relevant composition and the film formed therefrom can be enhanced.

As the sulfonate anion, an aliphatic sulfonate anion, an aromatic sulfonate anion, and a camphor sulfonate anion can be exemplified.

As the carboxylate anion, an aliphatic carboxylate anion, an aromatic carboxylate anion, and an aralkyl carboxylate anion can be exemplified.

The aliphatic moiety of the aliphatic sulfonate anion may be an alkyl group or a cycloalkyl group, being preferably an alkyl group having 1 to 30 carbon atoms or a cycloalkyl group having 3 to 30 carbon atoms. As such, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a boronyl group can be exemplified.

As a preferred aromatic group of the aromatic sulfonate anion, an aryl group having 6 to 14 carbon atoms, such as a phenyl group, a tolyl group and a naphthyl group can be exemplified. The alkyl group, cycloalkyl group and aryl group of the aliphatic sulfonate anion and aromatic sulfonate anion may have one or more substituents. As the substituent of the alkyl group, cycloalkyl group and aryl group of the aliphatic sulfonate anion and aromatic sulfonate anion, a nitro group, a halogen atom (fluorine atom, chlorine atom, bromine atom or iodine atom), a carboxy group, a hydroxy group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms) can be exemplified. The aryl group or ring structure of these groups may further have an alkyl group (preferably having 1 to 15 carbon atoms) as its substituent.

As the aliphatic moiety of the aliphatic carboxylate anion, the same alkyl groups and cycloalkyl groups as mentioned with respect to the aliphatic sulfonate anion can be exemplified.

As the aromatic group of the aromatic carboxylate anion, the same aryl groups as mentioned with respect to the aromatic sulfonate anion can be exemplified.

As a preferred aralkyl group of the aralkyl carboxylate anion, an aralkyl group having 6 to 12 carbon atoms, such as a benzyl group, a phenethyl group, a naphthylmethyl group, a naphthylethyl group, and a naphthylbutyl group can be exemplified.

The alkyl group, cycloalkyl group, aryl group and aralkyl group of the aliphatic carboxylate anion, aromatic carboxylate anion and aralkyl carboxylate anion may have one or more substituents. As the substituent of the alkyl group, cycloalkyl group, aryl group and aralkyl group of the aliphatic carboxylate anion, aromatic carboxylate anion and aralkyl carboxylate anion, the same halogen atom, alkyl group, cycloalkyl group, alkoxy group, and alkylthio group, etc. as mentioned with respect to the aromatic sulfonate anion can be exemplified.

As the sulfonylimido anion, a saccharin anion can be exemplified.

The alkyl group of the bis(alkylsulfonyl)imido anion and tris(alkylsulfonyl)methyl anion is preferably an alkyl group having 1 to 5 carbon atoms. As such, a methyl group, an ethyl group, a propyl group, an isopropyl group, an n-butyl group, an isobutyl group, a sec-butyl group, a pentyl group, and a neopentyl group can be exemplified. As a substituent of these alkyl groups, a halogen atom, an alkyl group substituted with a halogen atom, an alkoxy group, an alkylthio group, an alkyloxysulfonyl group, an aryloxysulfonyl group, and a cycloalkylaryloxysulfonyl group can be exemplified. An alkyl group substituted with one or more fluorine atoms is preferred.

As the other nonnucleophilic anions, BF₄⁻, PF₆⁻, and SbF₆⁻ can be exemplified.

The nonnucleophilic anion represented by Z⁻ is preferably selected from among an aliphatic sulfonate anion substituted at its α-position of sulfonic acid with a fluorine atom, an aromatic sulfonate anion substituted with one or more fluorine atoms or a group having a fluorine atom, a bis(alkylsulfonyl)imido anion whose alkyl group is substituted with one or more fluorine atoms and a tris(alkylsulfonyl)methide anion whose alkyl group is substituted with one or more fluorine atoms. More preferably, the nonnucleophilic anion is a perfluorinated aliphatic sulfonate anion having 4 to 8 carbon atoms or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

As preferred organic anions represented by Z⁻, there can be mentioned, for example, those of the following formulae.

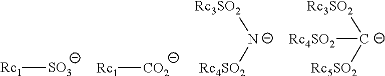

In the formulae, Rc₁ represents an organic group.

As the organic group, there can be mentioned any of those having 1 to 30 carbon atoms. This organic group is preferably an alkyl group, an aryl group or a group consisting of two or more of these groups linked together by means of a single bond or a connecting group. As the connecting group, there can be mentioned, for example, —O—, —CO₂—, —S—, —SO₃— or —SO₂N(Rd₁)—. In the last formula; Rd₁ represents a hydrogen atom or an alkyl group. These organic groups may further have one or more substituents.

Each of Rc₃, Rc₄ and Rc₅ independently represents an organic group.

As these organic groups, there can be mentioned, for example, those set forth above with respect to Rc₁. Among them, a perfluoroalkyl group having 1 to 4 carbon atoms is especially preferred.

Rc₃ and Rc₄ may be bonded to each other to thereby form a ring. As the group formed by the mutual bonding of Rc₃ and Rc₄, there can be mentioned, for example, an alkylene group or an arylene group. The above group is preferably a perfluoroalkylene group having 2 to 4 carbon atoms.

It is especially preferred for each of the organic groups represented by Rc₁, Rc₃, Rc₄ and Rc₅ to be an alkyl group substituted at its 1-position with a fluorine atom or a fluoroalkyl group, or a phenyl group substituted with one or more fluorine atoms or a fluoroalkyl group. The acidity of the acid generated by light exposure can be increased by the introduction of the fluorine atom or fluoroalkyl group in these organic groups, so that the sensitivity can be enhanced.

Further, Z⁻ can be any of the anions of general formula (A1) below.

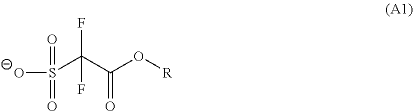

In the formula, R represents a hydrogen atom or an organic group.

When R represents an organic group, the organic group preferably has 1 to 40 carbon atoms, more preferably 3 to 20 carbon atoms.

This organic group is not particularly limited as long as it has at least one carbon atom. However, it is preferred for the atom bonded to the oxygen atom of the ester bond appearing in the general formula (A1) to be a carbon atom. For example, the organic group is preferably an alkyl group, a cycloalkyl group, an aryl group, an aralkyl group or a group with a lactone structure. These groups in the chain thereof may contain a hetero-atom, such as an oxygen atom or a sulfur atom. These groups may be introduced in each other as substituents, and they may have another substituent, such as a hydroxyl group, an acyl group, an acyloxy group, an oxy group (═O) or a halogen atom.

R is further preferably any of the organic groups of general formula (Ala) below.

(CH₂)ₙ—Rc—(Y)ₘ (A1a)

In the formula (Ala), Rc represents a cyclic organic group of a single ring or multiple rings. This cyclic organic group preferably has 3 to 30 carbon atoms, and more preferably 7 to 16 carbon atoms. This cyclic organic group contains, for example, a cyclic ether, cyclic thioether, cyclic ketone, cyclic carbonic ester, lactone or lactam structure.

Y represents a hydroxyl group, a halogen atom, a cyano group, a carboxyl group, a hydrocarbon group having 1 to 10 carbon atoms, a hydroxyalkyl group having 1 to 10 carbon atoms, an alkoxy group having 1 to 10 carbon atoms, an acyl group having 1 to 10 carbon atoms, an alkoxycarbonyl group having 2 to 10 carbon atoms, an acyloxy group having 2 to 10 carbon atoms, an alkoxyalkyl group having 2 to 10 carbon atoms, or a halogenated alkyl group having 1 to 8 carbon atoms. When m≧2, the multiple Ys may be identical to or different from each other.

In the formula, m is an integer of 0 to 6.

n is an integer of 0 to 10, preferably 0 to 3.

The sum of carbon atoms contained in each of the Rs of the formula (Ala) is preferably 40 or less.

Further, Z⁻ can be any of the anions of general formula (A2) below.

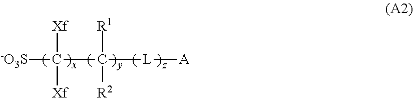

In the formula (A2), each of Xfs independently represents a fluorine atom or an alkyl group having at least one hydrogen atom thereof substituted with one or more fluorine atoms.

Each of R¹ and R² independently represents a hydrogen atom, a fluorine atom, an alkyl group or an alkyl group having at least one hydrogen atom thereof substituted with one or more fluorine atoms. When the multiple R¹s, and also the multiple R²s, may be identical to or different from each other.

L represents a single bond or a bivalent) connecting group. When z≧2, the multiple Ls may be identical to or different from each other.

A represents a group with a cyclic structure.

In the formula, x is an integer of 1 to 20, y an integer of 0 to 10 and z an integer of 0 to 10.

The anions of the general formula (A2) will be described in greater detail below.

As mentioned above, Xf is a fluorine atom or an alkyl group having at least one hydrogen atom thereof substituted with one or more fluorine atoms. The alkyl group preferably has 1 to 4 carbon atoms. The alkyl group having at least one hydrogen atom thereof substituted with one or more fluorine atoms is preferably a perfluoroalkyl group.

Xf is preferably a fluorine atom or a perfluoroalkyl group having 1 to 4 carbon atoms. In particular, it is preferred for Xf to represent a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, a fluorine atom and CF₃ are especially preferred.

As mentioned above, each of R¹ and R² is a hydrogen atom, a fluorine atom, an alkyl group or an alkyl group having at least one hydrogen atom thereof substituted with one or more fluorine atoms. The alkyl group optionally substituted with one or more fluorine atoms preferably has 1 to 4 carbon atoms. The alkyl group having at least one hydrogen atom thereof substituted with one or more fluorine atoms is preferably a perfluoroalkyl group having 1 to 4 carbon atoms. In particular, there can be mentioned, for example, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, CF₃ is especially preferred.

As mentioned above, L represents a single bond or a bivalent connecting group. As the bivalent-connecting group, there can be mentioned, for example, —COO—, —OCO—, —CO—, —O—, —S—, —SO—, —SO₂—, an alkylene group, a cycloalkylene group or an alkenylene group. Of these, —COO—, —OCO—, —CO— and —O— are preferred. —COO— and —OCO— are more preferred.

As mentioned above, A represents a group with a cyclic structure. As the group with a cyclic structure, there can be mentioned, for example, an alicyclic group, an aryl group or a group with a heterocyclic structure. The group with a cyclic structure is, for example, a tetrahydropyranyl group or a lactone group. It is optional for the group with a heterocyclic structure to exhibit aromaticity.

The alicyclic group represented by A may have a monocyclic structure or a polycyclic structure.

Preferably, the alicyclic group having a monocyclic structure is a cycloalkyl group of a single ring, such as a cyclopentyl group, a cyclohexyl group or a cyclooctyl group.

The alicyclic group having a polycyclic structure is preferably a cycloalkyl group of multiple rings, such as a norbornyl group, a tricyclodecanyl group, a tetracyclodecanyl group, a tetracyclododecanyl group or an adamantyl group. A cycloalkyl group of multiple rings having 7 or more carbon atoms is especially preferred. Any in-film diffusion of acids during the PEB step can be suppressed by the employment of these alicyclic groups with a bulky structure, so that a further improvement of MEEF (mask error enhancement factor) can be attained.

The aryl group represented by A is, for example, a phenyl group, a naphthyl group, a phenanthryl group or an anthryl group. Of these, a naphthyl group exhibiting a low absorbance to a light of 193 nm wavelength is especially preferably used.

As the group with a heterocyclic structure represented by A, there can be mentioned, for example, a furan ring, a thiophene ring, a benzofuran ring, a benzothiophene ring, a dibenzofuran ring, a dibenzothiophene ring or a pyridine ring. Of these, a furan ring, a thiophene ring and a pyridine ring are especially preferred.

The alicyclic group, aryl group and group with a heterocyclic structure represented by A may further have one or more substituents. As the substituents, there can be mentioned, for example, an alkyl group (may be linear, branched or cyclic, preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamido group and a sulfonic ester group.

In the formula,

x is preferably 1 to 8, more preferably 1 to 4,

y is preferably 0 to 4, more preferably 0, and

z is preferably 0 to 8, more preferably 0 to 4.

Moreover, as Z⁻, there can be mentioned any of the anions of general formulae (A3) and (A4) below disclosed in JP-A-2005-221721.

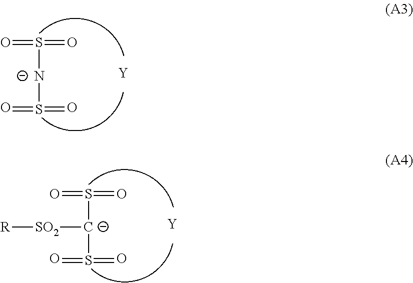

In the formulae (A3) and (A4), Y represents an alkylene group having at least one hydrogen atom thereof substituted with one or more fluorine atoms. This alkylene group may contain an oxygen atom in its chain.

This alkylene group preferably has 2 to 4 carbon atoms. Y is preferably a perfluoroalkylene group having 2 to 4 carbon atoms, more preferably a tetrafluoroethylene group, a hexafluoropropylene group or an octafluorobutylene group.

In the formula (A4), R represents an alkyl group or a cycloalkyl group. Each of these alkyl and cycloalkyl groups may contain an oxygen atom in its chain.

As the compounds having the anions of the general formulae (A3) and (A4), there can be mentioned, for example, those described in JP-A-2005-221721.

Compounds having two or more of the structures of the general formula (ZI) may be used as the acid generator. For example, use may be made of a compound having a structure in which at least one of the R₂₀₁ to R₂₀₃ of one of the compounds of the general formula

(ZI) is bonded to at least one of the R₂₀₁ to R₂₀₃ of another of the compounds of the general formula (ZI).

As preferred compound represented by the general formula (ZI), the following compounds (ZI-1), (ZI-2), and (ZI-3) can be exemplified.

The compounds (ZI-1) are arylsulfonium compounds represented by the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group. When any of the compounds (ZI-1) has a plurality of aryl groups, the aryl groups may be identical to or different from each other.

As the arylsulfonium compounds, a triarylsulfonium compound, a diarylalkylsulfonium compound, an aryldialkylsulfonium compound, a diarylcycloalkylsulfonium compound and an aryldicycloalkylsulfonium compound can be exemplified.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the aryl group having a heterocyclic structure, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), and a benzothiophene residue (group formed by loss of one hydrogen atom from benzothiophene) can be exemplified. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, a methyl group, an ethyl group, a propyl group, an n-butyl group, a sec-butyl group, a t-butyl group, a cyclopropyl group, a cyclobutyl group, and a cyclohexyl group can be exemplified.

The aryl group, alkyl group or cycloalkyl group represented by R₂₀₁ to R₂₀₃ may have as its substituent an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a halogen atom, a hydroxy group or a phenylthio group.

Preferred substituents include a linear or branched alkyl group having 1 to 12 carbon atoms, a cycloalkyl group having 3 to 12 carbon atoms, and a linear, branched or cyclic alkoxy group having 1 to 12 carbon atoms. More preferred substituents include an alkyl group having 1 to 4 carbon atoms and an alkoxy group having 1 to 4 carbon atoms.

The substituents may be contained in any one of the three R₂₀₁ to R₂₀₃, or alternatively may be contained in all three of R₂₀₁ to R₂₀₃. When R₂₀₁ to R₂₀₃ represent a phenyl group, the substituent preferably lies at the p-position of the phenyl group.

Now, the compounds (ZI-2) will be described.

The compounds (ZI-2) are compounds represented by the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a 2-oxoalkyl group, an alkoxycarbonylmethyl group, an allyl group, and a vinyl group. More preferred groups include a linear or branched 2-oxoalkyl group and an alkoxycarbonylmethyl group. Especially preferred is a linear or branched 2-oxoalkyl group.

As preferred alkyl groups and cycloalkyl groups represented by R₂₀₁ to R₂₀₃, a linear or branched alkyl group having 1 to 10 carbon atoms (for example, a methyl group, an ethyl group, a propyl group, a butyl group or a pentyl group) and a cycloalkyl group having 3 to 10 carbon atoms (for example, a cyclopentyl group, a cyclohexyl group or a norbornyl group) can be exemplified.

As more preferred alkyl groups, a 2-oxoalkyl group and an alkoxycarbonylmethyl group can be exemplified. As more preferred cycloalkyl group, a 2-oxocycloalkyl group can be exemplified.

The 2-oxoalkyl group may be linear or branched. A group having >C═O at the 2-position of the above-described alkyl group can be preferably exemplified.

The 2-oxocycloalkyl group is preferably a group having >O═O at the 2-position of the above-described cycloalkyl group.

As preferred alkoxy groups of the alkoxycarbonylmethyl group, alkoxy groups having 1 to 5 carbon atoms can be exemplified. As such, there can be mentioned, for example, a methoxy group, an ethoxy group, a propoxy group, a butoxy group and a pentoxy group.

The organic groups containing no aromatic ring represented by R₂₀₁ to R₂₀₃ may further have one or more substituents. As the substituents, a halogen atom, an alkoxy group (having, for example, 1 to 5 carbon atoms), a hydroxy group, a cyano group and a nitro group can be exemplified.

Now the compounds (ZI-3) will be described.

The compounds (ZI-3) are those represented by the following general formula (1-1) or (1-2).

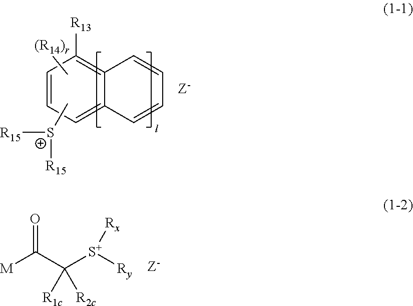

In the general formula (1-1),

R₁₃ represents a hydrogen atom, a fluorine atom, a hydroxyl group, an alkyl group, a cycloalkyl group, an alkoxy group, an alkoxycarbonyl group or a group with a cycloalkyl skeleton of a single ring or multiple rings.

R₁₄, or each of R₁₄s independently, represents an alkyl group, a cycloalkyl group, an alkoxy group, an alkoxycarbonyl group, an alkylcarbonyl group, an alkylsulfonyl group, a cycloalkylsulfonyl group or a group with a cycloalkyl skeleton of a single ring or multiple rings.

Each of R₁₅s independently represents an alkyl group, a cycloalkyl group or a naphthyl group, provided that two R₁₅s may be bonded to each other to thereby form a ring.

l is an integer of 0 to 2.

r is an integer of 0 to 8.

Z⁻ represents a nonnucleophilic anion. As such, any of the same nonnucleophilic anions as mentioned with respect to the Z⁻ of the general formula (ZI) can be exemplified.

In the general formula (1-2),

M represents an alkyl group; a cycloalkyl group, an aryl group or a benzyl group. When a cyclic structure is contained, the cyclic structure may contain an oxygen atom, a sulfur atom, an ester bond, an amido bond or a carbon to carbon double bond.

Each of R_{1c} and R_{2c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, an alkoxycarbonylalkyl group, a cycloalkoxycarbonylalkyl group, an allyl group or a vinyl group.

Rₓ and R_{y} may be bonded to each other to thereby form a ring.

At least two of M, R_{1c} and R_{2c} may be bonded to each other to thereby form a ring. The ring structure may contain a carbon to carbon double bond.

Z⁻ represents a nonnucleophilic anion. As such, any of the same nonnucleophilic anions as mentioned with respect to the Z⁻ of the general formula (ZI) can be exemplified.

First, the explanation will be given of the compounds represented by the general formula (1-1).

The alkyl groups represented by R₁₃, R₁₄ and R₁₅ may be linear or branched and preferably each has 1 to 10 carbon atoms. As such, a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group can be exemplified. Preferred alkyl groups include a methyl group, an ethyl group, an n-butyl group, and a t-butyl group.

As the cycloalkyl groups represented by R₁₃, R₁₄ and R₁₅, a cyclopropyl, a cyclobutyl, a cyclopentyl, a cyclohexyl, a cycloheptyl, a cyclooctyl, a cyclododecanyl, a cyclopentenyl, a cyclohexenyl, and a cyclooctadienyl group can be exemplified. Cyclopropyl, cyclopentyl, cyclohexyl and cyclooctyl groups are especially preferred.

The alkoxy groups represented by R₁₃ and R₁₄ may be linear or branched and preferably each have 1 to 10 carbon atoms. As such, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group can be exemplified. Preferred alkoxy groups include a methoxy group, an ethoxy group, an n-propoxy group, and an n-butoxy group.

The alkoxycarbonyl group represented by R₁₃ and R₁₄ may be linear or branched and preferably has 2 to 11 carbon atoms. As such, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, and an n-decyloxycarbonyl group can be exemplified. Preferred alkoxycarbonyl groups include a methoxycarbonyl group, an ethoxycarbonyl group, and an n-butoxycarbonyl group.

The sum of carbon atoms contained in each of the groups with a cycloalkyl skeleton of a single ring or multiple rings (also referred to as a mono- or polycycloalkyl skeleton) represented by R₁₃ and R₁₄ is preferably 7 or greater, more preferably in the range of 7 to 15.

As the groups with a mono- or polycycloalkyl skeleton, there can be mentioned; for example, a mono- or polycycloalkyloxy group and an alkoxy group with a mono- or polycycloalkyl group. Having a monocycloalkyl skeleton is preferred. These groups may further have one or more substituents.

As the monocycloalkyloxy group, there can be mentioned, for example, a cyclopropyloxy group, a cyclobutyloxy group, a cyclopentyloxy group, a cyclohexyloxy group, a cycloheptyloxy group, a cyclooctyloxy group or a cyclododecanyloxy group. These groups may further have one or more substituents selected from among, for example, an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a tert-butyl group or an isoamyl group; a hydroxyl group; a halogen atom such as a fluorine, chlorine, bromine or iodine atom; a nitro group; a cyano group; an amido group; a sulfonamido group; an alkoxy group such as a methoxy group, an ethoxy group, a hydroxyethoxy group, a propoxy group, a hydroxypropoxy group or a butoxy group; an alkoxycarbonyl group such as a methoxycarbonyl group or an ethoxycarbonyl group; an acyl group such as a formyl group, an acetyl group or a benzoyl group; an acyloxy group such as an acetoxy group or a butyryloxy group; and a carboxyl group.

As the polycycloalkyloxy group, there can be mentioned, for example, a norbornyloxy group or an adamantyloxy group.

As mentioned above, the sum of carbon atoms contained in the mono- or polycycloalkyloxy group is preferably 7 or greater. Namely, it is preferred to employ an arrangement in which the sum of the number of carbon atoms contained in the cycloalkyloxy group mentioned above and the number of carbon atoms contained in each of the above substituents is 7 or greater.

As the alkoxy group having a monocycloalkyl group, there can be mentioned, for example, one consisting of an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with a monocycloalkyl group. This monocycloalkyl group may further have any of the above-mentioned substituents. For example, there can be mentioned a cyclohexylmethoxy group, a cyclopentylethoxy group, a cyclohexylethoxy group or the like. A cyclohexylmethoxy group is preferred.

As the polycycloalkyloxy group, there can be mentioned, for example, a norbornyloxy group or an adamantyloxy group.

As mentioned above, the sum of carbon atoms contained in the alkyloxy group having a mono- or polycycloalkyl group is preferably 7 or greater. Namely, it is preferred to employ an arrangement in which the sum of the number of carbon atoms contained in the alkyloxy group mentioned above, the number of carbon atoms contained in the mono- or polycycloalkyl group and the number of carbon atoms contained in each of the above substituents is 7 or greater.

As the alkyl group moiety of the alkylcarbonyl group represented by R₁₄, specific examples given for the alkyl groups represented by R₁₃ through R₁₅ can be exemplified.

The alkylsulfonyl groups represented by R₁₄ may be linear or branched.

The alkylsulfonyl groups and cycloalkylsulfonyl groups represented by R₁₄ preferably have 1 to 10 carbon atoms. As such, a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, and a cyclohexanesulfonyl group can be exemplified. Preferred alkylsulfonyl and cycloalkylsulfonyl groups include a methanesulfonyl group, an ethanesulfonyl group, an n-propanesulfonyl group, an n-butanesulfonyl group, a cyclopentanesulfonyl group, and a cyclohexanesulfonyl group.

These groups may further have one or more substituents. As the substituents, there can be mentioned, for example, a halogen atom such as a fluorine atom, a hydroxyl group, a carboxyl group, a cyano group, a nitro group, an alkoxy group, a cycloalkoxy group, an alkoxyalkyl group, a cycloalkoxyalkyl group, an alkoxycarbonyl group, a cycloalkoxycarbonyl group, an alkoxycarbonyloxy group and a cycloalkoxycarbonyloxy group. Of these, a hydroxyl group, an alkoxy group, an alkoxycarbonyl group and a halogen atom are preferred. The halogen atom is most preferably a fluorine atom.

The alkoxy group may be linear or branched. As the alkoxy group, that having 1 to 20 carbon atoms, such as a methoxy group, an ethoxy group, an n-propoxy group, an i-propoxy group, an n-butoxy group, a 2-methylpropoxy group, a 1-methylpropoxy group, and a t-butoxy group can be exemplified.

As the cycloalkoxy group, that having 4 to 20 carbon atoms, such as a cyclopentyloxy group and a cyclohexyloxy group can be exemplified.

The alkoxyalkyl group may be linear or branched. As the alkoxyalkyl group, that having 2 to 21 carbon atoms, such as a methoxymethyl group, an ethoxymethyl group, a 1-methoxyethyl group, a 2-methoxyethyl group, a 1-ethoxyethyl group and a 2-ethoxyethyl group can be exemplified.

As the cycloalkoxyalkyl group, a cyclopentyloxymethyl group and a cyclopentyloxymethylethoxy group can be exemplified.

The alkoxycarbonyl group may be linear or branched. As the alkoxycarbonyl group, that having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, and a t-butoxycarbonyl group can be exemplified.

As the cycloalkoxycarbonyl group, that having 4 to 21 carbon atoms, such as a cyclopentyloxycarbonyl group and a cyclohexyloxycarbonyl group can be exemplified.

The alkoxycarbonyloxy group may be linear or branched. As the alkoxycarbonyloxy group, that having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, and a t-butoxycarbonyloxy group can be exemplified.

As the cycloalkoxycarbonyloxy group, that having 4 to 21 carbon atoms, such as a cyclopentyloxycarbonyloxy group and a cyclohexyloxycarbonyloxy group can be exemplified.

The cyclic structure that may be formed by the bonding of the two R₁₅s to each other is preferably a 5- or 6-membered ring, especially a 5-membered ring (namely, a tetrahydrothiophene ring) formed by two bivalent R₁₅s in cooperation with the sulfur atom of the general formula (1-1).

The cyclic structure may have one or more substituents. As such substituents, a hydroxyl group, a carboxyl group, a cyano group, a nitro group, an alkoxy group, an alkoxyalkyl group, an alkoxycarbonyl group, and an alkoxycarbonyloxy group can be exemplified.

It is especially preferred for the R₁₅ of the general formula (1-1) to be a methyl group, an ethyl group, a 1-naphthyl group, the above-mentioned bivalent group allowing two R₁₅s to be bonded to each other so as to form a tetrahydrothiophene ring structure in cooperation with the sulfur atom of the general formula (1-1), or the like.

In the formula, 1 is preferably 0 or 1, more preferably 1, and r is preferably 0 to 2.

Preferred specific examples of cations in the compounds represented by the general formula (1-1) will be shown below.

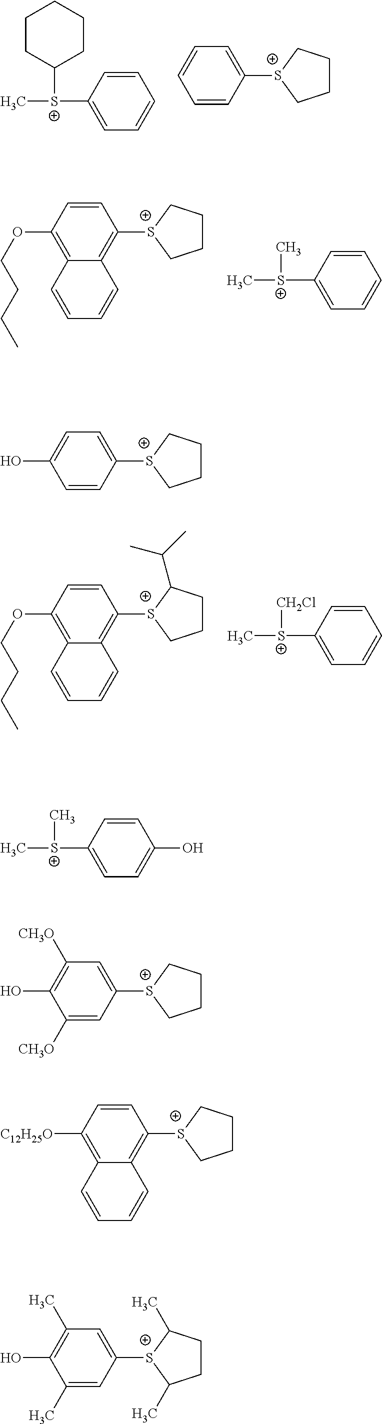

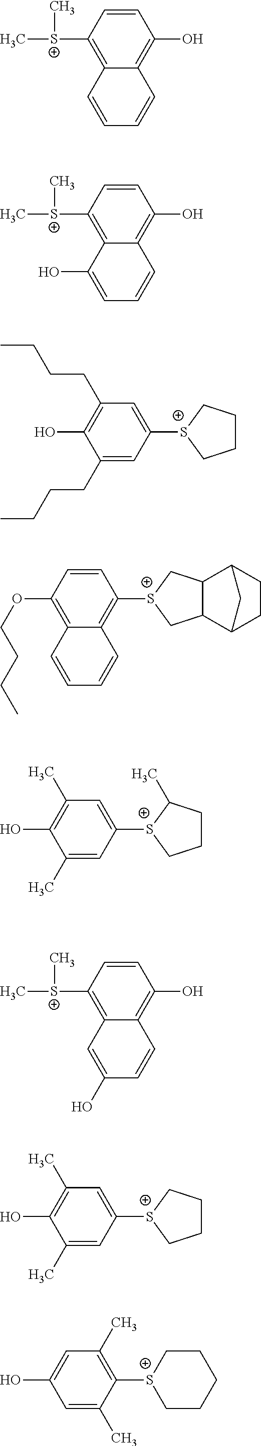

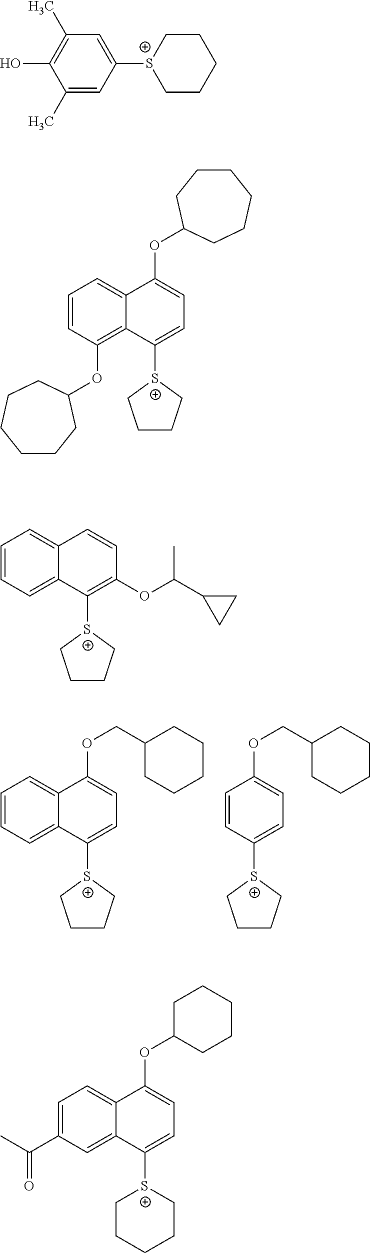

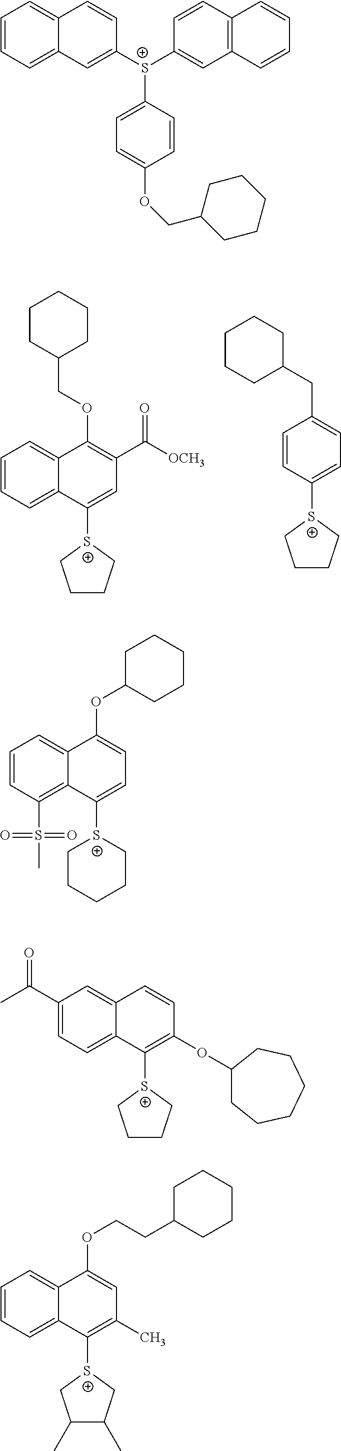

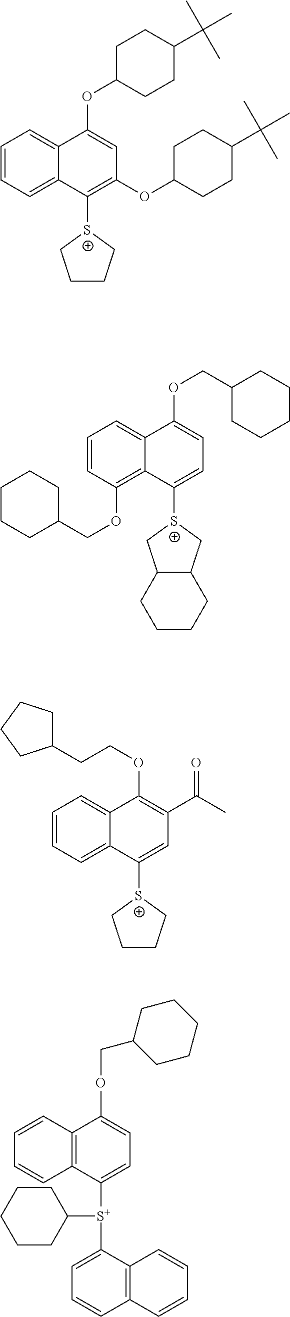

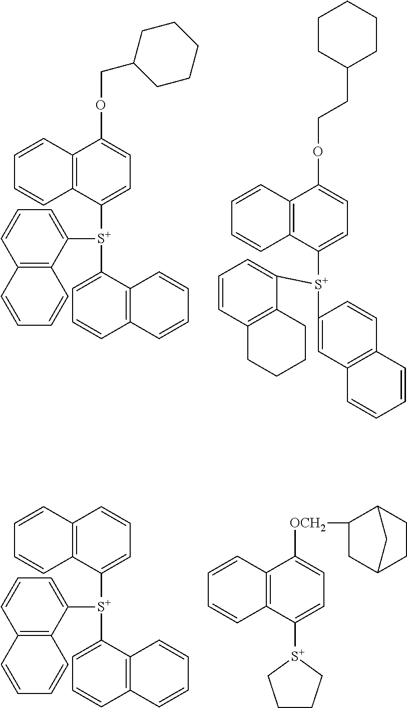

Preferred specific examples of the compounds represented by the general formula (1-1) will be given below.

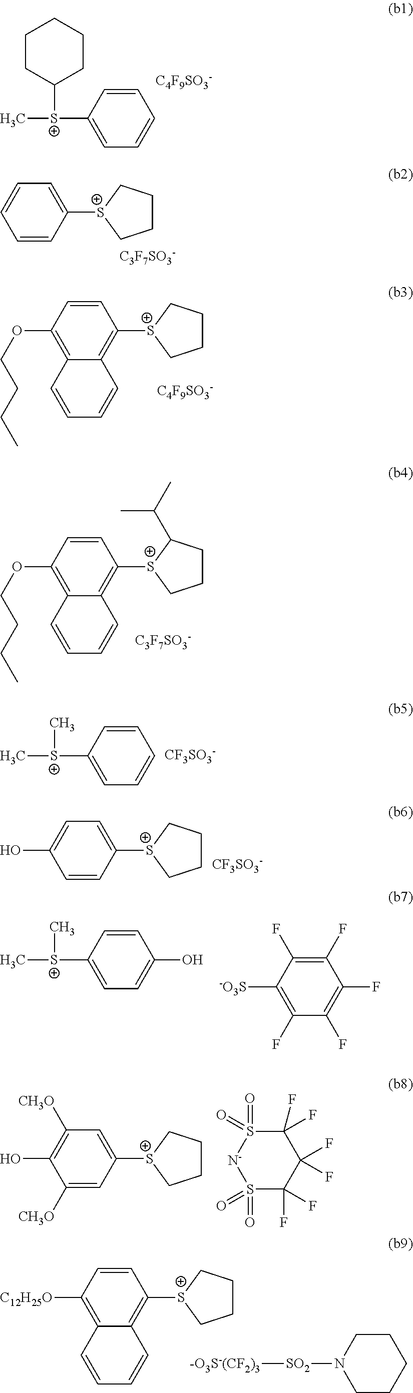

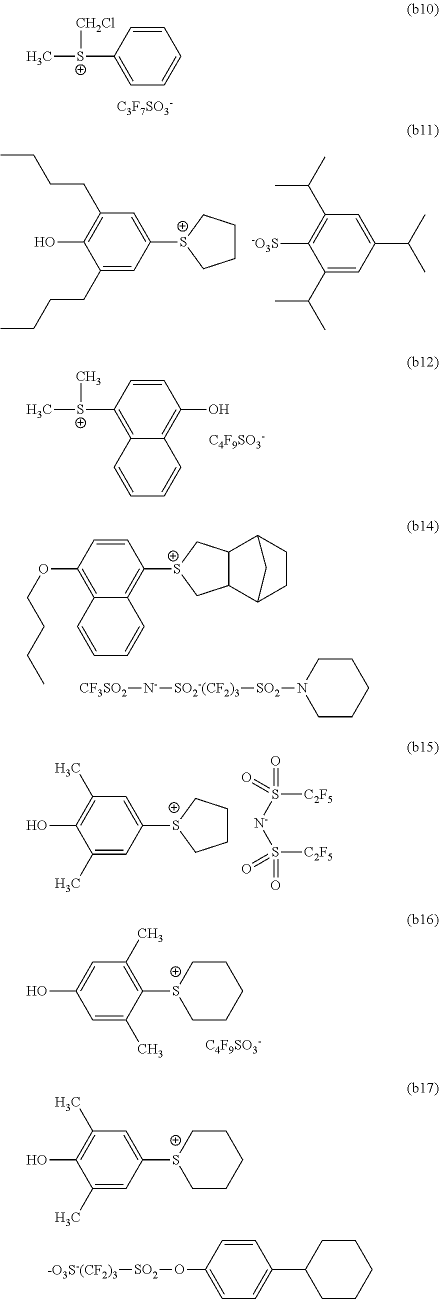

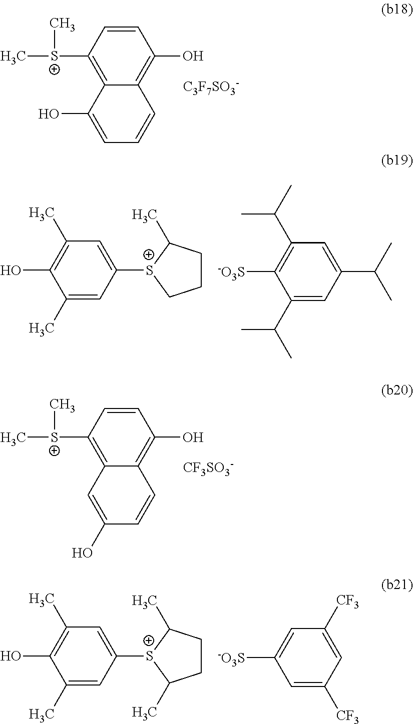

Now, the compounds of the general formula (1-2) will be described.

As mentioned above, M represents an alkyl group, a cycloalkyl group, an aryl group or a benzyl group. When a cyclic structure is contained, the cyclic structure may contain an oxygen atom, a sulfur atom, an ester bond, an amido bond or a carbon to carbon double bond.

The alkyl group represented by M may be linear or branched. This alkyl group preferably has 1 to 20 carbon atoms, more preferably 1 to 12 carbon atoms. As such an alkyl group, there can be mentioned, for example, a methyl group, an ethyl group, an n-propyl group, an isopropyl group, an n-butyl group, a sec-butyl group, a tert-butyl group, a pentyl group, a hexyl group, an octyl group or a 2-ethylhexyl group.

The cycloalkyl group represented by M preferably has 3 to 12 carbon atoms. As such a cycloalkyl group, there can be mentioned, for example, a cyclopropyl group, a cyclobutyl group, a cyclopentyl group, a cyclohexyl group, a cycloheptyl group, a cyclodecyl group or the like.

The aryl group represented by M preferably has 5 to 15 carbon atoms. As such an aryl group, there can be mentioned, for example, a phenyl group or a naphthyl group.

A substituent, such as a cycloalkyl group, an alkoxy group, a halogen atom, a phenylthio group or the like, may be introduced in each of the groups represented by M. An alkyl group as a substituent may be introduced in the cycloalkyl group and aryl group represented by M. The number of carbon atoms contained in each of these substituents is preferably 15 or less.

When M is a phenyl group, it is preferred for the same to have at least one alkyl group, cycloalkyl group, alkoxy group, cycloalkoxy group or phenylthio group as a substituent. More preferably, the sum of carbon atoms contained in each of these substituents is in the range of 2 to 15. The solubility of the acid generator in solvents can be increased and further any particle generation during storage can be suppressed by the employment of this arrangement.

As mentioned above, each of R_{1c} and R_{2c} independently represents a hydrogen atom, an alkyl group, a cycloalkyl group, a halogen atom, a cyano group or an aryl group.

This alkyl group may be linear or branched. The alkyl group preferably has 1 to 12 carbon atoms, more preferably 1 to 5 carbon atoms. As such an alkyl group, there can be mentioned, for example, a methyl group, an ethyl group or a linear or branched propyl group.

The cycloalkyl group is, for example, one having 3 to 12 carbon atoms. As preferred examples thereof, there can be mentioned a cyclopropyl group, a cyclobutyl group, a cyclopentyl group, a cyclohexyl group, a cycloheptyl group, a cyclodecyl group and the like.

As the halogen atom, a fluorine atom, a chlorine atom, a bromine atom, and an iodine atom can be exemplified.

The aryl group represented by each of R_{1c} and R_{2c} preferably has 5 to 15 carbon atoms. For example, there can be mentioned a phenyl group or a naphthyl group.

As preferred forms of R_{1c} and R_{2c}, there can be mentioned an instance in which both of R_{1c} and R_{2c} are alkyl groups. In such an instance, each of the alkyl groups is especially preferably a linear or branched alkyl group having 1 to 4 carbon atoms. A methyl group is most preferred.

Moreover, as mentioned above, at least two of M, R_{1c} and R_{2c} may be bonded to each other to thereby form a ring. This ring is preferably a 3- to 12-membered ring, more preferably a 3- to 10-membered ring and further more preferably a 3- to 6-membered ring. The ring may contain a carbon to carbon double bond.

When R_{1c} and R_{2c} are bonded to each other to thereby form a ring, the group formed by the mutual bonding of R_{1c} and R_{2c} is preferably an alkylene group having 2 to 10 carbon atoms. For example, there can be mentioned an ethylene group, a propylene group, a butylene group, a pentylene group, a hexylene group or the like. The ring formed by the mutual bonding of R_{1c} and R_{2c} may contain a hetero-atom, such as an oxygen atom, in the ring.

As mentioned above, each of Rₓ and R_{y} independently represents an alkyl group, a cycloalkyl group, a 2-oxoalkyl group, an alkoxycarbonylalkyl group, a cycloalkoxycarbonylalkyl group, an allyl group or a vinyl group.

As the alkyl group, there can be mentioned, for example, any of those mentioned above as the alkyl groups represented by R_{1c} and R_{2c}.

The cycloalkyl group preferably has 3 to 12 carbon atoms. For example, there can be mentioned a cyclopropyl group, a cyclobutyl group, a cyclopentyl group, a cyclohexyl group, a cycloheptyl group or a cyclodecyl group.

As the 2-oxoalkyl group, for example, that having >C═O at the 2-position of the above-described alkyl group can be exemplified.

The alkoxy group moiety of the alkoxycarbonylalkyl group may be linear or branched. This alkoxy group moiety preferably has 1 to 10 carbon atoms, more preferably 1 to 5 carbon atoms. As such an alkoxy group, there can be mentioned, for example, a methoxy group, an ethoxy group, a linear or branched propoxy group, a linear or branched butoxy group or a linear or branched pentoxy group.

The cycloalkoxy group moiety of the cycloalkoxycarbonylalkyl group preferably has 3 to 8 carbon atoms. As such a cycloalkoxy group, there can be mentioned, for example, a cyclopentyloxy group or a cyclohexyloxy group. As the alkyl group contained in the alkoxycarbonylalkyl group, there can be mentioned, for example, an alkyl group having 1 to 12 carbon atoms, preferably a linear alkyl group having 1 to 5 carbon atoms. For example, a methyl group or an ethyl group can be mentioned.

As mentioned above, Rₓ and R_{y} may be bonded to each other to thereby form a ring. As the group formed by the mutual bonding of Rₓ and R_{y}, there can be mentioned, for example, an alkylene group, such as a butylene group, a pentylene group or the like.

The allyl group is not particularly limited. Preferably, it is an allyl group substituted with an unsubstituted mono- or polycycloalkyl group.

The vinyl group is not particularly limited. Preferably, it is a vinyl group substituted with an unsubstituted mono- or polycycloalkyl group.

Each of Rₓ and R_{y} is preferably an alkyl group having 4 or more carbon atoms, more preferably having 6 or more carbon atoms, and further preferably 8 or more carbon atoms.

As Z⁻ in the general formula (1-2), the same anions explained with regard to the general formula (1-1) above can be exemplified.

Specific examples of cations in the general formula (1-2) will be described below.

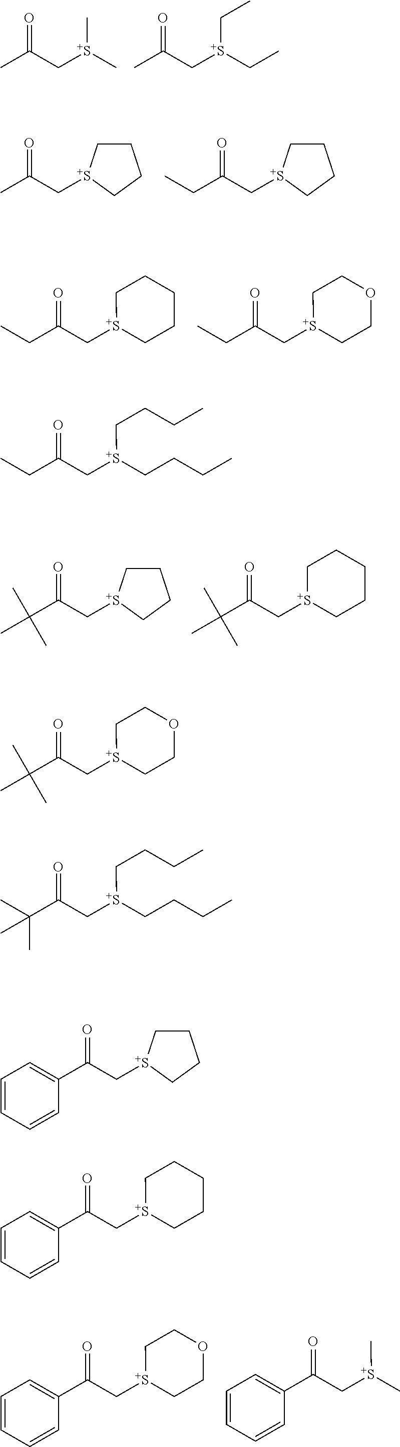

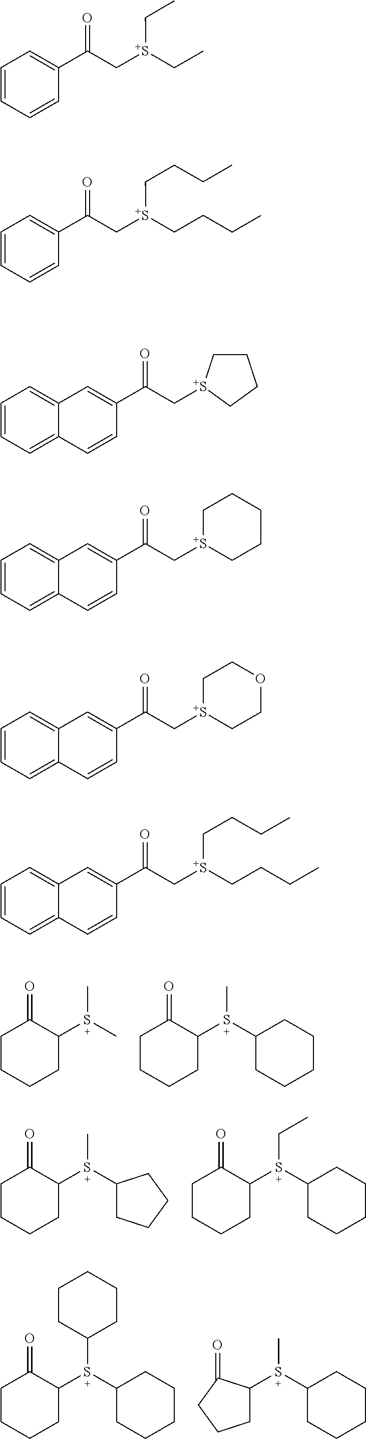

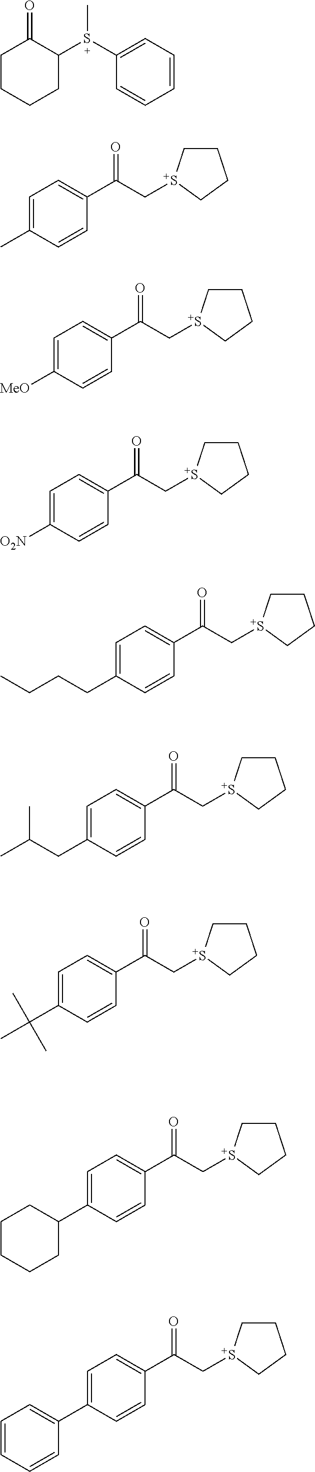

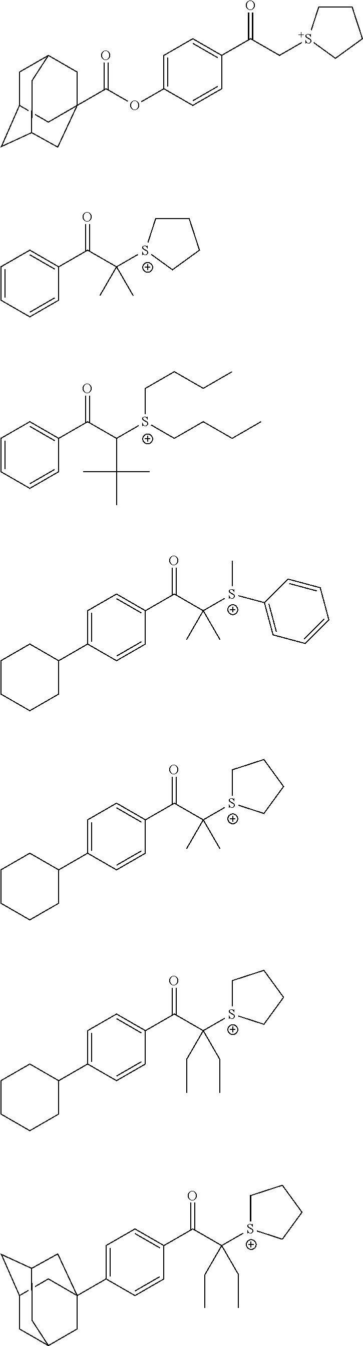

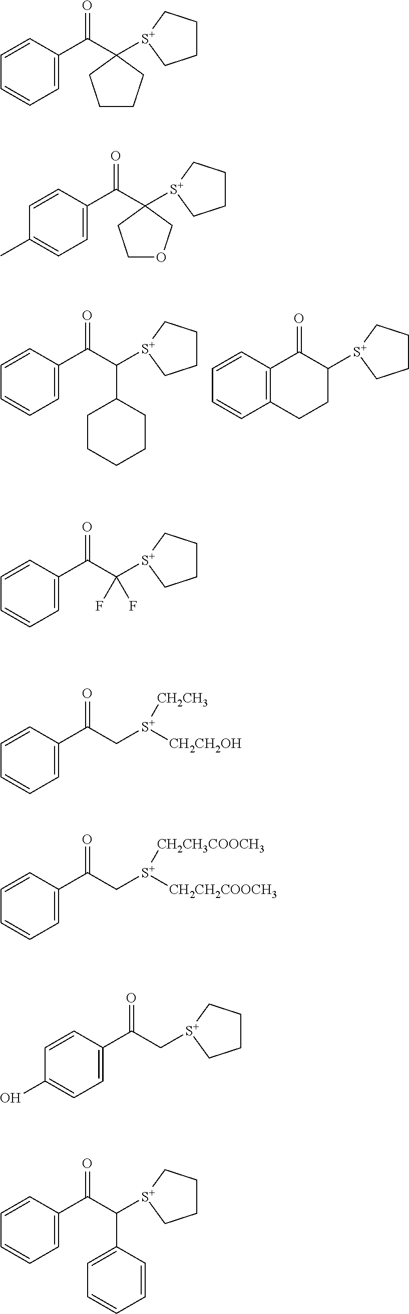

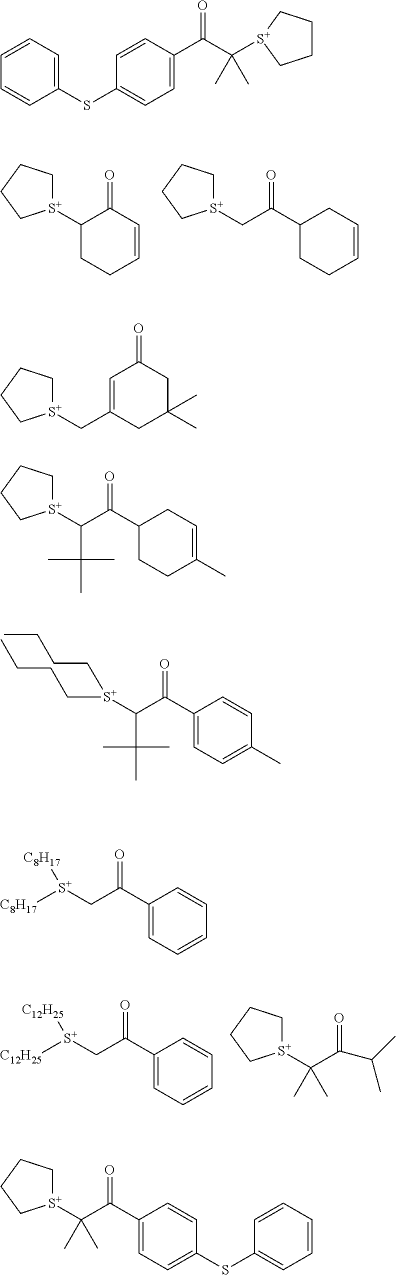

Preferred specific examples of the compounds represented by the general formula (1-2) will be described below.

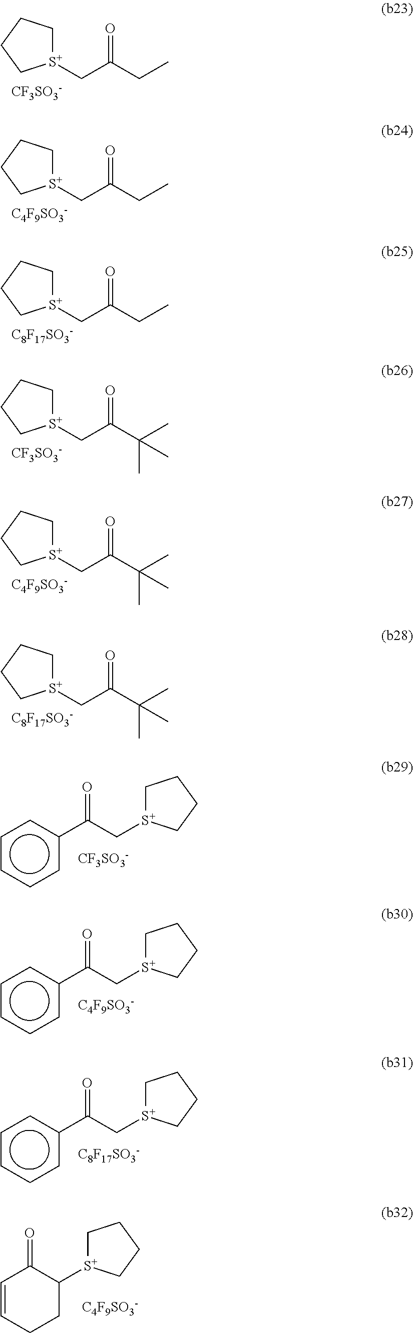

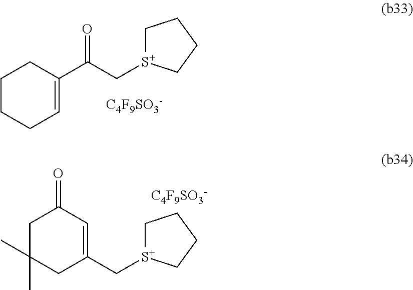

Now the compounds represented by the general formula (ZII) or (ZIII) will be described.

In the general formulae (ZII) and (ZIII), each of R₂₀₄ to R₂₀₇ independently represents an aryl group, an alkyl group or a cycloalkyl group.

The aryl group represented by R₂₀₄ to R₂₀₇ is preferably a phenyl group or a naphthyl group, more preferably a phenyl group. The aryl group may be one having a heterocyclic structure containing an oxygen atom, nitrogen atom, sulfur atom, etc. As the aryl group having a heterocyclic structure, a pyrrole residue (group formed by loss of one hydrogen atom from pyrrole), a furan residue (group formed by loss of one hydrogen atom from furan), a thiophene residue (group formed by loss of one hydrogen atom from thiophene), an indole residue (group formed by loss of one hydrogen atom from indole), a benzofuran residue (group formed by loss of one hydrogen atom from benzofuran), and a benzothiophene residue (group formed by loss of one hydrogen atom from benzothiophene) can be exemplified. When the arylsulfonium compound contains two or more aryl group, these aryl groups may be identical or different from each other.

As preferred alkyl groups and cycloalkyl groups represented by R₂₀₄ to R₂₀₇, a linear or branched alkyl group having 1 to 10 carbon atoms and a cycloalkyl group having 3 to 10 carbon atoms can be exemplified. As the alkyl group, for example, a methyl group, an ethyl group, a propyl group, a butyl group and a pentyl group can be exemplified. As the cycloalkyl group, for example, a cyclopentyl group, a cyclohexyl group and a norbornyl group can be exemplified.

The aryl group, alkyl group and cycloalkyl group represented by R₂₀₄ to R₂₀₇ may have one or more substituents. As a possible substituent on the aryl group, alkyl group and cycloalkyl group represented by R₂₀₄ to R₂₀₇, an alkyl group (having, for example, 1 to 15 carbon atoms), a cycloalkyl group (having, for example, 3 to 15 carbon atoms), an aryl group (having, for example, 6 to 15 carbon atoms), an alkoxy group (having, for example, 1 to 15 carbon atoms), a halogen atom, a hydroxy group, and a phenylthio group can be exemplified.

Z⁻ represents a nonnucleophilic anion. As such, the same nonnucleophilic anions as mentioned with respect to the Z⁻ in the general formula (ZI) can be exemplified.

As the acid generators, the compounds represented by the following general formulae (ZIV), (ZV) and (ZVI) can further be exemplified.

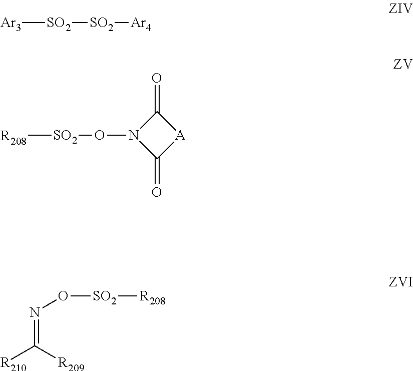

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an ajkenylene group or an arylene group.

Among the acid generators, the compounds represented by the general formulae (ZI) to (ZIII) are more preferred.

As a preferred acid generator, a compound that generates an acid having one sulfonate group or imido group. As a more preferred acid generator, a compound that generates a monovalent perfluoroalkanesulfonic acid, a compound that generates a monovalent aromatic sulfonic acid substituted with one or more fluorine atoms or fluorine-atom-containing group, and a compound that generates a monovalent imidic acid substituted with one or more fluorine atoms or fluorine-atom-containing group can be exemplified. As a still more preferred acid generator, any of sulfonium salts of fluorinated alkanesulfonic acid, fluorinated benzenesulfonic acid, fluorinated imidic acid and fluorinated methide acid can be exemplified.

It is preferred for the acid generator to be one from which an acid of −1 or below pKa is generated. The sensitivity of the composition can be enhanced by the use of this acid generator. As acid generators, it is especially preferred for the generated acid to be a fluorinated alkanesulfonic acid, fluorinated benzenesulfonic acid or fluorinated imidic acid, each of which having pKa's of −1 or below.

Specific examples of the particularly preferred acid generators will be given below.

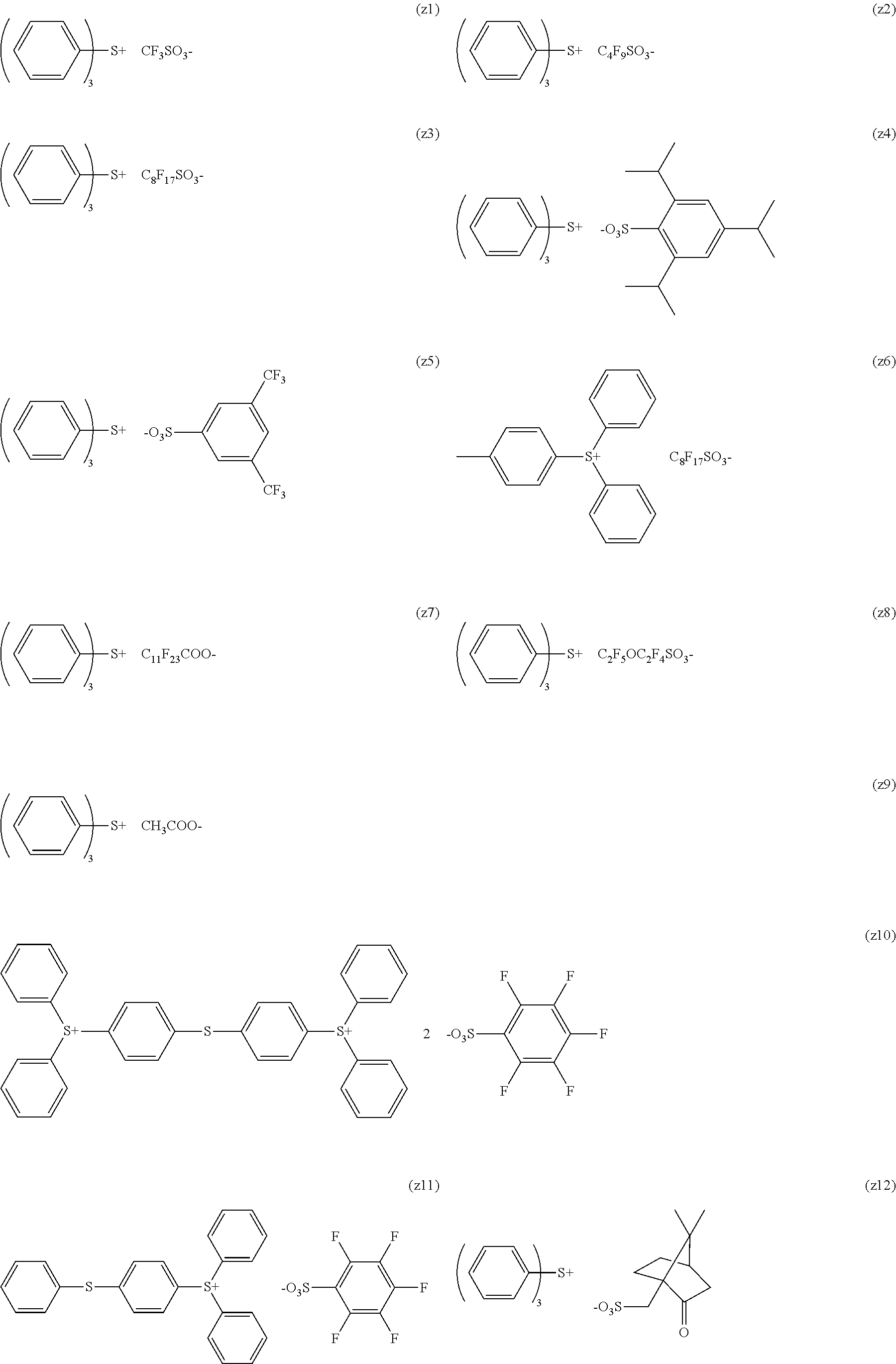

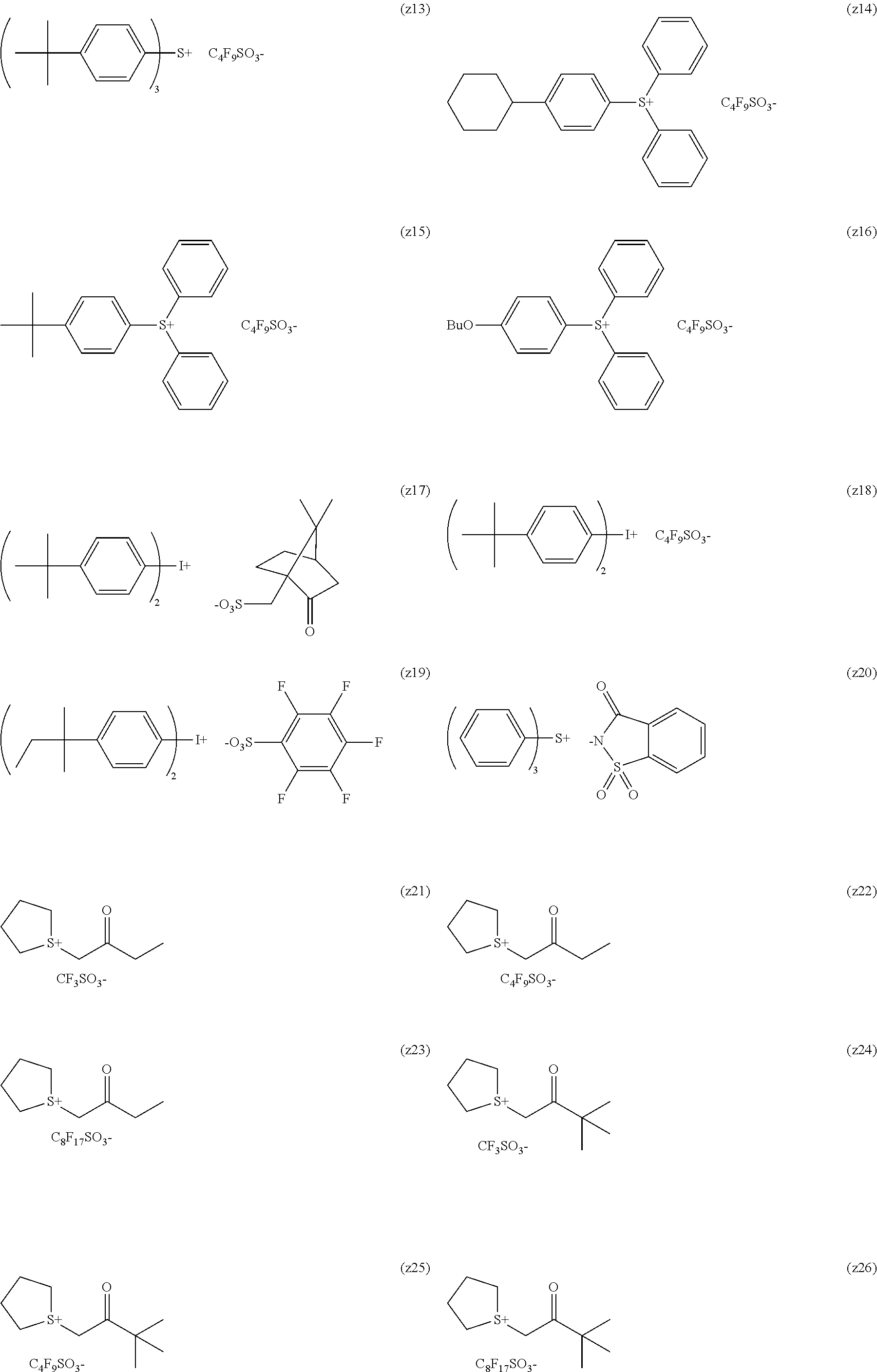

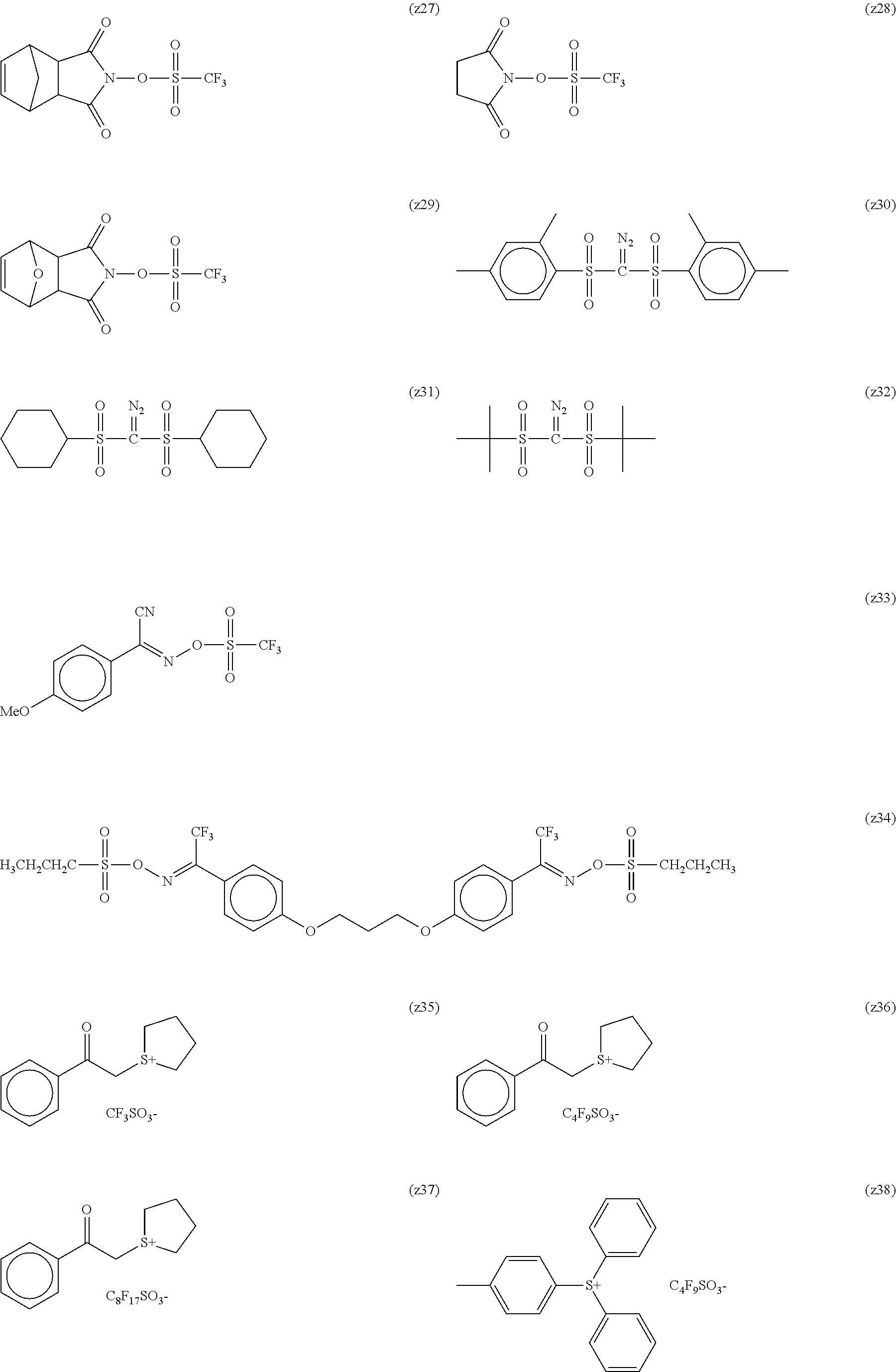

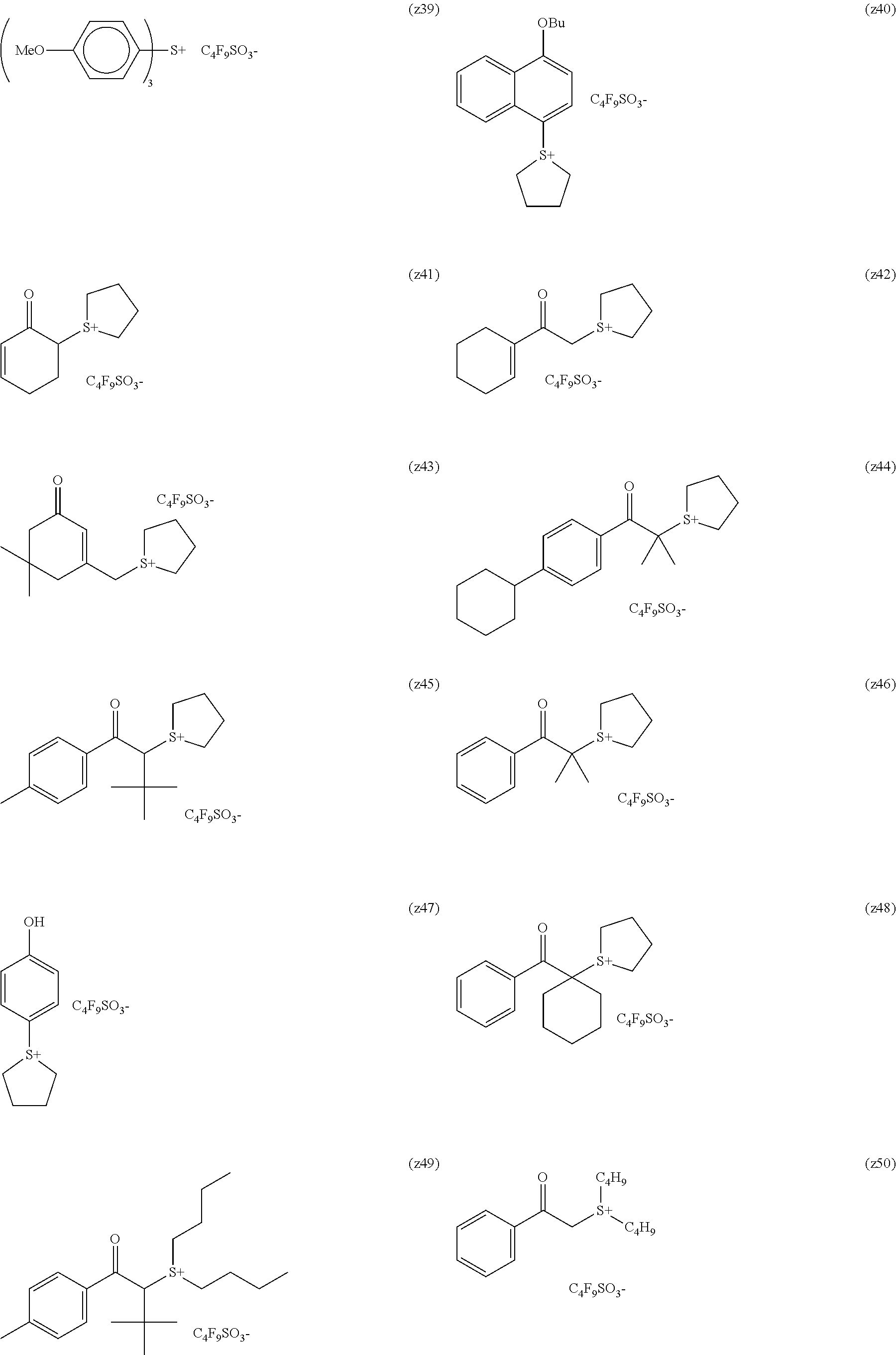

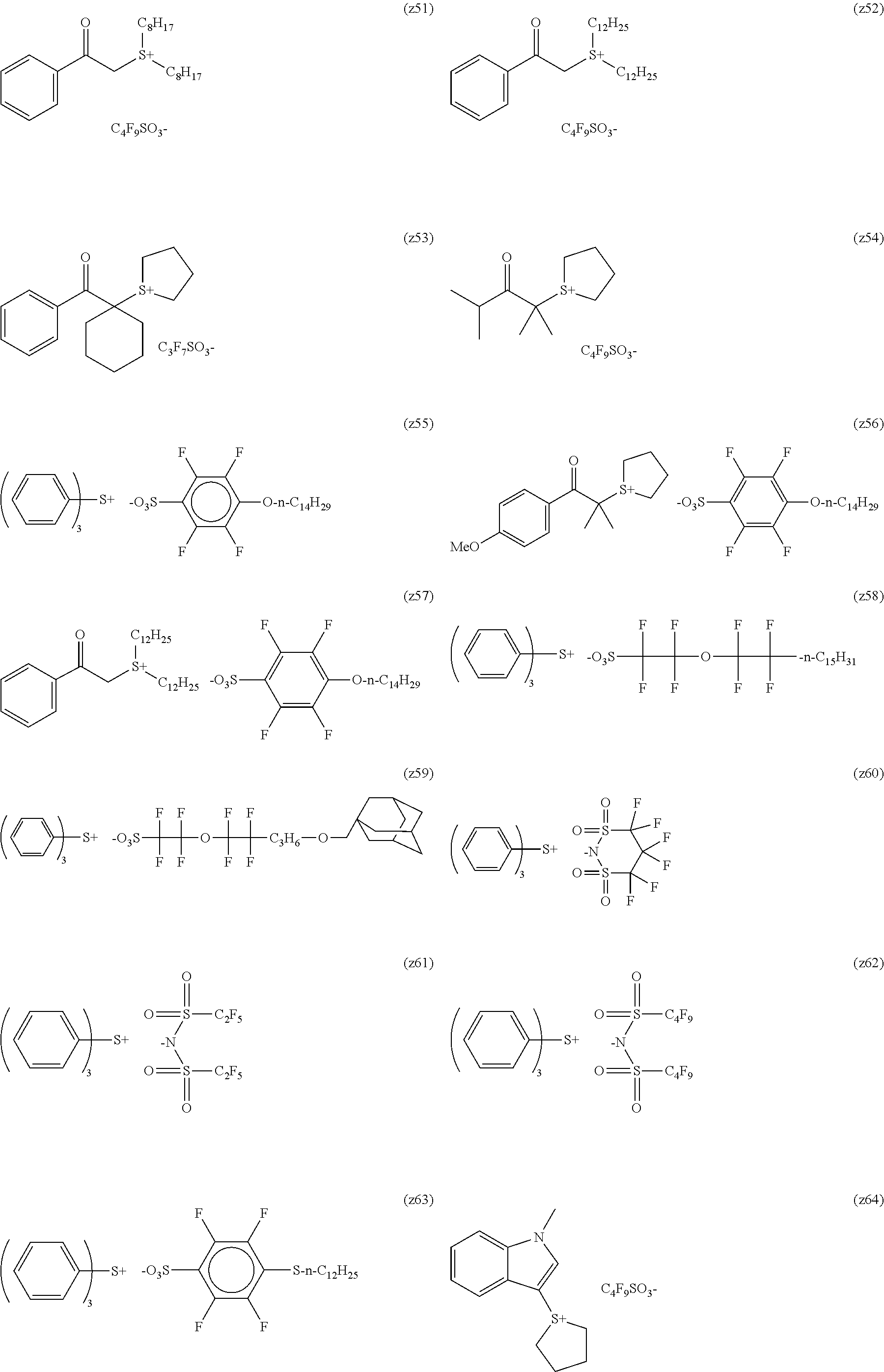

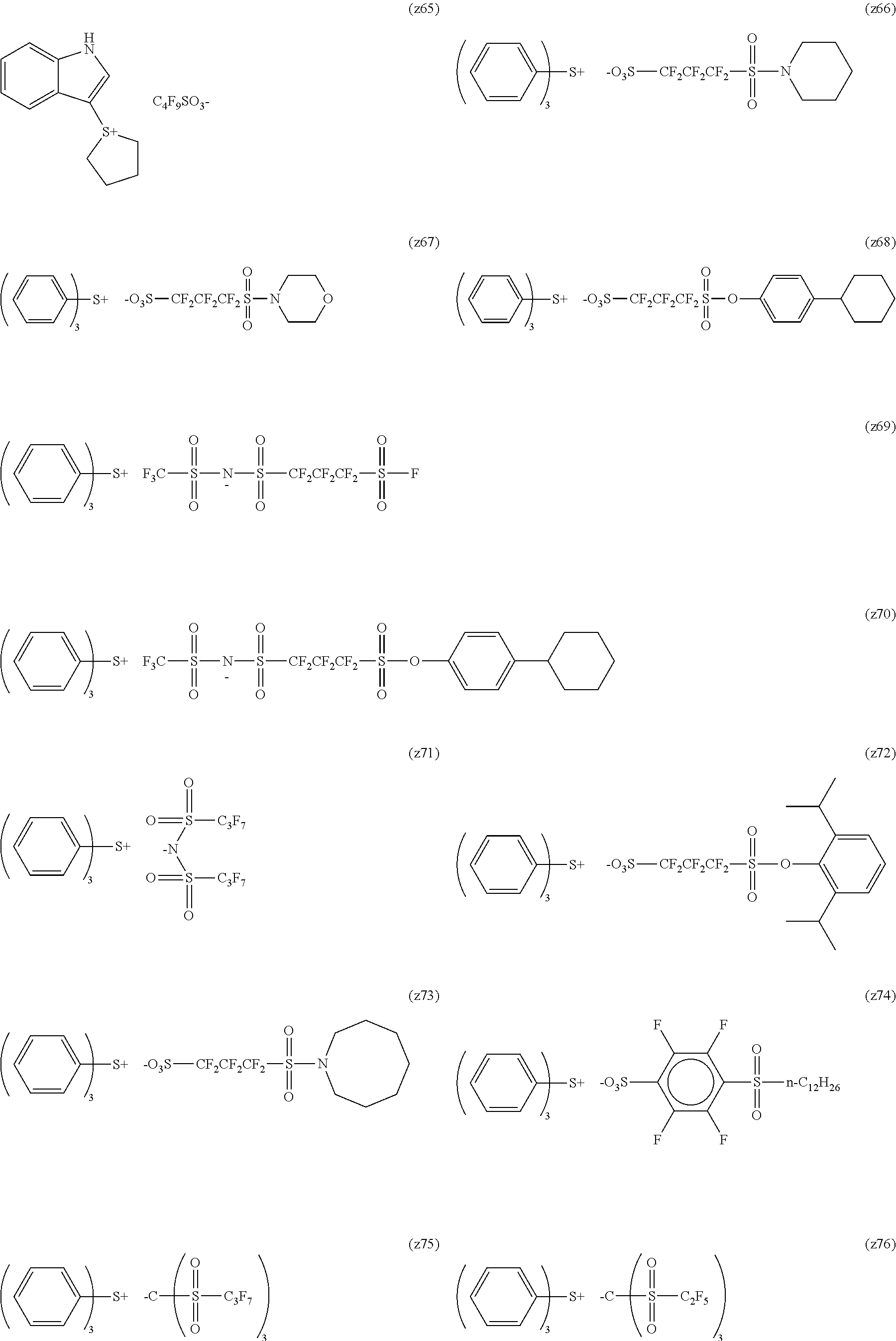

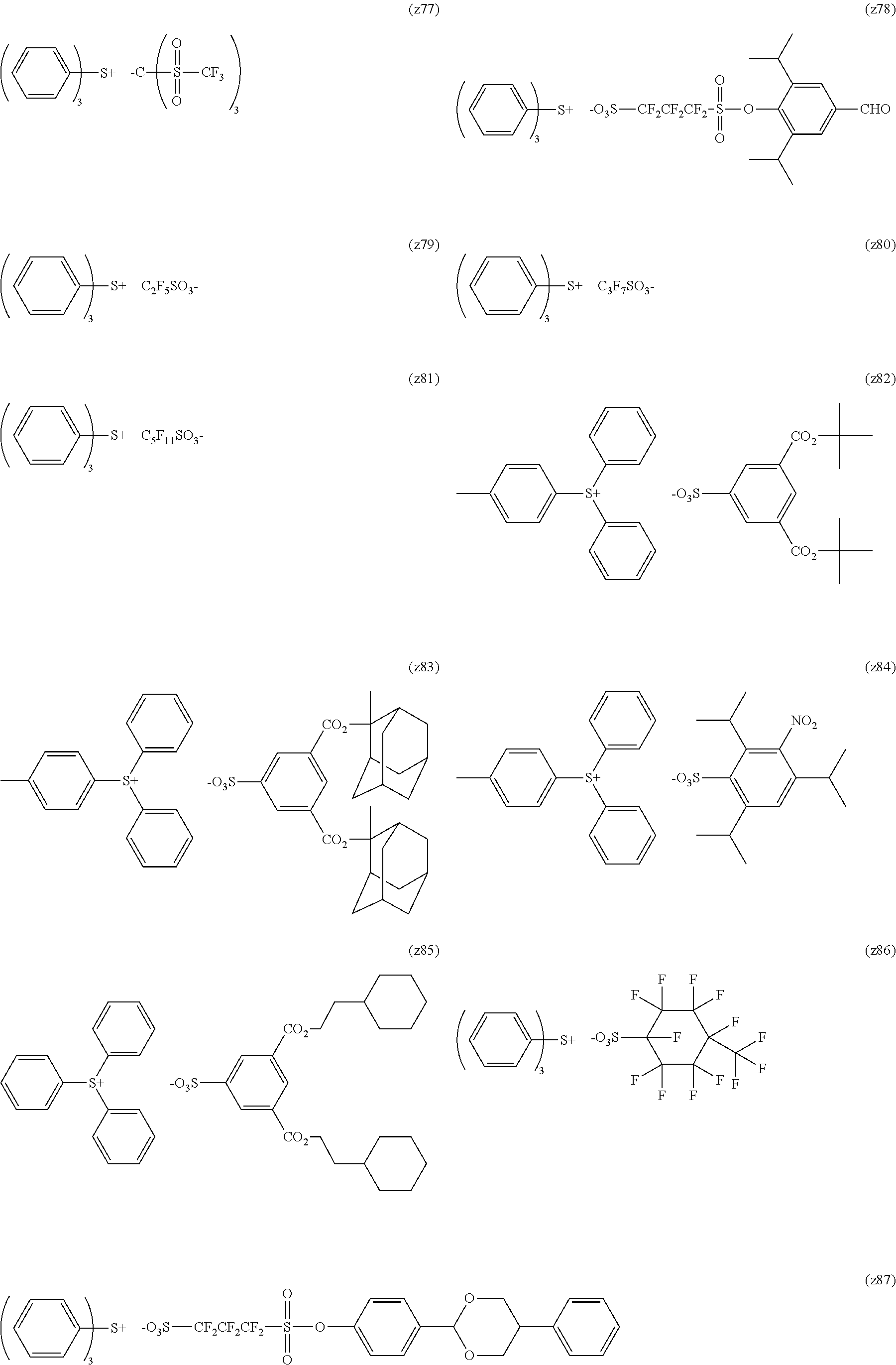

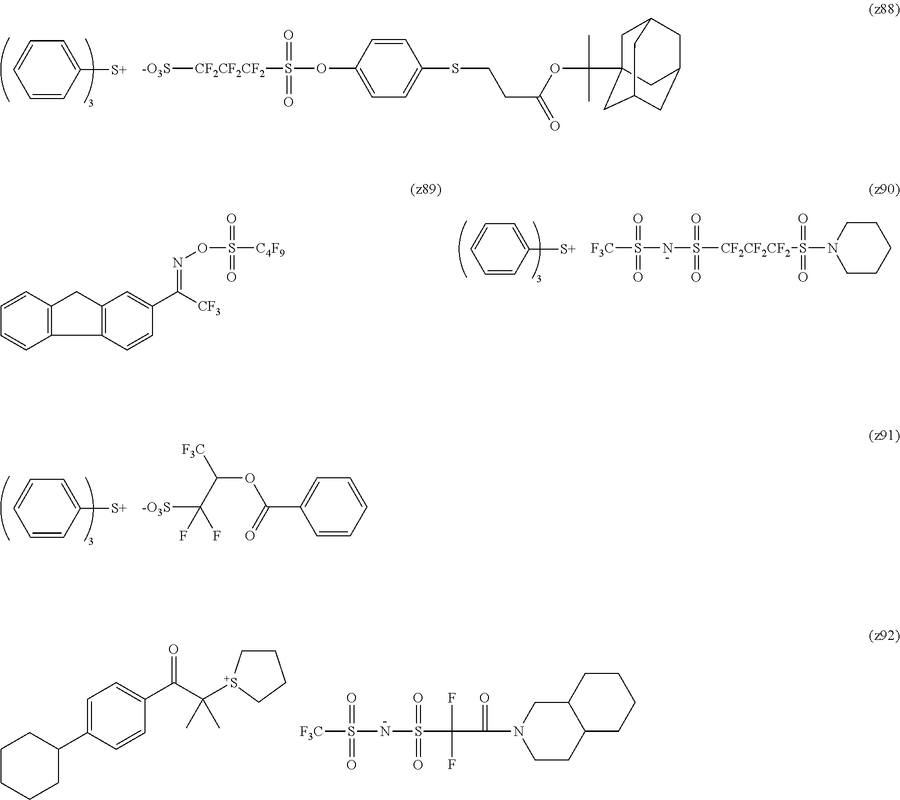

The acid generators can be used either individually or in combination of two or more kinds.

When the composition of the present invention contains an acid generator, the content thereof based on the total solids of the composition is preferably in the range of 0.1 to 20 mass %, more preferably 0.5 to 10 mass % and further more preferably 1 to 7 mass %.

When the composition of the present invention contains any of the compounds (ZI-3) as an acid generator, the content thereof based on the total solids of the composition is preferably in the range of 0.1 to 40 mass %, more preferably 0.5 to 30 mass % and further more preferably 1 to 30 mass %.

<Other Components>

The composition of the present invention may further contain a hydrophobic resin, a solvent, a basic compound, a surfactant, a carboxylic acid onium salt, a dissolution inhibiting compound and/or other additives.

(Hydrophobic Resin)

As mentioned above, the composition of the present invention may further contain a hydrophobic resin.

When a hydrophobic resin is further contained, the hydrophobic resin is unevenly localized in the surface layer of the film formed from the composition. Thus, when water is used as a liquid for liquid immersion, the receding contact angle of the film with reference to the liquid for liquid immersion can be increased. Accordingly, the liquid-immersion liquid tracking property of the film can be enhanced.

The hydrophobic resin typically contains fluorine atom and/or silicone atom. The fluorine atom and/or silicon atom in the hydrophobic resin may be present in the principal chain of the resin or may be a substituent on the side chain thereof.

When the hydrophobic resin contains fluorine atom, the resin preferably has, as a partial structure containing one or more fluorine atoms, an alkyl group containing one or more fluorine atoms, a cycloalkyl group containing one or more fluorine atoms, or an aryl group containing one or more fluorine atoms.

The alkyl group containing one or more fluorine atoms is a linear or branched alkyl group having at least one hydrogen atom thereof substituted with one or more fluorine atoms. The group preferably has 1 to 10 carbon atoms, more preferably 1 to 4 carbon atoms. Further, other substituents than fluorine atom may also be contained.

The cycloalkyl group containing one or more fluorine atoms is a monocyclic or polycyclic alkyl group having at least one hydrogen atom thereof substituted with one or more fluorine atoms. Further, other substituents than fluorine atom may also be contained.

The aryl group containing one or more fluorine atoms is an aryl group having at least one hydrogen atom of an aryl group substituted with one or more fluorine atoms. As the aryl group, a phenyl or a naphthyl group can be exemplified. Further, other substituents than fluorine atom may also be contained.

As preferred alkyl groups containing one or more fluorine atoms, cycloalkyl groups containing one or more fluorine atoms and aryl groups containing one or more fluorine atoms, groups of the following general formulae (F2) to (F4) can be exemplified.

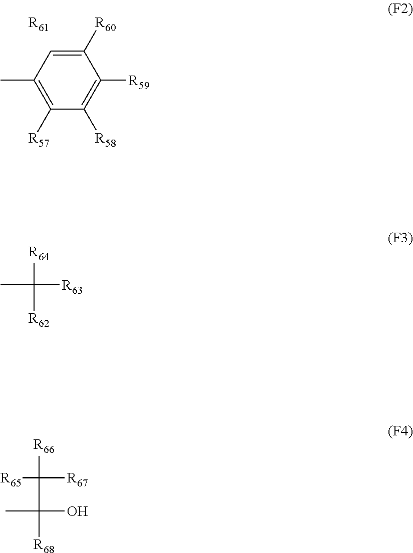

In the general formulae (F2) to (F4),

each of R₅₇ to R₆₈ independently represents a hydrogen atom, a fluorine atom or an alkyl group in condition that: at least one of R₅₇-R₆₁ represents a fluorine atom or an alkyl group having at least one hydrogen atom thereof substituted with one or more fluorine atoms; at least one of R₆₂-R₆₄ represents a fluorine atom or an alkyl group having at least one hydrogen atom thereof substituted with one or more fluorine atoms; and at least one of R₆₅-R₆₈ represents a fluorine atom or an alkyl group having at least one hydrogen atom thereof substituted with one or more fluorine atoms. These alkyl groups preferably are those having 1 to 4 carbon atoms.

It is preferred that all of R₅₇-R₆₁ and R₆₅-R₆₇ represent fluorine atoms. Each of R₆₂, R₆₃ and R₆₈ preferably represents an alkyl group having at least one hydrogen atom thereof substituted with one or more fluorine atoms, more preferably a perfluoroalkyl group having 1 to 4 carbon atoms. R₆₂ and R₆₃ may be bonded to each other to form a ring.

Specific examples of the groups represented by the general formula (F2) include a p-fluorophenyl group, a pentafluorophenyl group, and a 3,5-di(trifluoromethyl)phenyl group.

Specific examples of the groups represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups represented by the general formula (F4) include —C(CF₃)₂OH, —C(C₂F₅)₂OH, —C(CF₃)(CH₃)OH, —CH(CF₃)OH and the like. Of these, —C(CF₃)₂OH is particularly preferred.

Specific examples of the repeating units having a fluorine atom will be shown below.

In the specific examples, X₁ represents a hydrogen atom, —CH₃, —F or —CF₃. X₂ represents —F or —CF₃.

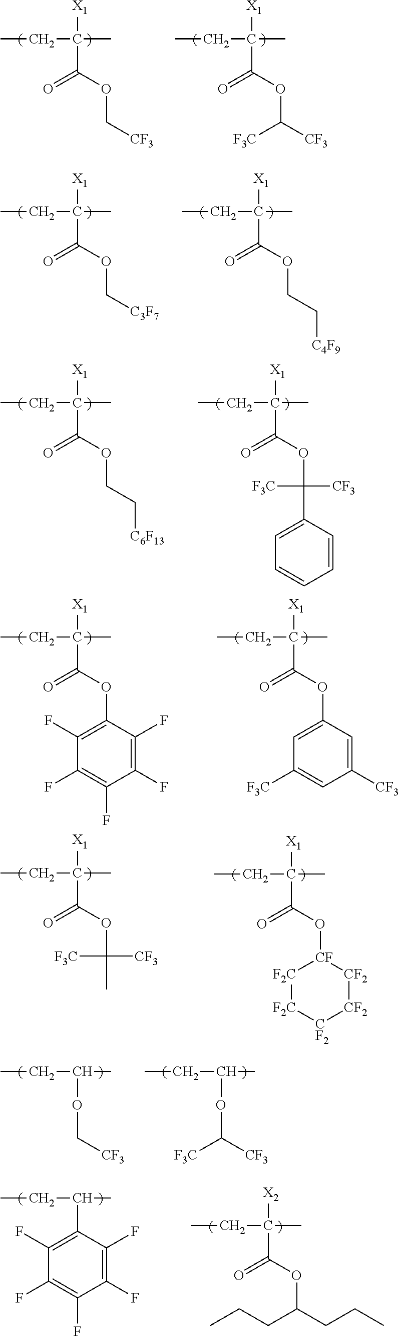

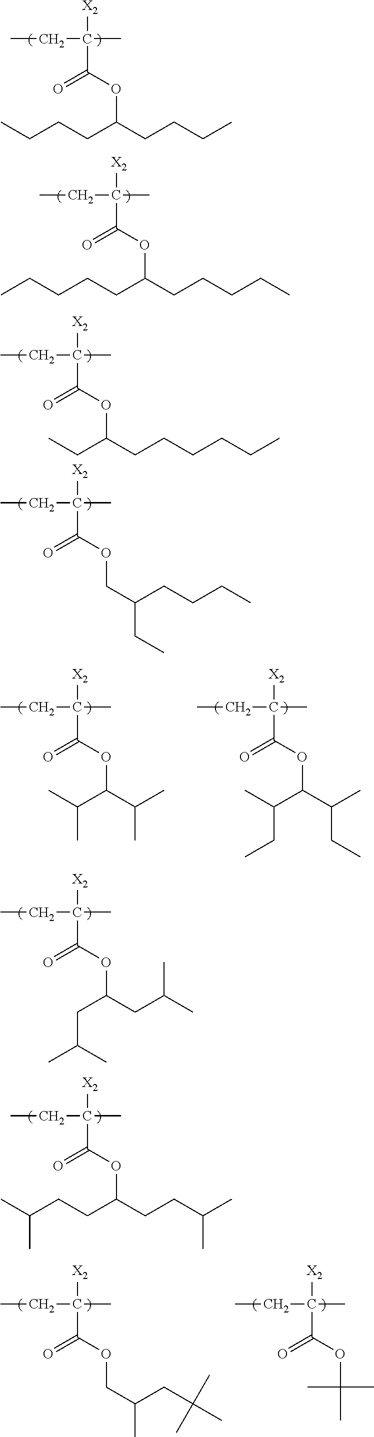

When the hydrophobic resin contains one or more silicon atoms, the resin preferably contains, as partial structure containing the silicon atom, an alkylsilyl structure or a cyclosiloxane structure. Preferred alkylsilyl structure is that containing one or more trialkylsilyl groups.

As the alkylsilyl structure and cyclosiloxane structure, any of the groups represented by the following general formulae (CS-1) to (CS-3) can be exemplified.

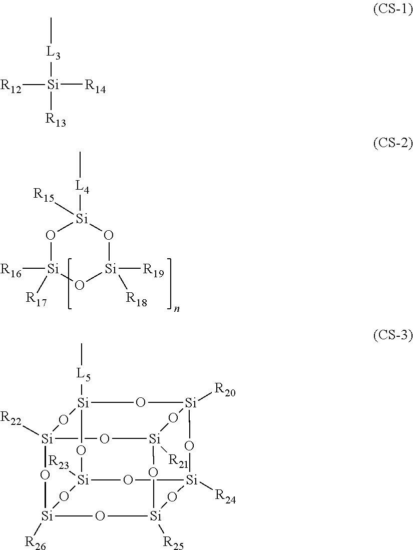

In the general formulae (CS-1) to (CS-3),

each of R₁₂ to R₂₆ independently represents a linear or branched alkyl group or a cycloalkyl group.

The alkyl group preferably has 1 to 20 carbon atoms. The cycloalkyl group preferably has 3 to 20 carbon atoms.

Each of L₃ to L₅ represents a single bond or a bivalent connecting group. As the bivalent connecting group, any one or a combination of two or more groups selected from the group consisting of an alkylene group, a phenylene group, an ether group, a thioether group, a carbonyl group, an ester group, an amido group, a urethane group and a urea group can be exemplified.

In the formulae, n is an integer of 1 to 5, and preferably an integer of 2 to 4.

Specific examples of the repeating units having the groups represented by the general formulae (CS-1) to (CS-3) will be shown below. In the specific examples, X₁ represents a hydrogen atom, —CH₃, —F or —CF₃.

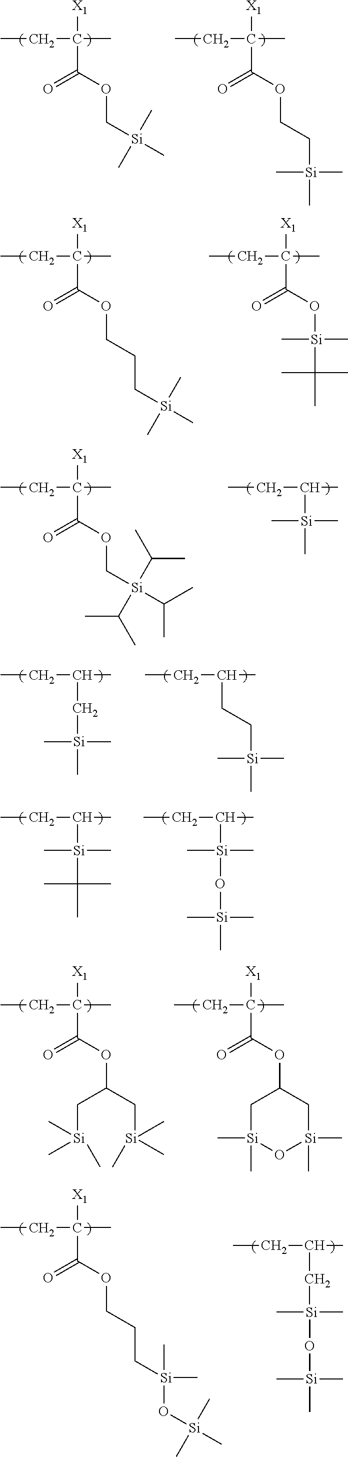

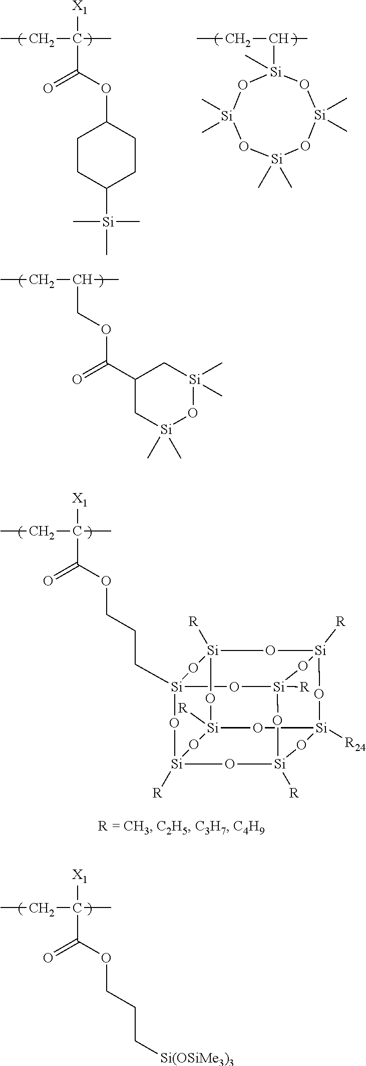

The hydrophobic resin may further contain at least one group selected from among the following groups (x) to (z):

(x) an alkali soluble group,

(y) a group that is decomposed by the action of an alkali developer, resulting in an increase of solubility in the alkali developer, and

(z) a group that is decomposed by the action of an acid.

As the alkali soluble group (x), a phenolic hydroxy group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group can be exemplified. As preferred alkali soluble groups, a fluoroalcohol group, a sulfonimido group, and a bis(carbonyl)methylene group can be exemplified. As preferred fluoroalcohol group, a hexafluoroisopropanol group can be exemplified.

As the repeating unit having an alkali soluble group (x), use can be made of any of a repeating unit resulting from direct bonding of an alkali soluble group to the principal chain of a resin like a repeating unit of acrylic acid or methacrylic acid; a repeating unit resulting from bonding, via a connecting group, of an alkali soluble group to the principal chain of a resin; and a repeating unit resulting from polymerization with the use of a chain transfer agent or polymerization initiator having an alkali soluble group to introduce the same in a polymer chain terminal.

The content of repeating units having an alkali soluble group based on all the repeating units of the polymer is preferably in the range of 1 to 50 mol %, more preferably 3 to 35 mol %, and still more preferably 5 to 20 mol %.

Specific examples of the repeating units having an alkali soluble group will be shown below. In the formulae, Rx represents H, CH₃, CF₃, or CH₂OH.

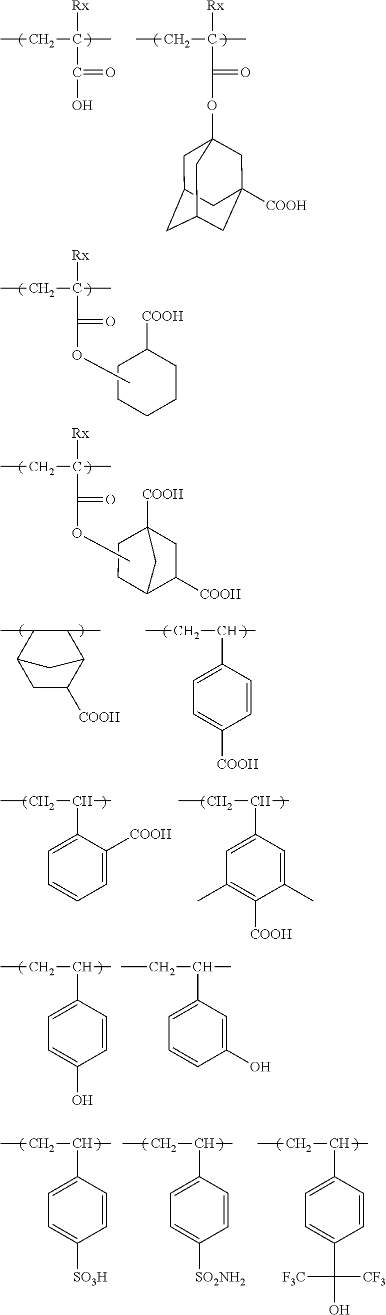

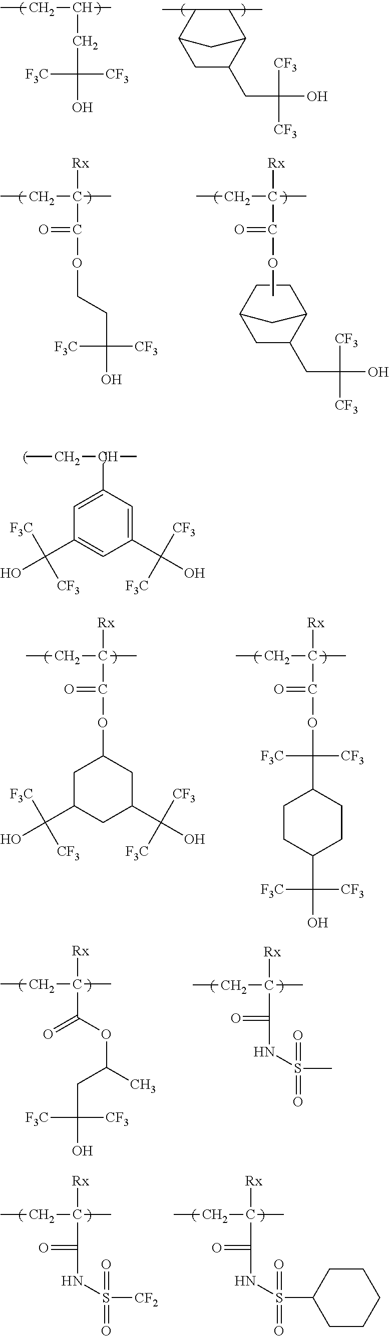

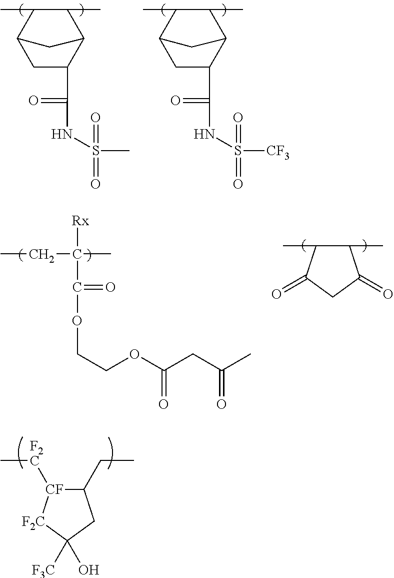

As the group (y) that is decomposed by the action of an alkali developer resulting in an increase of solubility in the alkali developer, a group having lactone structure, an acid anhydride group, and an acid imide group can be exemplified. Of these, a group having a lactone structure is particularly preferred.

As the repeating unit having a group that is decomposed by the action of an alkali developer resulting in an increase of solubility in the alkali developer, use can be made of both of a repeating unit resulting from bonding of a group that is decomposed by the action of an alkali developer resulting in an increase of solubility in the alkali developer to the principal chain of a resin such as a repeating unit of acrylic ester or methacrylic ester, and a repeating unit resulting from polymerization with the use of a chain transfer agent or polymerization initiator having a group resulting in an increase of solubility in an alkali developer to introduce the same in a polymer chain terminal.

As the repeating unit having a group that is decomposed by the action of an alkali developer resulting in an increase of solubility in the alkali developer, for example, those explained in connection with [1] Resin (P) can be exemplified.

The content of repeating units having a group resulting in an increase of solubility in an alkali developer based on all the repeating units of the polymer is preferably in the range of 1 to 40 mol %, more preferably 3 to 30 mol %, and still more preferably 5 to 15 mol %.

As the repeating unit having a group that is decomposed by the action of an acid, those explained in connection with [1] Resin (P) can be exemplified.

The content of repeating units having a group that is decomposed by the action of an acid in the hydrophobic resin based on all the repeating units of the polymer is preferably in the range of 1 to 80 mol %, more preferably 10 to 80 mol %, and still more preferably 20 to 60 mol %.

The hydrophobic resin may further have any of the repeating units represented by the following general formula (III).

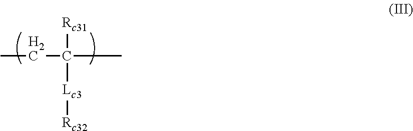

In the general formula (III),

R_{c31} represents a hydrogen atom, an alkyl group, an alkyl group optionally substituted with one or more fluorine atoms, a cyano group or a group of the formula —CH₂O—R_{ac2} in which R_{ac2} represents a hydrogen atom, an alkyl group or an acyl group.

R_{c31} is preferably a hydrogen atom, a methyl group, a hydroxymethyl group, or a trifluoromethyl group, more preferably a hydrogen atom or a methyl group.

R_{c32} represents a group containing an alkyl group, a cycloalkyl group, an alkenyl group, or a cycloalkenyl group. These groups may be substituted with fluorine atom and/or silicon atom.

The alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

Preferably, R_{c32} represents an unsubstituted alkyl group or an alkyl group substituted with one or more fluorine atoms.

L_{c3} represents a single bond or a bivalent connecting group. As the bivalent connecting group represented by L_{c3}, an ester group, an alkylene group (preferably having 1 to 5 carbon atoms), an oxy group, or a phenylene group can be exemplified.

The hydrophobic resin may further have any of the repeating units represented by general formula (CII-AB) below.

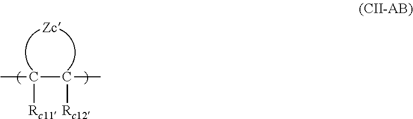

In the general formula (CII-AB),

each of R_{c11}′ and R_{c12}′ independently represents a hydrogen atom, a cyano group, a halogen atom or an alkyl group. Zc′ represents an atomic group required for forming an alicyclic structure in cooperation with two carbon atoms (C—C) to which R_{c11}′ and R_{c12}′ are respectively bonded.

Specific examples of the repeating units represented by the general formula (III) and general formula (CII-AB) will be shown below. In the specific examples, Ra represents H, CH₃, CH₂OH, CF₃ or CN.

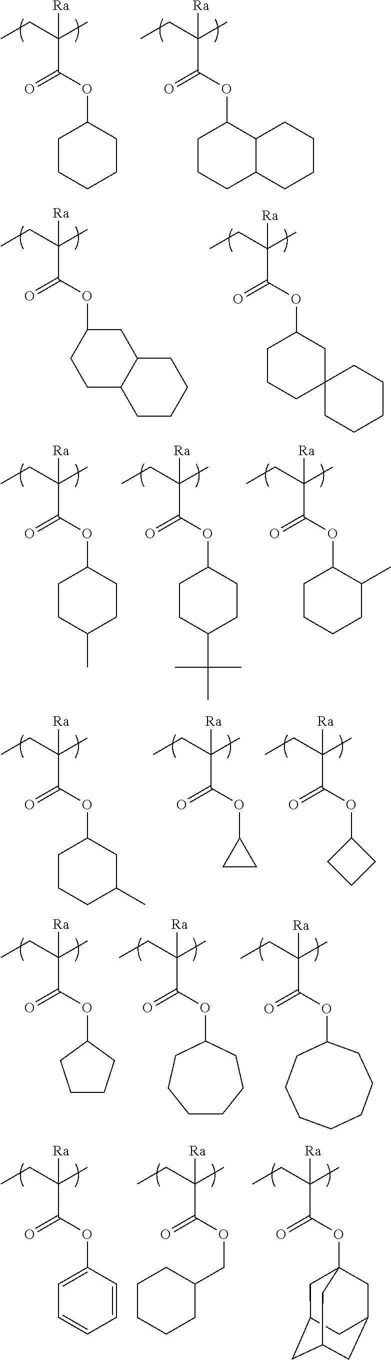

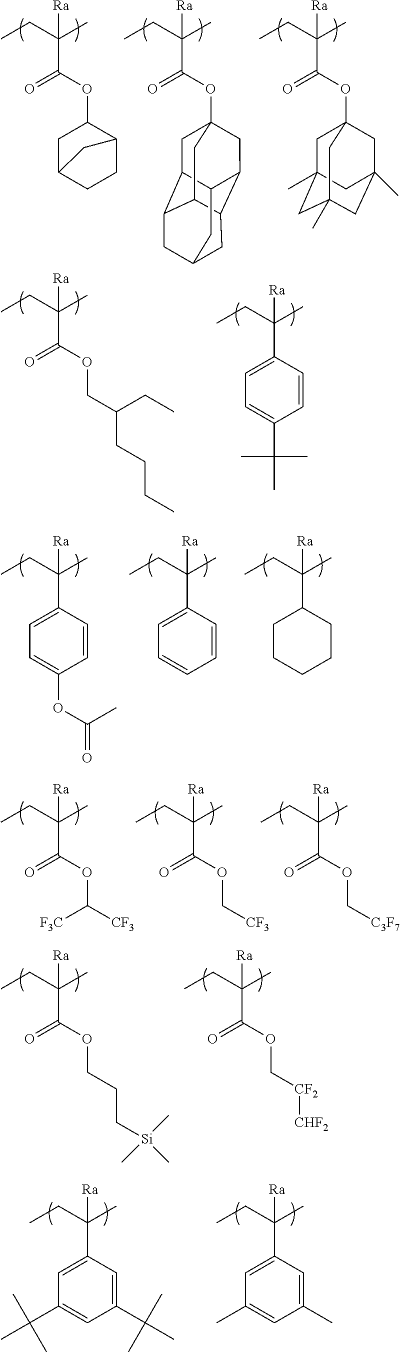

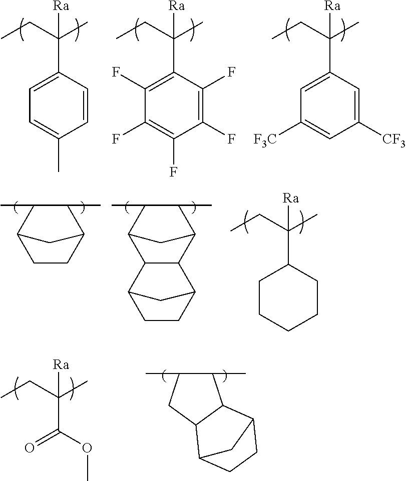

Specific examples of the hydrophobic resins will be shown below. The following Table 1 shows the molar ratio of individual repeating units (corresponding to individual repeating units in order from the left), weight average molecular weight, and degree of dispersal with respect to each of the resins.

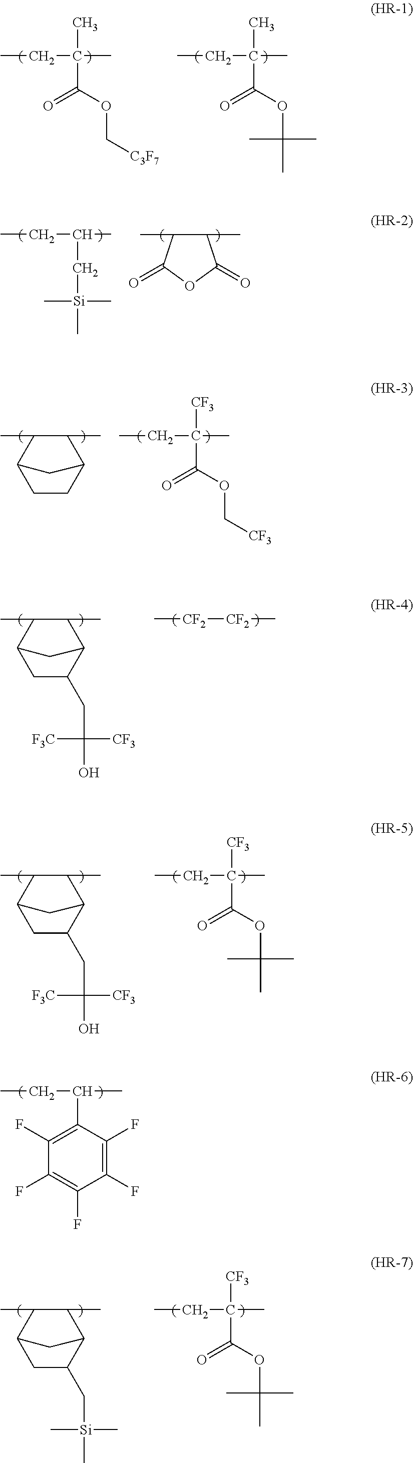

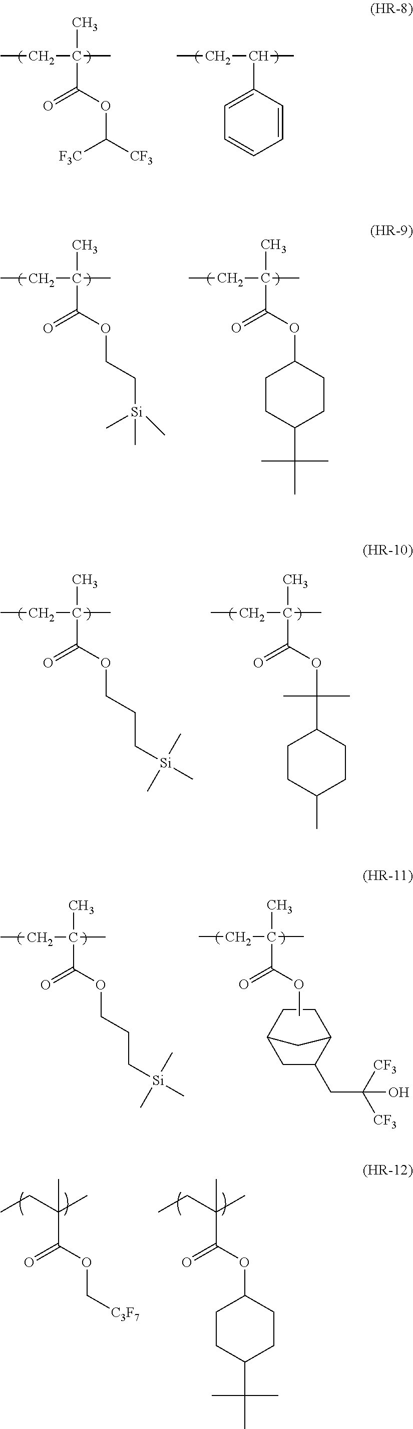

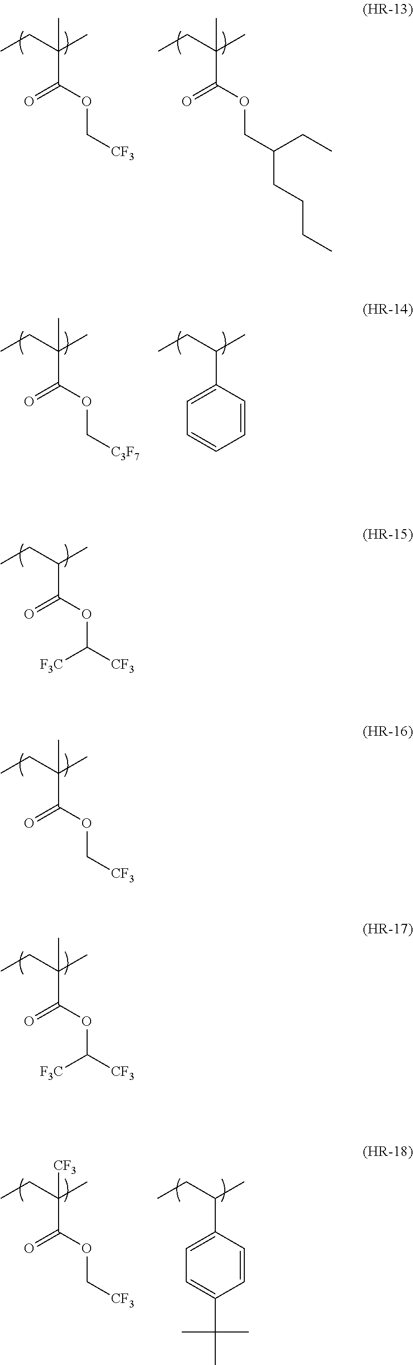

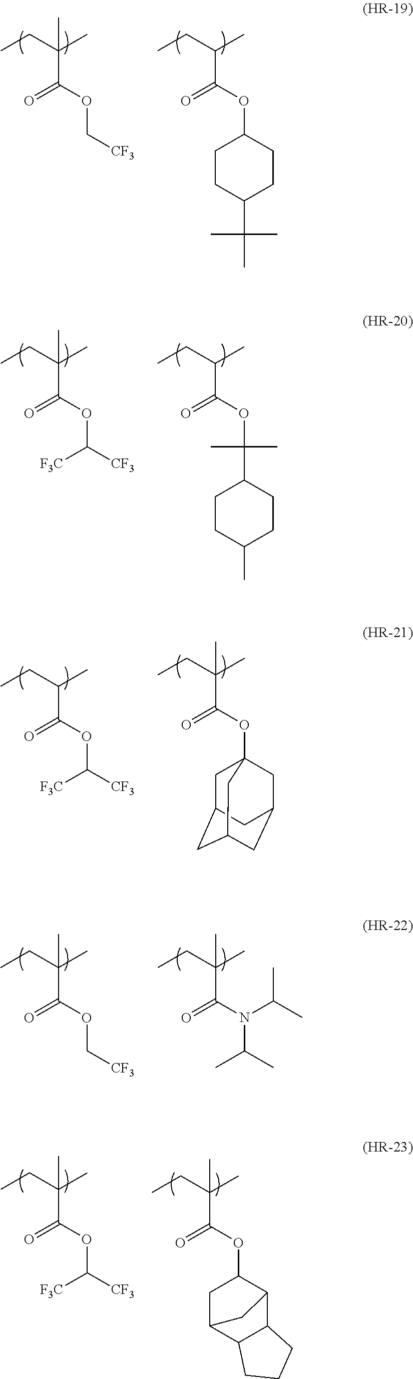

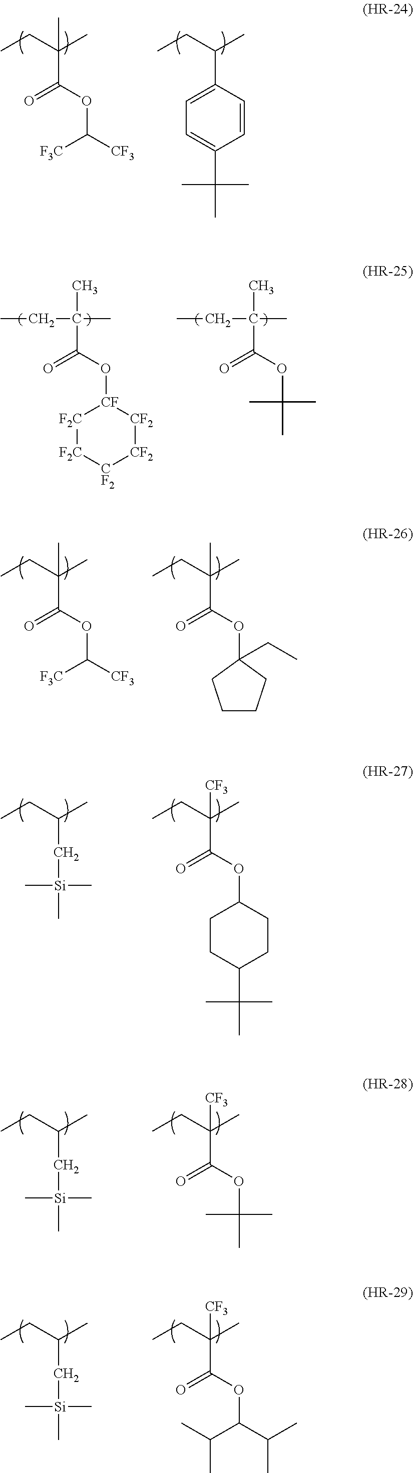

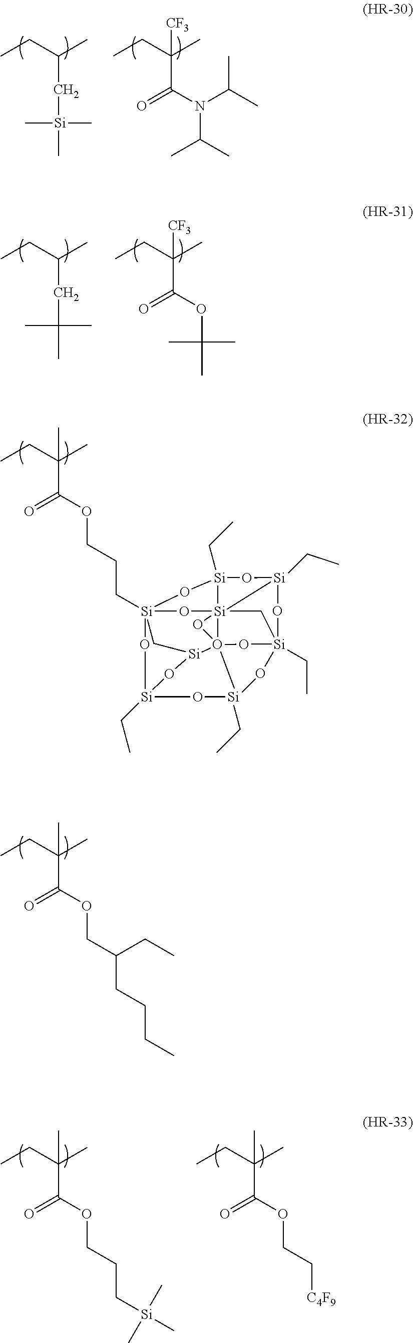

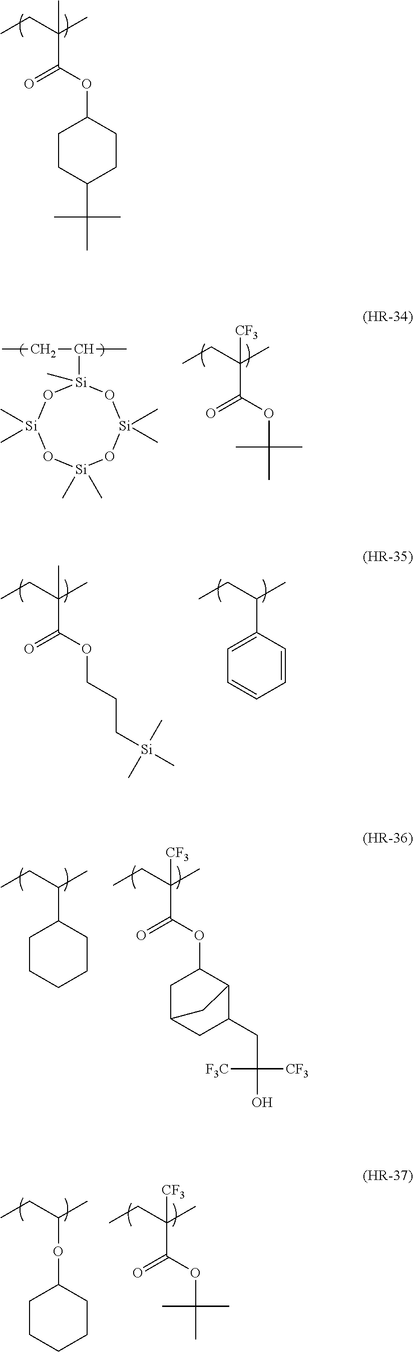

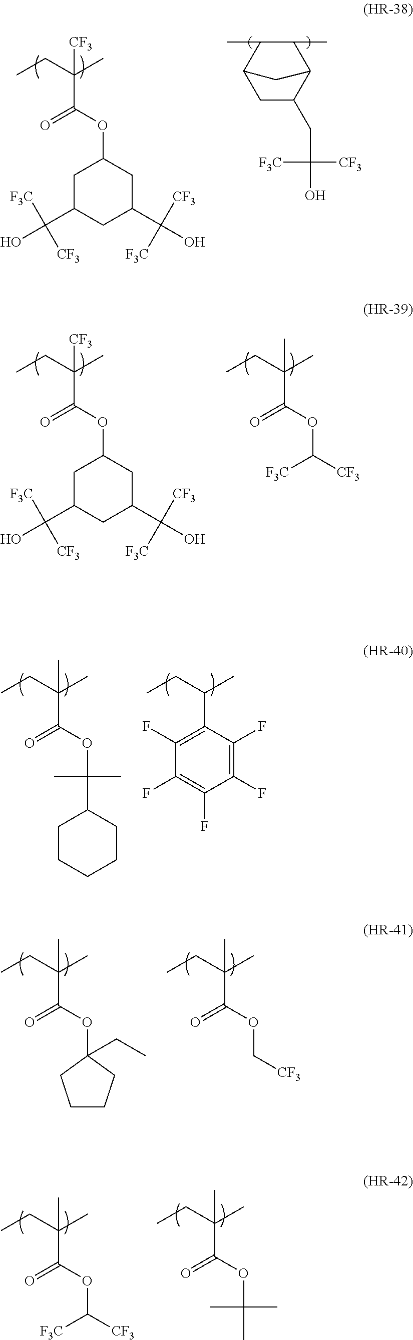

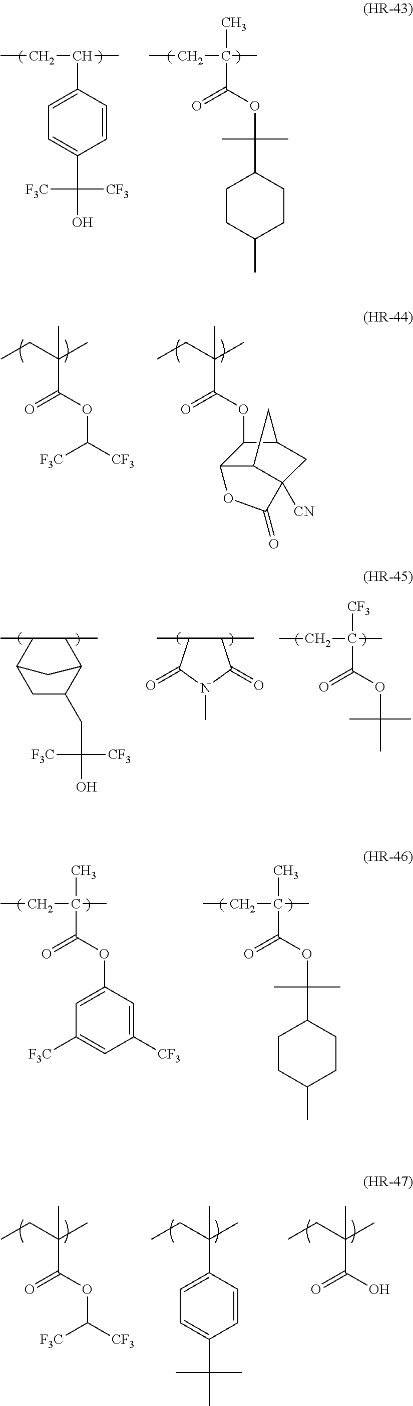

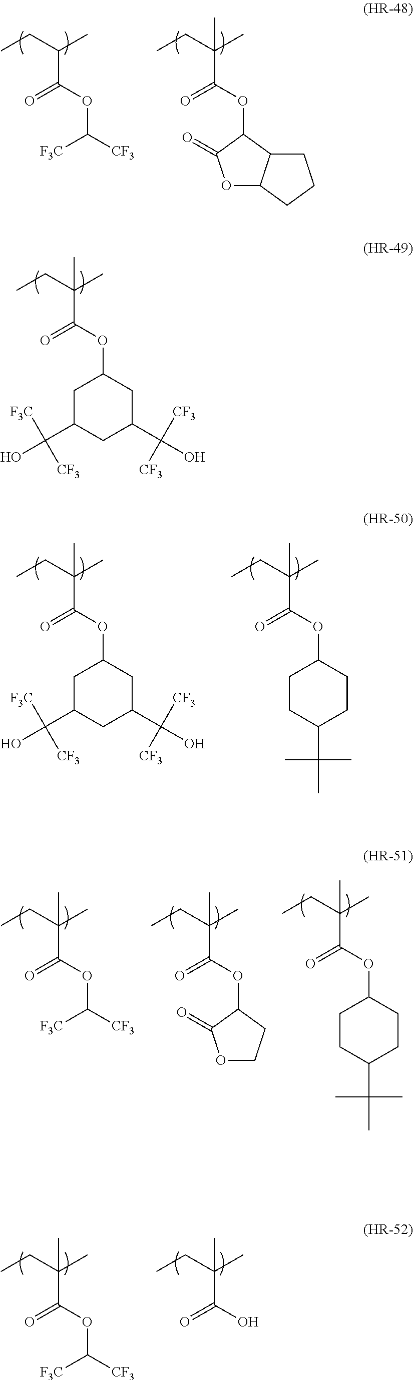

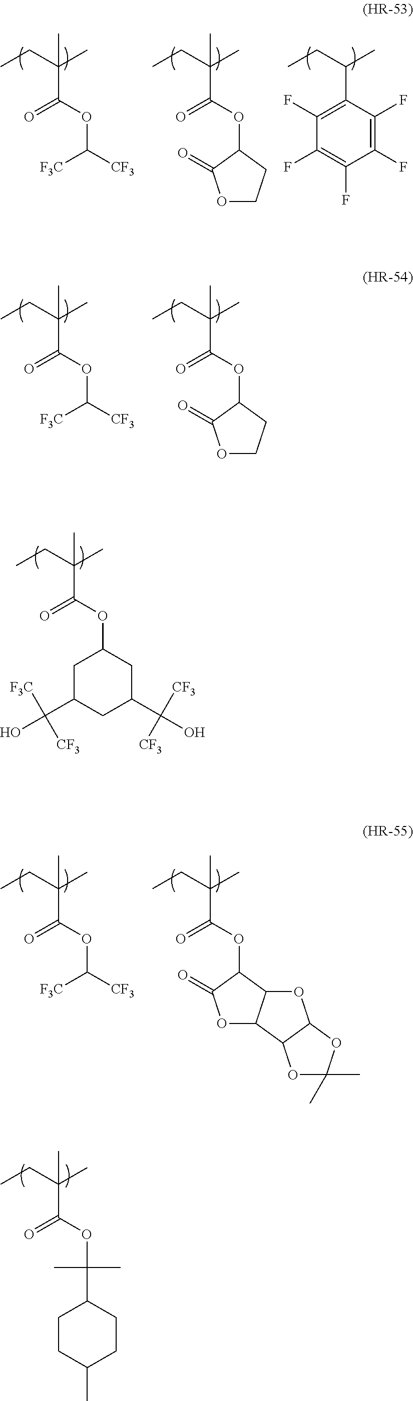

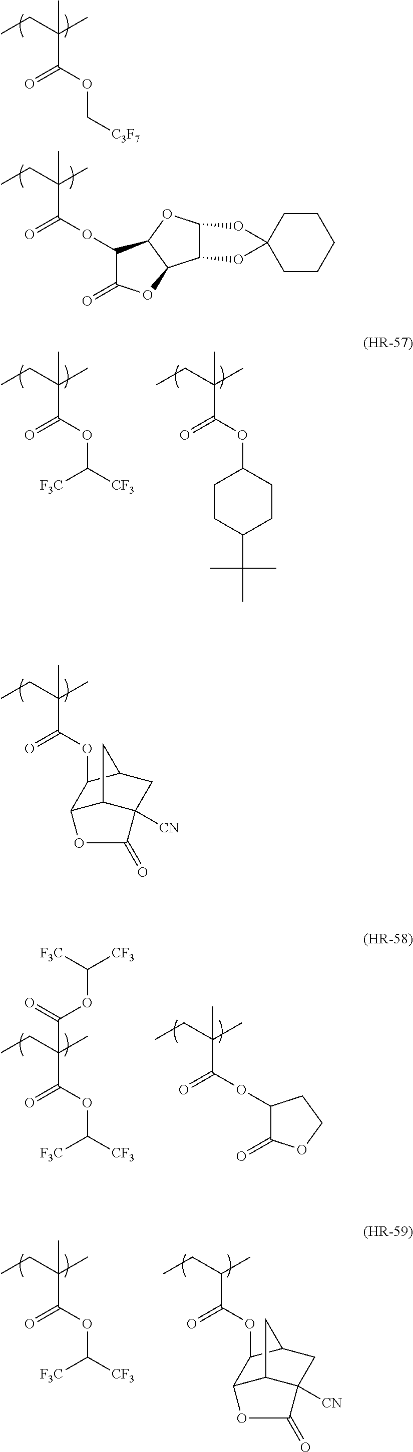

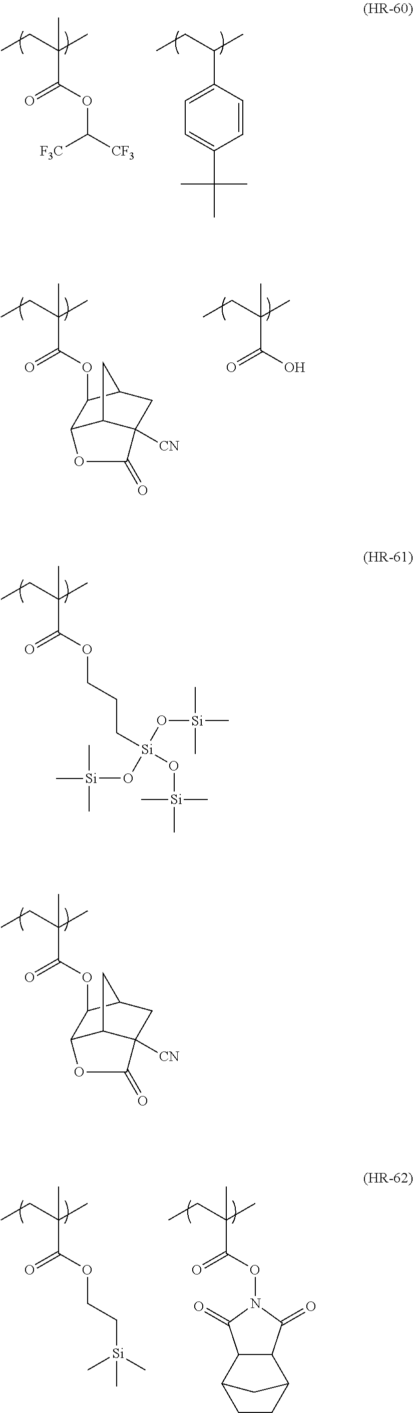

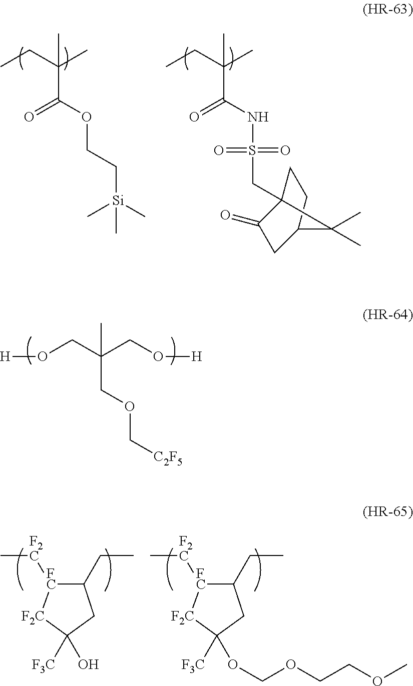

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

It is preferred for the hydrophobic resin to be a resin not only containing a repeating unit containing at least two polarity conversion groups but also containing at least either a fluorine atom or a silicon atom. The number of development defects can further be reduced by use of this resin as the hydrophobic resin. The above fluorine atom may be one contained as an electron withdrawing group in the polarity conversion groups, or another fluorine atom.

The expression “polarity conversion group” used herein means a group that is decomposed by the action of an alkali developer to thereby increase its solubility in the alkali developer. For example, the portion of the formula “—COO—” in general formulae (KA-1) and (KB-1) to be given hereinafter corresponds to the same, provided that the ester group directly bonded to the principal chain of a resin (for example, the ester group of an acrylate) is not included in the category of “polarity conversion groups” because its capability of increasing the solubility by the action of an alkali developer is poor.

The polarity conversion group is decomposed by the action of an alkali developer so as to have its polarity converted. This further decreases the receding contact angle of water as a liquid for liquid immersion on the film after alkali development.

The receding contact angle of water on the film after alkali development is preferably 50° or less, more preferably 40° or less, further more preferably 35° or less and most preferably 30° or less as measured under the conditions of temperature 23±3° C. and humidity 45±5%.

The receding contact angle refers to a contact angle determined when the contact line at a droplet-substrate interface draws back. It is generally known that the receding contact angle is useful in the simulation of droplet mobility in a dynamic condition. In brief, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

When the hydrophobic resin is a resin not only containing a repeating unit containing at least two polarity conversion groups but also containing at least either a fluorine atom or a silicon atom, it is preferred for the resin to contain a repeating unit simultaneously containing on its one side chain at least two polarity conversion groups and at least either a fluorine atom or a silicon atom. Namely, preferably, this hydrophobic resin contains a repeating unit containing at least either a fluorine atom or a silicon atom on its side chain having a plurality of polarity conversion groups.

Alternatively, in such an instance, the hydrophobic resin may contain both a repeating unit containing at least two polarity conversion groups but containing neither a fluorine atom nor a silicon atom and a repeating unit containing at least either a fluorine atom or a silicon atom.

Further alternatively, in such an instance, the hydrophobic resin may contain a repeating unit in which at least two polarity conversion groups are introduced in its one side chain while at least either a fluorine atom or a silicon atom is introduced in its another side chain within the same repeating unit. In this hydrophobic resin, it is preferred for the side chain having polarity conversion groups introduced therein and the side chain having at least either a fluorine atom or a silicon atom introduced therein to have a positional relationship such that the one lies on the α-position to the other via a carbon atom of the principal chain. That is, it is preferred for these side chains to have a positional relationship shown in formula (4) below. In the formula, B1 represents a side chain containing polarity conversion groups, and B2 represents a side chain containing at least either a fluorine atom or a silicon atom.

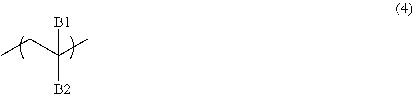

It is preferred for the above side chain containing polarity conversion groups to contain any of the partial structures of general formulae (KA-1) and (KB-1) below. Containing any of the partial structures of general formula (KA-1) below is more preferred.

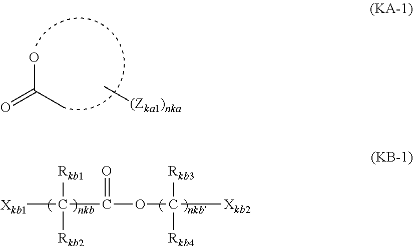

In the general formula (KA-1),

Zₖₐ₁, each independently when nka≧2, represents an alkyl group, a cycloalkyl group, an ether group, a hydroxyl group, an amido group, an aryl group, a lactone ring group or an electron withdrawing group. When nka≧2, the plurality of Zₖₐ₁s may be bonded to each other to thereby form a ring. As this ring, there can be mentioned, for example, a cycloalkyl ring or a hetero-ring, such as a cycloether ring or a lactone ring.

In the formula, nka is an integer of 0 to 10, preferably 0 to 8, more preferably 0 to 5, further more preferably 1 to 4 and most preferably 1 to 3.

Note that each of the structures of the general formula (KA-1) is in the form of a mono- or higher valent substituent resulting from the removal of at least one hydrogen atom contained in the structure.

In the general formula (KB-1), each of X_{kb1} and X_{kb2} independently represents an electron withdrawing group.

Each of nkb and nkb′ independently is 0 or 1.

When nkb=nkb′=0, X_{kb1} and X_{kb2} are directly bonded to the ester group (—COO—).

Each of R_{kb1} to R_{kb4} independently represents a hydrogen atom, an alkyl group, a cycloalkyl group, an aryl group or an electron withdrawing group. At, least two of R_{kb1}, R_{kb2} and X_{kb1} may be bonded to each other to thereby form a ring. Also, at least two of R_{kb3}, R_{kb4} and X_{kb2} may be bonded to each other to thereby form a ring.

As preferred rings formed by the mutual bonding of at least two of R_{kb3}, R_{kb4} and X_{kb2}, there can be mentioned a cycloalkyl group and a hetero-ring group. The hetero-ring group is most preferably a lactone ring group. As the lactone ring, there can be mentioned, for example, any of those of formulae (KA-1-1) to (KA-1-17) to be shown hereinafter.

When both X_{kb1} and X_{kb2} are monovalent substituents, each of the structures of the general formula (KB-1) is in the form of a mono- or higher valent substituent resulting from the removal of at least one hydrogen atom contained in the structure.

In the partial structures of the general formula (KB-1), the electron withdrawing group lies adjacent to the ester group. Therefore, the partial structures can exhibit excellent polarity conversion capability.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be an alkyl ether group or a cycloalkyl ether group.

The alkyl group represented by Zₖₐ₁ may be linear or branched. This alkyl group may further have one or more substituents.

The linear alkyl group preferably has 1 to 30 carbon atoms, more preferably 1 to 20 carbon atoms. As the linear alkyl group, there can be mentioned, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group or an n-decanyl group.

The branched alkyl group preferably has 3 to 30 carbon atoms, more preferably 3 to 20 carbon atoms. As the branched alkyl group, there can be mentioned, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group or a t-decanyl (t-decanoyl) group.

It is preferred for the alkyl group represented by Zₖₐ₁ to be one having 1 to 4 carbon atoms, such as a methyl group, an ethyl group, an n-propyl group, an i-propyl group, an n-butyl group, an i-butyl group or a t-butyl group.

The cycloalkyl group represented by Zₖₐ₁ may be monocyclic or polycyclic. In the latter case, the cycloalkyl group may be a bridged one. Namely, the cycloalkyl group may have a bridged structure. The carbon atoms of the cycloalkyl group may be partially replaced with a hetero-atom, such as an oxygen atom.

The monocycloalkyl group preferably has 3 to 8 carbon atoms. As such, there can be mentioned, for example, a cyclopropyl group, a cyclobutyl group, a cyclopentyl group, a cyclohexyl group or a cyclooctyl group.

As the polycycloalkyl group, there can be mentioned, for example, a group with a bicyclo, tricyclo or tetracyclo structure having 5 or more carbon atoms. This polycycloalkyl group preferably has 6 to 20 carbon atoms. As such, there can be mentioned, for example, an adamantyl group, a norbornyl group, an isobornyl group, a camphonyl group, a bicyclopentyl group, an α-pinel group, a tricyclodecanyl group, a tetracyclododecyl group or an androstanyl group.

As these cycloalkyl groups, there can be mentioned, for example, those of the following formulae.

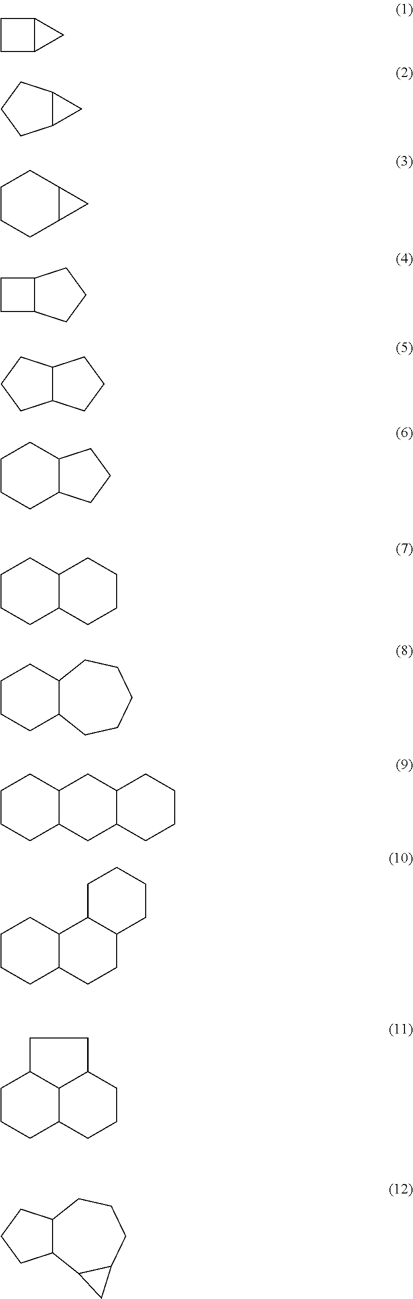

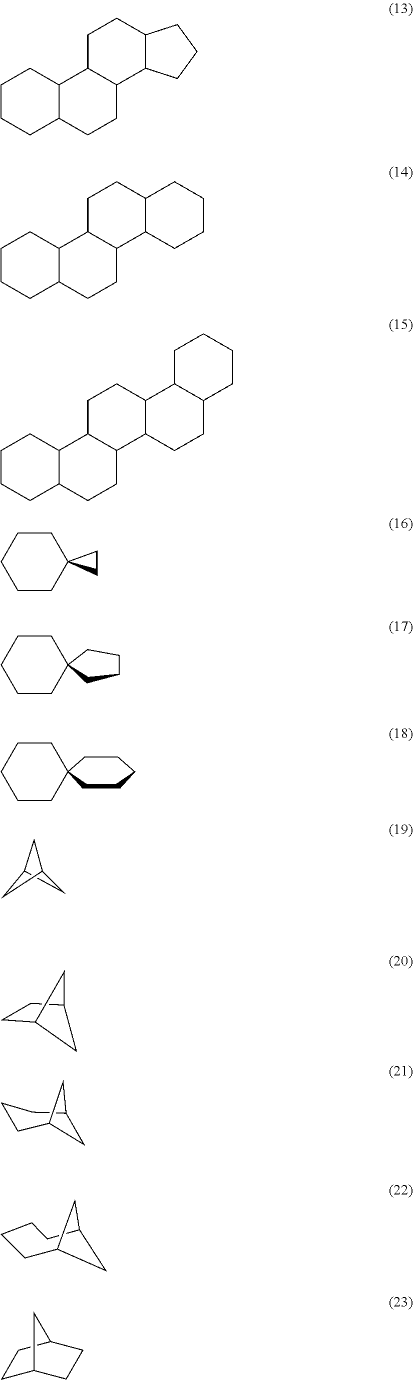

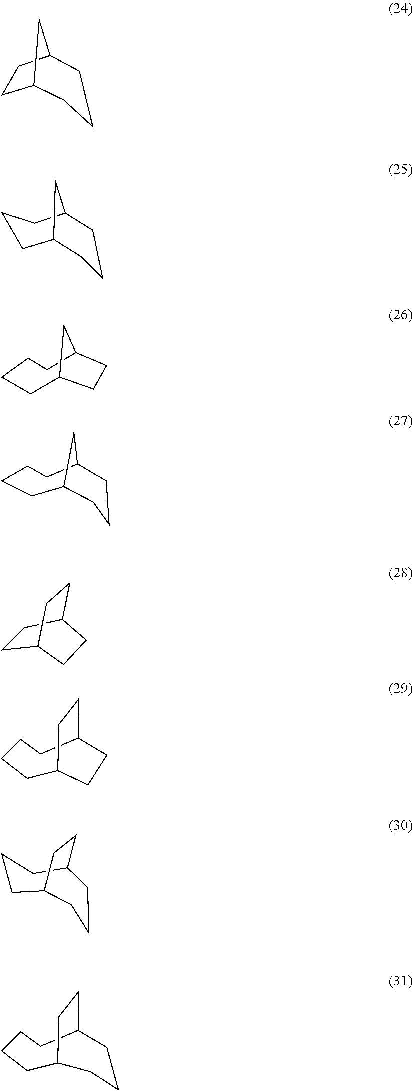

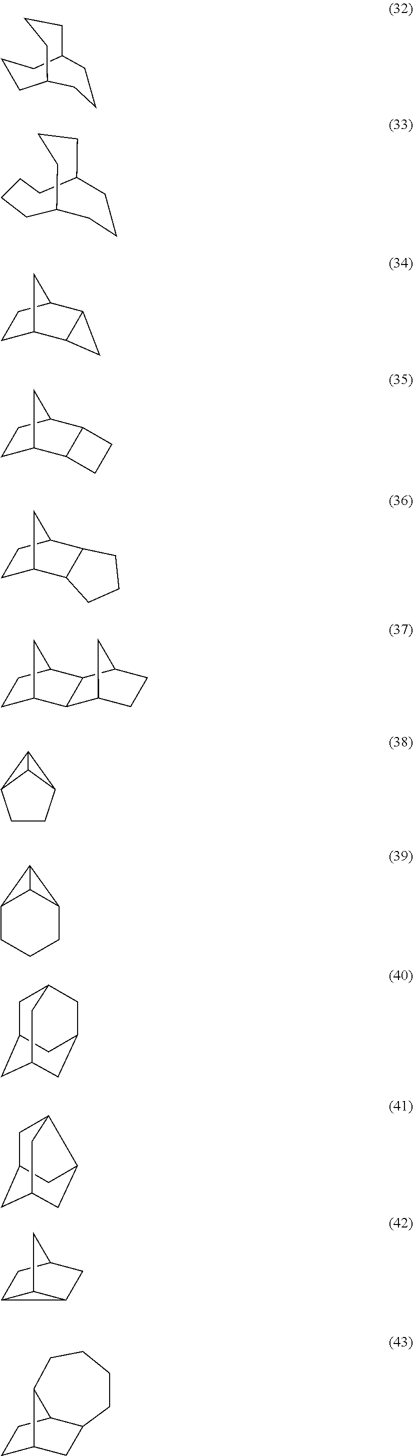

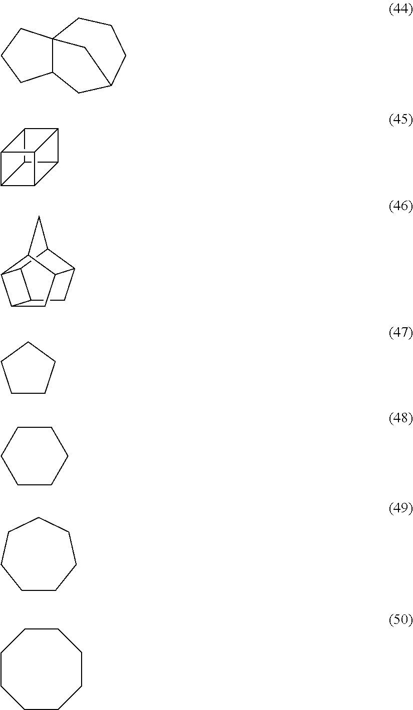

As preferred alicyclic structures among the above, there can be mentioned, for example, an adamantyl group; a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group. As more preferred structures, there can be mentioned an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group.

These alicyclic structures may further have one or more substituents. As such substituents, there can be mentioned, for example, an alkyl group, a halogen atom, a hydroxyl group, an alkoxy group, a carboxyl group and an alkoxycarbonyl group.

The alkyl group as the substituent is preferably a lower alkyl group, such as a methyl group, an ethyl group, a propyl group, an isopropyl group or a butyl group. More preferably, the alkyl group is a methyl group, an ethyl group, a propyl group or an isopropyl group.

As preferred alkoxy groups as the substituent, there can be mentioned those each having 1 to 4 carbon atoms, such as a methoxy group, an ethoxy group, a propoxy group and a butoxy group.

These alkyl groups and alkoxy groups as the substituents may further have one or more substituents. As such further substituents, there can be mentioned, for example, a hydroxyl group, a halogen atom and an alkoxy group (preferably having 1 to 4 carbon atoms).

As the aryl group represented by Zₖₐ₁, there can be mentioned, for example, a phenyl group or a naphthyl group.

As substituents that can be further introduced in the alkyl group, cycloalkyl group and aryl group represented by Zₖₐ₁, there can be mentioned, for example, a hydroxyl group; a halogen atom; a nitro group; a cyano group; the above alkyl groups; an alkoxy group, such as a methoxy group, an ethoxy group, a hydroxyethoxy group, a propoxy group, a hydroxypropoxy group, an n-butoxy group, an isobutoxy group, a sec-butoxy group or a t-butoxy group; an alkoxycarbonyl group, such as a methoxycarbonyl group or an ethoxycarbonyl group; an aralkyl group, such as a benzyl group, a phenethyl group or a cumyl group; an aralkyloxy group; an acyl group, such as a formyl group, an acetyl group, a butyryl group, a benzoyl group, a cyanamyl group or a valeryl group; an acyloxy group, such as a butyryloxy group; an alkenyl group; an alkenyloxy group, such as a vinyloxy group, a propenyloxy group, an allyloxy group or a butenyloxy group; the above aryl groups; an aryloxy group, such as a phenoxy group; and an aryloxycarbonyl group, such as a benzoyloxy group.

As the electron withdrawing groups represented by Zₖₐ₁, X_{kb1} and X_{kb2}, there can be mentioned, for example, a halogen atom, a cyano group, an oxy group, a carbonyl group, a carbonyloxy group, an oxycarbonyl group, a nitrile group, a nitro group, a sulfonyl group, a sulfinyl group, the halo(cyclo)alkyl groups of the formula —C(Rf1)(Rf2)-Rf3, an haloaryl group and combinations thereof. The expression “halo(cyclo)alkyl groups” means (cyclo)alkyl groups each having its at least one hydrogen atom substituted with a halogen atom.

As the halogen atom represented by Zₖₐ₁, there can be mentioned a fluorine atom, a chlorine atom, a bromine atom or an iodine atom. Among these, a fluorine atom is most preferred.

In the halo(cyclo)alkyl groups of the formula —C(Rf1)(Rf2)-Rf3, Rf1 represents a halogen atom, a perhaloalkyl group, a perhalocycloalkyl group or a perhaloaryl group. This Rf1 is preferably a fluorine atom, a perfluoroalkyl group or a perfluorocycloalkyl group, more preferably a fluorine atom or a trifluoromethyl group.

In the halo(cyclo)alkyl groups of the formula —C(Rf1)(Rf2)-Rf3, each of Rf2 and Rf3 independently represents a hydrogen atom, a halogen atom or an organic group. As the organic group, there can be mentioned, for example, an alkyl group, a cycloalkyl group or an alkoxy group. These groups may further have one or more substituents, such as a halogen atom.

At least two of Rf1 to Rf3 may be bonded to each other to thereby form a ring. As the ring, there can be mentioned, for example, a cycloalkyl ring, a halocycloalkyl ring, an aryl ring or a haloaryl ring.

As the alkyl and haloalkyl groups represented by Rf1 to Rf3, there can be mentioned, for example, the alkyl groups and alkyl groups having the hydrogen atoms thereof at least partially substituted with halogen atoms as mentioned above with respect to Zₖₐ₁.

As the above halocycloalkyl group and haloaryl group, there can be mentioned, for example, the cycloalkyl groups and aryl groups having the hydrogen atoms thereof at least partially substituted with halogen atoms as mentioned above with respect to Zₖₐ₁. The halocycloalkyl group and haloaryl group are preferably any of the fluoroalkyl groups of the formula —C(n)F(2n−2)H and any of the perfluoroaryl groups of the formula —C(n)F(2n−1). The range of the number of carbon atoms, n, is not particularly limited. However, n=5 to 13 is preferred, and n=6 is most preferred.

It is more preferred for Rf2 to be the same group as represented by Rf1, or to be bonded to Rf3 to thereby form a ring.

Each of these electron withdrawing groups is most preferably a halogen atom, a halo(cyclo)alkyl group or a haloaryl group. In these electron withdrawing groups, the fluorine atoms thereof may be partially substituted with electron withdrawing groups other than a fluorine atom.

When use is made of a bi-valent or higher valent electron withdrawing group, the remaining bonding hands are used in the bonding to arbitrary atoms or substituents. If so, the above partial structures may be bonded via the further substituents to the principal chain of the hydrophobic resin.

The partial structures of the general formula (KA-1) are lactone structures. Each of these lactone structures is preferably a 5 to 7-membered ring structure, more preferably one in which a 5 to 7-membered ring lactone structure is condensed with another cyclic structure in a fashion to form a bicyclo structure or spiro structure.

As lactone structures in the general formula (KA-1), those represented by any of general formulae (KA-1-1) to (KA-1-17) below can be exemplified. Of these, more preferred are those of formulae (KA-1-1), (KA-1-4), (KA-1-5), (KA-1-6), (KA-1-13), (KA-1-14) or (KA-1-17).

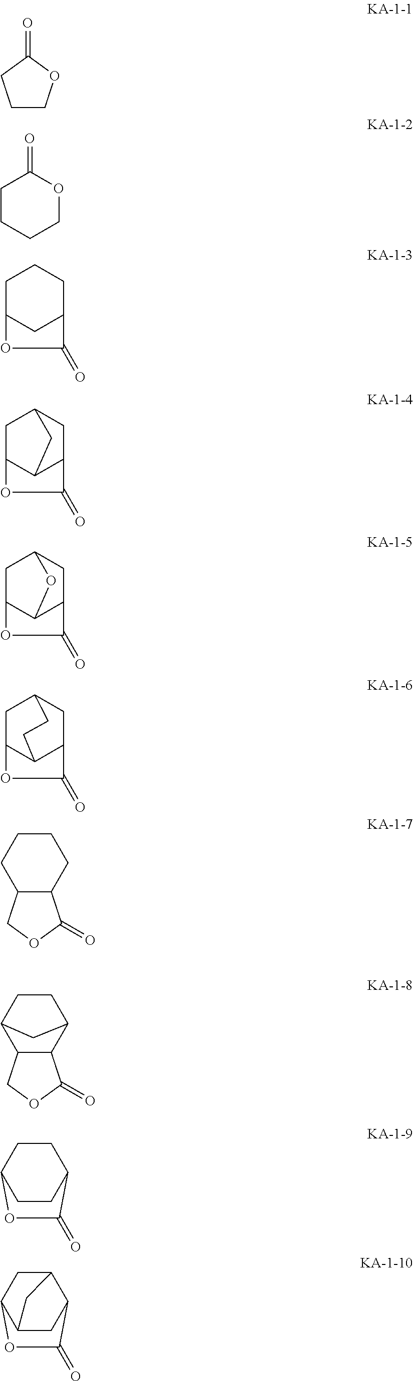

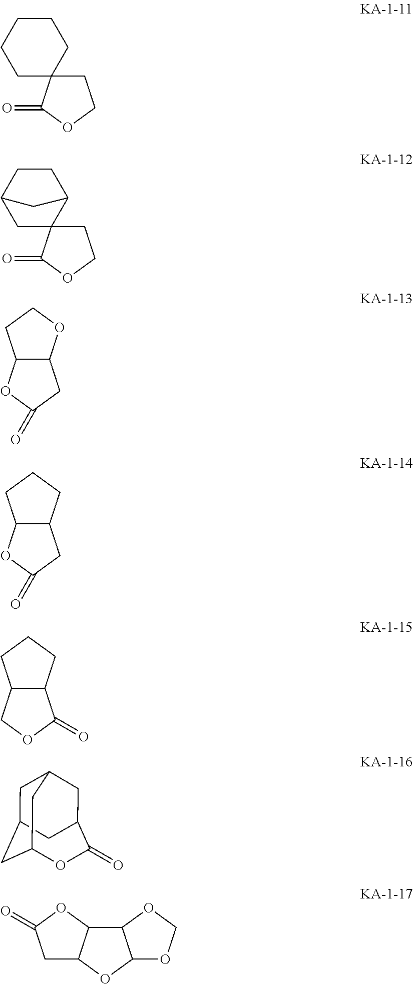

The lactone structure may contain one or more substituents. As a preferred substituent, an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxy group, a cyano group, and an acid-decomposable group can be exemplified. Of these, more preferred are an alkyl group having 1 to 4 carbon atoms, a cycloalkyl group having 5 to 6 carbon atoms, a cyano group, an alkoxycarbonyl group having 1 to 4 carbon atoms, a carboxyl group, a halogen atom, a hydroxy group, and an acid-decomposable group. When the plurality of substituents exist, they may be identical or different from each other, or may form a ring through a mutual bonding.

The lactone structure is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity thereof is preferably 90% ee or higher, more preferably 95% ee or higher, and further more preferably 98% ee or higher.

More preferably, the hydrophobic resin contains any of the structures of general formula (KY-1) below as the partial structure having two polarity conversion groups. Each of the structures of the general formula (KY-1) is in the form of a mono- or higher valent substituent resulting from the removal of at least one of the hydrogen atoms contained in the structure.

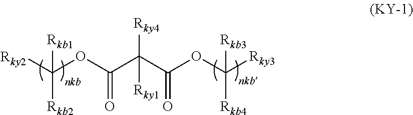

In the general formula (KY-1), each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. Alternatively, both R_{ky1} and R_{ky4} may be bonded to the same atom to thereby form a double bond. For example, both R_{ky1} and R_{ky4} may be bonded to the same oxygen atom to thereby form a part (═O) of a carbonyl group.

Each of R_{ky2} and R_{ky3} independently represents an electron withdrawing group. Alternatively, optionally, R_{ky1} and R_{ky2} are bonded to each other to thereby form a lactone structure, and R_{ky3} is an electron withdrawing group.

The lactone structure is preferably any of the above-mentioned structures (KA-1-1) to (KA-1-17). As the electron withdrawing group, there can be mentioned any of the same groups as mentioned above with respect to X_{kb1} of the general formula (KB-1). This electron withdrawing group is preferably a halogen atom, any of the halo(cyclo)alkyl groups of the formula —C(Rf1)(Rf2)-Rf3 or an haloaryl group.

At least two of R_{ky1}, R_{ky2} and R_{ky4} may be bonded to each other to thereby form a monocyclic or polycyclic structure. R_{kb1} to R_{kb4}, nkb and nkb′ are as defined above in connection with the formula (KB-1). As R_{ky1} and R_{ky4}, there can be mentioned, for example, the same groups as set forth above with respect to Zₖₐ₁ of the general formula (KA-1).

It is more preferred for the partial structures of the general formula (KY-1) to be the structures of general formula (KY-2) below. Each of the structures of the general formula (KY-2) is in the form of a mono- or higher valent substituent resulting from the removal of at least one of the hydrogen atoms contained in the structure.

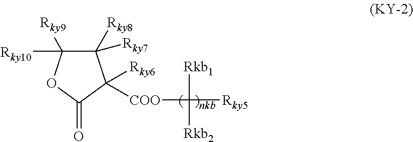

In the formula (KY-2), each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. At least two of R_{ky6} to R_{ky10} may be bonded to each other to thereby form a ring.

R_{ky5} represents an electron withdrawing group. As the electron withdrawing group, there can be mentioned any of the same groups as set forth above with respect to X_{kb1} of the general formula (KB-1). This electron withdrawing group is preferably a halogen atom, any of the halo(cyclo)alkyl groups of the formula —C(Rf1)(Rf2)-Rf3 or an haloaryl group.

R_{kb1}, R_{kb2} and nkb are as defined above in connection with the general formula (KB-1). As R_{ky5} to R^{ky10}, there can be mentioned, for example, the same groups as set forth above with respect to Zₖₐ₁ of the general formula (KA-1).

It is more preferred for the structures of the general formula (KY-2) to be the structures of general formula (KY-3) below.

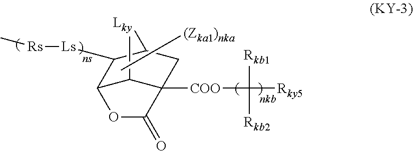

Zₖₐ₁ and nka appearing in the formula (KY-3) are as defined above in connection with the general formula (KA-1). R_{ky5} is as defined above in connection with the general formula (KY-2). R_{kb1}, R_{kb2} and nkb are as defined above in connection with the general formula (KB-1).

L_{ky} represents an alkylene group, an oxygen atom or a sulfur atom. As the alkylene group represented by L_{ky}, there can be mentioned, for example, a methylene group or an ethylene group. L_{ky} is preferably an oxygen atom or a methylene group, more preferably a methylene group.

Rs, each independently when ns≧2, represents an alkylene group or a cycloalkylene group. When ns≧2, the plurality of Rs's may be identical to or different from each other.

Ls, each independently when ns≧2, represents a single bond, an ether bond, an ester bond, an amido bond, a urethane bond or a urea, bond. When ns≧2, the plurality of Ls's may be identical to or different from each other.

In the formula, ns represents the number of repetitions of each of the connecting groups of the formula -(Rs-Ls)-, being an integer of 0 to 5.

It is also preferred for the hydrophobic resin to contain any of the repeating units of general formula (K0) below.

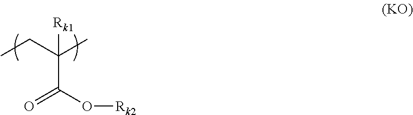

In the formula (KO), Rₖ₁ represents a hydrogen atom, a halogen atom, a hydroxyl group, an alkyl group, a cycloalkyl group, an aryl group or a polarity conversion group. Rₖ₂ represents an alkyl group, a cycloalkyl group, an aryl group or a polarity conversion group, provided that the sum of the number of polarity conversion groups contained in Rₖ₁ and the number of polarity conversion groups contained in Rₖ₂ is 2 or greater.

As generally mentioned above, the ester group directly bonded to the principal chain of the repeating units of the general formula (KO) is not included in the category of “polarity conversion groups.”

The repeating units contained in the hydrophobic resin are not limited as long as they are derived by polymerization, such as addition polymerization, condensation polymerization or addition condensation. Preferred repeating units are those obtained by the addition polymerization of a carbon to carbon double bond.

As such repeating units, there can be mentioned, for example, acrylate repeating units (including the family having a substituent at the α- and/or β-position), styrene repeating units (including the family having a substituent at the α- and/or β-position), vinyl ether repeating units, norbornene repeating units and repeating units of maleic acid derivatives (maleic anhydride, its derivatives, maleimide, etc.). Of these, acrylate repeating units, styrene repeating units, vinyl ether repeating units and norbornene repeating units are preferred. Acrylate repeating units, vinyl ether repeating units and norbornene repeating units are more preferred. Acrylate repeating units are most preferred.

Specific examples of the repeating units containing at least two polarity conversion groups will be shown below. In the specific examples, Ra represents a hydrogen atom, a fluorine atom, a methyl group or a trifluoromethyl group.

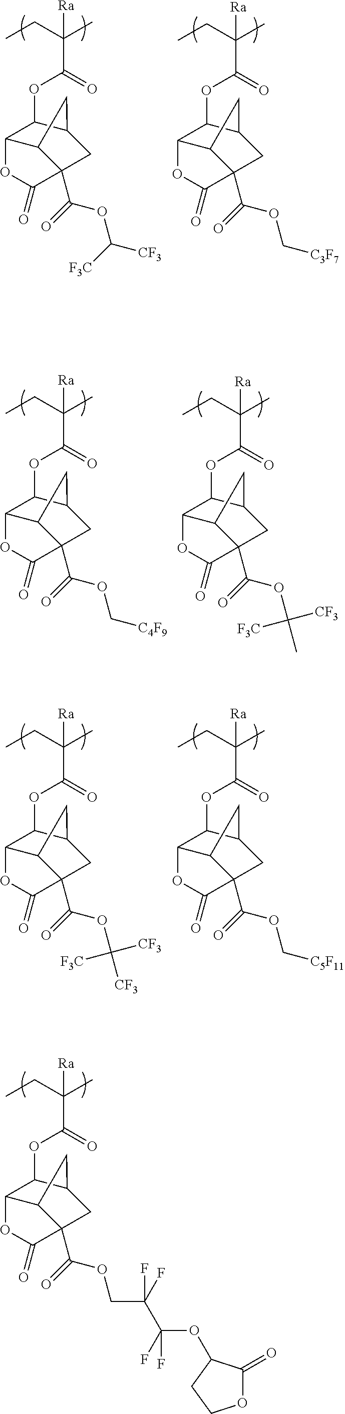

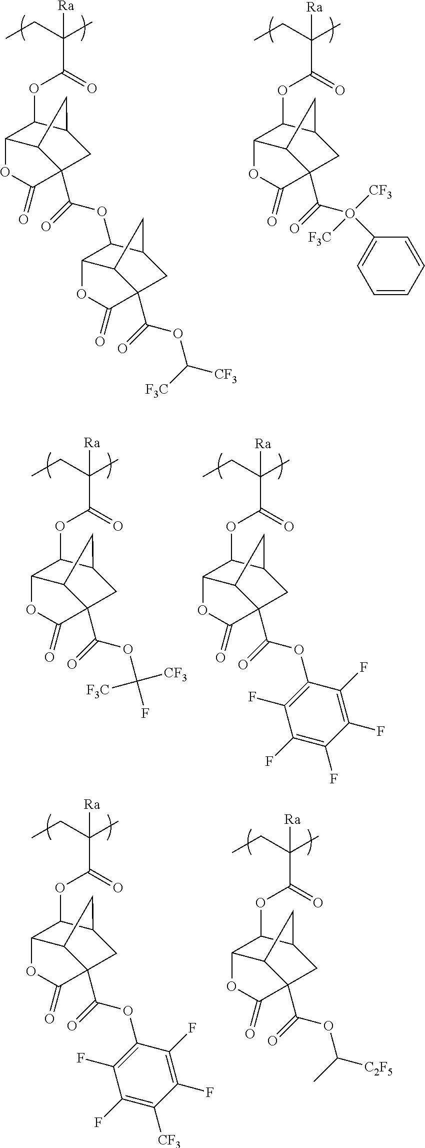

The resin containing any of the repeating units containing at least two polarity conversion groups may further contain other repeating units. As the other repeating units, there can be mentioned, for example, those set forth above as the repeating units that can be contained in the hydrophobic resin.

The content of repeating units containing at least two polarity conversion groups based on all the repeating units of the hydrophobic resin is preferably in the range of 10 to 100 mol %, more preferably 20 to 100 mol %, further more preferably 30 to 100 mol % and most preferably 40 to 100 mol %.

When the hydrophobic resin contains a repeating unit simultaneously containing at least two polarity conversion groups and at least either a fluorine atom or a silicon atom on its one side chain, the content of such a repeating unit based on all the repeating units of the hydrophobic resin is preferably in the range of 10 to 100 mol %, more preferably 20 to 100 mol %, further more preferably 30 to 100 mol % and most preferably 40 to 100 mol %.

When the hydrophobic resin contains both a repeating unit containing at least two polarity conversion groups but neither a fluorine atom nor a silicon atom and a repeating unit containing at least either a fluorine atom or a silicon atom, the preferred contents of such repeating units are as follows. That is, the content of the former repeating unit based on all the repeating units of the hydrophobic resin is preferably in the range of 10 to 90 mol %, more preferably 15 to 85 mol %, further more preferably 20 to 80 mol % and most preferably 25 to 75 mol %. The content of the latter repeating unit based on all the repeating units of the hydrophobic resin is preferably in the range of 10 to 90 mol %, more preferably 15 to 85 mol %, further more preferably 20 to 80 mol % and most preferably 25 to 75 mol %.

When the hydrophobic resin contains a repeating unit containing at least two polarity conversion groups on its one side chain and containing at least either a fluorine atom or a silicon atom on another side chain lying in the same repeating unit, the content of such a repeating unit is preferably in the range of 10 to 100 mol %, more preferably 20 to 100 mol %, further more preferably 30 to 100 mol % and most preferably 40 to 100 mol %.

Specific examples of the resins not only containing a repeating unit containing at least two polarity conversion groups but also containing at least either a fluorine atom or a silicon atom will be shown below. The following Table 2 shows the molar ratio of individual repeating units (corresponding to individual repeating units in order from the left), weight average molecular weight, and degree of dispersal with respect to each of the resins.

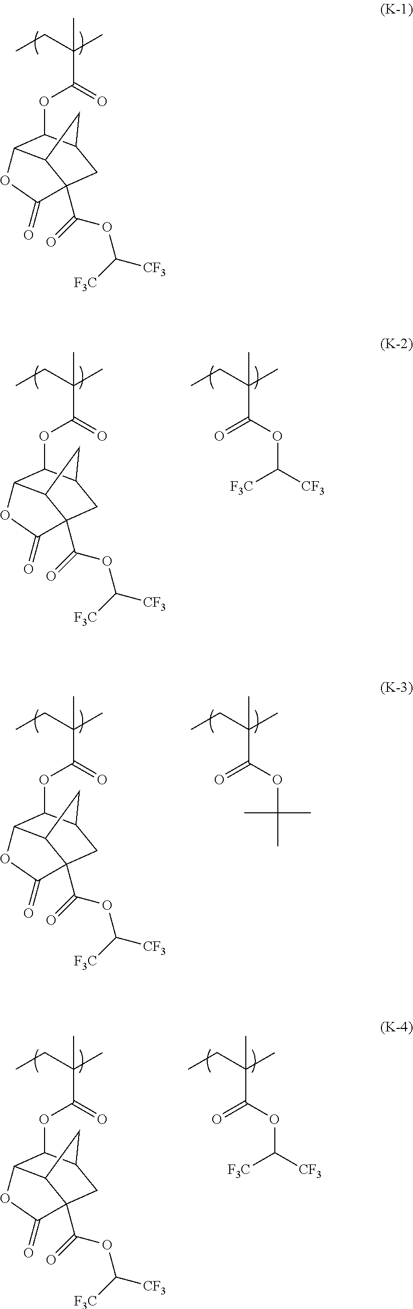

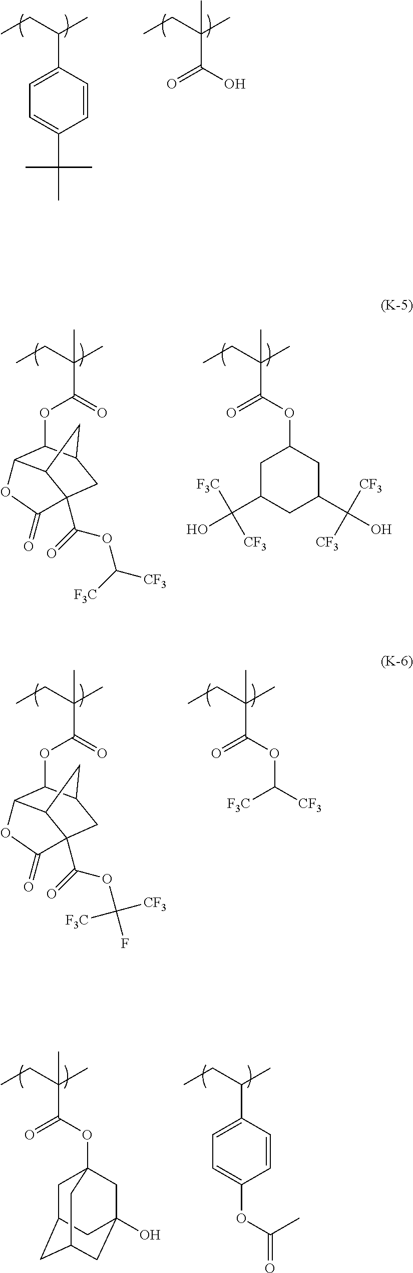

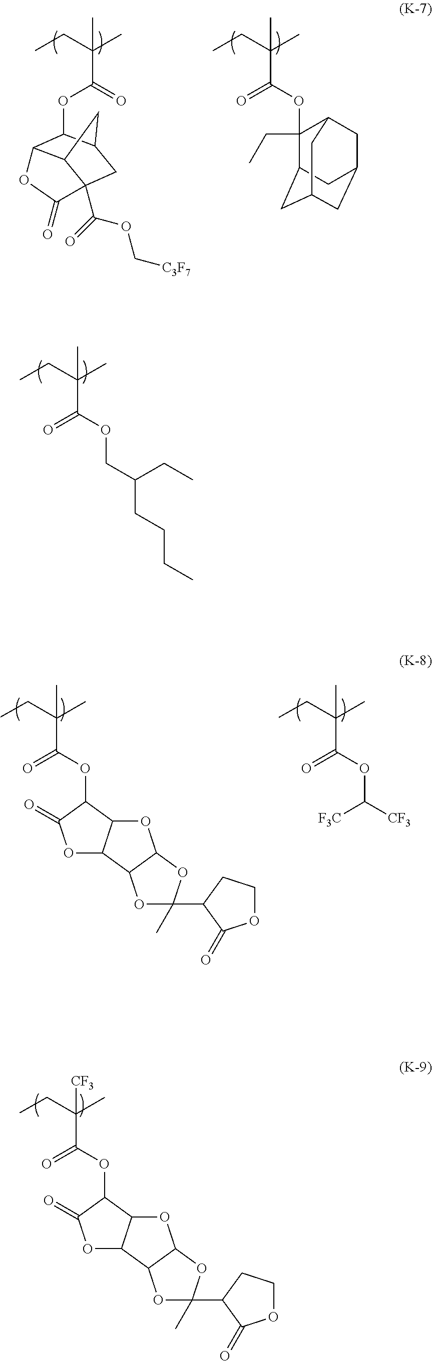

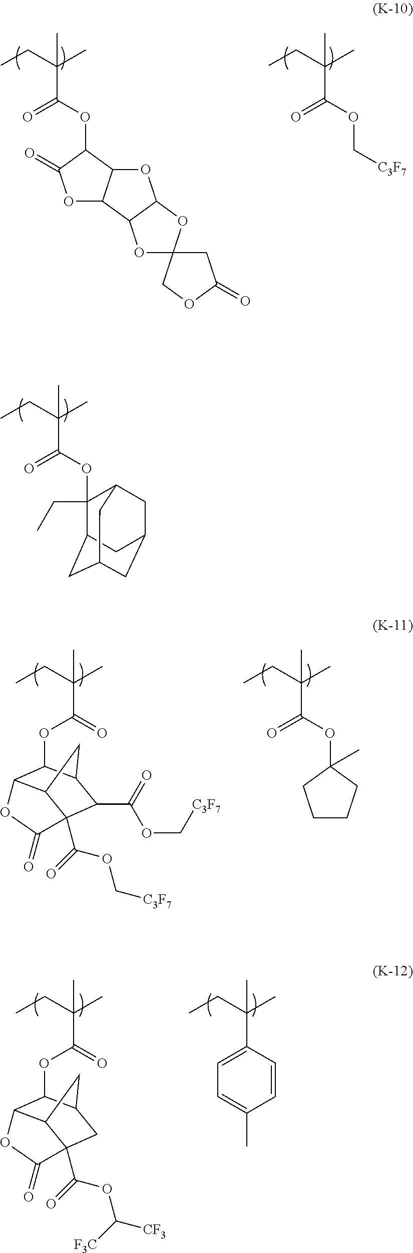

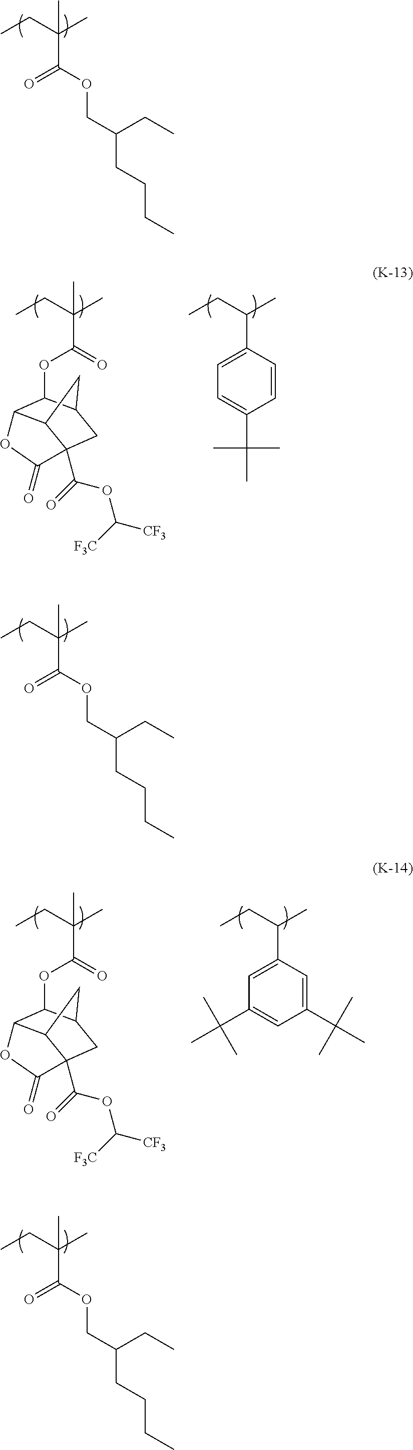

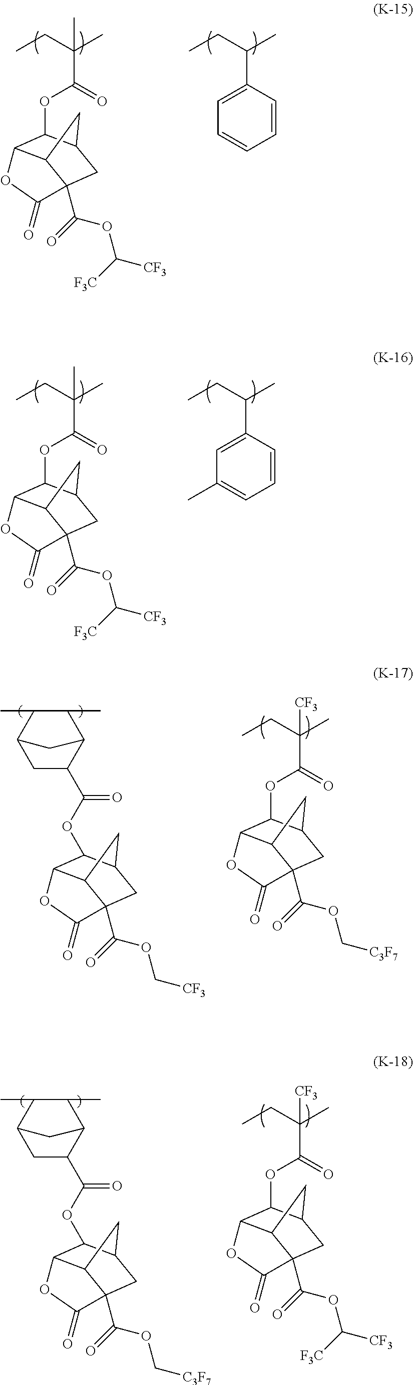

TABLE 2

| Resin | Composition | Mw | Mw/Mn |
|---|---|---|---|
| K-1 | 100 | 6000 | 1.5 |
| K-2 | 50/50 | 6500 | 1.4 |
| K-3 | 60/40 | 8000 | 1.3 |
| K-4 | 30/30/30/10 | 9500 | 1.4 |
| K-5 | 80/20 | 6000 | 1.4 |
| K-6 | 40/40/10/10 | 6000 | 1.4 |
| K-7 | 80/10/10 | 8500 | 1.5 |
| K-8 | 50/50 | 6000 | 1.5 |
| K-9 | 25/50/25 | 6000 | 1.5 |
| K-10 | 100 | 3500 | 1.4 |
| K-11 | 70/30 | 10000 | 1.5 |
| K-12 | 85/10/5 | 5000 | 1.5 |
| K-13 | 90/8/2 | 13000 | 1.5 |
| K-14 | 90/8/2 | 8000 | 1.4 |
| K-15 | 85/15 | 6500 | 1.5 |
| K-16 | 90/10 | 3500 | 1.5 |
| K-17 | 50/50 | 6000 | 1.5 |
| K-18 | 50/50 | 4000 | 1.5 |

The hydrophobic resin may further contain any of the above-mentioned repeating units (A). If so, the content of repeating unit (A) based on all the repeating units of the hydrophobic resin is preferably in the range of 5 to 50 mol %, more preferably 10 to 30 mol %.

When the hydrophobic resin contains fluorine atoms, the content of the fluorine atoms based on the molecular weight of the hydrophobic resin is preferably in the range of 5 to 80 mass %, and more preferably 10 to 80 mass %. The repeating unit containing fluorine atoms preferably exists in the hydrophobic resin in an amount of 10 to 100 mass %, more preferably 30 to 100 mass %.

When the hydrophobic resin contains silicon atoms, the content of the silicon atoms based on the molecular weight of the hydrophobic resin is preferably in the range of 2 to 50 mass %, more preferably 2 to 30 mass %. The repeating unit containing silicon atoms preferably exists in the hydrophobic resin in an amount of 10 to 100 mass %, more preferably 20 to 100 mass %.

The weight average molecular weight of the hydrophobic resin in terms of standard polystyrene molecular weight is preferably in the range of 1,000 to 100,000, more preferably 1,000 to 50,000, and still more preferably 2,000 to 15,000.

The dispersity of the hydrophobic resin is preferably in the range of 1 to 5, more preferably 1 to 3 and further more preferably 1 to 2. If so, excellent resolution, pattern configuration and roughness performance can be attained.

The hydrophobic resin may be used either individually or in combination.

The content of the hydrophobic resin in the composition based on the total solids thereof is preferably in the range of 0.01 to 10 mass %, more preferably 0.05 to 8 mass %, and most preferably 0.1 to 5 mass %.

The rate of hydrolysis of the hydrophobic resin in alkali developers is preferably 0.001 nm/sec or higher, more preferably 0.01 nm/sec or higher, further more preferably 0.1 nm/sec or higher and most preferably 1 nm/sec or higher. The rate of hydrolysis of the hydrophobic resin in alkali developers refers to the rate of reduction of the thickness of a film, the film produced from the hydrophobic resin only, exhibited in a 2.38 mass % aqueous solution of TMAH (tetramethylammonium hydroxide) at 23° C.

Both commercially available resins and resins synthesized by routine procedure can be used as the hydrophobic resin. The generally employed methods for synthesizing the hydrophobic resin are, for example, the same as described above with respect to the acid-decomposable resins.

Impurities, such as metals, should naturally be of minute quantity in the hydrophobic resin. Further, the content of residual monomers and oligomer components is preferably in the range of 0 to 10 mass %, more preferably 0 to 5 mass % and further more preferably 0 to 1 mass %. Accordingly, the amount of in-liquid foreign matter can be decreased, and any change of, sensitivity, etc., over time can be reduced.

(Solvent)

The composition according to the present invention may further contain solvent.

As the solvent, an organic solvent such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate and an alkyl pyruvate can be exemplified.

As alkylene glycol monoalkyl ether carboxylates, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate can be exemplified.

As alkylene glycol monoalkyl ethers, propylene glycol monomethyl ether, propylene glycol monoethyl ether, propylene glycol monopropyl ether, propylene glycol monobutyl ether, ethylene glycol monomethyl ether, and ethylene glycol monoethyl ether can be exemplified.

As alkyl lactates, methyl lactate, ethyl lactate, propyl lactate and butyl lactate can be exemplified.

As alkyl alkoxypropionates, ethyl 3-ethoxypropionate, methyl 3-methoxypropionate, methyl 3-ethoxypropionate, and ethyl 3-methoxypropionate can be exemplified.

As cyclolactones, β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone can be exemplified.

As optionally cyclized monoketone compounds, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone can be exemplified.

As alkylene carbonates, propylene carbonate, vinylene carbonate, ethylene carbonate, and butylene carbonate can be exemplified.

As alkyl alkoxyacetates, acetic acid 2-methoxyethyl ester, acetic acid 2-ethoxyethyl ester, acetic acid 2-(2-ethoxyethoxy)ethyl ester, acetic acid 3-methoxy-3-methylbutyl ester, and acetic acid 1-methoxy-2-propyl ester can be exemplified.

As alkyl pyruvates, methyl pyruvate, ethyl pyruvate and propyl pyruvate can be exemplified.

As a preferably employable solvent, a solvent having a boiling point measured at ordinary temperature under ordinary pressure of 130° C. or above can be mentioned. As the solvent, cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxy)ethyl ester, and propylene carbonate can be exemplified.

These solvents may be used either individually or in combination. When in the latter case, a mixed solvent consisting of a mixture of a solvent having a hydroxy group in its structure and a solvent having no hydroxy group may be used as the organic solvent.

As the solvent having a hydroxy group, ethylene glycol, ethylene glycol monomethyl ether, ethylene glycol monoethyl ether, propylene glycol, propylene glycol monomethyl ether, propylene glycol monoethyl ether, and ethyl lactate can be exemplified. Of these, propylene glycol monomethyl ether, and ethyl lactate are especially preferred.

As the solvent having no hydroxy group, propylene glycol monomethyl ether acetate, ethyl ethoxypropionate, 2-heptanone, γ-butyrolactone, cyclohexanone, butyl acetate, N-methylpyrrolidone, N,N-dimethylacetamide, and dimethyl sulfoxide can be exemplified. Of these, propylene glycol monomethyl ether acetate, ethyl ethoxypropionate, 2-heptanone, y-butyrolactone, cyclohexanone, and butyl acetate are especially preferred. Among them, propylene glycol monomethyl ether acetate, ethyl ethoxypropionate and 2-heptanone are most preferred.

When employing a mixed solvent consisting of a mixture of a solvent having a hydroxy group in its structure and a solvent having no hydroxy group, the mass ratio between them is preferably in the range of 1/99 to 99/1, more preferably 10/90 to 90/10, and further more preferably 20/80 to 60/40.

The mixed solvent containing 50 mass % or more of a solvent having no hydroxy group is especially preferred from the viewpoint of uniform applicability.

It is preferred for the solvent to be a mixed solvent consisting of two or more solvents and to contain propylene glycol monomethyl ether acetate.

(Basic Compound)

The composition according to the present invention may further contain one or more basic compounds. As preferred basic compounds, the compounds having the structures represented by the following formulae (A) to (E) can be exemplified.

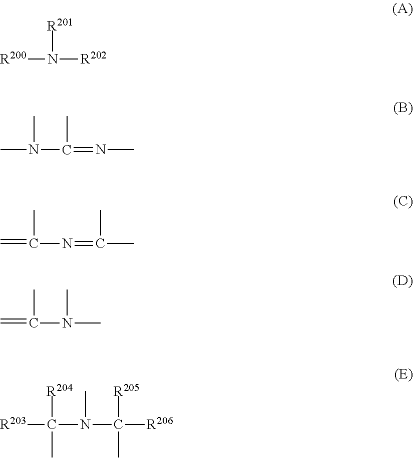

In the general formulae (A) and (E),

R²⁰⁰, R²⁰¹ and R²⁰² each independently represents a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded to each other to form a ring.

R²⁰³, R²⁰⁴, R²⁰⁵ and R²⁰⁶ each independently represents an alkyl group having 1 to 20 carbon atoms.

With respect to the above alkyl group, as a preferred substituted alkyl group, an aminoalkyl group having 1 to 20 carbon atoms, a hydroxyalkyl group having 1 to 20 carbon atoms, and a cyanoalkyl group having 1 to 20 carbon atoms can be exemplified. More preferably, the alkyl groups are unsubstituted.

As preferred compounds, guanidine, aminopyrrolidine, pyrazole, pyrazoline, piperazine, aminomorpholine, aminoalkylmorpholine and piperidine can be exemplified. As more preferred compounds, those with an imidazole structure, a diazabicyclo structure, an onium hydroxide structure, an onium carboxylate structure, a trialkylamine structure, an aniline structure or a pyridine structure, alkylamine derivatives having a hydroxy group and/or an ether bond, and aniline derivatives having a hydroxy group and/or an ether bond can be exemplified.

As the compounds with an imidazole structure, imidazole, 2,4,5-triphenylimidazole, benzimidazole, and 2-phenylbenzoimidazole can be exemplified.

As the compounds with a diazabicyclo structure, 1,4-diazabicyclo[2,2,2]octane, 1,5-diazabicyclo[4,3,0]non-5-ene, and 1,8-diazabicyclo[5,4,0]undec-7-ene can be exemplified.

As the compounds with an onium hydroxide structure, tetrabutylammonium hydroxide, triarylsulfonium hydroxide, phenacylsulfonium hydroxide, and sulfonium hydroxides having a 2-oxoalkyl group, such as triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide can be exemplified.

As the compounds with an onium carboxylate structure, those having a carboxylate at the anion moiety of the compounds with an onium hydroxide structure, such as acetate, adamantane-1-carboxylate, and perfluoroalkyl carboxylate can be exemplified.

As the compounds with a trialkylamine structure, tri(n-butyl)amine and tri(n-octyl)amine can be exemplified.

As the aniline compounds, 2,6-diisopropylaniline, N,N-dimethylaniline, N,N-dibutylaniline, and N,N-dihexylaniline can be exemplified.

As the alkylamine derivatives having a hydroxy group and/or an ether bond, ethanolamine, diethanolamine, triethanolamine, N-phenyldiethanolamine, and tris(methoxyethoxyethyl)amine can be exemplified.

As the aniline derivatives having a hydroxy group and/or an ether bond, N,N-bis(hydroxyethyl)aniline can be exemplified.

As preferred basic compounds, an amine compound having a phenoxy group, an ammonium salt compound having a phenoxy group, an amine compound having a sulfonic ester group, and an ammonium salt compound having a sulfonic ester group can further be exemplified.

In these compounds, it is preferred for at least one alkyl group to be bonded to a nitrogen atom. More preferably, an oxygen atom is contained in the chain of the alkyl group, thereby forming an oxyalkylene group. With respect to the number of oxyalkylene groups in each molecule, one or more is preferred, three to nine more preferred, and four to six further more preferred. Of these oxyalkylene groups, the groups of the formulae —CH₂CH₂O—, —CH(CH₃)CH₂O— and —CH₂CH₂CH₂O— are especially preferred.

As specific examples of these compounds, there can be mentioned, for example, the compounds (C1-1) to (C3-3) given as examples in section [0066] of US Patent Application Publication No. 2007/0224539 A.

The total amount of basic compound used based on the solid contents of the actinic ray-sensitive or radiation-sensitive resin composition is generally in the range of 0.001 to 10 mass %, preferably 0.01 to 5 mass %.

The molar ratio of the total amount of acid generators to the total amount of basic compounds is preferably in the range of 2.5 to 300, more preferably 5.0 to 200 and further more preferably 7.0 to 150. When this molar ratio is extremely lowered, the possibility of sensitivity and/or resolution deterioration is invited. On the other hand, when the molar ratio is extremely raised, any pattern thickening might occur during the period between exposure and postbake.

(Surfactant)

The composition according to the present invention may further contain one or more surfactants. The composition according to the present invention when containing the above surfactant would, in the use of an exposure light source of 250 nm or below, especially 220 nm or below, realize favorable sensitivity and resolving power and produce a resist pattern with less adhesion and development defects.

It is especially preferred to use a fluorinated and/or siliconized surfactant as the surfactant.

As fluorinated and/or siliconized surfactants, there can be mentioned, for example, those described in section [0276] of US Patent Application Publication No. 2008/0248425. Further, as useful commercially available surfactants, fluorinated surfactants or siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS) can be exemplified. Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound, produced by a telomerization technique (also called a telomer process) or an oligomerization technique (also called an oligomer process). In particular, polymers each having a fluoroaliphatic group derived from such a fluoroaliphatic compound may be used as the surfactant. The fluorinated aliphatic compound can be synthesized by the process described in JP-A-2002-90991.

The polymer having a fluorinated aliphatic group is preferably a copolymer from a monomer having a fluorinated aliphatic group and a poly(oxyalkylene) acrylate and/or poly(oxyalkylene) methacrylate, in which copolymer may have an irregular distribution or may result from block copolymerization.

As the poly(oxyalkylene) group, a poly(oxyethylene) group, a poly(oxypropylene) group, and a poly(oxybutylene) group can be exemplified.

Further, use can be made of a unit having alkylene groups of different chain lengths in a single chain, such as poly(oxyethylene-oxypropylene-oxyethylene block concatenation) or poly(oxyethylene-oxypropylene block concatenation).

As a commercially available surfactant, Megafac F178, F-470, F-473, F-475, F-476 and F-472 (produced by Dainippon Ink & Chemicals, Inc.) can be exemplified. A copolymer from an acrylate (or methacrylate) having a C6F13 group and a poly(oxyalkylene) acrylate (or methacrylate); and a copolymer from an acrylate (or methacrylate) having a C₃F₇ group, poly(oxyethylene) acrylate (or methacrylate), and poly(oxypropylene) acrylate (or methacrylate) can further be exemplified.

Further, use may be made of surfactants other than the fluorinated and/or siliconized surfactants, described in section [0280] of US Patent Application Publication No. 2008/0248425.

These surfactants may be used either individually or in combination.

When the composition according to the present invention contains the surfactant, the total amount thereof used based on the total solids of the composition is preferably in the range of 0 to 2 mass %, more preferably 0.0001 to 2 mass %, and most preferably 0.0005 to 1 mass %.

(Carboxylic Acid Onium Salt)

The composition according to the present invention may further contain one or more carboxylic acid onium salts. Accordingly, there would be achieved securement of the transparency in 220 nm or shorter light, enhancement of the sensitivity and resolving power, and improvement of the dependency on pattern-width and exposure margin.

Preferred carboxylic acid onium salt is a sulfonium salt and an iodonium salt. In particular, the especially preferred anion moiety thereof is a linear or branched alkylcarboxylate anion, and monocyclic or polycyclic cycloalkylcarboxylate anion each having 1 to 30 carbon atoms. A more preferred anion moiety is an anion of carboxylic acid wherein the alkyl group or the cycloalkyl group is partially or wholly fluorinated (hereinafter also called as fluorinated carboxylic acid anion). The alkyl or cycloalkyl chain may contain an oxygen atom.

As the fluorinated carboxylic acid anion, any of the anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid can be exemplified.

When the composition according to the present invention contains the carboxylic acid onium salt, the total amount thereof used based on the total solids of the composition is preferably in the range of 0.1 to 20 mass %, more preferably 0.5 to 10 mass %, and most preferably 1 to 7 mass %.

(Dissolution Inhibiting Compound)

The composition according to the present invention may further contain one or more dissolution inhibiting compounds. Here the “dissolution inhibiting compound” means compound having 3000 or less molecular weight that is decomposed by the action of an acid to increase the solubility in an alkali developer

From the viewpoint of preventing lowering of the transmission at the wavelength of 220 nm or shorter, the dissolution inhibiting compound is preferably an alicyclic or aliphatic compound having an acid-decomposable group, such as any of cholic acid derivatives having an acid-decomposable group described in Proceeding of SPIE, 2724, 355 (1996). The acid-decomposable group and alicyclic structure can be the same as described earlier.

When the composition according to the present invention is exposed to a KrF excimer laser or irradiated with electron beams, preferred use is made of one having a structure resulting from substitution of the phenolic hydroxy group of a phenol compound with an acid-decomposable group. The phenol compound preferably contains 1 to 9 phenol skeletons, more preferably 2 to 6 phenol skeletons.

When the composition according to the present invention contains the dissolution inhibiting compound, the total amount thereof used based on the total solids of the composition is preferably in the range of 3 to 50 mass %, and more preferably 5 to 40 mass %.

Specific examples of the dissolution inhibiting compound will be shown below.

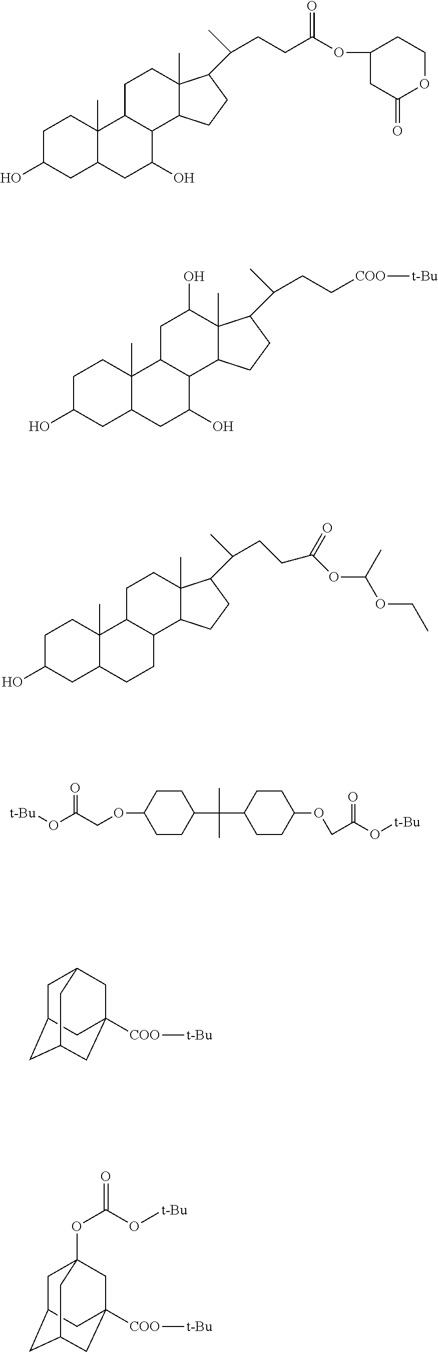

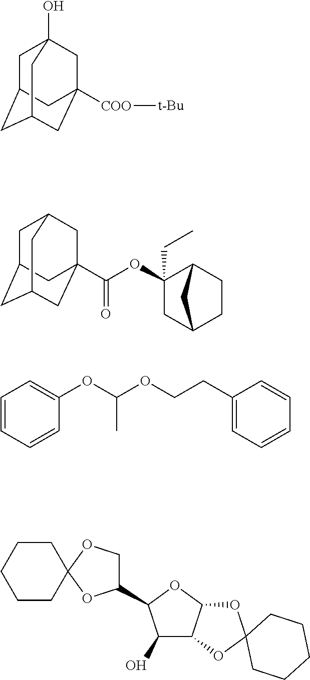

(Other Additives)

The composition according to the present invention may further contain a dye, a plasticizer, a photosensitizer, a light absorber, a compound capable of increasing the solubility in a developer (for example, a phenolic compound of 1000 or less molecular weight or a carboxylated alicyclic or aliphatic compound), etc.

The above phenolic compound of 1000 or less molecular weight can be easily synthesized by persons of ordinary skill in the art while consulting the processes described in, for example, JP-As 4-122938 and 2-28531, U.S. Pat. No. 4,916,210, and EP 219294.

As the nonlimiting examples of the carboxylated alicyclic or aliphatic compound, a carboxylic acid derivative of steroid structure such as cholic acid, deoxycholic acid or lithocholic acid, an adamantanecarboxylic acid derivative, adamantanedicarboxylic acid, cyclohexanecarboxylic acid, and cyclohexanedicarboxylic acid can be exemplified.

<Method of Forming Pattern>

When forming a film using the composition according to the present invention, the thickness thereof is preferably in the range of 30-250 nm, and more preferably in the range of 30-200 nm. If so, the resolution can be enhanced. The films with the above thickness can be produced by regulating the solid content of the composition so as to fall within an appropriate range, thereby adjusting the viscosity of the composition and thus enhancing the coatability and film formability thereof.

The total solids concentration of the actinic ray-sensitive or radiation-sensitive resin composition is generally in the range of 1 to 10 mass %, preferably 1 to 8.0 mass %, and more preferably 1.0 to 6.0 mass %.

The composition according to the present invention is typically used as follows. That is, the above components are dissolved in a given organic solvent, preferably the above mixed solvent, and filtered and applied onto a given support. The pore size of the filter for the filtration is 0.1 μm or less, preferably 0.05 μm or less, and more preferably 0.03 μm or less. The filter medium for the filtration is preferably made of a polytetrafluoroethylene, polyethylene or nylon.

The obtained composition is applied onto, for example, a substrate (e.g., silicon/silicon dioxide coating, silicon nitride or chromium-vapor-deposited quartz substrate or the like) for use in the production of precision integrated circuit elements, etc. by means of a spinner, a coater or the like. The thus applied composition is dried, thereby forming an actinic-ray- or radiation-sensitive film (hereinafter also referred to as a photosensitive film). The application of the composition to the substrate can be preceded by the application of a heretofore known antireflection film.

The resultant photosensitive film is exposed to actinic rays or radiation, preferably baked (heated), and developed. A pattern of enhanced quality can be obtained by baking.

As the actinic rays or radiation, infrared rays, visible light, ultraviolet rays, far ultraviolet rays, extreme ultraviolet rays, X-rays, and electron beams can be exemplified. Among them, preferred use is made of far ultraviolet rays with wavelength of preferably 250 nm or less, more preferably 220 nm or less, and still more preferably 1 to 200 nm, such as a KrF excimer laser (248 nm), an ArF excimer laser (193 nm) and an F₂ excimer laser (157 nm), as well as X-rays, and electron beams. More preferred use is made of an ArF excimer laser, an F₂ excimer laser, EUV (13 nm) and electron beams.

As the anti-reflection film, use can be made of not only an inorganic film of titanium, titanium oxide, titanium nitride, chromium oxide, carbon, amorphous silicon or the like but also an organic film composed of a light absorber and a polymer material. Also, as the organic anti-reflection film, use can be made of commercially available organic anti-reflection films, such as the DUV30 Series and DUV40 Series produced by Brewer Science Inc. and AR-2, AR-3 and AR-5 produced by Shipley Co., Ltd.

A liquid immersion exposure may be carried out for the film produced from the composition of the present invention. Namely, the film may be exposed to actinic rays or radiation under the conditions that the space between the film and a lens is filled with a liquid whose refractive index is higher than that of air. If so, an enhanced resolution can be attained.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any distortion of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

For the attainment of further wavelength shortening, use can be made of a medium whose refractive index is 1.5 or higher. Such a medium may be either an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power.

The additive is preferably an aliphatic alcohol with a refractive index approximately equal to that of water, for example, methyl alcohol, ethyl alcohol, isopropyl alcohol, etc. The addition of an alcohol with a refractive index approximately equal to that of water is advantageous in that even when the alcohol component is evaporated from water to cause a change of content concentration, the change of refractive index of the liquid as a whole can be minimized. On the other hand, when a substance being opaque in 193 nm rays or an impurity whose refractive index is greatly different from that of water is mixed therein, the mixing would invite a distortion of optical image projected on the resist film. Accordingly, it is preferred to use distilled water as the liquid immersion water. Furthermore, use may be made of pure water having been filtered through, for example, an ion exchange filter.

Desirably, the electrical resistance of the water is 18.3 MΩcm or higher, and the TOC (organic matter concentration) thereof is 20 ppb or below. Prior deaeration of the water is also desired.

Raising the refractive index of the liquid for liquid immersion would enable an enhancement of lithography performance. From this viewpoint, an additive suitable for refractive index increase may be added to the water. Alternatively, heavy water (D₂O) may be used in place of water.

For the prevention of direct contact of a film with a liquid for liquid immersion, a film that is highly insoluble in the liquid for liquid immersion (hereinafter also referred to as a “top coat”) may be provided between the film formed by the composition according to the present invention and the liquid for liquid immersion. The functions to be fulfilled by the top coat are applicability to an upper layer portion of the film, transparency in radiation of especially 193 nm, and high insolubility in the liquid for liquid immersion. Preferably, the top coat does not mix with the film and is uniformly applicable to an upper layer of the film.

From the viewpoint of transparency in radiation of 193 nm, the top coat preferably consists of a polymer not abundantly containing an aromatic moiety. As such, a hydrocarbon polymer, an acrylic ester polymer, polymethacrylic acid, polyacrylic acid, polyvinyl ether, a siliconized polymer, and a fluoropolymer can be exemplified. The aforementioned hydrophobic resins (HR) also find appropriate application in the top coat. From the viewpoint of contamination of an optical lens by leaching of impurities from the top coat into the liquid for liquid immersion, it is preferred to reduce the amount of residual monomer components of the polymer contained in the top coat.

At the detachment of the top coat, use may be made of a developer, or a separate peeling agent may be used. The peeling agent preferably consists of a solvent having low permeation into the film. Detachability by an alkali developer is preferred from the viewpoint of simultaneous attainment of the detachment step with the development processing step for the resist film. The top coat is preferred to be acidic from the viewpoint of detachment with the use of an alkali developer. However, from the viewpoint of non-intermixability with the resist film, the top coat may be neutral or alkaline.

Preferably, the refractive index difference between the top coat and the liquid for liquid immersion is nil or slight. If so, the resolving power can be enhanced. When the exposure light source is an ArF excimer laser (wavelength: 193 nm), it is preferred to use water as the liquid for liquid immersion. Accordingly, it is preferred for the top coat for ArF liquid immersion exposure to have a refractive index close to that of water (1.44).

Further, from the viewpoint of transparency and refractive index, it is preferred for the top coat to be a thin film. Preferably, the top coat does not mix with the film and also does not mix with the liquid for liquid immersion. From this viewpoint, when the liquid for liquid immersion is water, it is preferred for the solvent used in the top coat to be highly insoluble in the solvent used in the actinic ray-sensitive or radiation-sensitive resin composition and be a non-water-soluble medium. When the liquid for liquid immersion is an organic solvent, the top coat may be soluble or insoluble in water.

Usually, an aqueous solution of a quaternary ammonium salt, such as tetramethylammonium hydroxide, is employed as the alkali developer for use in the development step. However, other aqueous alkali solutions of an inorganic alkali, a primary amine, a secondary amine, a tertiary amine, an alcoholamine, a cycloamine, etc. can also be employed. Appropriate amounts of an alcohol and/or a surfactant may be added to the alkali developer before the use thereof.

The alkali concentration of the alkali developer is generally in the range of 0.1 to 20 mass %.

The pH value of the alkali developer is generally in the range of 10.0 to 15.0.

Pure water can be used as the rinse liquid. Before the use, an appropriate amount of surfactant may be added thereto.

The development operation or rinse operation may be followed by the operation for removing any developer or rinse liquid adhering onto the pattern by the use of a supercritical fluid.

### EXAMPLES

The present invention will now be described in greater detail with reference to Examples, which however in no way limit the scope of the present invention.

### Synthetic Example 1

### Synthesis of Monomer (1)

Monomer (1) was synthesized in accordance with the following scheme.

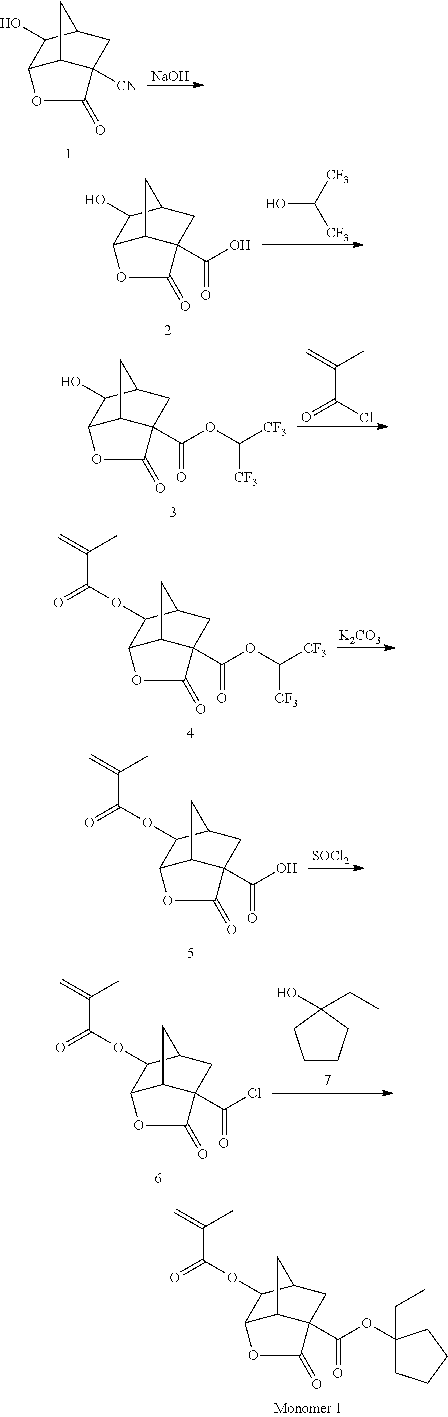

First, compound (1) was synthesized by the method described in the pamphlet of International Publication No. 07/037,213. Subsequently, 150.00 g of water was added to 35.00 g of compound (1), and 27.30 g of NaOH was added thereto. The thus obtained reaction liquid was agitated while heating under reflux for 9 hours. Hydrochloric acid was added so as to acidify the liquid, and a product was extracted using ethyl acetate. The resultant organic phase was collected and concentrated, thereby obtaining 36.90 g of compound (2) (yield: 93%).

Ethyl acetate amounting to 300 g was'added to 50.87 g of compound (2). Thereafter, 51.76 g of 1,1,1,3,3,3-hexafluoroisopropyl alcohol and 3.18 g of 4-dimethylaminopyridine were added and agitated. Further, 54.20 g of 1-ethyl-3-(3-dimethylaminopropyl)carbodiimide hydrochloride was added to the obtained solution and agitated for 5 hours. The reaction solution was poured into 200 ml of 1N hydrochloric acid, thereby terminating the reaction. The resultant organic phase was separated, washed with 1N hydrochloric acid, further washed with water, and concentrated. Thereafter, azeotropic dehydration of the organic phase was performed using toluene, thereby obtaining 67.60 g of compound (3) (yield: 76%).

Compound (3) amounting to 15.00 g was dissolved in 67.5 g of deaerated acetonitrile and bubbled using nitrogen gas. The thus obtained reaction liquid was cooled to 10° C. or below. While maintaining the liquid temperature at 10° C. or below, 8.11 g of methacrylic chloride was added, and 7.85 g of triethylamine was dropped thereinto. Thereafter, the reaction liquid was further agitated at room temperature for 2 hours. After the completion of the reaction, the reaction solution was poured into a liquid obtained by diluting 9.0 g of concentrated hydrochloric acid with 675 g of water and cooling the dilution to 5° C., and agitated for 30 minutes. The resultant precipitate was collected by filtration, and washed with water. The thus obtained powder was dissolved in 45.6 g of acetonitrile. The obtained solution was dropped into 304.0 g of water cooled to 5° C. and agitated for 30 minutes. The resultant precipitate was collected by filtration, and washed with water. Heptane amounting to 76.1 g was added to the thus obtained powder, and agitated at room temperature for one hour. The resultant solid was collected by filtration, and dried, thereby obtaining 13.7 g of compound (4) (yield: 77%).

Compound (4) amounting to 5.00 g was dissolved in 50 g of tetrahydrofuran, and 50 g of water and 2.16 g of potassium carbonate were added to the obtained solution and agitated at room temperature for one hour. After the completion of the reaction, concentrated hydrochloric acid was added so as to adjust the pH value of the reaction solution to 1 or below. Ethyl acetate amounting to 100 ml was added to the solution, thereby extracting a product. The resultant organic phase was separated and washed with 50 ml of 1N hydrochloric acid. The organic phase was concentrated, thereby obtaining 3.01 g of compound (5) (yield: 94%).

Further, 0.13 ml of dimethylformamide and 2.00 g of thionyl chloride were added to 2.00 g of compound (5). The obtained reaction solution was heated to 75° C. and agitated for one hour. After the completion of the reaction, unreacted thionyl chloride was removed in vacuum. Thus, compound (6) was obtained.

Subsequently, compound (7) was synthesized by the method described in Journal of Medicinal Chemistry, 1975, Vol. 18, No. 11, 1065-1070. Compound (7) amounting to 0.86 g was dissolved in 4.0 g of acetonitrile, and 0.84 g of triethylamine and 0.28 g of 4-dimethylaminopyridine were added to the obtained solution. The reaction solution was cooled to 10° C. or below, and agitated. While maintaining the liquid temperature at 10° C. or below, a solution of the above synthesized compound (6) in 3.5 g of acetonitrile was dropped thereinto. After the completion of the reaction, 50 ml of ethyl acetate and 25 ml of an aqueous solution of sodium hydrogen carbonate were added, thereby extracting a product. The resultant organic phase was separated, washed with saturated sodium bicarbonate water, and further washed with water. The organic phase was concentrated, and the obtained concentrate was purified by column chromatography. Thus, 0.54 g of monomer (1) was obtained (yield: 21%).

¹H-NMR (400 MHz in (CD₃)₂CO): δ(ppm)=0.83-1.00 (3H), 1.63-1.77 (8H), 1.85-2.15 (8H), 2.18-2.56 (1H), 2.64 (1H), 3.55-3.56 (1H), 4.63 (1H), 4.69-4.71 (1H), 5.67 (1H), 6.10 (1H).

### Synthetic Examples 2 and 3

### Synthesis of Monomers (2) and (3)

Monomer (2) shown below was synthesized in the same manner as in Synthetic Example 1 except that compound (8) shown below was used in place of the compound (7).

Further, monomer (3) shown below was synthesized in the same manner as in Synthetic Example 1 except that compound (9) shown below was used in place of the compound (7).

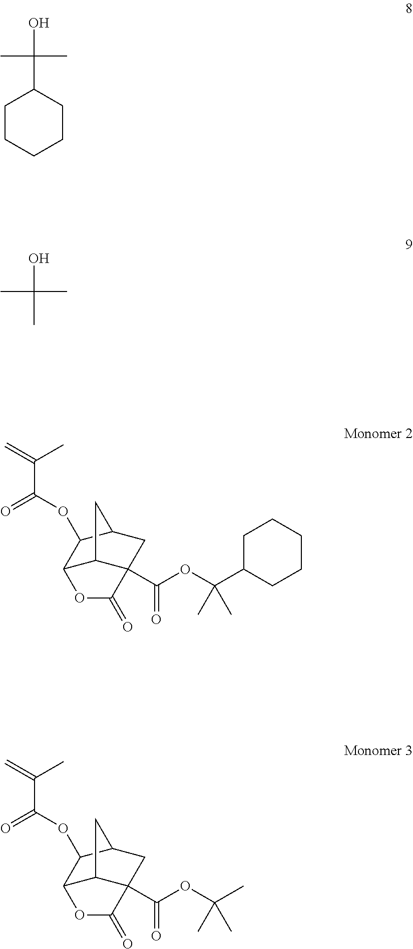

### Synthetic Example 4

### Synthesis of Monomer (4)

Monomer (4) was synthesized in accordance with the following scheme.

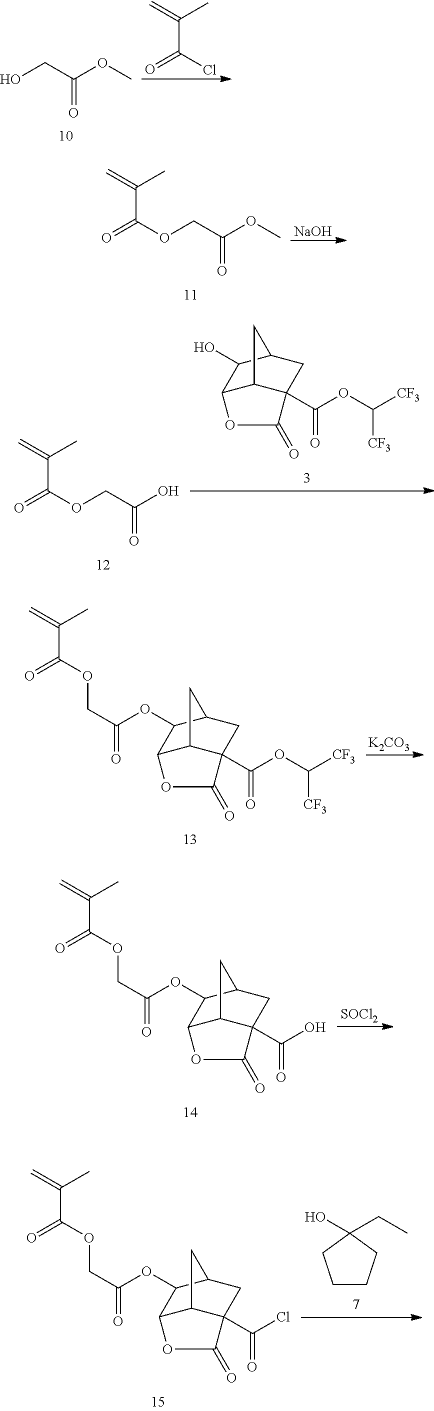

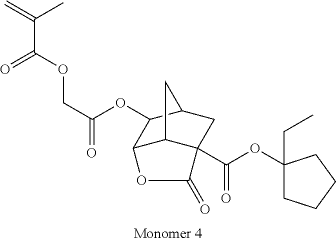

Tetrahydrofuran amounting to 30.00 g was added to 17.09 g of methyl glycolate (compound (10) produced by TCI). Further, 21.15 g of triethylamine was added and cooled to 0° C. Thereafter, 20.85 g of methacrylic chloride was dropped into the cooled mixture. The mixture was warmed to room temperature, and agitated for two hours. An aqueous solution of sodium hydrogen carbonate was added to the mixture, and a product was extracted using ethyl acetate. The resultant organic phase was collected, and MgSO₄ was added. Filtration was performed, and the obtained filtrate was concentrated. Thus, 28.51 g of compound (11) was obtained (yield: 95%).

Acetone amounting to 180 ml was added to 28.5 g of compound (11), and cooled to 0° C. Thereafter, 180 ml of a 1N aqueous sodium hydroxide solution was dropped thereinto, and agitated for 30 minutes. Hydrochloric acid was added so as to acidify the mixture, and extraction using ethyl acetate was performed. The resultant organic phase was collected, and MgSO₄ was added. Filtration was performed, and the obtained filtrate was concentrated. Thus, 21.2 g of compound (12) was obtained (yield: 82%).

Toluene amounting to 300 g was added to 15.00 g of compound (12). Further, 7.00 g of compound (3) and 3.80 g of p-toluenesulfonic acid monohydrate were added thereto, and the mixture was refluxed for 6 hours while removing any formed water by azeotropy. The thus obtained reaction liquid was concentrated, and the concentrate was purified by column chromatography. Thus, 13.52 g of compound (13) was obtained (yield: 71%).

Thereafter, monomer (4) was synthesized in the same manner as in Synthetic Example 1 except that compound (13) was used in place of the compound (4).

### Synthetic Examples 5 and 6

### Synthesis of Monomers (5) and (6)

Monomer (5) shown below was synthesized in the same manner as in Synthetic Example 4 except that compound (16) shown below was used in place of the compound (7).

Further, monomer (6) shown below was synthesized in the same manner as in Synthetic Example 4 except that compound (17) shown below was used in place of the compound (7).

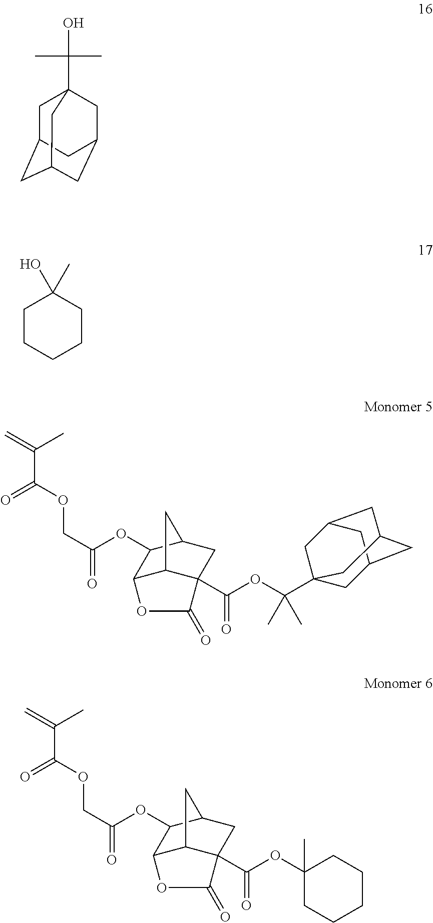

### Synthetic Example 7

### Synthesis of Monomer (7)

Monomer (7) was synthesized in accordance with the following scheme.

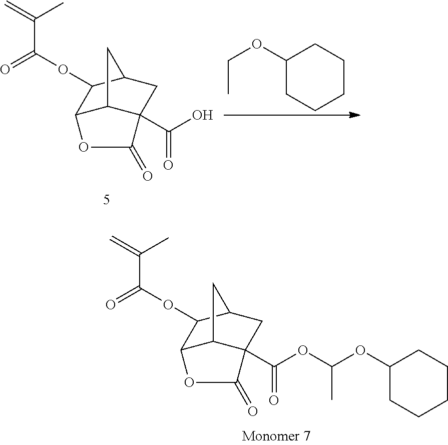

Cyclohexyl vinyl ether (produced by TCI) amounting to 20.00 g was cooled to 10° C. or below. While maintaining the liquid temperature at 10° C. or below, 4.26 g of compound (5) was added thereto. The liquid temperature was returned to room temperature, and the mixture was agitated for one hour. After the completion of the reaction, unreacted cyclohexyl vinyl ether was removed in vacuum. The obtained crude product was purified by column chromatography. Thus, 1.32 g of monomer (7) was obtained (yield: 21%).

### Synthetic Example 8

### Synthesis of Monomer (8)

Monomer (8) was synthesized in accordance with the following scheme.

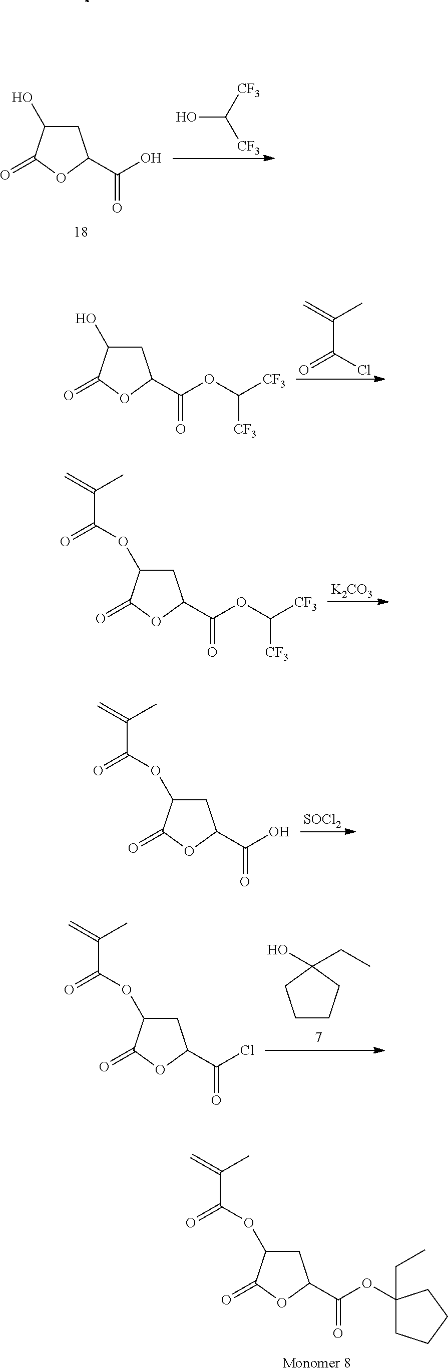

The above compound (18) was synthesized by the method described in Journal of the Chemical Society, 1925, 127, 475. Monomer (8) was synthesized in the same manner as in Synthetic Example 1 except that the compound (18) was used in place of the compound (2).

### Synthetic Example 9

### Synthesis of Monomer (9)

Monomer (9) was synthesized in accordance with the following scheme.

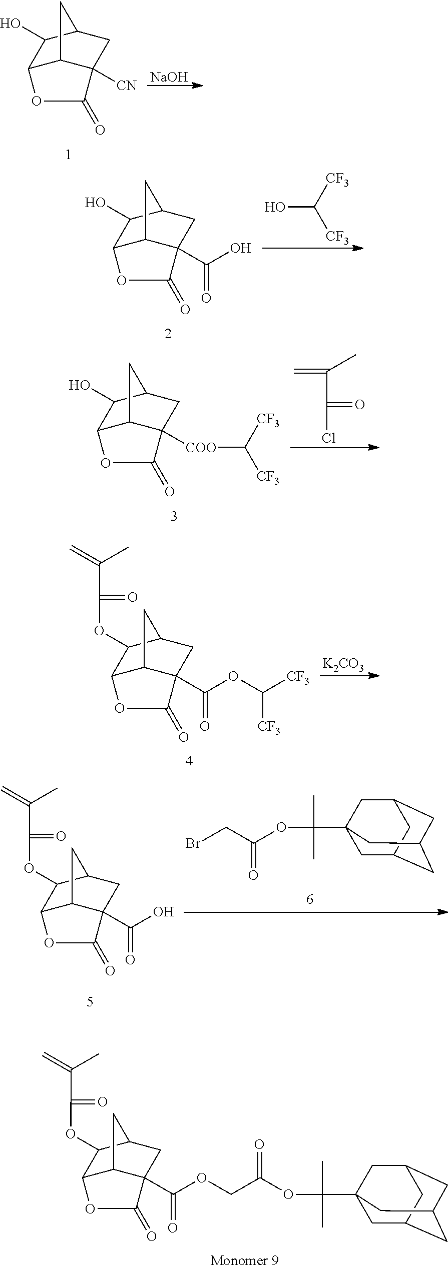

First, 30.00 g of 2-(1-adamantyl)-2-propanol was dissolved in 570 g of N-methylpyrrolidone, and 35.26 g of 1,8-diazabicyclo[5,4,0]undec-7-ene was added to the solution and agitated. The thus obtained solution was cooled to 5° C., and 77.91 g of bromoacetyl bromide was dropped thereinto over a period of 30 minutes. After the completion of the dropping, the mixture was heated to room temperature and agitated for 6 hours. After the completion of the reaction, the mixture was cooled to 5° C., and 300 ml of distilled water was added. Extraction using ethyl acetate was performed three times: The resultant organic phase was collected, washed with a saturated aqueous solution of sodium hydrogen carbonate and distilled water, and dried over anhydrous magnesium sulfate. The solvent was distilled off, thereby obtaining 46.24 g of compound (6) (yield: 95%).

Compound (6) amounting to 42.63 g was dissolved in 170 g of N-methylpyrrolidone. The obtained solution was cooled to 5° C., and 23.36 g of K₂CO₃ and 30.00 g of compound (5) synthesized in the same manner as in Synthetic Example 1 were put in the cooled solution. Thereafter, the mixture was agitated at room temperature for 6 hours, and cooled once more to 5° C. Distilled water amounting to 200 g was dropped into the mixture over a period of 30 minutes. The obtained reaction solution was extracted three times by adding ethyl acetate. The resultant organic phase was collected and washed with distilled water three times, and 10 g of active carbon was added to the organic phase and agitated for one hour. Thereafter, the organic phase was dried over anhydrous magnesium sulfate, a filtrate was recovered, and the solvent was distilled off. Thus, 49.04 g (yield: 87%) of monomer (9) was obtained.

¹H-NMR (400 MHz in CDCl₃): δ(ppm)=1.47 (6H, s), 1.54-1.84 (14H, m), 1.90-2.09 (4H, m), 1.94 (3H, s), 2.58-2.71 (2H, m), 3.69 (1H, d), 4.51 (1H, d), 4.64 (1H, d), 4.68 (1H, brs), 4.73 (1H, d), 5.62 (1H, s), 6.10 (1H, s)

Other required monomers were synthesized in the same manner as in Synthetic Examples 1 to 9 described above.

### Synthetic Example 10

### Synthesis of Polymer (1)

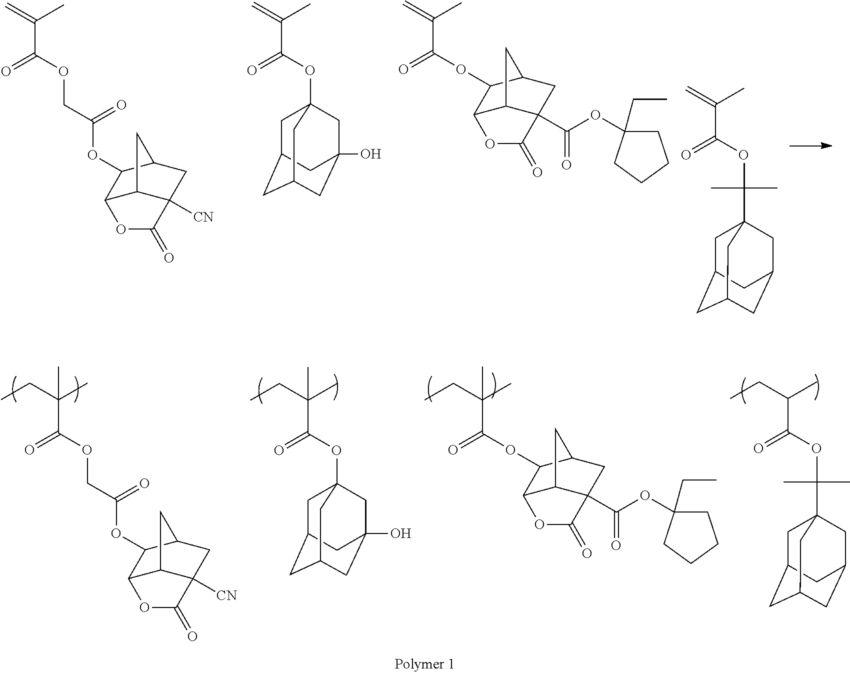

In a nitrogen stream, 7.12 g of a mixed solvent of PGMEA/PGME (mass ratio: 8/2) was placed in a three-necked flask and heated at 85° C. A solution obtained by dissolving the above monomers amounting in order from the left side to 3.16, 0.54, 1.04 and 1.96 g and further 0.344 g (0.65 mol % based on the monomers) of polymerization initiator V601 (produced by Wako Pure Chemical Industries, Ltd.) in 3.2 g of a mixed solvent of PGMEA/PGME (mass ratio: 8/2) was dropped into the heated solvent over a period of 6 hours. After the completion of the dropping, reaction was continued at 85° C. for 2 hours. The thus obtained reaction liquid was allowed to stand still to cool and was dropped into a mixed liquid consisting of 140 g of heptane and 60 g of ethyl acetate over a period of 20 minutes. The thus precipitated powder was collected by filtration and dried, thereby obtaining 4.6 g of a polymer (1). The weight average molecular weight of the obtained polymer (1) in terms of standard polystyrene molecular weight as measured by GPC was 8260, and the dispersity (Mw/Mn) thereof was 1.50.

The following polymers (2) to (32) were synthesized in the same manner as in the production of the polymer (1). Table 3 given below indicates the component ratios (mol %, corresponding to shown individual repeating units in order from the left), weight average molecular weight and dispersity with respect to each of the polymers.

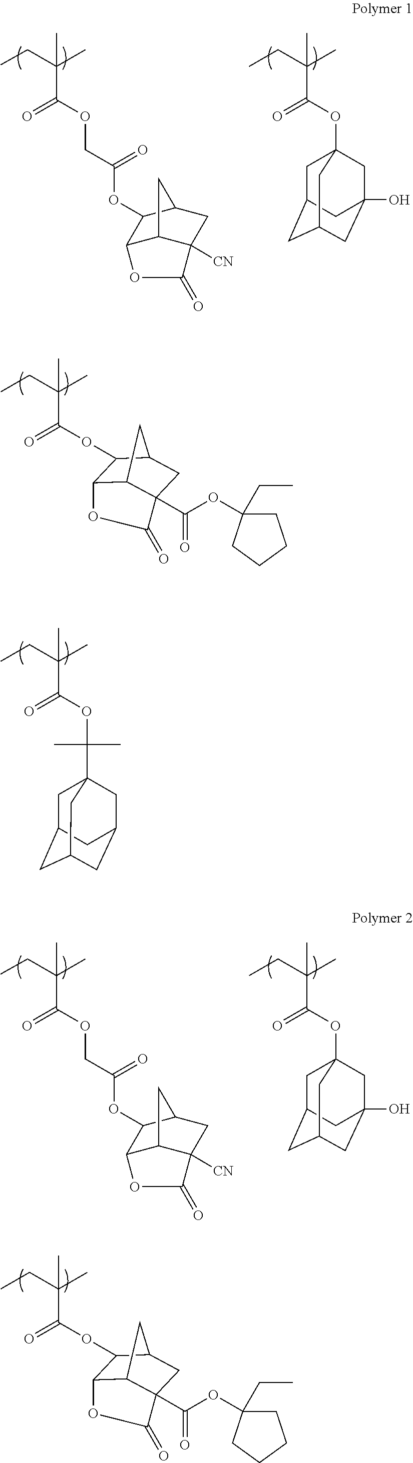

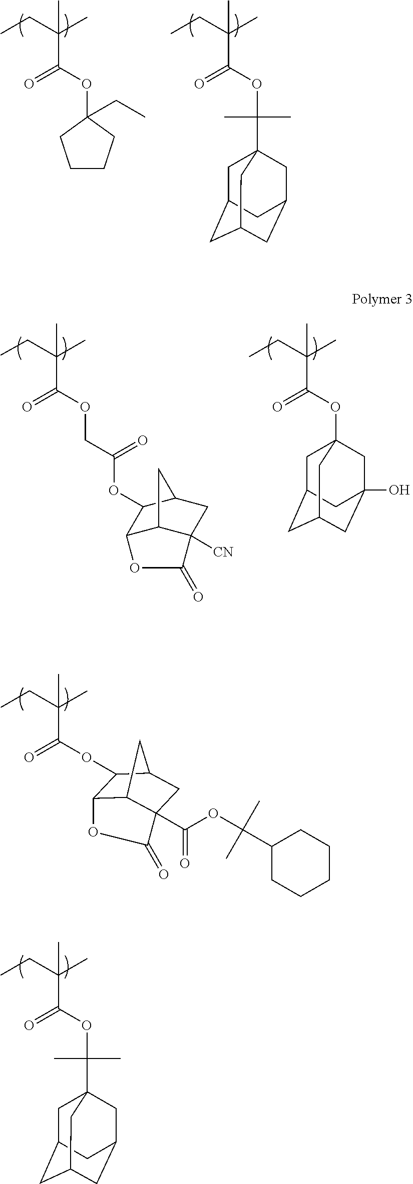

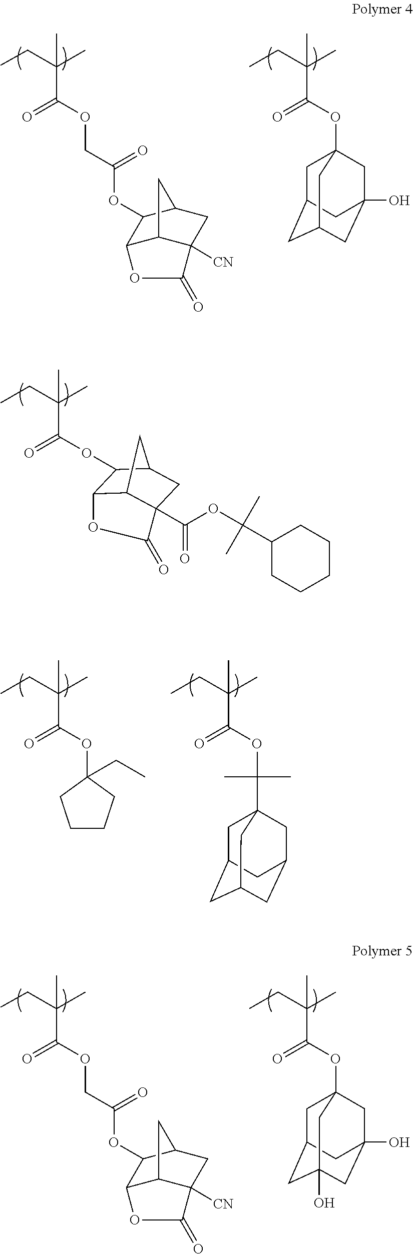

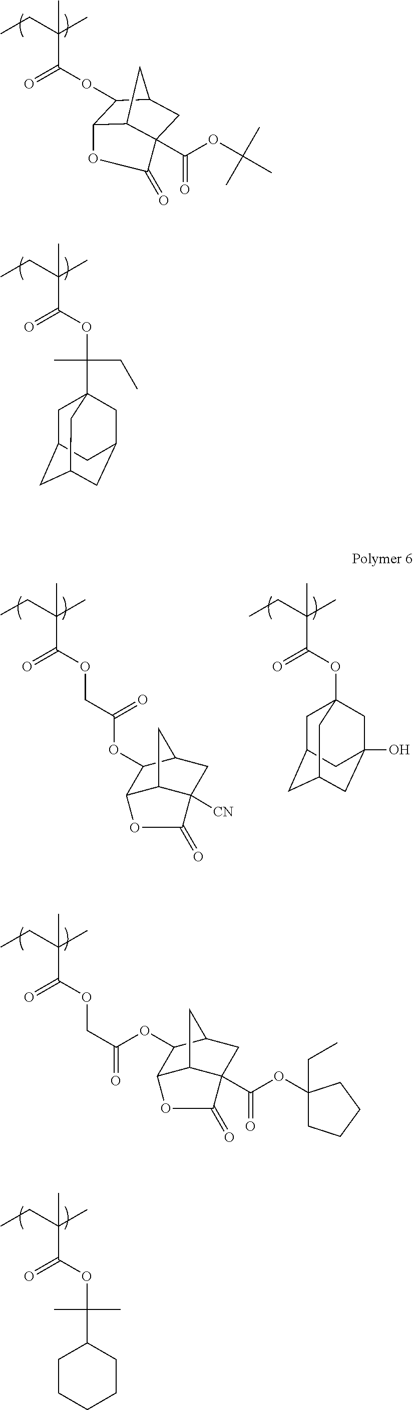

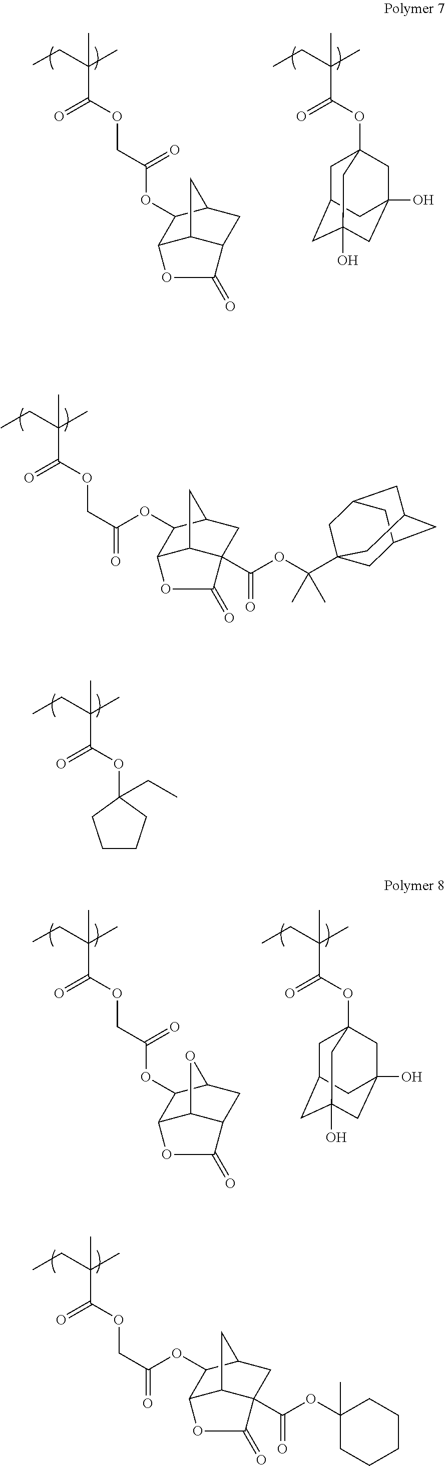

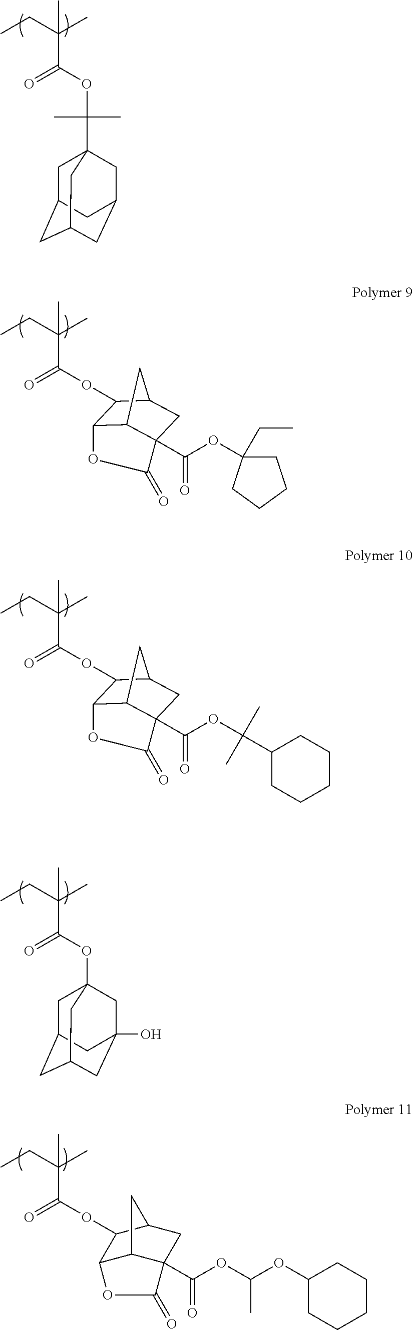

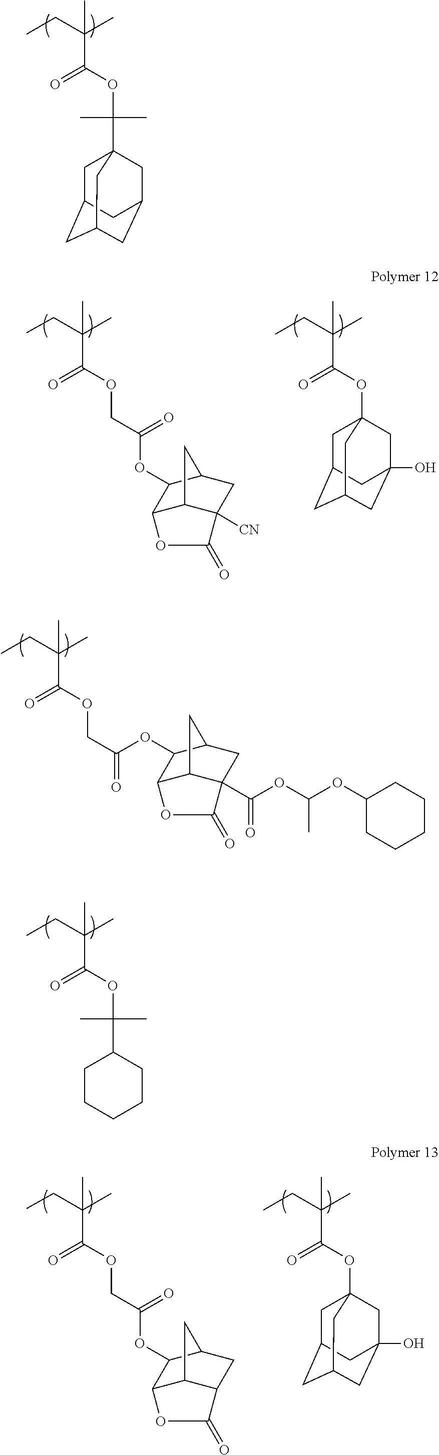

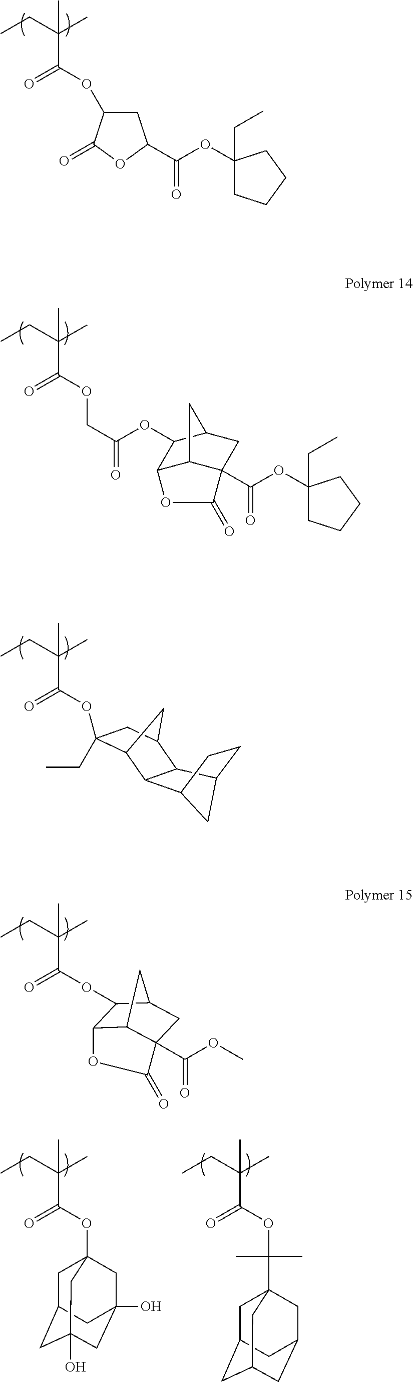

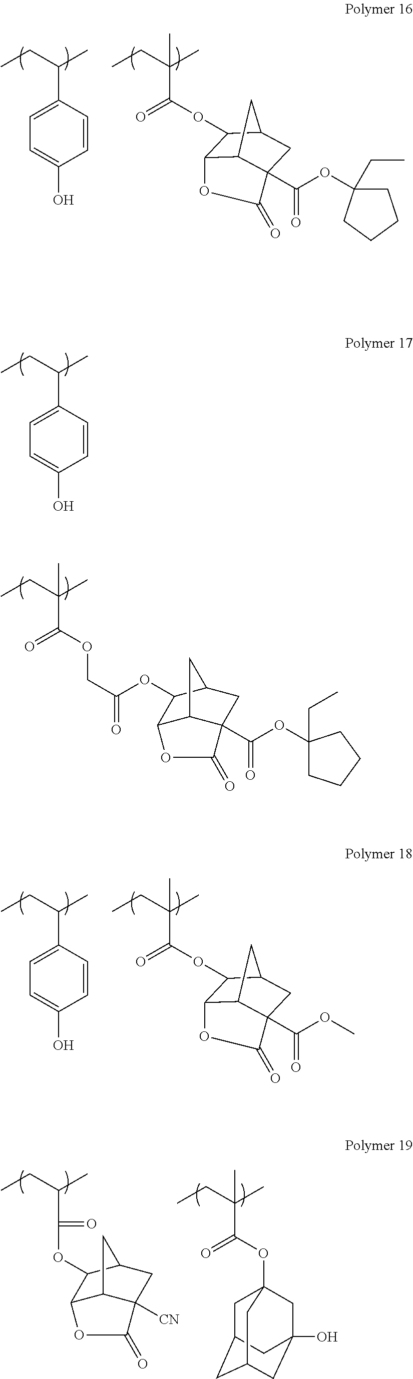

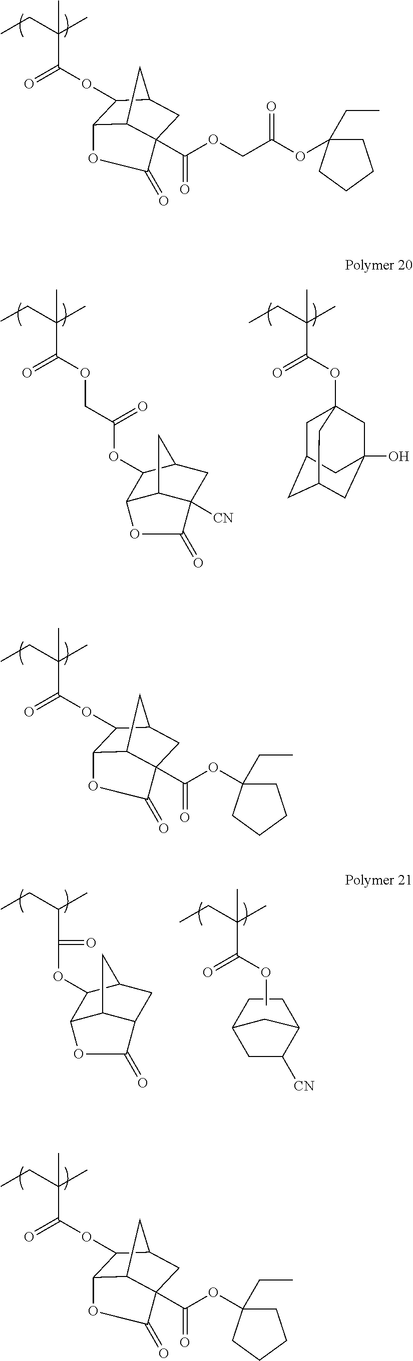

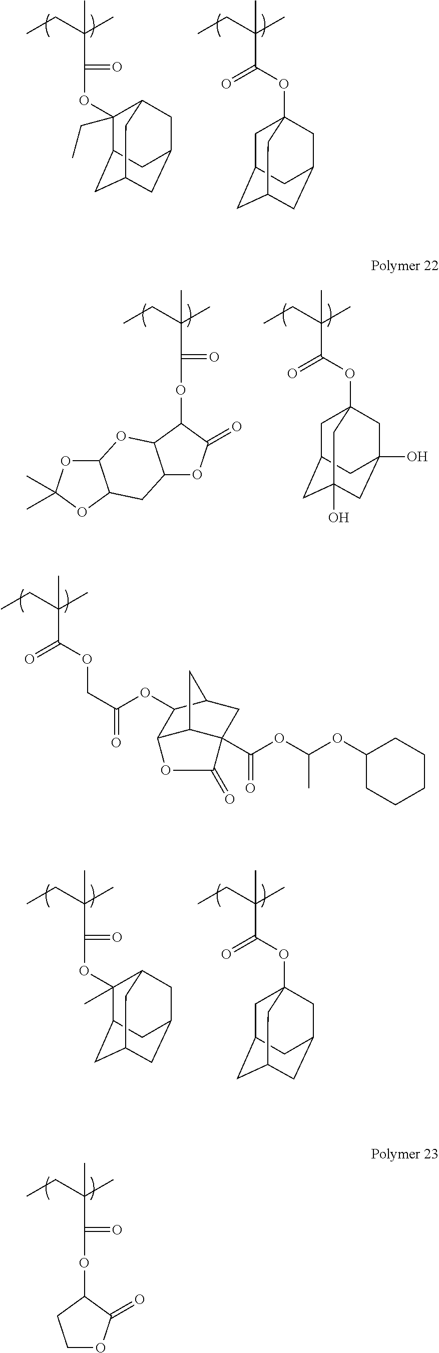

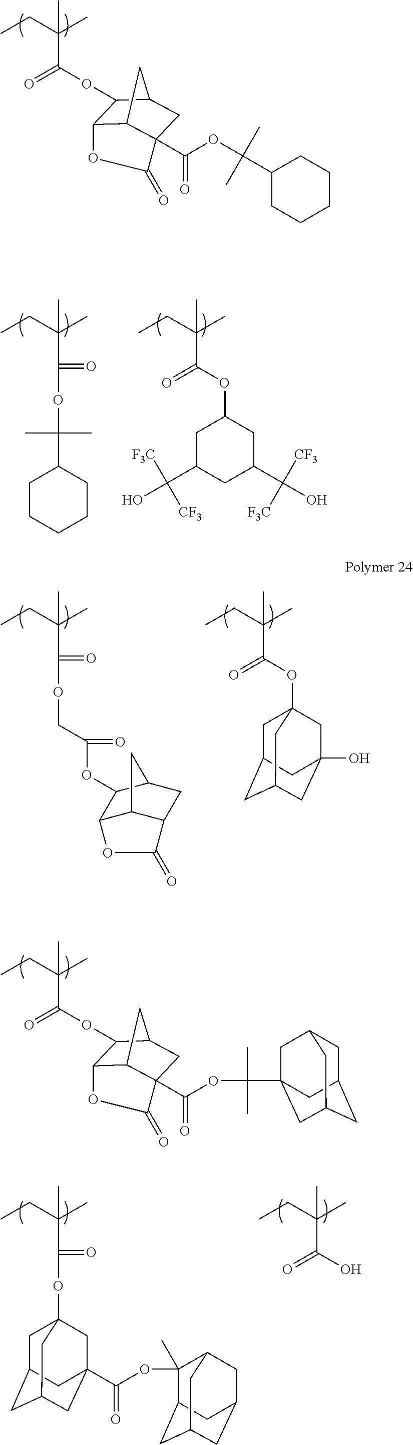

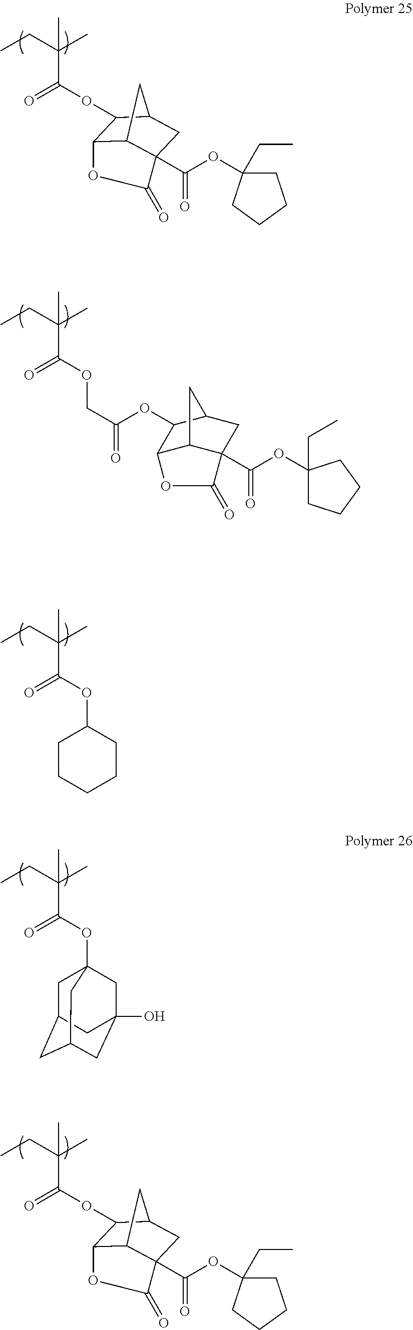

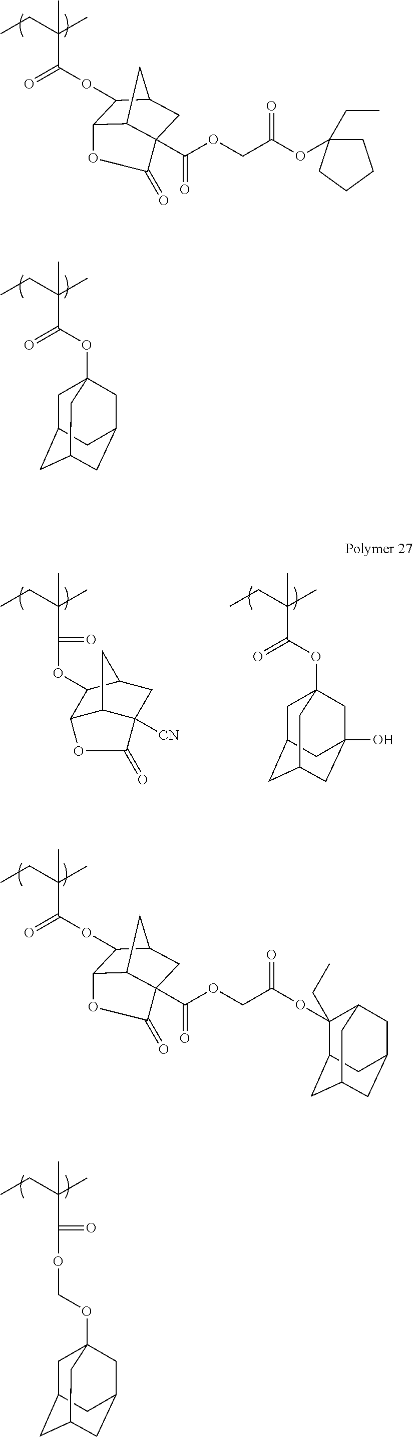

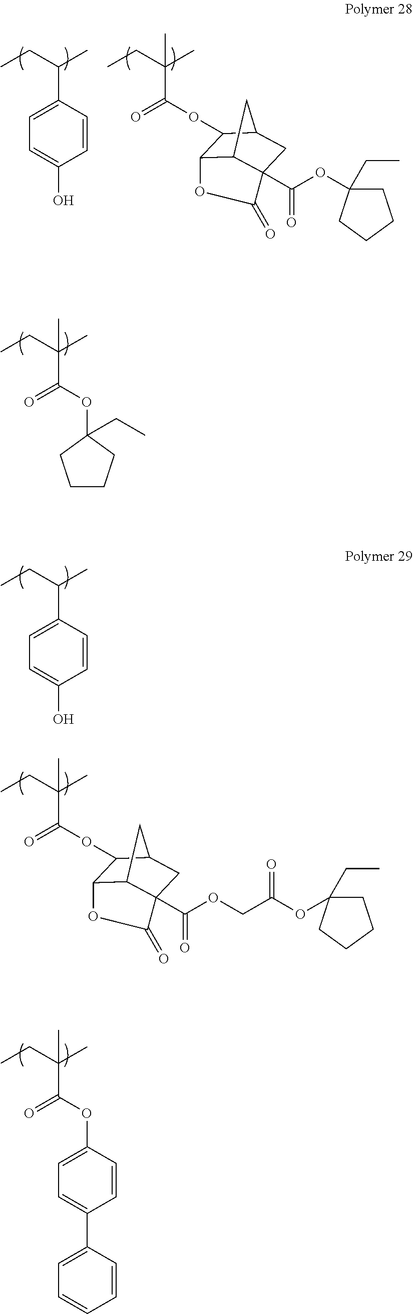

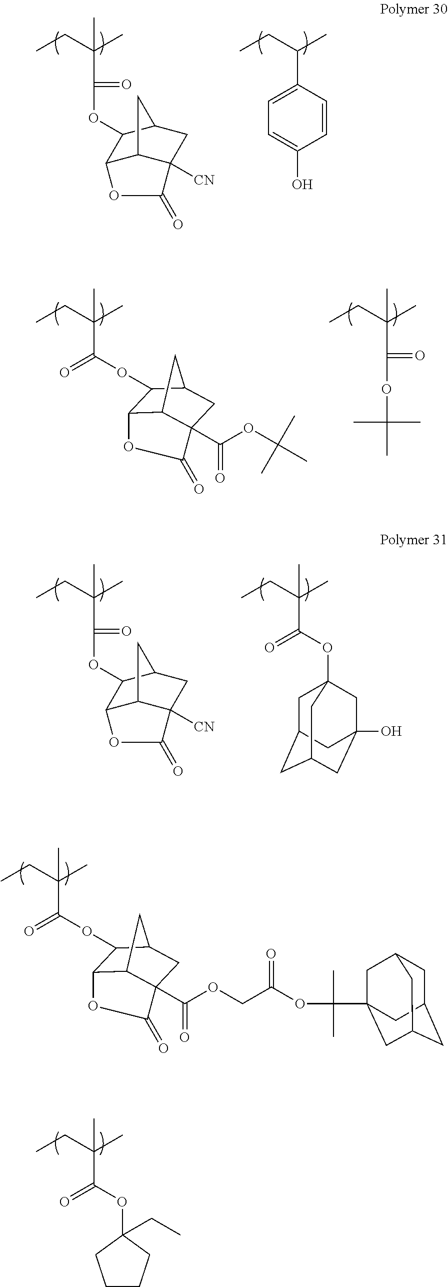

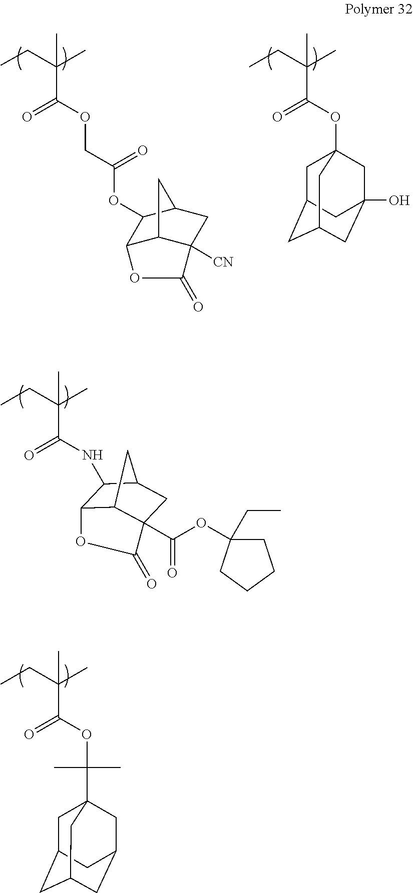

TABLE 3

| Polymer | Composition (mol %) | | | | | Mw | Mw/Mn |
|---|---|---|---|---|---|---|---|
| 1 | 45 | 10 | 12.5 | 32.5 | — | 8260 | 1.50 |
| 2 | 45 | 10 | 7.5 | 5 | 32.5 | 8560 | 1.49 |
| 3 | 35 | 10 | 22.5 | 32.5 | — | 9100 | 1.56 |
| 4 | 40 | 10 | 12.5 | 5 | 32.5 | 7950 | 1.61 |
| 5 | 45 | 5 | 17.5 | 32.5 | — | 8430 | 1.65 |
| 6 | 45 | 12 | 10.5 | 32.5 | — | 10510 | 1.52 |
| 7 | 45 | 10 | 10 | 35 | — | 11000 | 1.48 |
| 8 | 40 | 10 | 20 | 30 | — | 9500 | 1.51 |
| 9 | 100 | — | — | — | — | 10100 | 1.53 |
| 10 | 90 | 10 | — | — | — | 11100 | 1.65 |
| 11 | 50 | 50 | — | — | — | 8900 | 1.50 |
| 12 | 40 | 10 | 25 | 25 | — | 9210 | 1.56 |
| 13 | 40 | 10 | 50 | — | — | 4110 | 1.55 |
| 14 | 50 | 50 | — | — | — | 7400 | 1.77 |
| 15 | 40 | 20 | 40 | — | — | 8800 | 1.97 |
| 16 | 40 | 60 | — | — | — | 11050 | 1.87 |
| 17 | 40 | 60 | — | — | — | 11400 | 1.83 |
| 18 | 40 | 60 | — | — | — | 11000 | 1.88 |
| 19 | 50 | 5 | 45 | — | — | 10200 | 1.73 |
| 20 | 45 | 10 | 45 | — | — | 10800 | 1.72 |
| 21 | 40 | 5 | 25 | 25 | 5 | 6700 | 1.65 |
| 22 | 20 | 10 | 35 | 30 | 5 | 8200 | 1.69 |
| 23 | 10 | 50 | 35 | 5 | — | 9000 | 1.71 |
| 24 | 30 | 10 | 30 | 25 | 5 | 13600 | 1.64 |
| 25 | 45 | 45 | 10 | — | — | 11100 | 1.70 |
| 26 | 10 | 45 | 40 | 5 | — | 9500 | 1.73 |
| 27 | 30 | 5 | 45 | 20 | — | 7300 | 1.68 |
| 28 | 55 | 25 | 20 | — | — | 10600 | 1.67 |
| 29 | 60 | 30 | 10 | — | — | 8200 | 1.71 |
| 30 | 10 | 55 | 20 | 15 | — | 5800 | 1.76 |
| 31 | 40 | 10 | 20 | 30 | — | 9500 | 1.61 |
| 32 | 35 | 15 | 30 | 20 | — | 8900 | 1.59 |

<(1) ArF Dry Exposure>

(Preparation of Resist)

The components indicated in Table 4 below were dissolved in the solvents indicated in the same table, thereby obtaining solutions of 5 mass % solid content. The thus obtained solutions were passed through a polyethylene filter of 0.1 μm pore size, thereby obtaining positive resist compositions.

(Evaluation of Resist)

An organic antireflection film ARC29A (produced by Nissan Chemical Industries, Ltd.) was applied onto a silicon wafer and baked at 205° C. for 60 seconds, thereby forming a 78 nm thick antireflection film on the silicon wafer. Each of the above prepared positive resist solutions was applied thereonto and baked at 85° C. for 60 seconds, thereby forming a 120 nm thick resist film.

Each of the obtained resist films was patternwise exposed by means of an ArF excimer laser scanner (manufactured by ASML, PAS5500/1100, NA0.75). A 6% half-tone mask of 75 nm line size and 1:1 line:space was used as a rectile. The exposed resist film was baked at 85° C. for 60 seconds and developed with a 2.38 mass % aqueous tetramethylammonium hydroxide solution for 30 seconds. The developed resist film was rinsed with pure water and spin dried, thereby obtaining a resist pattern.

[Roughness Characteristic: LWR]

A line pattern of 75 nm line width (line:space=1:1) was observed by means of a scanning electron microscope (model S-9260, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LWR (nm).”

[Exposure Latitude (EL)]

The exposure amount that reproduced a line and space (line:space=1:1) mask pattern of 75 nm line width was determined, and this exposure amount was denoted as optimum exposure amount Eopt. Thereafter, the exposure amounts that caused the line width to become ±10% of the target 75 nm (namely, 82.5 nm and 67.5 nm) were determined. Then, the exposure latitude (EL) defined by the following formula was calculated. The greater the value of EL, the less the change of performance by exposure amount changes.

[EL(%)]=[(exposure amount for 67.5 nm line width)−(exposure amount for 82.5 nm line width)]/Eopt

[Development Defect Performance: Number of Defects]

Each of the above positive resist solutions was uniformly applied onto an 8-inch silicon substrate having undergone a hexamethyldisilazane treatment by means of a spin coater, and dried by heating on a hot plate at 120° C. for 60 seconds, thereby obtaining a 0.10 μm thick resist film. This resist film without being exposed was baked on a hot plate at 110° C. for 90 seconds, developed with a 2.38 mass % aqueous solution of tetramethylammonium hydroxide at 23° C. for 60 seconds, rinsed with pure water for 30 seconds and dried. On the thus obtained individual sample wafer, the number of development defects was counted by means of an instrument KLA-2360 (manufactured by KLA-Tencor Corporation). Table 4 below shows the count results as relative values to the number of defects in Example 14 which was normalized as 1. The smaller the value, the higher the development defect performance.

The obtained evaluation results are given in Table 4 below.

TABLE 4

| | | Polymer | | | | Dissolution | Organic | | | | The number of |
|---|---|---|---|---|---|---|---|---|---|---|---|
| | | (6.5 g) | Acid | Basic | | inhibiting | solvent | | | | development |
| | | (mass | generator | compound | Surfactant | compound | (mass | LWR | EL | EL/LWR | defects |
| Example | Resist | ratio) | (g) | (g) | (g) | (g) | ratio) | (nm) | (%) | (%/nm) | (normalized) |
| 1 | 1 | 1 | z92(0.5) | DIA(0.07) | W-5(0.02) | — | A1/B1 | 4.7 | 18.2 | 3.87 | 0.053 |
| | | | | | | | (8/2) | | | | |
| 2 | 2 | 2 | z38(0.5) | DIA(0.05) | W-5(0.02) | — | A1/B1 | 4.9 | 18.0 | 3.67 | 0.071 |
| | | | | | | | (6/4) | | | | |
| 3 | 3 | 3 | z2(0.7) | DIA(0.1) | W-3(0.02) | — | A1/B1 | 5.1 | 17.9 | 3.51 | 0.059 |
| | | | | | | | (7/3) | | | | |
| 4 | 4 | 4 | z38(0.5) | DIA(0.05) | W-5(0.02) | — | A1/B1 | 5.2 | 17.9 | 3.44 | 0.065 |
| | | | | | | | (8/2) | | | | |
| 5 | 5 | 5 | z2(0.5) | DIA(0.05) | W-1(0.02) | D-1(0.1) | A1/B1 | 5.3 | 17.0 | 3.21 | 0.071 |
| | | | | | | | (7/3) | | | | |
| 6 | 6 | 6 | z2(0.5) | DIA(0.12) | W-4(0.02) | — | A1/B2 | 4.7 | 16.3 | 3.47 | 0.055 |
| | | | | | | | (9/1) | | | | |
| 7 | 7 | 7 | z38(0.5) | PEA(0.05) | W-5(0.02) | — | A1/B1 | 4.9 | 16.2 | 3.31 | 0.061 |
| | | | | | | | (8/2) | | | | |
| 8 | 8 | 8 | z38(0.5) | DIA(0.05) | W-3(0.04) | — | A1/B1 | 4.8 | 16.4 | 3.42 | 0.055 |
| | | | | | | | (8/2) | | | | |
| 9 | 9 | 9 | z38(0.5) | DIA(0.1) | W-5(0.02) | — | A1/B2 | 4.6 | 17.2 | 3.74 | 0.051 |
| | | | | | | | (9/1) | | | | |
| 10 | 10 | 10 | z1(0.5) | PEA(0.05) | W-5(0.02) | — | A1 | 4.8 | 17.4 | 3.63 | 0.061 |
| 11 | 11 | 11 | z2(0.5) | DIA(0.05) | W-5(0.02) | — | A1/B1 | 5.1 | 17.2 | 3.37 | 0.055 |
| | | | | | | | (8/2) | | | | |
| 12 | 12 | 12 | z2(0.5) | DIA(0.1) | W-5(0.02) | D-1(0.1) | A1/B1 | 5.2 | 16.8 | 3.23 | 0.057 |
| | | | | | | | (7/3) | | | | |
| 13 | 13 | 13 | z38(0.5) | DIA(0.05) | W-5(0.02) | — | A1/B1 | 5.5 | 17.0 | 3.09 | 0.061 |
| | | | | | | | (8/2) | | | | |
| 14 | 14 | 14 | z38(0.5) | DIA(0.05) | W-5(0.02) | — | A1/B1 | 6.0 | 13.0 | 2.17 | 1 |
| | | | | | | | (8/2) | | | | |
| 15 | 15 | 15 | z38(0.6) | DIA(0.06) | W-5(0.03) | — | A1/B1 | 7.0 | 12.0 | 1.71 | 0.814 |
| | | | | | | | (8/2) | | | | |
| 16 | 16 | 1/7 | z38(0.5) | PEA(0.05) | W-5(0.02) | — | A1/B1 | 4.8 | 18.1 | 3.77 | 0.067 |
| | | (1/1) | | | | | (6/4) | | | | |
| 17 | 17 | 2 | z1/z38 | PEA(0.06) | W-5(0.03) | — | A1/B1 | 4.8 | 18.2 | 3.79 | 0.071 |
| | | | (0.2/0.3) | | | | (8/2) | | | | |
| 18 | 18 | 4 | z38(0.5) | DIA(0.05) | — | — | A1/B2 | 5.3 | 17.9 | 3.38 | 0.061 |
| | | | | | | | (9/1) | | | | |

The meanings of the brevity codes appearing in the table are as follows. The brevity codes for the acid generators correspond to the formula numbers employed in the specific examples set forth hereinbefore. These brevity codes are common through the Examples to be described hereinafter as well.

(Basic Compounds)

DIA: 2,6-diisopropylaniline,

TBAH: tetrabutylammonium hydroxide,

TMEA: tris(methoxyethoxyethyl)amine,

PEA: N-phenyldiethanolamine,

TOA: trioctylamine,

PBI: 2-phenylbenzoimidazole,

DHA: N,N-dihexylaniline,

TEA: triethanolamine, and

DBA: N,N-dibutylaniline.

(Surfactant)

W-1: Megafac F176 (produced by Dainippon Ink & Chemicals, Inc.; fluorinated),

W-2: Megafac R₀₈ (produced by Dainippon Ink & Chemicals, Inc.; fluorinated and siliconized),

W-3: Troy Sol S-366 (produced by Troy Chemical Co., Ltd.),

W-4: PF656 (produced by OMNOVA; fluorinated), and

W-5: PF6320 (produced by OMNOVA; fluorinated).

(Solvent)

A1: propylene glycol monomethyl ether acetate,

A2: cyclohexanone,

A3: γ-butyrolactone,

B1: propylene glycol monomethyl ether, and

B2: ethyl lactate.

(Dissolution Inhibiting Compound)

D-1: lithocholic acid t-butylate.

Table 4 attests to the excellence of the compositions of the present invention in the roughness characteristics, exposure latitude and development defect performance under ArF dry exposure.

<(2) ArF Liquid-Immersion Exposure>

(Preparation of Resist)

The components indicated in Table 5 below were dissolved in the solvents indicated in the same table, thereby obtaining solutions of 5 mass % solid content. The thus obtained solutions were passed through a polyethylene filter of 0.1 μm pore size, thereby obtaining positive resist compositions.

(Evaluation of Resist)

An organic antireflection film ARC29A (produced by Nissan Chemical Industries, Ltd.) was applied onto a silicon wafer and baked at 205° C. for 60 seconds, thereby forming a 98 nm thick antireflection film on the silicon wafer. Each of the above prepared positive resist solutions was applied thereonto and baked at 130° C. for 60 seconds; thereby forming a 120 nm thick resist film.

Each of the obtained resist films was patternwise exposed by means of an ArF excimer laser liquid immersion scanner (manufactured by ASML, XT1700i, NA 1.20, C-Quad, outer sigma 0.981, inner sigma 0.895, XY deflection). A 6% half-tone mask of 65 nm line size and 1:1 line:space was used as a rectile. Ultrapure water was used as the liquid for liquid immersion.

The exposed resist film was baked at 130° C. for 60 seconds and developed with a 2.38 mass % aqueous tetramethylammonium hydroxide solution for 30 seconds.

Thereafter, the developed resist film was rinsed with pure water and spin dried, thereby obtaining a resist pattern. The LWR, EL and number of development defects thereof were evaluated in the same manner as described above. The number of development defects was determined as a relative value to the number of development defects in Example 22 which was normalized as 1.

The obtained evaluation results are given in Table 5 below.

TABLE 5

| | | | Acid | Basic | | Dissolution | Organic | Hydro- | | Sol- | | | EL/ | The number of |
|---|---|---|---|---|---|---|---|---|---|---|---|---|---|---|
| | | Poly- | gener- | com- | Surfac- | inhibiting | solvent | phobic | Addi- | vent | | | LWR | development |
| Exam- | Re- | mer | ator | pound | tant | compound | (mass | resin | tion | when | LWR | EL | (%/ | defects |
| ple | sist | (6.5 g) | (g) | (g) | (g) | (g) | ratio) | (g) | mode | TC | (nm) | (%) | nm) | (normalized) |
| 19 | 19 | 1 | z2(0.5) | DIA(0.07) | W-5(0.02) | — | A1/B1 | K-13 | TC | S-1 | 4.6 | 18.2 | 3.96 | 0.055 |
| | | | | | | | (8/2) | | | | | | | |
| 20 | 20 | 7 | z38(0.5) | PEA(0.05) | W-5(0.02) | — | A1/B1 | HR-26 (0.1) | added | — | 5.2 | 17.6 | 3.38 | 0.063 |
| | | | | | | | (8/2) | | | | | | | |
| 21 | 21 | 12 | z2(0.5) | DIA(0.1) | W-5(0.02) | D-1(0.1) | A1/B1 | HR-8 (0.5) | added | — | 5.4 | 17.0 | 3.15 | 0.055 |
| | | | | | | | (7/3) | | | | | | | |
| 22 | 22 | 14 | z38(0.5) | DIA(0.05) | W-5(0.02) | — | A1/B1 | HR-22 | TC | S-1 | 6.1 | 13.0 | 2.13 | 1 |
| | | | | | | | (8/2) | | | | | | | |
| 23 | 23 | 15 | z38(0.5) | DIA(0.05) | W-5(0.02) | — | A1/B1 | HR-26 (0.1) | added | — | 7.0 | 12.2 | 1.74 | 0.816 |
| | | | | | | | (8/2) | | | | | | | |

In the column “addition mode” of Table 5, “added” and “TC” are used to express the addition mode of hydrophobic resins. In Examples in which the expression “added” is made, hydrophobic resins were incorporated in the resist solutions. In Examples in which the expression “TC” is made, resist films were in advance formed from resist solutions containing no hydrophobic resins, and thereafter top coat (TC) protective layers containing hydrophobic resins were provided as upper layers thereof.

When the addition mode of hydrophobic resins was “TC,” the formation of each resist film was followed by the following procedure. The solvent indicated in the column “solvent when TC” was as follows.

S-1: 2-ethylbutanol.

<Method of Forming Top Coat>

Referring to Table 5, each hydrophobic resin was dissolved in the solvent, and the obtained solution was applied onto the above resist film by means of a spin coater. The applied solution was dried by heating at 115° C. for 60 seconds, thereby forming a 0.05 μm thick top coat layer. After the formation, the top coat was inspected with respect to any application irregularity, thereby ascertaining the uniform application of the top coat layer.

Table 5 attests to the excellence of the compositions of the present invention in the roughness characteristics, exposure latitude and development defect performance under ArF liquid immersion exposure.

<(3) KrF Exposure>

(Preparation of Resist)

The components indicated in Table 6 below were dissolved in the solvents indicated in the same table, thereby obtaining solutions of 10.0 mass % solid content. The thus obtained solutions were passed through a polyethylene filter of 0.1 μm pore size, thereby obtaining positive resist compositions.

(Evaluation of Resist)

Each of the above positive resist solutions was applied onto a silicon substrate having undergone a hexamethyldisilazane treatment by means of a spin coater, and baked at 90° C. for 90 seconds, thereby obtaining a resist film of 400 nm average thickness.

Each of the obtained resist films was patternwise exposed by means of a KrF excimer laser scanner (manufactured by ASML, PAS5500/850C, wavelength=248 nm, NA=0.60, Sigma=0.70). A binary mask was used as a rectile.

The exposed resist film was baked at 110° C. for 60 seconds. The baked film was dipped in a 2.38 mass % aqueous tetramethylammonium hydroxide solution for 60 seconds. After this development operation, the individual film was rinsed with pure water for 30 seconds and dried, thereby obtaining a line pattern.

[Roughness Characteristic: LWR]

A line pattern of 150 nm line width (line:space=1:1) was observed by means of a scanning electron microscope (model S-9260, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LWR (nm).”

[Exposure Latitude (EL)]

The exposure amount that reproduced a line and space (line:space=1:1) mask pattern of 150 nm line width was determined, and this exposure amount was denoted as optimum exposure amount Eopt. Thereafter, the exposure amounts that caused the line width to become ±10% of the target 150 nm (namely, 135 nm and 165 nm) were determined. Then, the exposure latitude (EL) defined by the following formula was calculated. The greater the value of EL, the less the change of performance by exposure amount changes.

[EL(%)]=[(exposure amount for 135 nm line width)−(exposure amount for 165 nm line width)]/Eopt

[Development Defect Performance: Number of Defects]

Each of the above positive resist solutions was uniformly applied onto an 8-inch silicon substrate having undergone a hexamethyldisilazane treatment by means of a spin coater, and dried by heating on a hot plate at 120° C. for 60 seconds, thereby obtaining a 0.10 μm thick resist film. This resist film without being exposed was baked on a hot plate at 110° C. for 90 seconds, developed with a 2.38 mass % aqueous solution of tetramethylammonium hydroxide at 23° C. for 60 seconds, rinsed with pure water for 30 seconds and dried. On the thus obtained individual sample wafer, the number of development defects was counted by means of an instrument KLA-2360 (manufactured by KLA-Tencor Corporation). Table 6 below shows the count results as relative values to the number of defects in Example 26 which was normalized as 1. The smaller the value, the higher the development defect performance.

The obtained evaluation results are given in Table 6 below.

TABLE 6

| | | | | | | | | | | The number of |
|---|---|---|---|---|---|---|---|---|---|---|
| | | | Acid | Basic | | Organic | | | | development |
| | | Polymer | generator | compound | Surfactant | solvent | LWR | EL | EL/LWR | defects |
| Example | Resist | (6.5 g) | (g) | (g) | (g) | (mass ratio) | (nm) | (%) | (%/nm) | (normalized) |
| 24 | 24 | 16 | z2(0.5) | DIA(0.07) | W-5(0.02) | A1/B1 | 8.8 | 18.0 | 2.05 | 0.061 |
| | | | | | | (8/2) | | | | |
| 25 | 25 | 17 | z38(0.5) | DIA(0.05) | W-5(0.02) | A1/B1 | 8.6 | 16.9 | 1.97 | 0.062 |
| | | | | | | (8/2) | | | | |

| | | | | | | | | |
|---|---|---|---|---|---|---|---|---|
| 26 | 26 | 18 | z38(0.5) | DIA(0.05) | W-5(0.02) | A1/B1 | * | 1 |
| | | | | | | (8/2) | | |

* Pattern with 150 nm L/S cannot be formed.

Table 6 attests to the excellence of the compositions of the present invention in the roughness characteristics, exposure latitude and development defect performance under KrF exposure.

<(4) EUV Exposure>

(Preparation of Resist)

The same positive resist solutions as described in (3) KrF exposure except that the solid content was changed to 4.0 mass % were prepared.

(Evaluation of Resist)

Each of the above positive resist solutions was applied onto a silicon substrate having undergone a hexamethyldisilazane treatment by means of a spin coater, and baked at 100° C. for 90 seconds, thereby obtaining a resist film of 100 nm average thickness.

Each of the resist films was patternwise exposed using EUV light (wavelength: 13 nm, EUVES, manufactured by Lithotrack Japan). The exposed resist film was baked at 110° C. for 60 seconds. The baked resist film was developed with a 2.38 mass % aqueous tetramethylammonium hydroxide solution.

The exposure to EUV light was carried out while changing the exposure amount 0.5 by 0.5 mJ/cm² within the range of 0 to 20.0 mJ/cm². The rate of dissolution of the resist film into the developer was measured with respect to each of the exposure amounts. Thus, a dissolution rate curve showing the relationship between exposure amount and dissolution rate was obtained.

[Sensitivity and Resolving Power]

The “sensitivity” was defined as the exposure amount at which the dissolution rate was saturated on the dissolution rate curve. The dissolution contrast (γ-value) was calculated from the gradient of the straight line portion of the dissolution rate curve. It was judged that the larger the γ-value, the more favorable the dissolution contrast and the higher the resolving power.

The obtained evaluation results are given in Table 7 below.

TABLE 7

| | | Sensitivity | |
|---|---|---|---|
| Example | Resist | (mJ/cm²) | γ |
| 27 | 24 | 3.1 | 6.3 |
| 28 | 25 | 2.5 | 7.8 |
| 29 | 26 | * | * |

*Change in exposure amount did not affect the dissolution rate

Table 7 attests to the excellence of the compositions of the present invention in the sensitivity and resolving power under EUV exposure.

<(5) EB Exposure>

(Preparation of Resist)

The same positive resist solutions as described in (3) KrF exposure except that the solid content was changed to 4.0 mass % were prepared.

(Evaluation of Resist)

Each of the above positive resist solutions was applied onto a silicon substrate having undergone a hexamethyldisilazane treatment by means of a spin coater, and baked at 100° C. for 90 seconds, thereby obtaining a resist film of 100 nm average thickness.

Each of the resist films was patternwise exposed by means of an electron beam lithography system (model HL750 manufactured by Hitachi, Ltd., acceleration voltage: 50 KeV). The exposed resist film was baked at 110° C. for 60 seconds. The baked film was dipped in a 2.38 mass % aqueous tetramethylammonium hydroxide solution for 60 seconds. After this development operation, the individual film was rinsed with pure water for 30 seconds and dried, thereby obtaining a line pattern.

[Sensitivity]

Each of the obtained patterns was observed by means of a scanning electron microscope (model S-9220, manufactured by Hitachi, Ltd.). The “sensitivity” was defined as the exposure energy at which a line pattern of 100 nm line width (line:space=1:1) could be resolved.

[Resolving Power]

In the resolution of a line pattern of line:space=1:1 with the exposure energy equal to the above sensitivity, the minimum of the width of resolvable line was determined by observation by means of the above scanning electron micrograph. The “resolving power” was defined as the minimum of the line width.

[Roughness Characteristic: LER]

A line pattern of 100 nm line width (line:space=1:1) formed with the exposure energy equal to the above sensitivity was observed by means of a scanning electron microscope (model S-9220, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LER (nm).”

The obtained evaluation results are given in Table 8 below.

TABLE 8

| | | | Acid | Basic | | Organic | | Resolving | |
|---|---|---|---|---|---|---|---|---|---|
| | | Polymer | generator | compound | Surfactant | solvent | Sensitivity | power | LER |
| Example | Resist | (6.5 g) | (g) | (g) | (g) | (mass ratio) | (μC/cm²) | (nm) | (nm) |
| 30 | 24 | 16 | z2(0.5) | DIA(0.07) | W-5(0.02) | A1/B1 | 25.0 | 65 | 5.0 |
| | | | | | | (8/2) | | | |
| 31 | 25 | 17 | z38(0.5) | DIA(0.05) | W-5(0.02) | A1/B1 | 24.5 | 65 | 4.8 |
| | | | | | | (8/2) | | | |

| | | | | | | | |
|---|---|---|---|---|---|---|---|
| 32 | 26 | 18 | z38(0.5) | DIA(0.05) | W-5(0.02) | A1/B1 | * |
| | | | | | | (8/2) | |

* Pattern with 100 nm L/S cannot be formed.

Table 8 attests to the excellence of the compositions of the present invention in the sensitivity, resolving power, and roughness characteristic under EB exposure.

<ArF Dry Exposure (Part 2)>

(Preparation of Resist)

The components indicated in Table 9 below were dissolved in the solvents indicated in the same table, thereby obtaining solutions of 5.0 mass % solid content. The thus obtained solutions were passed through a polyethylene filter of 0.1 μm pore size, thereby obtaining positive resist compositions.

(Evaluation of Resist)

An organic antireflection film ARC29A (produced by Nissan Chemical Industries, Ltd.) was applied onto a silicon wafer and baked at 205° C. for 60 seconds, thereby forming a 78 nm thick antireflection film on the silicon wafer. Each of the above prepared positive resist solutions was applied thereonto and baked at 90° C. for 60 seconds, thereby forming a 120 nm thick resist film.

Each of the obtained resist films was patternwise exposed by means of an ArF excimer laser scanner (manufactured by ASML, PAS5500/1100, NA0.75). A 6% half-tone mask of 75 nm line size and 1:1 line:space was used as a rectile. The exposed resist film was baked at 95° C. for 60 seconds and developed with a 2.38 mass % aqueous tetramethylammonium hydroxide solution for 30 seconds. The developed resist film was rinsed with pure water and spin dried, thereby obtaining a resist pattern.

[Roughness Characteristic: LWR]

A line pattern of 75 nm line width (line:space=1:1) was observed by means of a scanning electron microscope (model S-9380II, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LWR (nm).”

[Exposure Latitude (EL)]

The exposure amount that reproduced a line and space (line:space=1:1) mask pattern of 75 nm line width was determined, and this exposure amount was denoted as optimum exposure amount Eopt. Thereafter, the exposure amounts that caused the line width to become ±10% of the target 75 nm (namely, 82.5 nm and 67.5 nm) were determined. Then, the exposure latitude (EL) defined by the following formula was calculated. The greater the value of EL, the less the change of performance by exposure amount changes.

[EL(%)]=[(exposure amount for 67.5 nm line width)−(exposure amount for 82.5 nm line width)]/Eopt

[Development Defect Performance: Number of Defects]

Each of the above positive resist solutions was uniformly applied onto an 8-inch silicon substrate having undergone a hexamethyldisilazane treatment by means of a spin coater, and dried by heating on a hot plate at 90° C. for 60 seconds, thereby obtaining a 120 nm thick resist film. This resist film without being exposed was baked on a hot plate at 95° C. for 60 seconds, developed with a 2.38 mass % aqueous solution of tetramethylammonium hydroxide at 23° C. for 60 seconds, rinsed with pure water for 30 seconds and dried. On the thus obtained individual sample wafer, the number of development defects was counted by means of an instrument KLA-2360 (manufactured by KLA-Tencor Corporation). Table 9 below shows the count results as relative values to the number of defects in Example 2-46 which was normalized as 1. The smaller the value, the higher the development defect performance.

[Configuration of Pattern]

The shape of cross section of each line pattern of 75 nm line width (line:space=1:1) was observed by means of a scanning electron microscope (model S-4800, manufactured by Hitachi, Ltd.), and the pattern configuration was evaluated on the following criteria.

∘ (good): the shape of cross section was “rectangular” and no “trailing” was observed;

Δ (fairly good): the shape of cross section was “rectangular” but “trailing” was observed; and

x (bad): the shape of cross section was “round top” or “T-top.”

[Defocus Latitude (Depth of Focus DOF)]

Each of the obtained resist films was patternwise exposed by means of an ArF excimer laser scanner (manufactured by ASML, PAS5500/1100, NA0.75). A 6% half-tone mask of space size=100 nm and line:space=2:1 was used as a rectile. The exposed resist film was baked at 95° C. for 60 seconds and developed with a 2.38 mass % aqueous tetramethylammonium hydroxide solution for 30 seconds. The thus developed resist film was rinsed with pure water and spin dried, thereby obtaining a resist pattern.

The space pattern of 100 nm line width (line:space=2:1) was observed by means of a scanning electron microscope (model S-938011, manufactured by Hitachi, Ltd.). The focal depth breadth that reproduced line widths of 100 nm±10% was measured as DOF (μm). The larger the value, the desirably greater the defocus latitude.

The obtained evaluation results are given in Table 9 below.

TABLE 9

| | | | | | | Organic | | | | | Configu- | The number of |
|---|---|---|---|---|---|---|---|---|---|---|---|---|
| | | | Acid | Basic | Surfac- | solvent | | | | | ration | development |
| Exam- | Re- | Polymer | generator | compound | tant | (mass | LWR | EL | EL/LWR | DOF | of | defects |
| ple | sist | (6.5 g) | (g) | (g) | (g) | ratio) | (nm) | (%) | (%/nm) | (μm) | pattern | (normalized) |
| 2-1 | 2-1 | 1 | Z92(0.5) | DIA/PEA | W-3(0.02) | A1/A2/B1 | 4.5 | 18.5 | 4.11 | 0.21 | ∘ | 0.051 |
| | | | | (0.04/0.03) | | (7/1/2) | | | | | | |
| 2-2 | 2-2 | 1 | Z90(0.5) | TMEA(0.05) | W-1(0.02) | A1/B1 | 4.8 | 18.2 | 3.79 | 0.21 | ∘ | 0.059 |
| | | | | | | (8/2) | | | | | | |
| 2-3 | 2-3 | 1/2 | Z76(0.5) | TEA(0.05) | W-5(0.02) | A1/B1 | 5.3 | 17.3 | 3.26 | 0.18 | ∘ | 0.063 |
| | | (5 g/1.5 g) | | | | (8/2) | | | | | | |
| 2-4 | 2-4 | 1 | Z66/Z40 | DIA(0.05) | W-3(0.02) | A1/B1 | 4.8 | 17.8 | 3.71 | 0.21 | ∘ | 0.058 |
| | | | (0.25/0.25) | | | (8/2) | | | | | | |
| 2-5 | 2-5 | 2 | Z92(0.5) | TEA(0.05) | W-5(0.02) | A1/B1 | 4.7 | 18.4 | 3.91 | 0.18 | ∘ | 0.065 |
| | | | | | | (8/2) | | | | | | |
| 2-6 | 2-6 | 2/9 | Z90(0.5) | TMEA(0.05) | W-3(0.02) | A1/B2 | 4.9 | 18.0 | 3.67 | 0.21 | ∘ | 0.069 |
| | | (3.5 g/3.0 g) | | | | (9/1) | | | | | | |
| 2-7 | 2-7 | 2 | Z66(0.5) | DBA(0.05) | W-4(0.02) | A1/B1 | 5.1 | 18.1 | 3.55 | 0.21 | ∘ | 0.072 |
| | | | | | | (8/2) | | | | | | |
| 2-8 | 2-8 | 2 | Z90/Z92 | DIA(0.05) | W-5(0.02) | A1/B1 | 4.8 | 18.2 | 3.79 | 0.21 | ∘ | 0.069 |
| | | | (0.4/0.2) | | | (7/3) | | | | | | |
| 2-9 | 2-9 | 3 | Z92(0.5) | DHA(0.05) | W-3(0.02) | A1/B1 | 4.6 | 18.4 | 4.00 | 0.21 | ∘ | 0.064 |
| | | | | | | (8/2) | | | | | | |
| 2-10 | 2-10 | 4 | Z60(0.5) | DIA(0.05) | W-2(0.02) | A1/B1 | 5.0 | 17.9 | 3.58 | 0.21 | ∘ | 0.056 |
| | | | | | | (9/1) | | | | | | |
| 2-11 | 2-11 | 5 | Z76(0.5) | DBA(0.05) | W-5(0.02) | A1/B1 | 5.3 | 17.2 | 3.25 | 0.18 | ∘ | 0.061 |
| | | | | | | (8/2) | | | | | | |
| 2-12 | 2-12 | 6 | Z44(0.5) | DIA/DHA | W-1(0.02) | A1/B2 | 5.1 | 16.8 | 3.29 | 0.18 | ∘ | 0.064 |
| | | | | (0.04/0.01) | | (9/1) | | | | | | |
| 2-13 | 2-13 | 7 | Z92(0.5) | DIA(0.05) | W-5(0.02) | A1/B1 | 4.9 | 18.1 | 3.69 | 0.21 | ∘ | 0.058 |
| | | | | | | (8/2) | | | | | | |
| 2-14 | 2-14 | 8 | Z40(0.5) | DHA(0.05) | W-2(0.02) | A1/A3/B1 | 5.0 | 17.6 | 3.52 | 0.18 | ∘ | 0.053 |
| | | | | | | (7/1/2) | | | | | | |
| 2-15 | 2-15 | 9 | Z92(0.5) | TMEA(0.05) | W-5(0.02) | A1/B1 | 4.8 | 17.9 | 3.73 | 0.21 | ∘ | 0.051 |
| | | | | | | (8/2) | | | | | | |
| 2-16 | 2-16 | 9 | Z66(0.5) | TEA(0.05) | W-3(0.02) | A1/B2 | 5.1 | 17.8 | 3.49 | 0.21 | ∘ | 0.049 |
| | | | | | | (9/1) | | | | | | |
| 2-17 | 2-17 | 10 | Z90(0.5) | DIA(0.05) | W-2(0.02) | A1 | 4.9 | 17.7 | 3.61 | 0.21 | ∘ | 0.057 |
| 2-18 | 2-18 | 11 | Z60(0.5) | PBI/DIA | W-5(0.02) | A1/A2/B1 | 4.9 | 17.5 | 3.57 | 0.18 | ∘ | 0.054 |
| | | | | (0.02/0.03) | | (8/1/1) | | | | | | |
| 2-19 | 2-19 | 12 | Z92(0.5) | DHA(0.05) | W-4(0.02) | A1/B2 | 4.8 | 17.8 | 3.71 | 0.18 | ∘ | 0.056 |
| | | | | | | (9/1) | | | | | | |
| 2-20 | 2-20 | 13 | Z60(0.5) | DIA(0.05) | W-5(0.02) | A1/B1 | 4.9 | 17.3 | 3.53 | 0.15 | ∘ | 0.059 |
| | | | | | | (7/3) | | | | | | |
| 2-21 | 2-21 | 19 | Z92(0.5) | TMEA(0.05) | W-5(0.02) | A1/B2 | 4.5 | 18.4 | 4.09 | 0.21 | ∘ | 0.057 |
| | | | | | | (9/1) | | | | | | |
| 2-22 | 2-22 | 19 | Z90(0.5) | DIA(0.05) | W-5(0.02) | A1/B1 | 5.0 | 18.2 | 3.64 | 0.21 | ∘ | 0.063 |
| | | | | | | (8/2) | | | | | | |
| 2-23 | 2-23 | 19 | Z90/Z92 | TEA(0.05) | W-3(0.02) | A1/A2/B1 | 4.7 | 18.3 | 3.89 | 0.21 | ∘ | 0.059 |
| | | | (0.4/0.2) | | | (8/1/1) | | | | | | |
| 2-24 | 2-24 | 19 | Z76(0.5) | DIA/PEA | W-1(0.02) | A1/B2 | 5.2 | 17.6 | 3.38 | 0.21 | ∘ | 0.064 |
| | | | | (0.03/0.04) | | (9/1) | | | | | | |
| 2-25 | 2-25 | 19 | Z66(0.5) | DHA(0.05) | W-5(0.02) | A1/B1 | 5.1 | 17.9 | 3.51 | 0.21 | ∘ | 0.063 |
| | | | | | | (8/2) | | | | | | |
| 2-26 | 2-26 | 20 | Z66/Z40 | DIA(0.05) | W-3(0.02) | A1/B1 | 5.3 | 17.8 | 3.36 | 0.21 | ∘ | 0.064 |
| | | | (0.25/0.25) | | | (8/2) | | | | | | |
| 2-27 | 2-27 | 20 | Z92(0.5) | TMEA(0.05) | W-5(0.02) | A1/B1 | 4.8 | 18.0 | 3.75 | 0.21 | ∘ | 0.058 |
| | | | | | | (8/2) | | | | | | |
| 2-28 | 2-28 | 20 | Z90(0.5) | DIA/DBA | W-3(0.02) | A1/B2 | 5.0 | 17.8 | 3.56 | 0.21 | ∘ | 0.06 |
| | | | | (0.03/0.02) | | (9/1) | | | | | | |
| 2-29 | 2-29 | 20 | Z60(0.5) | TEA(0.05) | W-4(0.02) | A1/B1 | 5.1 | 17.7 | 3.47 | 0.18 | ∘ | 0.062 |
| | | | | | | (8/2) | | | | | | |
| 2-30 | 2-30 | 20 | Z90(0.5) | DIA(0.05) | W-5(0.02) | A1/B1 | 4.9 | 17.9 | 3.65 | 021 | ∘ | 0.058 |
| | | | | | | (7/3) | | | | | | |
| 2-31 | 2-31 | 21 | Z60(0.5) | DHA(0.05) | W-3(0.02) | A1/B1 | 5.2 | 17.5 | 3.37 | 0.18 | ∘ | 0.045 |
| | | | | | | (8/2) | | | | | | |
| 2-32 | 2-32 | 21 | Z92(0.5) | DIA(0.05) | W-2(0.02) | A1/A2/B1 | 4.9 | 18.0 | 3.67 | 0.21 | ∘ | 0.049 |
| | | | | | | (7/1/2) | | | | | | |
| 2-33 | 2-33 | 22 | Z66(0.5) | DBA(0.05) | W-5(0.02) | A1/B1 | 5.2 | 17.8 | 3.42 | 0.18 | ∘ | 0.053 |
| | | | | | | (8/2) | | | | | | |
| 2-34 | 2-34 | 22 | Z44(0.5) | DIA(0.05) | W-1(0.02) | A1/A2/B1 | 5.3 | 17.4 | 3.28 | 0.15 | ∘ | 0.061 |
| | | | | | | (7/1/2) | | | | | | |
| 2-35 | 2-35 | 23 | Z92(0.5) | DBA(0.05) | W-5(0.02) | A1/B1 | 5.0 | 17.9 | 3.58 | 0.18 | ∘ | 0.057 |
| | | | | | | (8/2) | | | | | | |
| 2-36 | 2-36 | 23 | Z40(0.5) | DIA(0.05) | W-2(0.02) | A1/A3/B1 | 5.5 | 17.3 | 3.15 | 0.15 | ∘ | 0.055 |
| | | | | | | (7/1/2) | | | | | | |
| 2-37 | 2-37 | 24 | Z92(0.5) | DHA(0.05) | W-5(0.02) | A1/B1 | 5.1 | 17.6 | 3.45 | 0.21 | ∘ | 0.054 |
| | | | | | | (8/2) | | | | | | |
| 2-38 | 2-38 | 24 | Z66(0.5) | TMEA(0.05) | W-3(0.02) | A1/B2 | 5.2 | 17.7 | 3.40 | 0.21 | ∘ | 0.059 |
| | | | | | | (9/1) | | | | | | |
| 2-39 | 2-39 | 25 | Z92(0.5) | TEA(0.05) | W-2(0.02) | A1 | 5.0 | 17.9 | 3.58 | 0.21 | ∘ | 0.058 |
| 2-40 | 2-40 | 26 | Z76(0.5) | PBI/DIA | W-5(0.02) | A1/B1 | 5.4 | 17.7 | 3.28 | 0.21 | ∘ | 0.053 |
| | | | | (0.01/0.04) | | (9/1) | | | | | | |
| 2-41 | 2-41 | 26 | Z92(0.5) | DIA(0.05) | W-4(0.02) | A1/B2 | 4.9 | 17.8 | 3.63 | 0.21 | ∘ | 0.055 |
| | | | | | | (9/1) | | | | | | |
| 2-42 | 2-42 | 27 | Z60(0.5) | DIA/TEA | W-5(0.02) | A1/B1 | 5.3 | 17.6 | 3.32 | 0.21 | ∘ | 0.059 |
| | | | | (0.04/0.01) | | (7/3) | | | | | | |
| 2-43 | 2-43 | 31 | Z66(0.5) | DIA(0.05) | W-1(0.02) | A1/B1 | 5.0 | 18.0 | 3.60 | 0.21 | ∘ | 0.054 |
| | | | | | | (9/1) | | | | | | |
| 2-44 | 2-44 | 31 | Z90(0.5) | DBA(0.05) | W-3(0.02) | A1/B1 | 4.9 | 18.1 | 3.69 | 0.21 | ∘ | 0.052 |
| | | | | | | (8/2) | | | | | | |
| 2-45 | 2-45 | 32 | Z92(0.5) | DIA(0.05) | W-4(0.02) | A1/A2/B1 | 5.3 | 17.8 | 3.36 | 0.15 | ∘ | 0.061 |
| | | | | | | (7/1/2) | | | | | | |
| 2-46 | 2-46 | 14 | Z38(0.5) | DIA(0.05) | W-5(0.02) | A1/B1 | 6.2 | 12.8 | 2.06 | 0.09 | x | 1 |
| | | | | | | (8/2) | | | | | | |

<ArF Liquid-Immersion Exposure (Part 2)>

(Preparation of Resist)

The components indicated in Table 10 below were dissolved in the solvents indicated in the same table, thereby obtaining solutions of 5 mass % solid content. The thus obtained solutions were passed through a polyethylene filter of 0.1 μm pore size, thereby obtaining positive resist compositions.

(Evaluation of Resist)

An organic antireflection film ARC29A (produced by Nissan Chemical Industries, Ltd.) was applied onto a silicon wafer and baked at 205° C. for 60 seconds, thereby forming a 98 nm thick antireflection film on the silicon wafer. Each of the above prepared positive resist solutions was applied thereonto and baked at 90° C. for 60 seconds, thereby forming a 120 nm thick resist film.

Each of the obtained resist films was patternwise exposed by means of an ArF excimer laser liquid immersion scanner (manufactured by ASML, XT1700i, NA 1.20, C-Quad, outer sigma 0.960, inner sigma 0.709, XY deflection). A 6% half-tone mask of 65 nm line size and 1:1 line:space was used as a rectile. Ultrapure water was used as the liquid for liquid immersion.

The exposed resist film was baked at 95° C. for 60 seconds and developed with a 2.38 mass % aqueous tetramethylammonium hydroxide solution for 30 seconds. Thereafter, the developed resist film was rinsed with pure water and spin dried, thereby obtaining a resist pattern. The LWR, EL, configuration of pattern and number of development defects of each of the obtained resist patterns were evaluated in the same manner as described above. The number of development defects was determined as a relative value to the number of development defects in Example 3-28 which was normalized as 1. The defocus latitude was evaluated in the same manner as described above except that a space pattern of 75 nm line width (line:space=2:1) was observed.

The obtained evaluation results are given in Table 10 below.

In the column “addition mode” of Table 10, “added” and “TC” are used to express the addition mode of hydrophobic resins. In Examples in which the expression “added” is made, hydrophobic resins were incorporated in the resist solutions. In Examples in which the expression “TC” is made, resist films were in advance formed from resist solutions containing no hydrophobic resins, and thereafter top coat (TC) protective layers containing hydrophobic resins were provided as upper layers thereof.

When the addition mode of hydrophobic resins was “TC,” the formation of each resist film was followed by the following procedure. The solvent indicated in the column “solvent when TC” was as follows.

S-1: 2-ethylbutanol.

<Method of Forming Top Coat>

Referring to Table 10, each hydrophobic resin was dissolved in the solvent, and the obtained solution was applied onto the above resist film by means of a spin coater. The applied solution was dried by heating at 115° C. for 60 seconds, thereby forming a 0.05 μm thick top coat layer. After the formation, the top coat was inspected with respect to any application irregularity, thereby ascertaining the uniform application of the top coat layer.

TABLE 10

| | | | Acid | Basic | | Organic | Hydrophobic | |
|---|---|---|---|---|---|---|---|---|
| | | Polymer | generator | compound | Surfactant | solvent | resin | Addition |
| Example | Resist | (6.5 g) | (g) | (g) | (g) | (mass ratio) | (g) | mode |
| 3-1 | 3-1 | 1 | Z92 (0.5) | DIA/PEA | W-3 (0.02) | A1/A2/B1 | K-13 (0.1) | added |
| | | | | (0.04/0.03) | | (7/1/2) | | |
| 3-2 | 3-2 | 1/2 | Z76 (0.5) | TEA (0.05) | W-5 (0.02) | A1/B1 | HR-49 | TC |
| | | (5 g/1.5 g) | | | | (8/2) | | |
| 3-3 | 3-3 | 2 | Z92 (0.5) | TEA (0.05) | W-5 (0.02) | A1/B1 | HR-47 (0.1) | added |
| | | | | | | (8/2) | | |
| 3-4 | 3-4 | 3 | Z92 (0.5) | DHA (0.05) | W-3 (0.02) | A1/B1 | K-13 (0.1) | added |
| | | | | | | (8/2) | | |
| 3-5 | 3-5 | 4 | Z60 (0.5) | DIA (0.05) | W-2 (0.02) | A1/B1 | HR-22 | TC |
| | | | | | | (9/1) | | |
| 3-6 | 3-6 | 5 | Z76 (0.5) | DBA (0.05) | W-5 (0.02) | A1/BI | HR-22 | TC |
| | | | | | | (8/2) | | |
| 3-7 | 3-7 | 6 | Z44 (0.5) | DIA/DHA | W-1 (0.02) | A1/B2 | HR-49 | TC |
| | | | | (0.04/0.01) | | (9/1) | | |
| 3-8 | 3-8 | 7 | Z92 (0.5) | DIA (0.05) | W-5 (0.02) | A1/B1 | HR-47 (0.1) | added |
| | | | | | | (8/2) | | |
| 3-9 | 3-9 | 8 | Z40 (0.5) | DHA (0.05) | W-2 (0.02) | A1/A3/B1 | HR-22 | TC |
| | | | | | | (7/1/2) | | |
| 3-10 | 3-10 | 9 | Z92 (0.5) | TMEA (0.05) | W-5 (0.02) | A1/B1 | HR-53 (0.1) | added |
| | | | | | | (8/2) | | |
| 3-11 | 3-11 | 10 | Z90 (0.5) | DIA (0.05) | W-2 (0.02) | A1 | K-13 (0.1) | added |
| 3-12 | 3-12 | 11 | Z60 (0.5) | PBI/DIA | W-5 (0.02) | A1/A2/B1 | HR-26 (0.1) | added |
| | | | | (0.02/0.03) | | (8/1/1) | | |
| 3-13 | 3-13 | 12 | Z92 (0.5) | DHA (0.05) | W-4 (0.02) | A1/B2 | HR-47 (0.1) | added |
| | | | | | | (9/1) | | |
| 3-14 | 3-14 | 13 | Z60 (0.5) | DIA (0.05) | W-5 (0.02) | A1/B1 | HR-47 (0.1) | added |
| | | | | | | (7/3) | | |
| 3-15 | 3-15 | 19 | Z92 (0.5) | TMEA (0.05) | W-5 (0.02) | A1/B2 | HR-47 (0.1) | added |
| | | | | | | (9/1) | | |
| 3-16 | 3-16 | 19 | Z90/292 | TEA (0.05) | W-3 (0.02) | A1/A2/B1 | HR-47 (0.1) | added |
| | | | (0.4/0.2) | | | (8/1/1) | | |
| 3-17 | 3-17 | 20 | Z92 (0.5) | TMEA (0.05) | W-5 (0.02) | A1/B1 | HR-26 (0.1) | added |
| | | | | | | (8/2) | | |
| 3-18 | 3-18 | 20 | Z90 (0.5) | DIA/DBA | W-3 (0.02) | A1/B2 | HR-47 (0.1) | added |
| | | | | (0.03/0.02) | | (9/1) | | |
| 3-19 | 3-19 | 21 | Z92 (0.5) | DIA (0.05) | W-2 (0.02) | A1/A2/B1 | HR-53 (0.1) | added |
| | | | | | | (7/1/2) | | |
| 3-20 | 3-20 | 22 | Z66 (0.5) | DBA (0.05) | W-5 (0.02) | A1/B1 | HR-47 (0.1) | added |
| | | | | | | (8/2) | | |
| 3-21 | 3-21 | 23 | Z40 (0.5) | DIA (0.05) | W-2 (0.02) | A1/A3/B1 | HR-49 | TC |
| | | | | | | (7/1/2) | | |
| 3-22 | 3-22 | 24 | Z66 (0.5) | TMEA (0.05) | W-3 (0.02) | A1/B2 | HR-47 (0.1) | added |
| | | | | | | (9/1) | | |
| 3-23 | 3-23 | 25 | Z92 (0.5) | TEA (0.05) | W-2 (0.02) | A1 | K-13 (0.1) | added |
| 3-24 | 3-24 | 26 | Z92 (0.5) | DIA (0.05) | W-4 (0.02) | A1/B2 | HR-53 (0.1) | added |
| | | | | | | (9/1) | | |
| 3-25 | 3-25 | 27 | Z60 (0.5) | DIA/TEA | W-5 (0.02) | A1/B1 | HR-22 | TC |
| | | | | (0.04/0.01) | | (7/3) | | |
| 3-26 | 3-26 | 31 | Z90 (0.5) | DBA (0.05) | W-3 (0.02) | A1/B1 | K-13 (0.1) | added |
| | | | | | | (8/2) | | |
| 3-27 | 3-27 | 32 | Z92 (0.5) | DIA (0.05) | W-4 (0.02) | A1/A2/B1 | HR-26 (0.1) | added |
| | | | | | | (7/1/2) | | |
| 3-28 | 3-28 | 14 | Z38 (0.5) | DM (0.05) | W-5 (0.02) | A1/B1 | HR-22 | TC |
| | | | | | | (8/2) | | |

| | | | | | | | The number of |
|---|---|---|---|---|---|---|---|
| | Solvent | | | | | | development |
| | when | LWR | EL | EL/LWR | DOF | Configuration | defects |
| Example | TC | (nm) | (%) | (%/nm) | (μm) | of pattern | (normalized) |
| 3-1 | — | 4.6 | 18.4 | 4.00 | 0.15 | ∘ | 0.055 |
| 3-2 | S-1 | 5.2 | 17.1 | 3.29 | 0.15 | ∘ | 0.065 |
| 3-3 | — | 4.6 | 18.3 | 3.98 | 0.15 | ∘ | 0.059 |
| 3-4 | — | 4.4 | 18.3 | 4.16 | 0.15 | ∘ | 0.06 |
| 3-5 | S-1 | 4.8 | 18.0 | 3.75 | 0.15 | ∘ | 0.059 |
| 3-6 | S-1 | 5.1 | 17.3 | 3.39 | 0.15 | ∘ | 0.058 |
| 3-7 | S-1 | 4.9 | 16.9 | 3.45 | 0.12 | ∘ | 0.063 |
| 3-8 | — | 5.0 | 18.2 | 3.64 | 0.15 | ∘ | 0.055 |
| 3-9 | S-1 | 4.9 | 17.5 | 3.57 | 0.12 | ∘ | 0.051 |
| 3-10 | — | 4.9 | 17.8 | 3.63 | 0.15 | ∘ | 0.053 |
| 3-11 | — | 5.0 | 17.6 | 3.52 | 0.15 | ∘ | 0.055 |
| 3-12 | — | 4.8 | 17.4 | 3.63 | 0.12 | ∘ | 0.058 |
| 3-13 | — | 4.9 | 17.9 | 3.65 | 0.15 | ∘ | 0.057 |
| 3-14 | — | 4.7 | 17.2 | 3.66 | 0.15 | ∘ | 0.054 |
| 3-15 | — | 4.6 | 18.5 | 4.02 | 0.15 | ∘ | 0.056 |
| 3-16 | — | 4.6 | 18.2 | 3.96 | 0.15 | ∘ | 0.062 |
| 3-17 | — | 4.7 | 18.6 | 3.83 | 0.15 | ∘ | 0.059 |
| 3-18 | — | 5.1 | 17.9 | 3.51 | 0.15 | ∘ | 0.062 |
| 3-19 | — | 4.8 | 18.1 | 3.77 | 0.15 | ∘ | 0.051 |
| 3-20 | — | 5.1 | 17.9 | 3.51 | 0.12 | ∘ | 0.055 |
| 3-21 | S-1 | 5.6 | 17.5 | 3.13 | 0.12 | ∘ | 0.053 |
| 3-22 | — | 5.1 | 17.9 | 3.51 | 0.15 | ∘ | 0.057 |
| 3-23 | — | 4.9 | 17.5 | 3.57 | 0.15 | ∘ | 0.063 |
| 3-24 | — | 4.8 | 17.6 | 3.67 | 0.15 | ∘ | 0.059 |
| 3-25 | S-1 | 5.2 | 17.9 | 3.44 | 0.15 | ∘ | 0.057 |
| 3-26 | — | 4.9 | 18.1 | 3.69 | 0.15 | ∘ | 0.052 |
| 3-27 | — | 5.3 | 17.8 | 3.36 | 0.12 | ∘ | 0.061 |
| 3-28 | S-1 | 6.0 | 12.7 | 2.12 | 0.06 | x | 1 |

<KrF Exposure (Part 2)>

(Preparation of Resist)

The components indicated in Table 11 below were dissolved in the solvents indicated in the same table, thereby obtaining solutions of 10.0 mass % solid content. The thus obtained solutions were passed through a polyethylene filter of 0.1 μm pore size, thereby obtaining positive resist compositions.

(Evaluation of Resist)

Each of the above positive resist solutions was applied onto a silicon substrate having undergone a hexamethyldisilazane treatment by means of a spin coater, and baked at 90° C. for 90 seconds, thereby obtaining a resist film of 400 nm average thickness.

Each of the obtained resist films was patternwise exposed by means of a KrF excimer laser scanner (manufactured by ASML, PAS5500/850C, wavelength=248 nm, NA=0.60, Sigma=0.70). A binary mask was used as a rectile.

The exposed resist film was baked at 110° C. for 60 seconds. The baked film was dipped in a 2.38 mass % aqueous tetramethylammonium hydroxide solution for 60 seconds. After this development operation, the individual film was rinsed with pure water for 30 seconds and dried, thereby obtaining a line pattern.

[Roughness Characteristic: LWR]

A line pattern of 150 nm line width (line:space=1:1) was observed by means of a scanning electron microscope (model S-8840, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LWR (nm).”

[Exposure Latitude (EL)]

The exposure amount that reproduced a line and space (line:space=1:1) mask pattern of 150 nm line width was determined, and this exposure amount was denoted as optimum exposure amount Eopt. Thereafter, the exposure amounts that caused the line width to become ±10% of the target 150 nm (namely, 135 nm and 165 nm) were determined. Then, the exposure latitude (EL) defined by the following formula was calculated. The greater the value of EL, the less the change of performance by exposure amount changes.

[EL(%)]=[(exposure amount for 135 nm line width)−(exposure amount for 165 nm line width)]/Eopt

[Development Defect Performance: Number of Defects]

Each of the above positive resist solutions was uniformly applied onto an 8-inch silicon substrate having undergone a hexamethyldisilazane treatment by means of a spin coater, and dried by heating on a hot plate at 90° C. for 90 seconds, thereby obtaining a 400 nm thick resist film. This resist film without being exposed was baked on a hot plate at 110° C. for 60 seconds, developed with a 2.38 mass % aqueous solution of tetramethylammonium hydroxide at 23° C. for 60 seconds, rinsed with pure water for 30 seconds and dried. On the thus obtained individual sample wafer, the number of development defects was counted by means of an instrument KLA-2360 (manufactured by KLA-Tencor Corporation). Table 11 below shows the count results as relative values to the number of defects in Example 4-8 which was normalized as 1. The smaller the value, the higher the development defect performance.

The obtained evaluation results are given in Table 11 below.

TABLE 11

| | | | | | | | | | | The number of |
|---|---|---|---|---|---|---|---|---|---|---|
| | | | Acid | Basic | | Organic | | | | development |
| | | Polymer | generator | compound | Surfactant | solvent | LWR | EL | EL/LWR | defects |
| Example | Resist | (6.5 g) | (g) | (g) | (g) | (mass ratio) | (nm) | (%) | (%/nm) | (normalized) |
| 4-1 | 4-1 | 16 | z66(0.5) | TEA(0.05) | W-1(0.02) | A1/A2/B1 | 8.2 | 18.8 | 2.29 | 0.059 |
| | | | | | | (7/1/2) | | | | |
| 4-2 | 4-2 | 28 | z60(0.5) | DIA/DHA | W-3(0.02) | A1/B1 | 8.1 | 18.2 | 2.25 | 0.055 |
| | | | | (0.04/0.01) | | (8/2) | | | | |
| 4-3 | 4-3 | 28 | z90(0.5) | DIA(0.05) | W-5(0.02) | A1/B2 | 8.3 | 18.9 | 2.28 | 0.061 |
| | | | | | | (9/1) | | | | |
| 4-4 | 4-4 | 29 | z66(0.5) | TMEA(0.05) | W-5(0.02) | A1 | 8.4 | 18.7 | 2.23 | 0.058 |
| 4-5 | 4-5 | 29 | z90(0.5) | DHA(0.05) | W-4(0.02) | A1/B1 | 8.1 | 18.8 | 2.32 | 0.057 |
| | | | | | | (9/1) | | | | |
| 4-6 | 4-6 | 30 | z60/z90 | DBA(0.05) | W-5(0.02) | A1/B1 | 8.3 | 18.5 | 2.23 | 0.062 |
| | | | (0.3/0.2) | | | (8/2) | | | | |
| 4-7 | 4-7 | 30 | z66(0.5) | TEA(0.05) | W-2(0.02) | A1/A3/B1 | 8.2 | 18.6 | 2.27 | 0.063 |
| | | | | | | (7/1/2) | | | | |

| | | | | | | | | |
|---|---|---|---|---|---|---|---|---|
| 4-8 | 4-8 | 18 | z38(0.5) | DIA(0.05) | W-5(0.02) | A1/B1 | * | 1 |
| | | | | | | (8/2) | | |

* Pattern with 150 nm L/S cannot be formed.

<EB Exposure (Part 2)>

(Preparation of Resist)

The same positive resist solutions as described in KrF exposure (part 2) except that the solid content was changed to 4.0 mass % were prepared.

(Evaluation of Resist)

Each of the above positive resist solutions was applied onto a silicon substrate having undergone a hexamethyldisilazane treatment by means of a spin coater, and baked at 100° C. for 90 seconds, thereby obtaining a resist film of 100 nm average thickness.

Each of the resist films was patternwise exposed by means of an electron beam lithography system (model HL750 manufactured by Hitachi, Ltd., acceleration voltage: 50 KeV). The exposed resist film was baked at 110° C. for 60 seconds. The baked film was dipped in a 2.38 mass % aqueous tetramethylammonium hydroxide solution for 60 seconds. After this development operation, the individual film was rinsed with pure water for 30 seconds and dried, thereby obtaining a line pattern.

[Sensitivity].

Each of the obtained patterns was observed by means of a scanning electron microscope (model S-9220, manufactured by Hitachi, Ltd.). The “sensitivity” was defined as the exposure energy at which a line pattern of 100 nm line width (line:space=1:1) could be resolved.

[Resolving Power]

In the resolution of a line pattern of line:space=1:1 with the exposure energy equal to the above sensitivity, the minimum of the width of resolvable line was determined by observation by means of the above scanning electron micrograph. The “resolving power” was defined as the minimum of the line width.

[Roughness Characteristic: LER]

A line pattern of 100 nm line width (line:space=1:1) formed with the exposure energy equal to the above sensitivity was observed by means of a scanning electron microscope (model S-9220, manufactured by Hitachi, Ltd.). The distance between actual edge and a reference line on which edges were to be present was measured at 50 points of equal intervals within 2 μm in the longitudinal direction along the edges. The standard deviation of measured distances was determined, and 3σ was computed therefrom. This 3σ was denoted as “LER (nm).”

The obtained evaluation results are given in Table 12 below.

TABLE 12

| | | | Acid | Basic | | Organic | | Resolving | |
|---|---|---|---|---|---|---|---|---|---|
| | | Polymer | generator | compound | Surfactant | solvent | Sensitivity | power | LER |
| Example | Resist | (6.5 g) | (g) | (g) | (g) | (mass ratio) | (μC/cm²) | (nm) | (nm) |
| 5-1 | 5-1 | 16/28 | z66(0.5) | TBAH(0.07) | W-5(0.02) | A1/B1 | 24.8 | 65 | 4.8 |
| | | (3.5 g/3.0 g) | | | | (8/2) | | | |
| 5-2 | 5-2 | 28 | z60(0.5) | TOA(0.06) | W-4(0.02) | A1/A2/B1 | 22.7 | 65 | 4.7 |
| | | | | | | (7/1/2) | | | |
| 5-3 | 5-3 | 28 | z90(0.5) | TBAH(0.06) | W-3(0.02) | A1 | 23.4 | 60 | 4.6 |
| 5-4 | 5-4 | 29 | z66(0.5) | TBAH/TOA | W-1(0.02) | A1/B2 | 23.9 | 65 | 4.8 |
| | | | | (0.03/0.04) | | (9/1) | | | |
| 5-5 | 5-5 | 29 | z90(0.5) | TBAH(0.06) | W-5(0.02) | A1/A3/B1 | 23.6 | 60 | 4.6 |
| | | | | | | (7/1/2) | | | |
| 5-6 | 5-6 | 30 | z60/z90 | PBI/TOA | W-2(0.02) | A1/B1 | 23.0 | 65 | 4.9 |
| | | | (0.3/0.2) | (0.04/0.04) | | (9/1) | | | |
| 5-7 | 5-7 | 30 | z66(0.5) | TBAH(0.06) | W-5(0.02) | A1/B1 | 24.2 | 65 | 4.7 |
| | | | | | | (8/2) | | | |

What is claimed is:

1. An actinic-ray- or radiation-sensitive resin composition comprising:
a resin containing a repeating unit (A) containing both a structural moiety (S1) that is decomposed by an action of an acid to thereby generate an alkali-soluble group and a structural moiety (S2) that is decomposed by an action of an alkali developer to thereby increase its rate of dissolution into the alkali developer, and
a compound that generates an acid when exposed to actinic rays or radiation.

2. The composition according to claim 1, wherein the structural moiety (S2) contains a lactone structure.

3. The composition according to claim 2; wherein the structural moiety (S1) is bonded to at least one of the two carbon atoms neighboring the ester group as a constituent of the lactone structure.

4. The composition according to claim 3, wherein the repeating unit (A) contains any of the structures of general formula (1) below: 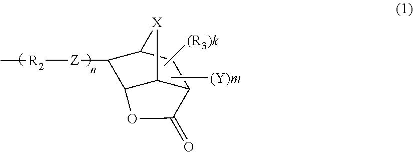
in which
R₂, each independently when n≧2, represents an alkylene group or a cycloalkylene group;
R₃, each independently when k≧2, represents an alkyl group or a cycloalkyl group, provided that when at least two of the R₃s may be bonded to each other to thereby form a ring;
X represents an alkylene group, an oxygen atom or a sulfur atom;
Y, each independently when m≧12, represents the structural moiety (S1);
Z, each independently when n≧2, represents a single bond, an ether bond, an ester bond, an amido bond, a urethane bond or a urea bond;
k is an integer of 0 to 5;
m is an integer of 1 to 5 satisfying a relationship m+k≦6; and
n is an integer of 0 to 5.

5. The composition according to claim 4, wherein the repeating unit (A) is any of those of general formula (PL-1) below: 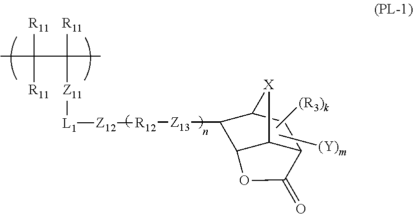
in which
each of R₁₁s independently represents a hydrogen atom, an alkyl group or a halogen atom;
R₁₂, each independently when n≧2, represents an alkylene group or a cycloalkylene group;
L₁ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;
R₃, each independently when k≧2, represents an alkyl group or a cycloalkyl group, provided that when k≧2, at least two of the R₃s may be bonded to each other to thereby form a ring;
X represents an alkylene group, an oxygen atom or a sulfur atom;
Y, each independently when m≧2, represents the structural moiety (S1);
each of Z₁₁ and Z₁₂ independently represents a single bond, —O—, —S—, —CO—, —SO₂—, —NR— (R is a hydrogen atom or an alkyl group), a bivalent nitrogenous nonaromatic heterocyclic group or a group consisting of a combination thereof;
Z₁₃, each independently when n≧2, represents a single bond, —O—, —S—, —CO—, —SO₂—, —NR— (R is a hydrogen atom or an alkyl group), a bivalent nitrogenous nonaromatic heterocyclic group or a group consisting of a combination thereof;
k is an integer of 0 to 5;
m is an integer of 1 to 5 satisfying a relationship m+k≦6; and
n is an integer of 0 to 5.

6. The composition according to claim 4, wherein the repeating unit (A) is any of those of general formula (2) below: 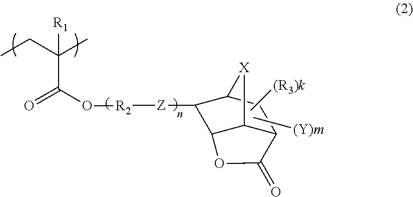
in which
R₁ represents a hydrogen atom, an alkyl group or a halogen atom;
R₂, each independently when n≧2, represents an alkylene group or a cycloalkylene group;
R₃, each independently when k≧2, represents an alkyl group or a cycloalkyl group, provided that when k≧2, at least two of the R₃s may be bonded to each other to thereby form a ring;
X represents an alkylene group, an oxygen atom or a sulfur atom;
Y, each independently when m≧2, represents the structural moiety (S1);
Z, each independently when n≧2, represents a single bond, an ether bond, an ester bond, an amido bond, a urethane bond or a urea bond;
k is an integer of 0 to 5;
m is an integer of 1 to 5 satisfying a relationship m+k≦6; and
n is an integer of 0 to 5.

7. The composition according to claim 6, wherein the repeating unit (A) is any of those of general formula (2A) below: 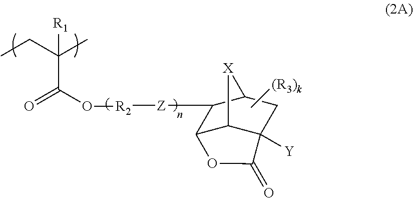
in which
R₁ represents a hydrogen atom, an alkyl group or a halogen atom;
R₂, each independently when n≧2, represents an alkylene group or a cycloalkylene group;
R₃, each independently when k≧2, represents an alkyl group or a cycloalkyl group, provided that when k≧2, at least two of the R₃s may be bonded to each other to thereby form a ring;
X represents an alkylene group, an oxygen atom or a sulfur atom;
Y, each independently when m≧2, represents the structural moiety (S1);
Z, each independently when n≧2, represents a single bond, an ether bond, an ester bond, an amido bond, a urethane bond or a urea bond;
k is an integer of 0 to 5; and
n is an integer of 0 to 5.

8. The composition according to claim 7, wherein the R₁ is a hydrogen atom or an alkyl group.

9. The composition according to claim 4, wherein the Y is any of the groups of formula (Y1) below: 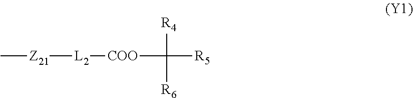
in which
Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;
L₂ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;
R₄ represents an alkyl group; and
each of R₅ and R₆ independently represents an alkyl group or a cycloalkyl group, provided that the R₅ and R₆ may be bonded to each other to thereby form a ring.

10. The composition according to claim 4, wherein the Y is any of the groups of formula (Y2) below: 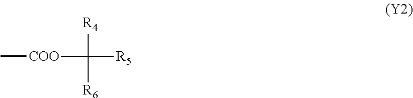
in which
R₄ represents an alkyl group; and
each of R₅ and R₆ independently represents an alkyl group or a cycloalkyl group, provided that the R₅ and R₆ may be bonded to each other to thereby form a ring.

11. The composition according to claim 4, wherein the Z is an ester bond.

12. The composition according to claim 7, wherein the repeating unit (A) is any of those of general formula (PL-2) below: 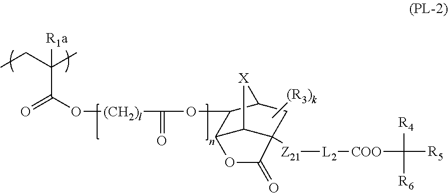
in which
R₁ₐ represents a hydrogen atom or an alkyl group;
R₃, each independently when k≧2, represents an alkyl group or a cycloalkyl group, provided that when k≧2, at least two of the R₃s may be bonded to each other to thereby form a ring;
X represents an alkylene group, an oxygen atom or a sulfur atom;
k is an integer of 0 to 5;
l is an integer of 1 to 5;
n is an integer of 0 to 5;
Z₂₁ represents a single bond, —O—, —S—, —CO—, —SO₂—, —NR— (R is a hydrogen atom or an alkyl group), a bivalent nitrogenous nonaromatic heterocyclic group or a group consisting of a combination thereof;
L₂ represents a single bond, an alkylene group, an alkenylene group, a cycloalkylene group, a bivalent aromatic ring group or a group consisting of a combination of two or more thereof, provided that in the group consisting of the combination, the two or more groups combined together may be identical to or different from each other, and also provided that the two or more groups may be linked together via a connecting group selected from the group consisting of —O—, —S—, —CO—, —SO₂—, —NR— (R is a hydrogen atom or an alkyl group), a bivalent nitrogenous nonaromatic heterocyclic group and a group consisting of a combination thereof;
R₄ represents an alkyl group; and
each of R₅ and R₆ independently represents an alkyl group or a cycloalkyl group, provided that the R₅ and R₆ may be bonded to each other to thereby form a ring.

13. The composition according to claim 7, wherein the repeating unit (A) is any of those of general formula (3) below: 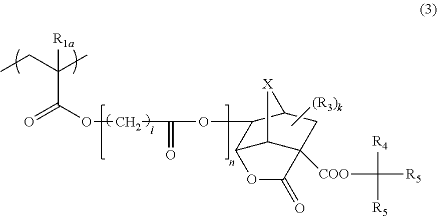
in which
R₁ₐ represents a hydrogen atom or an alkyl group;
R₃, each independently when k≧2, represents an alkyl group or a cycloalkyl group, provided that when k≧2, at least two of the R₃s may be bonded to each other to thereby form a ring;
R₄ represents an alkyl group;
each of R₅ and R₆ independently represents an alkyl group or a cycloalkyl group, provided that the R₅ and R₆ may be bonded to each other to thereby form a ring;
X represents an alkylene group, an oxygen atom or a sulfur atom;
k is an integer of 0 to 5;
l is an integer of 1 to 5; and
n is an integer of 0 to 5.

14. The composition according to claim 3, further comprising a hydrophobic resin.

15. A resist film formed from the composition according to claim 3.

16. A method of forming a pattern, comprising:
forming the composition according to claim 3 into a film;
exposing the film to light; and
developing the exposed film.

17. The method according to claim 16, wherein the exposure is performed through a liquid for liquid immersion.
